(19) United States
(12) Patent Application Publication
(10) Pub. No.: US 2025/0393474 A1
(43) Pub. Date: Dec. 25, 2025

(54) Boron-containing resonance-type organic compound and organic electroluminescent device containing the same

(71) Applicant: JIANGSU SUNERA TECHNOLOGY CO., LTD., Wuxi (CN)

(72) Inventors: Haojie Xu, Wuxi (CN); Xudong Cao, Wuxi (CN); Lian Duan, Wuxi (CN)

(73) Assignee: JIANGSU SUNERA TECHNOLOGY CO., LTD., Wuxi (CN)

(21) Appl. No.: 19/231,515

(22) Filed: Jun. 8, 2025

(30) Foreign Application Priority Data
Oct. 15, 2024 (CN) 202411435787.4

(51) Int. Cl. H10K 85/60; C07F 5/02; C09K 11/06; H10K 50/12; H10K 85/40; H10K 101/20

(52) U.S. Cl. CPC H10K 85/658; C07F 5/027; C09K 11/06; H10K 85/40; H10K 85/615; H10K 85/622; H10K 85/626; H10K 85/6574; H10K 85/6576; C09K 2211/1007; C09K 2211/1011; C09K 2211/1018; H10K 50/121; H10K 2101/20

(57) ABSTRACT

The present disclosure relates to a boron-containing resonance-type organic compound and an organic electroluminescent device containing the same, and belongs to the technical field of semiconductors. The structure of the compound provided by the present disclosure is as shown in general formula (1):

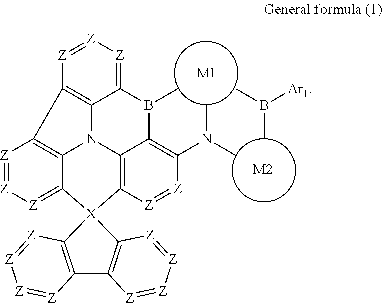

When the compound of the present disclosure is used as a doping material in a light-emitting layer material of an organic electroluminescent device, it can be used as a green light doping material in the light-emitting layer of the organic electroluminescent device, so that the service life of the device is prolonged.

### TECHNICAL FIELD

The present disclosure relates to the technical field of semiconductors, in particular to a boron-containing resonance-type organic compound and an organic electroluminescent device containing the same.

### BACKGROUND

Compared with liquid crystal display (LCD), the organic light-emitting diodes (OLEDs) have technical advantages such as lighter and thinner, high color contrast, low power consumption, fast response, high clarity, and flexibility, and is believed to dominate the future display terminal products. With the advent of the 5G era, the new information display industry is in urgent need of iterative development. The early lower color gamut standards (BT.709 and DCIP3) can no longer meet the high-quality technical development needs of display products. In order to achieve the performance requirements of ultra-high definition and higher picture quality of display products, the new generation of display standard (BT.2020) drives the OLED light-emitting materials to develop towards high color purity, which requires the core light-emitting materials to have a narrower emission spectrum. Among the current three commercialized OLED red, green and blue color rendering technologies, blue light uses traditional fluorescent triplet-triplet fusion (TTF) technology, which has low efficiency but high color purity and basically meets the BT.2020 display indicators; green light and red light use phosphorescence luminescent technology, which has high efficiency. Red light is close to the BT.2020 display indicators, however green light is limited by the wider luminescent spectrum of phosphorescence, which is quite different from the requirements of high-definition display indicators. Therefore, it is very critical to develop high-color-purity green light OLED materials.

Since 2020, green light materials with narrow half-peak width (half-peak width<30 nm) based on boron-nitrogen resonance structures have been reported one after another: DOI: 10.1002/adom.201902142, DOI: 10.1002/anie.202008264, DOI: 10.1021/jacs.0c10081, DOI: 10.1038/s41467-022-32607-3, DOI: 10.1002/anie.202202380, etc., showing the extremely high color purity and efficiency of such materials and becoming the development trend of high color purity green light OLED. However, there are still many technical difficulties in the development of green light ultra-high color purity materials containing boron and nitrogen structures. The existing materials also have the defects that their efficiency and service life cannot meet the needs of mass production. The development of narrow half-peak width green light materials based on boron and nitrogen resonance structures that can meet the practical applications is a key technical point for the next generation of display devices with high color purity, high color gamut coverage, high efficiency and high immersion sense.

In addition, the sensitization technology combines triplet state exciton-sensitizing materials (including but not limited to TADF materials and phosphorescent materials) with fluorescent doping materials, uses triplet state exciton-sensitizing materials as exciton-sensitizing media, and fully utilizes triplet state excitons to transfer energy to fluorescent doping materials through energy transfer, which can also achieve 100% quantum efficiency within devices. This technology can make up for the shortcomings of insufficient exciton utilization of fluorescent doping materials, and effectively give play to the characteristics of high fluorescence quantum yield, high device stability, high color purity and low price of fluorescent doping materials, and has broad prospects in the applications of OLEDs. For example, CN107507921A and CN110492006A disclose a light-emitting layer combination technology with the TADF materials with an energy level difference between the lowest singlet state and the lowest triplet state of less than or equal to 0.2 eV as the host materials and the boron-containing materials as the doping materials; CN110492005A and CN110492009A disclose a light-emitting layer combination scheme with an exciplex as the host materials and the boron-containing material as the doping materials; both of them can achieve efficiency comparable to phosphorescence and a relatively narrow half-peak width. Therefore, the development of sensitization technology based on narrow half-peak width boron-based light-emitting materials has unique advantages and strong potentials in terms of BT.2020 display indicators.

### SUMMARY

In view of the above technical problems in the prior art, the present disclosure provides a boron-containing resonance-type organic compound and an organic electroluminescent device containing the same, the compound in the present disclosure can emit green light when used as the doping material for the light-emitting layer of an organic electroluminescent device.

The technical solution of the present disclosure is as follows: a boron-containing resonance-type organic compound, and the structure of the boron-containing resonance-type organic compound is as shown in general formula (1):

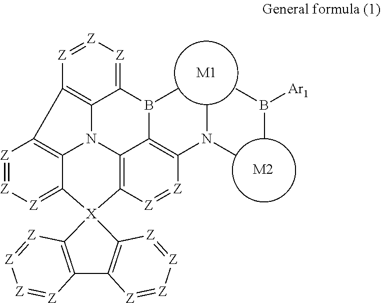

in the general formula (1), Z is the same or different at each occurrence and is represented by C—(H) or C—(R₀); R₀ is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
the M1 and M2 rings are represented by one of one or more R substituted or unsubstituted C₆-C₃₀ aromatic rings, one or more R substituted or unsubstituted C₂-C₃₀ heteroaromatic rings, one or more R substituted or unsubstituted C₆-C₃₀ aliphatic rings, and one or more R substituted or unsubstituted C₁₀-C₃₀ fused rings formed by fusing two or more of aromatic rings, heteroaromatic rings and aliphatic rings;
R is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted C₆-C₁₀ aryloxy group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
the substitution pattern of R is a single bond or a fused-ring connection;
Ar₁ is represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
any adjacent R₀ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the Ar₁ and M1 ring are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the Ar₁ and M2 ring are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
X is the same or different at each occurrence and is represented by one of a carbon atom or a silicon atom;
the substituents of the above-mentioned substitutable groups are optionally selected from any one or more of deuterium atoms, halogen atoms, cyano groups, C₁-C₁₀ alkyl groups, deuterium or tritium substituted C₁-C₁₀ alkyl groups, C₃-C₁₀ cycloalkyl groups, C₆-C₃₀ aryl groups, deuterium or tritium substituted C₆-C₃₀ aryl groups, C₅-C₃₀ heteroaryl groups, and deuterium or tritium substituted C₂-C₃₀ heteroaryl groups;
the heteroatoms in the heteroaryl groups are optionally selected from one or more of O, S, N, Si, and B.

Further, the structure of the boron-containing resonance-type organic compound is as shown in general formula (2):

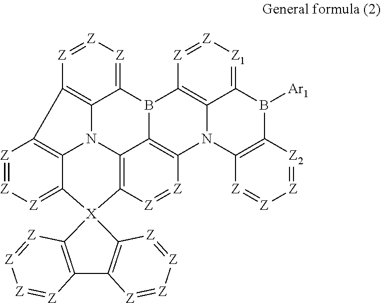

in the general formula (2), Z is the same or different at each occurrence and is represented by C—(H) or C—(R₀); R₀ is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Z₁ is represented by C—(H) or C—(Rₐ); Rₐ is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Z₂ is represented by C—(H) or C—(R_{b}); R_{b} is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Ar₁ is represented by one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
any adjacent R₀ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Ar₁ and Rₐ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Ar₁ and R_{b} are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented by one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
X is the same or different at each occurrence and is represented by one of a carbon atom or a silicon atom;
the substituents of the above-mentioned substitutable groups are optionally selected from any one or more of deuterium atoms, halogen atoms, cyano groups, C₁-C₁₀ alkyl groups, deuterium or tritium substituted C₁-C₁₀ alkyl groups, C₃-C₁₀ cycloalkyl groups, C₆-C₃₀ aryl groups, deuterium or tritium substituted C₆-C₃₀ aryl groups, C₅-C₃₀ heteroaryl groups, and deuterium or tritium substituted C₂-C₃₀ heteroaryl groups;
the heteroatoms in the heteroaryl groups are optionally selected from one or more of O, S, N, Si, and B.

Further, the structure of the boron-containing resonance-type organic compound is as shown in general formula (A-1) or general formula (A-2):

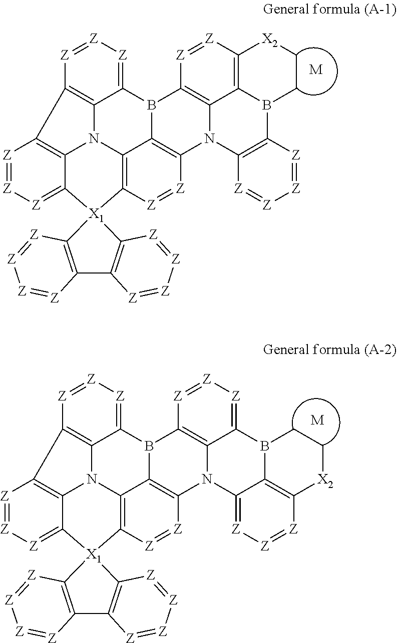

in the general formula (A-1) or general formula (A-2), Z is the same or different at each occurrence and is represented by C—(H) or C—(R₀); R₀ at each occurrence is independently represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
X₁ is the same or different at each occurrence and is independently represented by one of a carbon atom or a silicon atom;
X₂ is the same or different at each occurrence and is independently represented by one of O, S and N(Rᵢ);
the Rᵢ is represented by one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
M is represented by one of one or more R substituted or unsubstituted C₆-C₃₀ aromatic ring, or one or more R substituted or unsubstituted C₂-C₃₀ heteroaromatic ring.
R is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group; the substitution pattern of R is a single bond or a fused-ring connection;
any adjacent R₀ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Rᵢ and adjacent Z are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Rᵢ and M are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented by one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Further, the structure of the boron-containing resonance-type organic compound is as shown in any one of general formula (A-3) to general formula (A-6):

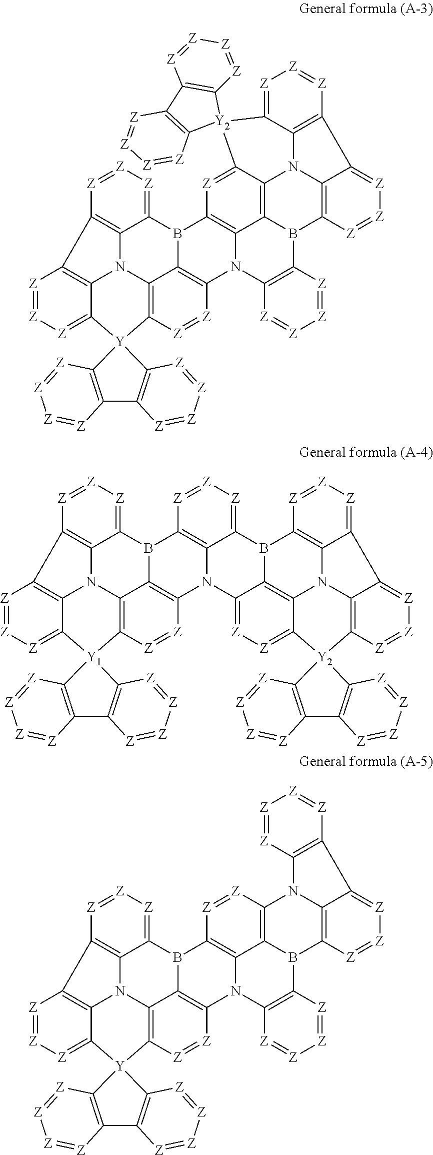

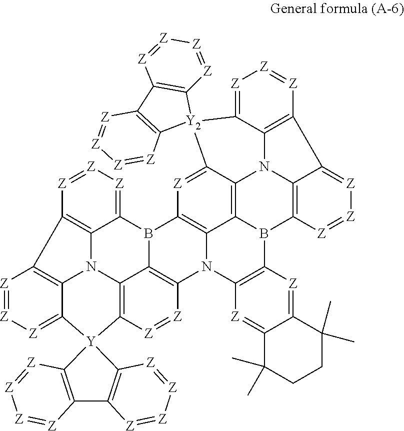

in the general formula (A-3) to general formula (A-6), Z is the same or different at each occurrence and is represented by C—(H) or C—(R₀); R₀ at each occurrence is independently represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Preferably, the structure of the boron-containing resonance-type organic compound is as shown in any one of general formula (A-7) to general formula (A-9):

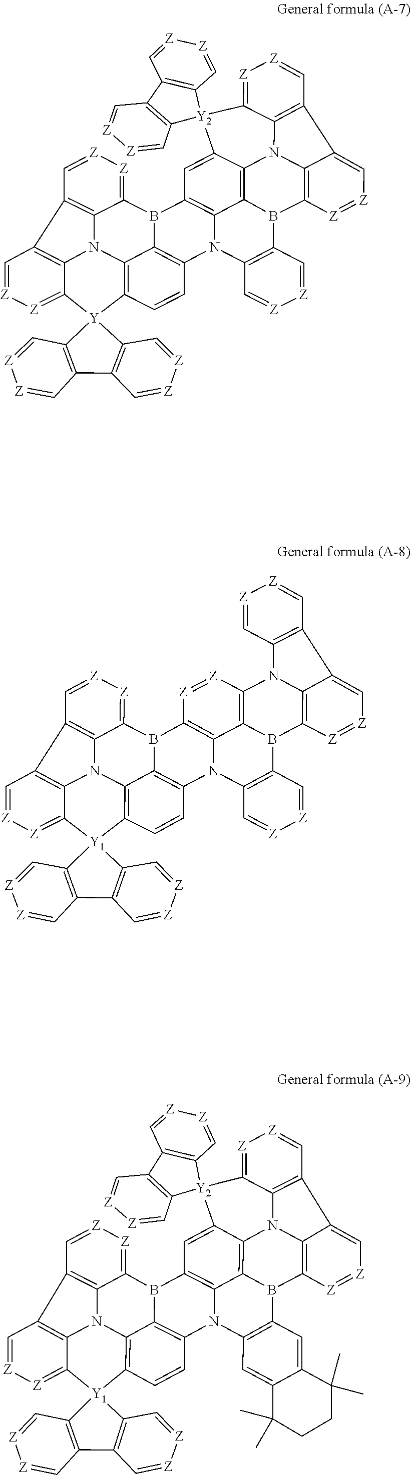

in the general formula (A-7) to general formula (A-9), Z is the same or different at each occurrence and is represented by C—(H) or C—(R₀); R₀ at each occurrence is independently represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Preferably, the structure of the boron-containing resonance-type organic compound is as shown in any one of general formula (A-10) to general formula (A-12):

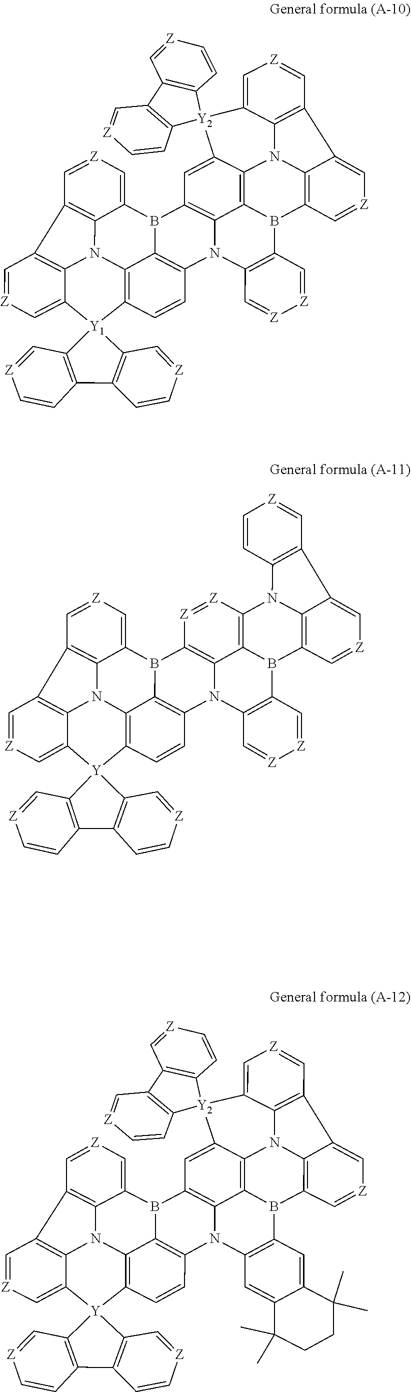

in the general formula (A-10) to general formula (A-12), Z is the same or different at each occurrence and is represented by C—(H) or C—(R₀); R₀ at each occurrence is independently represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Preferably, the structure of the boron-containing resonance-type organic compound is as shown in any one of general formula (A-13) to general formula (A-15):

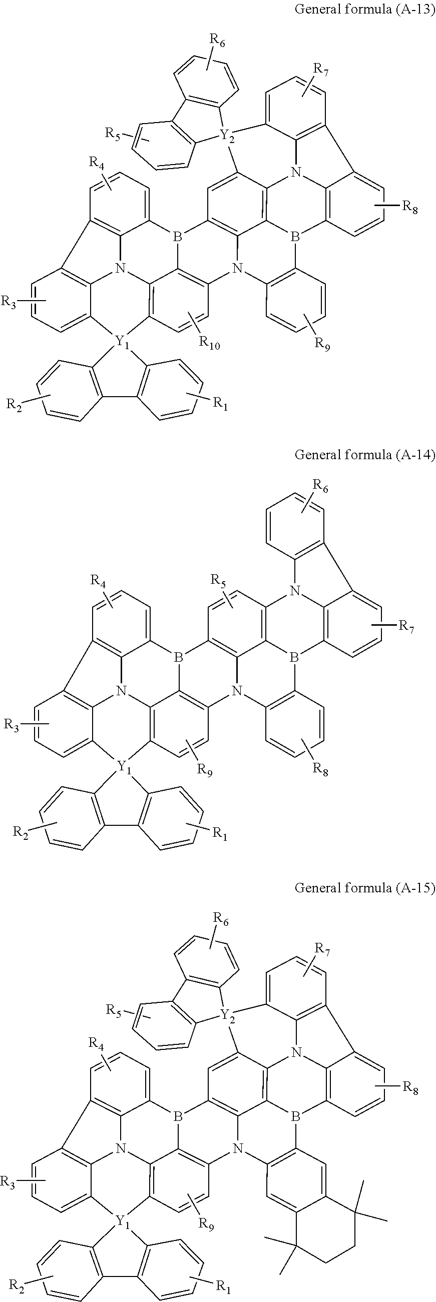

in the general formula (A-13) to general formula (A-15), R₁, R₂, R₃, R₄, R₅, R₆, R₇, R₈, R₉ and R₁₀ are the same or different at each occurrence and are represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Further, the structure of the boron-containing resonance-type organic compound is as shown in any one of general formula (B-1) to general formula (B-2):

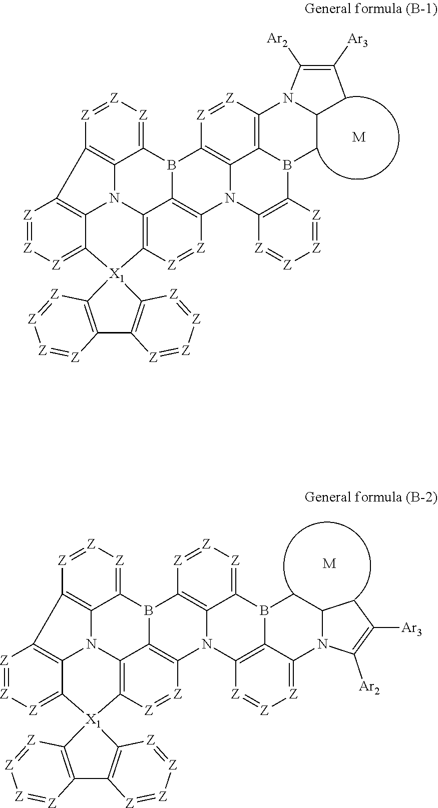

in the general formula (B-1) and general formula (B-2), Z at each occurrence is independently represented by C—(H) or C—(R₀) to each other; R₀ at each occurrence is independently represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group; any adjacent R₀ can be connected to form a ring;
X₁ at each occurrence is independently represented by one of a carbon atom or a silicon atom;
M is represented by one of one or more R substituted or unsubstituted C₆-C₃₀ aromatic ring, or one or more R substituted or unsubstituted C₂-C₃₀ heteroaromatic ring;
R is represented by one of a deuterium atom, a tritium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group; the substitution pattern of R is a single bond or a fused-ring connection;
Ar₂ and Ar₃ at each occurrence are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B;
preferably, the structure of the boron-containing resonance-type organic compound is as shown in any one of general formula (B-3) to general formula (B-8):

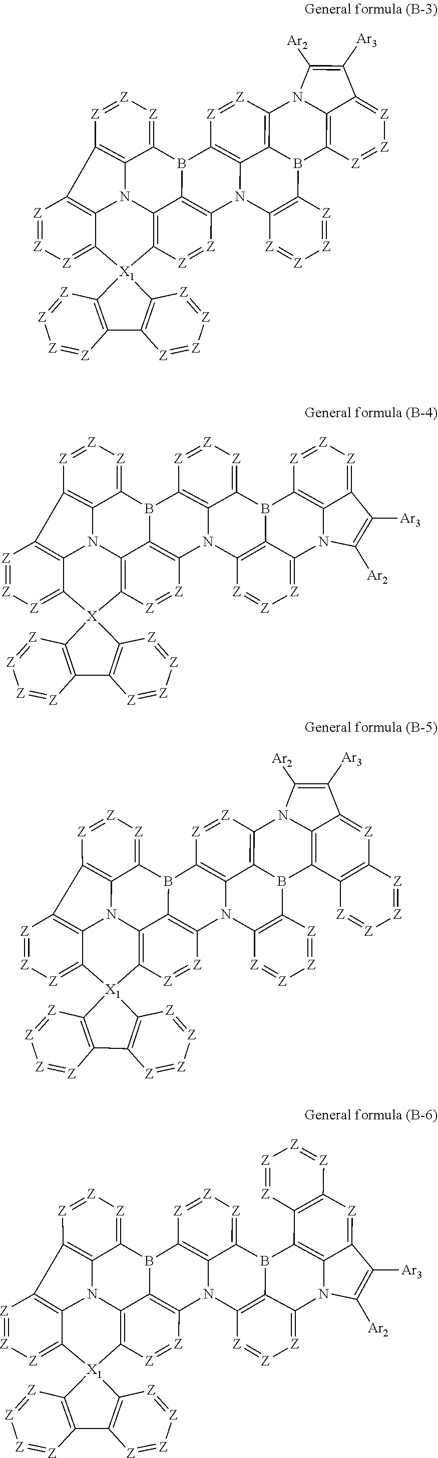

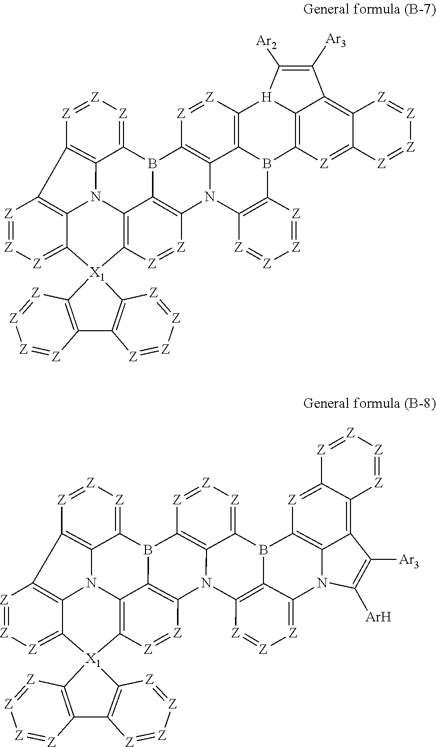

In the general formula (B-3) to general formula (B-8), the definitions of Z, Ar₂, Ar₃, and X₁ are the same as those in the general formula (B-1) and general formula (B-2);
preferably, the structure of the boron-containing resonance-type organic compound is as shown in any one of general formula (B-9) to general formula (B-12):

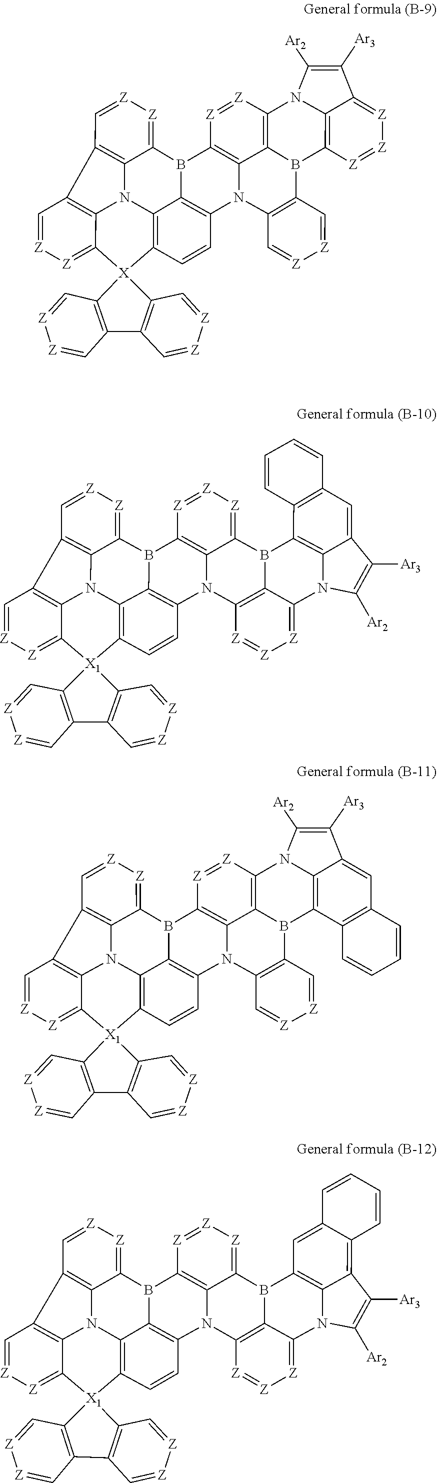

in the general formula (B-9) to general formula (B-12), the definitions of Z, Ar₂, Ar₃, and X₁ are the same as those in the general formula (B-1) and general formula (B-2);
preferably, the structure of the boron-containing resonance-type organic compound is as shown in any one of general formula (B-13) to general formula (B-16):

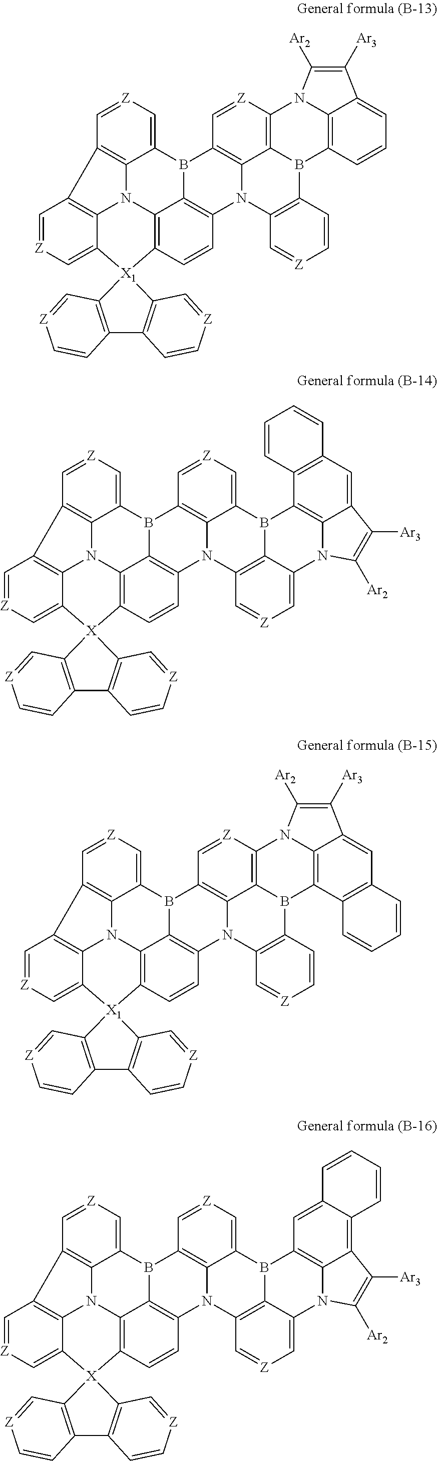

in the general formula (B-13) to general formula (B-16), the definitions of Z, Ar₂, Ar₃, and X₁ are the same as those in the general formula (B-1) and general formula (B-2);
preferably, the structure of the boron-containing resonance-type organic compound is as shown in any one of general formula (B-17) to general formula (B-20):

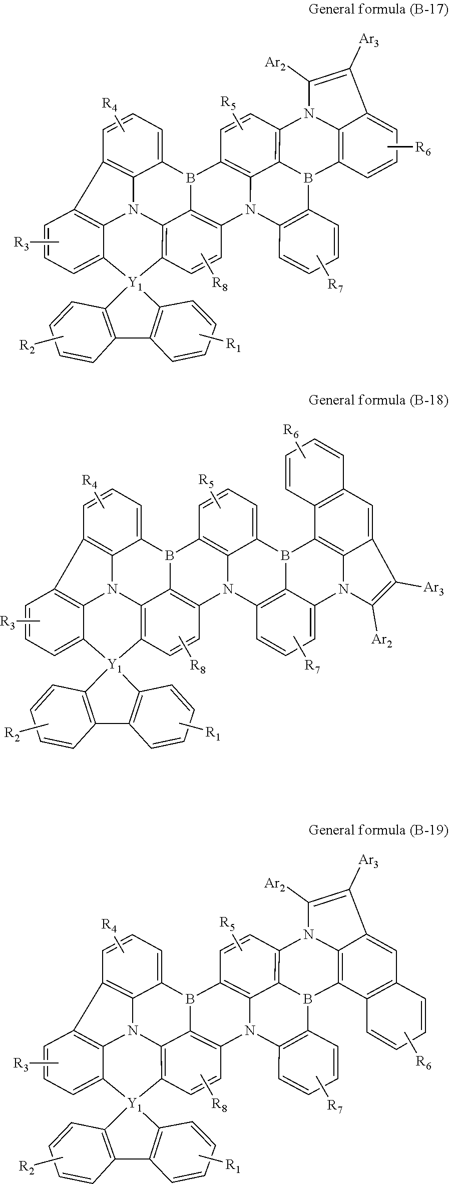

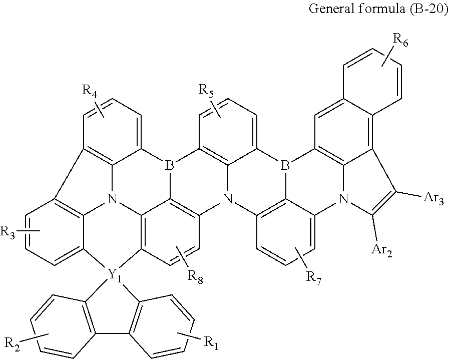

in the general formula (B-17) to general formula (B-20), R₁, R₂, R₃, R₄, R₅, R₆, R₇, and R₈ are the same or different at each occurrence and are represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Y₁ is independently represented by one of a carbon atom or a silicon atom;
Ar₂ and Ar₃ at each occurrence are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Further, the structure of the boron-containing resonance-type organic compound is as shown in general formula (C-1):

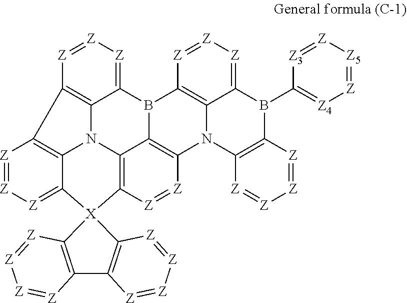

in the general formula (C-1), the definitions of X and Z are the same as those in the general formula (1);
Z₃, Z₄, and Z₅ at each occurrence are independently represented by C—(H) or C—(R₀); R₀ is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Further, the M1, M2, and M rings are represented by the following R substituted or unsubstituted groups: any one of phenyl, naphthyl, anthryl, phenanthryl, pyridyl, quinolyl, furyl, thienyl, benzofuranyl, benzothienyl, dibenzofuranyl, dibenzothienyl, N-phenylcarbazolyl, 9,9-dimethylfluorenyl, indolo[3,2,1-jk]carbazolyl, 1,1,4,4-tetramethyl-1,2,3,4-tetrahydronaphthyl, and spirofluorenyl;

the R, R₀, Rₐ, and R_{b} are represented by a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, and a substituted or unsubstituted triazinyl;
the R₁, R₂, R₃, R₄, R₅, R₆, R₇, R₈, R₉, and R₁₀ are represented by a hydrogen atom, a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, and a substituted or unsubstituted triazinyl;
the Rᵢ, R_{c}, R_{d}, Rₑ, R_{f}, R_{g}, Rₚ, R_{q}, Ar₁, Ar₂, and Ar₃ are independently represented by a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, and a substituted or unsubstituted triazinyl;
the substituents for substituting the groups are optionally selected from one or more of a deuterium atom, a chlorine atom, a fluorine atom, a trifluoromethyl, an adamantyl, a cyano, a methyl, an ethyl, a propyl, an isopropyl, a tert-amyl, a tert-butyl, a butyl, a methoxy, a phenyl, a biphenyl, a naphthyl, an anthryl, a phenanthryl, a pyridyl, a pyrimidyl, a pyrazinyl, a pyridazinyl, a benzoxazolyl, a benzothiazolyl, a quinoxalinyl, a quinolyl, an isoquinolyl, a furyl, a thienyl, an indolyl, a pyrrolyl, a dibenzofuranyl, a dibenzothienyl, a 9,9-dimethylfluorenyl, a spirofluorenyl, a carbazolyl, an N-phenylcarbazolyl, a carbazolinyl, and an azaphenanthryl;
preferably, the M1 and M rings are each independently represented by any one of the following ring structures:

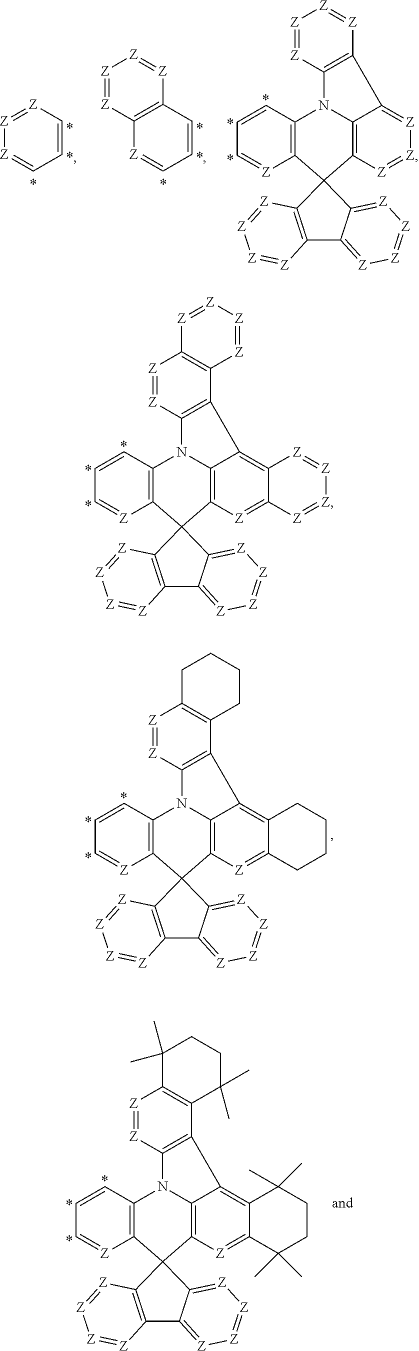

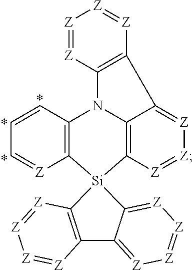

the M2 and M rings are represented by any one of the following groups:

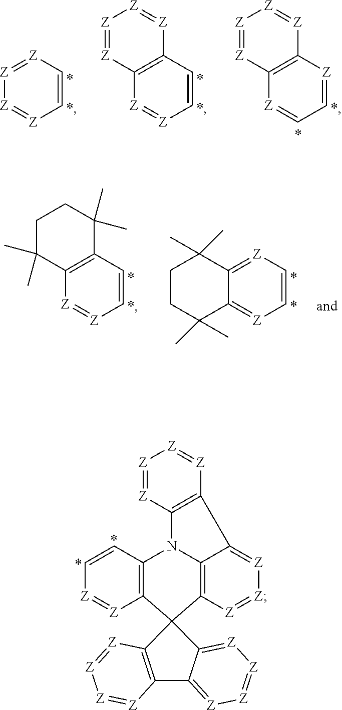

Z is the same or different at each occurrence and is represented by C—(H) or C—(R₀);
the R, R₀, Rₐ, R_{b}, R₁, R₂, R₃, R₄, R₅, R₆, R₇, R₈, R₉, and R₁₀ are each independently represented by any one of the following structures: a hydrogen atom, a deuterium atom, a methyl group, an ethyl group, an isopropyl group, a tert-butyl group, a cyano group, a trifluoromethyl group,

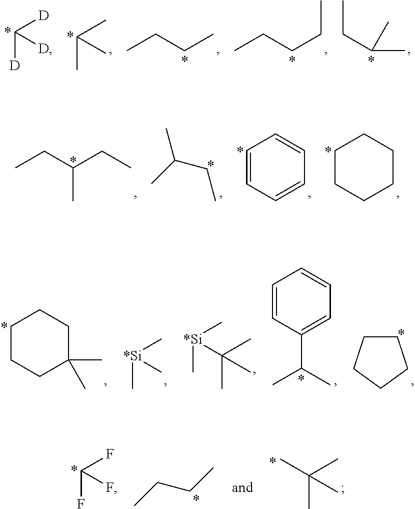

the Rᵢ, R_{c}, R_{d}, Rₑ, R_{f}, R_{g}, Rₚ, R_{q}, Ar₁, Ar₂, and Ar₃ are represented by any one of the following structures: a methyl group, an ethyl group, an isopropyl group, a tert-butyl group,

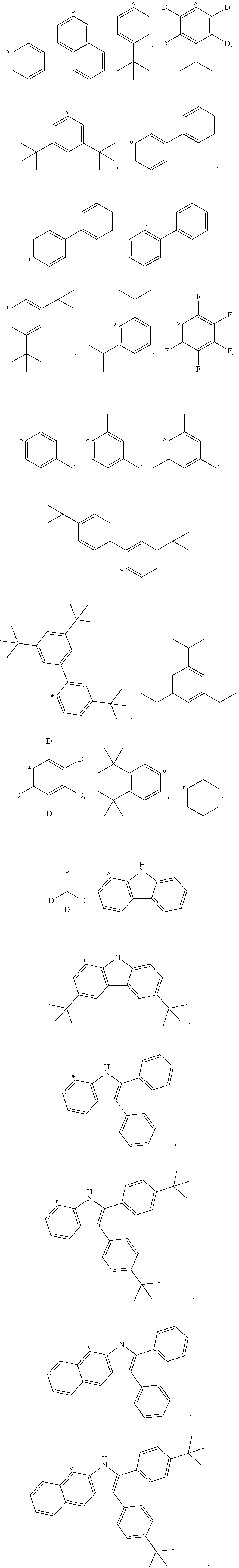

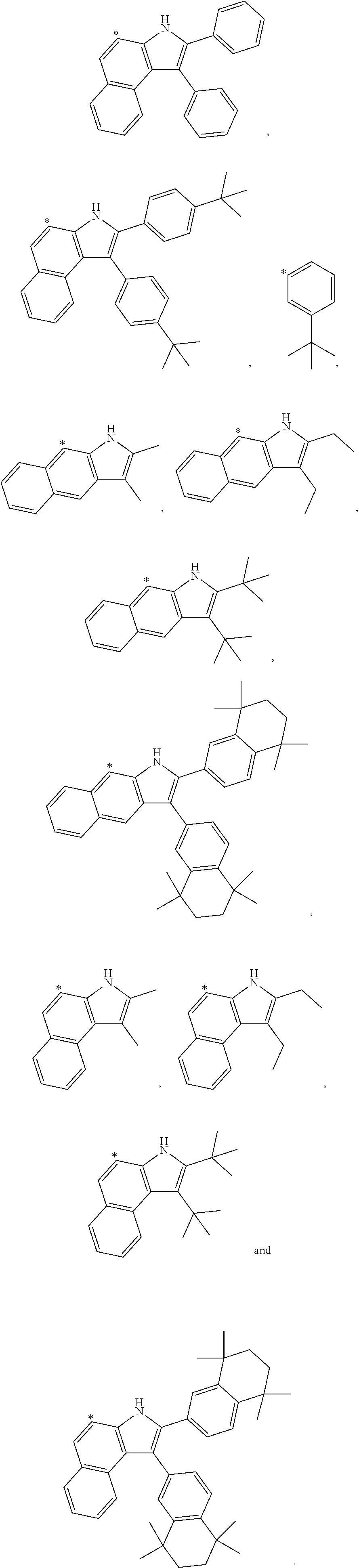

Further, the structure of the diboron-containing resonance-type organic compound is as shown in general formula (D-1):

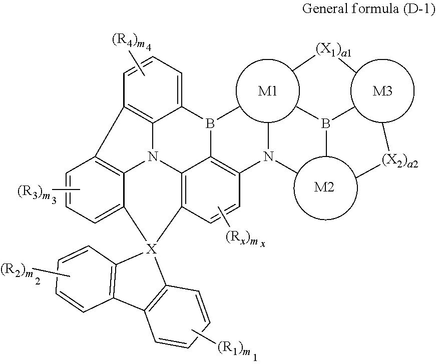

in the general formula (D-1), the M1, M2 and M3 are represented by one of one or more R substituted or unsubstituted C₆-C₃₀ aromatic rings, one or more R substituted or unsubstituted C₂-C₃₀ heteroaromatic rings, one or more R substituted or unsubstituted C₆-C₃₀ aliphatic rings, and one or more R substituted or unsubstituted C₁₀-C₃₀ fused rings formed by fusing two or more of aromatic rings, heteroaromatic rings and aliphatic rings;
R is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
the substitution pattern of R is a single bond or a fused-ring connection;
X is represented by one of a carbon atom or a silicon atom;
the R₁, R₂, R₃, R₄, and Rₓ are each independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₁ and m₂ are represented by 0, 1, 2, 3 or 4;
m₃ and m₄ are represented by 0, 1, 2 or 3;
mₓ is represented by 0, 1 or 2;
a₁ and a₂ are represented by 0 or 1;
X₁ and X₂ are represented by a single bond, a double bond, —O—, —S—, —N(R_{c})—, —C(R_{d})(Rₑ)—, —Si(R_{f})(R_{g})—, or —C(Rₚ)═C(R_{q})—;
R_{c} and M₁ ring are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
R_{c} and M₃ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are each independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group;
R_{d} and Rₑ are not connected or connected by a single bond, a double bond, —O—, —S—, —N(ph)-, a dimethyl-substituted methylene group, and a diphenyl-substituted methylene group;
R_{f} and R_{g} are not connected or connected by a single bond, a double bond, —O—, —S—, —N(ph)-, a dimethyl-substituted methylene group, and a diphenyl-substituted methylene group;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Preferably, the structure of the diboron-containing resonance-type organic compound is as shown in general formula (D-2):

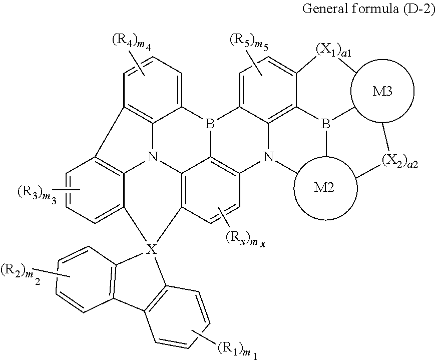

in the general formula (D-2), the definitions of X, X₁, X₂, R₁, R₂, R₃, R₄, Rₓ, a₁, a₂, m₁, m₂, m₃, m₄, mₓ, M2, and M3 are the same as those in the general formula (D-1);
the R₅ is represented as one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₅ is represented by 0, 1 or 2;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Preferably, at least one of a₁ and a₂ is represented by 1.

Preferably, the structure of the diboron-containing resonance-type organic compound is as shown in general formula (D-3) or general formula (D-4):

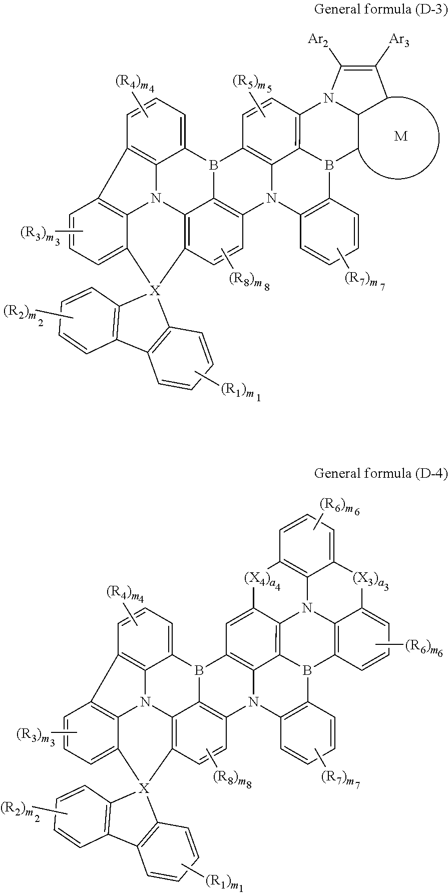

in the general formula (D-3) and general formula (D-4), the definitions of X, R₁, R₂, R₃, R₄, m₁, m₂, m₃, and m₄ are the same as those in the general formula (D-1);
M is represented by one of one or more R substituted or unsubstituted C₆-C₃₀ aromatic rings, and one or more R substituted or unsubstituted C₂-C₃₀ heteroaromatic rings;
R is represented by one of a deuterium atom, a tritium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group; the substitution pattern of R is a single bond or a fused-ring connection;
Ar₂ and Ar₃ are each independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, and a substituted or unsubstituted C₂-C₃₀ heteroaryl group;
the R₅, R₆, R₇, R₈, and R₉ are each independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₅ and m₈ are represented by 0, 1 or 2; m₇ is represented by 0, 1, 2, 3 or 4; m₆ and m₉ are represented by 0, 1, 2 or 3; and a₃ and a₄ are represented by 0 or 1;
X₃ and X₄ are each independently represented by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are each independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group;
the R_{d} and Rₑ are not connected or connected by a single bond, a double bond, —O—, —S—, —N(ph)-, a dimethyl-substituted methylene group, and a diphenyl-substituted methylene group;
the R_{f} and R_{g} are not connected or connected by a single bond, a double bond, —O—, —S—, —N(ph)-, a dimethyl-substituted methylene group, and a diphenyl-substituted methylene group;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Preferably, the structure of the diboron-containing resonance-type organic compound is as shown in any one of general formula (D-5) to general formula (D-9) and general formula (D-16):

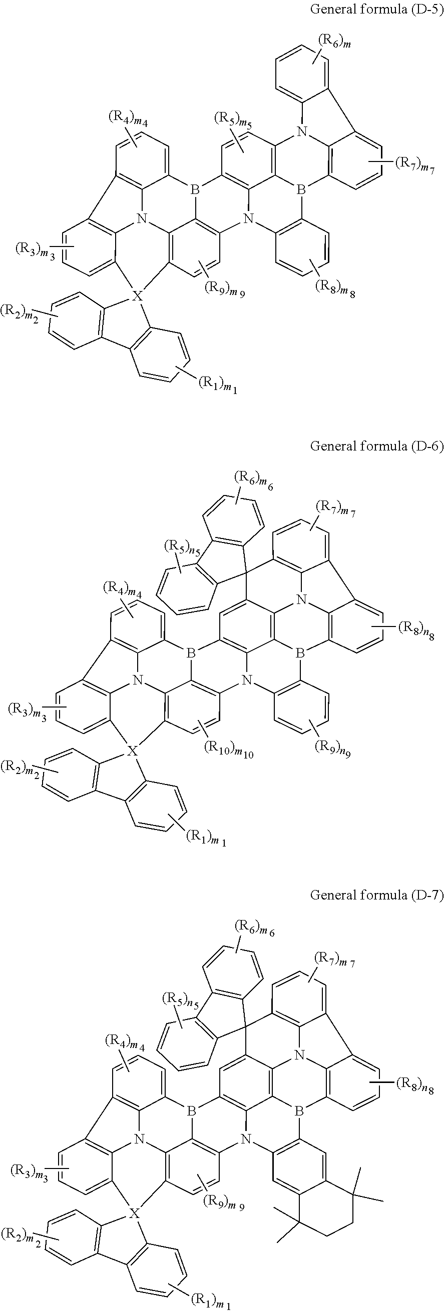

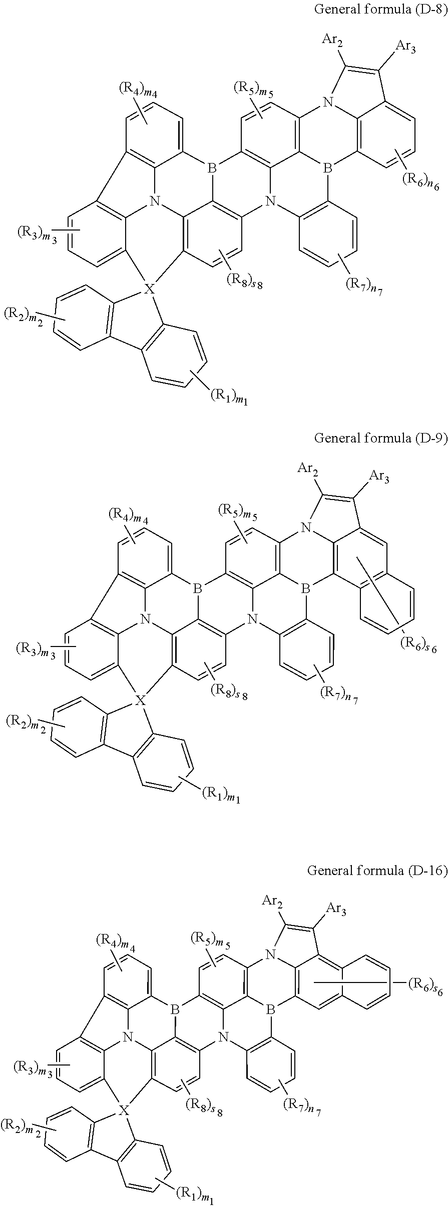

in any one of general formula (D-5) to general formula (D-9) and general formula (D-16), the definitions of X, R₁, R₂, R₃, R₄, m₁, m₂, m₃, and m₄ are the same as those in the general formula (D-1);
Ar₂ and Ar₃ are each independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, and a substituted or unsubstituted C₂-C₃₀ heteroaryl group;
the R₅, R₆, R₇, R₈, R₉, and R₁₀ are each independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₅, m₉, m₁₀, and s₈ are represented by 0, 1 or 2;
n₅, m₆, n₇, n₉, and m₈ are represented by 0, 1, 2, 3 or 4;
m₇, s₅, n₆, and n₈ are represented by 0, 1, 2 or 3;
s₆ is represented by 0, 1, 2, 3, 4 or 5;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Preferably, the structure of the diboron-containing resonance-type organic compound is as shown in any one of general formula (D-10) to general formula (D-15):

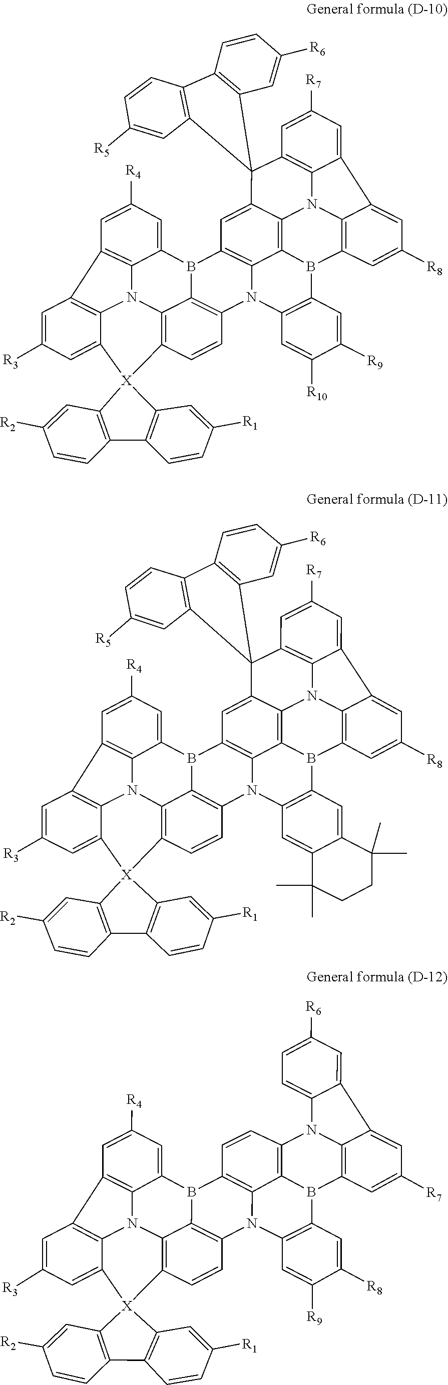

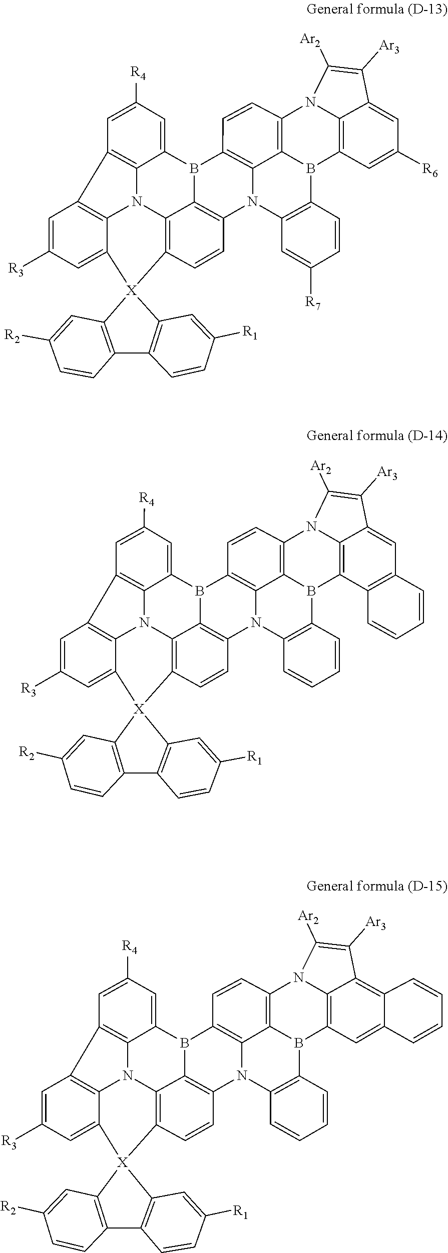

in the general formula (D-10) to general formula (D-15), the definitions of X, R₁, R₂, R₃, and R₄ are the same as those in the general formula (D-1);
Ar₂ and Ar₃ are each independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, and a substituted or unsubstituted C₂-C₃₀ heteroaryl group;
R₅, R₆, R₇, R₈, R₉, and R₁₀ are each independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

Further, the M₁, M₂, M₃ and M rings are represented by the following one or more R substituted or unsubstituted groups: any one of phenyl, naphthyl, anthryl, phenanthryl, pyridyl, quinolyl, furyl, thienyl, benzofuranyl, benzothienyl, dibenzofuranyl, dibenzothienyl, N-phenylcarbazolyl, 9,9-dimethylfluorenyl, indolo[3,2,1-jk]carbazolyl, 1,1,4,4-tetramethyl-1,2,3,4-tetrahydronaphthyl, and spirofluorenyl;
the R, R₀, Rₐ, R_{b}, R_{c}, R_{d}, Rₑ R_{f}, R_{g}, Rₚ, and R_{q} are represented by a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, a substituted or unsubstituted triazinyl, a substituted or unsubstituted 1,1,4,4-tetramethyl-1,2,3,4-tetrahydronaphthyl, a substituted or unsubstituted diphenylamino, a substituted or unsubstituted indolyl, and a substituted or unsubstituted benzindolyl;
the R₁, R₂, R₃, R₄, R₅, R₆, R₇, R₈, R₉, R₁₀, and Rₓ are represented by a hydrogen atom, a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, a substituted or unsubstituted triazinyl, a substituted or unsubstituted 1,1,4,4-tetramethyl-1,2,3,4-tetrahydronaphthyl, a substituted or unsubstituted diphenylamino, a substituted or unsubstituted indolyl, and a substituted or unsubstituted benzindolyl;
the Rᵢ, R_{c}, R_{d}, Rₑ, R_{f}, R_{g}, Rₚ, R_{q}, Ar₁, Ar₂, and Ar₃ are each independently represented by a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, a substituted or unsubstituted triazinyl, a substituted or unsubstituted 1,1,4,4-tetramethyl-1,2,3,4-tetrahydronaphthyl, a substituted or unsubstituted diphenylamino, a substituted or unsubstituted indolyl, and a substituted or unsubstituted benzindolyl;
the substituents for substituting the groups are optionally selected from one or more of a deuterium atom, a chlorine atom, a fluorine atom, a trifluoromethyl, an adamantyl, a cyano, a methyl, an ethyl, a propyl, an isopropyl, a tert-amyl, a tert-butyl, a butyl, a methoxy, a phenyl, a biphenyl, a naphthyl, an anthryl, a phenanthryl, a pyridyl, a pyrimidyl, a pyrazinyl, a pyridazinyl, a benzoxazolyl, a benzothiazolyl, a quinoxalinyl, a quinolyl, an isoquinolyl, a furyl, a thienyl, an indolyl, a pyrrolyl, a dibenzofuranyl, a dibenzothienyl, a 9,9-dimethylfluorenyl, a spirofluorenyl, a carbazolyl, an N-phenylcarbazolyl, a carbazolinyl, an azaphenanthryl, diphenylamino, 1,1,4,4-tetramethyl-1,2,3,4-tetrahydronaphthyl, methyl-substituted phenyl, ethyl-substituted phenyl, isopropyl-substituted phenyl, tert-butyl-substituted phenyl, adamantyl-substituted phenyl, methyl-substituted biphenyl, ethyl-substituted biphenyl, isopropyl-substituted biphenyl, tert-butyl-substituted biphenyl, deuterated methyl-substituted phenyl, deuterated ethyl-substituted phenyl, deuterated isopropyl-substituted phenyl, deuterated tert-butyl-substituted phenyl, deuterated methyl-substituted biphenyl, deuterated ethyl-substituted biphenyl, deuterated isopropyl-substituted biphenyl, and deuterated tert-butyl-substituted biphenyl.

Further, the specific structural formula of the boron-containing resonance-type organic compound is any one of the following structures:

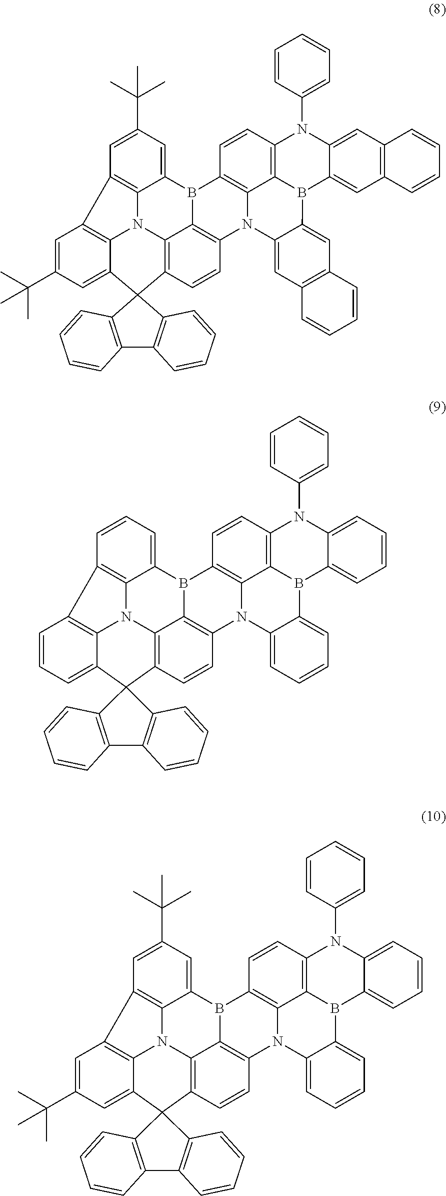 [SMILES: CC(C)(C)c1cc2c3c(c1)c1cc(C(C)(C)C)cc4c1n3-c1c(ccc3c1B2c1ccc2c5c1N3c1cc3ccccc3cc1B5c1cc3ccccc3cc1N2c1ccccc1)C41c2ccccc2-c2ccccc21 ; c1ccc(N2c3ccccc3B3c4ccccc4N4c5ccc6c7c5B(c5ccc2c3c54)c2cccc3c4cccc(c4n-7c23)C62c3ccccc3-c3ccccc32)cc1 ; CC(C)(C)c1cc2c3c(c1)c1cc(C(C)(C)C)cc4c1n3-c1c(ccc3c1B2c1ccc2c5c1N3c1ccccc1B5c1ccccc1N2c1ccccc1)C41c2ccccc2-c2ccccc21]

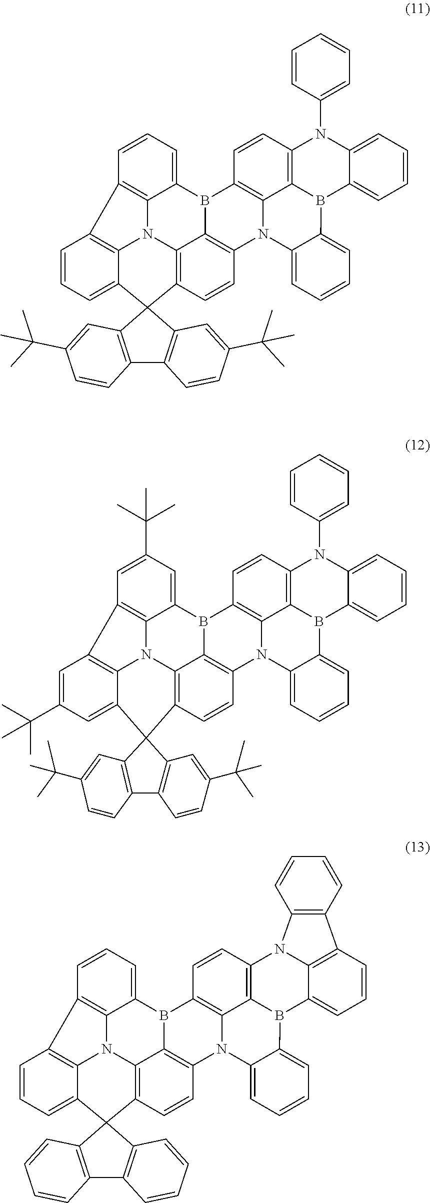 [SMILES: CC(C)(C)c1ccc2c(c1)C1(c3cc(C(C)(C)C)ccc3-2)c2ccc3c4c2-n2c5c(cccc5c5cccc1c52)B4c1ccc2c4c1N3c1ccccc1B4c1ccccc1N2c1ccccc1 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccccc1B4c1ccccc1N2c1ccccc1 ; c1ccc2c(c1)B1c3c(ccc4c3N2c2ccc3c5c2B4c2cccc4c6cccc(c6n-5c24)C32c3ccccc3-c3ccccc32)-n2c3ccccc3c3cccc1c32]

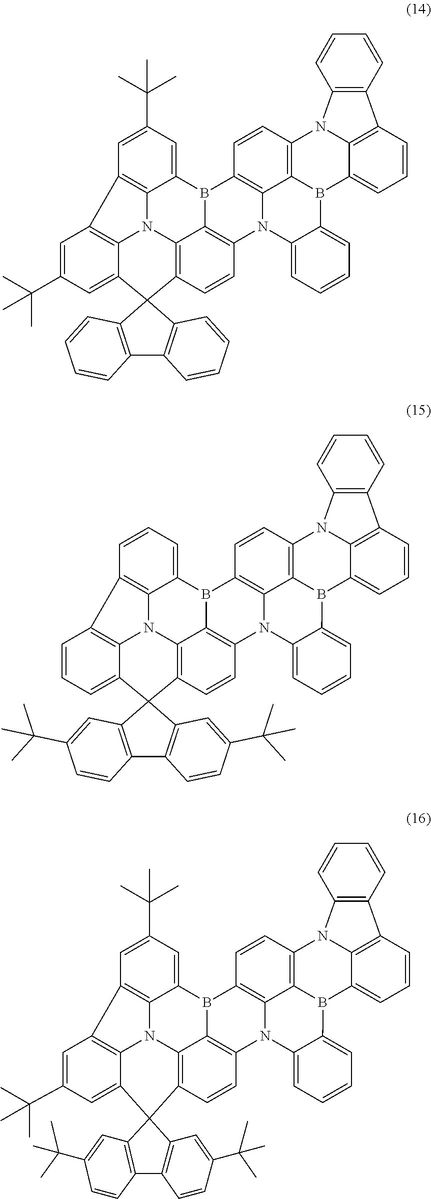 [SMILES: CC(C)(C)c1cc2c3c(c1)c1cc(C(C)(C)C)cc4c1n3-c1c(ccc3c1B2c1ccc2c5c1N3c1ccccc1B5c1cccc3c5ccccc5n-2c13)C41c2ccccc2-c2ccccc21 ; CC(C)(C)c1ccc2c(c1)C1(c3cc(C(C)(C)C)ccc3-2)c2ccc3c4c2-n2c5c(cccc5c5cccc1c52)B4c1ccc2c4c1N3c1ccccc1B4c1cccc3c4ccccc4n-2c13 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccccc1B4c1cccc3c4ccccc4n-2c13]

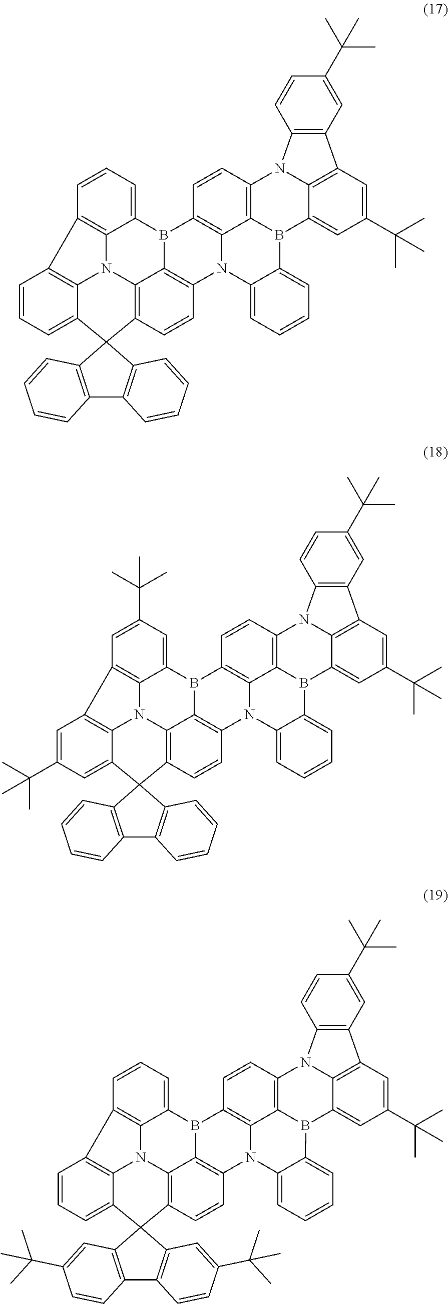

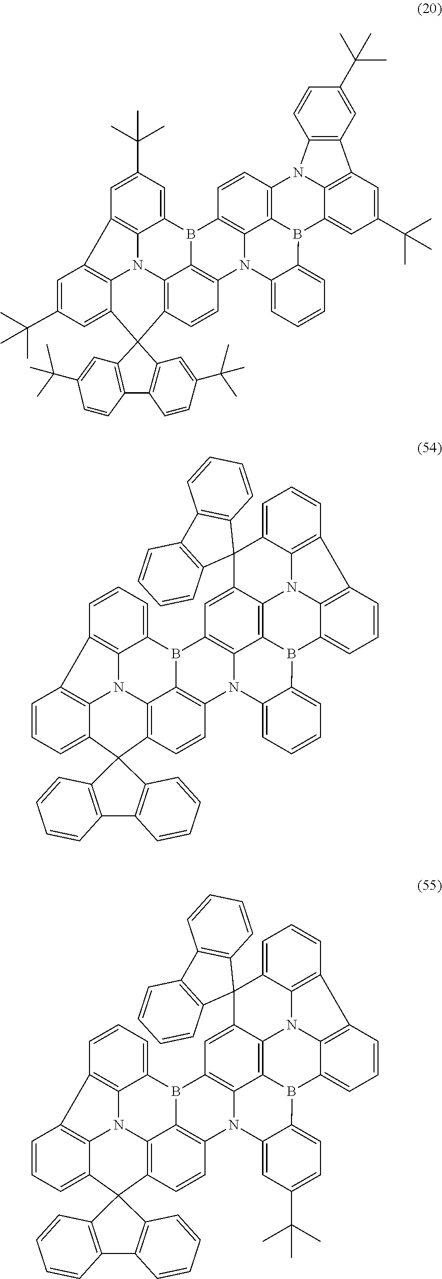 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccccc1B4c1cc(C(C)(C)C)cc3c4cc(C(C)(C)C)ccc4n-2c13 ; c1ccc2c(c1)B1c3c4c(cc5c3-n3c6c1cccc6c1cccc(c13)C51c3ccccc3-c3ccccc31)B1c3c(ccc5c3-n3c6c1cccc6c1cccc(c13)C51c3ccccc3-c3ccccc31)N24 ; CC(C)(C)c1ccc2c(c1)N1c3ccc4c5c3B(c3cc6c7c(c31)B2c1cccc2c3cccc(c3n-7c12)C61c2ccccc2-c2ccccc21)c1cccc2c3cccc(c3n-5c12)C41c2ccccc2-c2ccccc21]

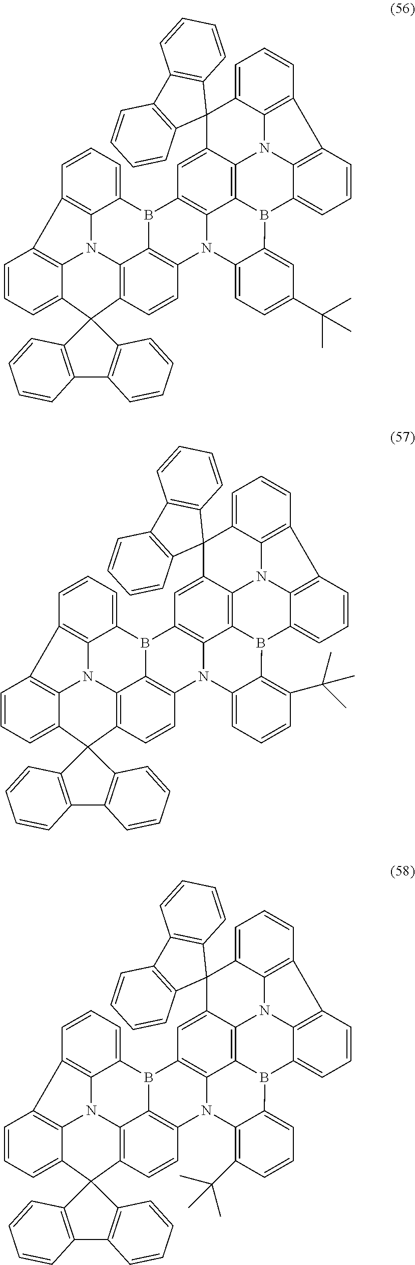 [SMILES: CC(C)(C)c1ccc2c(c1)B1c3c4c(cc5c3-n3c6c1cccc6c1cccc(c13)C51c3ccccc3-c3ccccc31)B1c3c(ccc5c3-n3c6c1cccc6c1cccc(c13)C51c3ccccc3-c3ccccc31)N24 ; CC(C)(C)c1cccc2c1B1c3c4c(cc5c3-n3c6c1cccc6c1cccc(c13)C51c3ccccc3-c3ccccc31)B1c3c(ccc5c3-n3c6c1cccc6c1cccc(c13)C51c3ccccc3-c3ccccc31)N24 ; CC(C)(C)c1cccc2c1N1c3ccc4c5c3B(c3cc6c7c(c31)B2c1cccc2c3cccc(c3n-7c12)C61c2ccccc2-c2ccccc21)c1cccc2c3cccc(c3n-5c12)C41c2ccccc2-c2ccccc21]

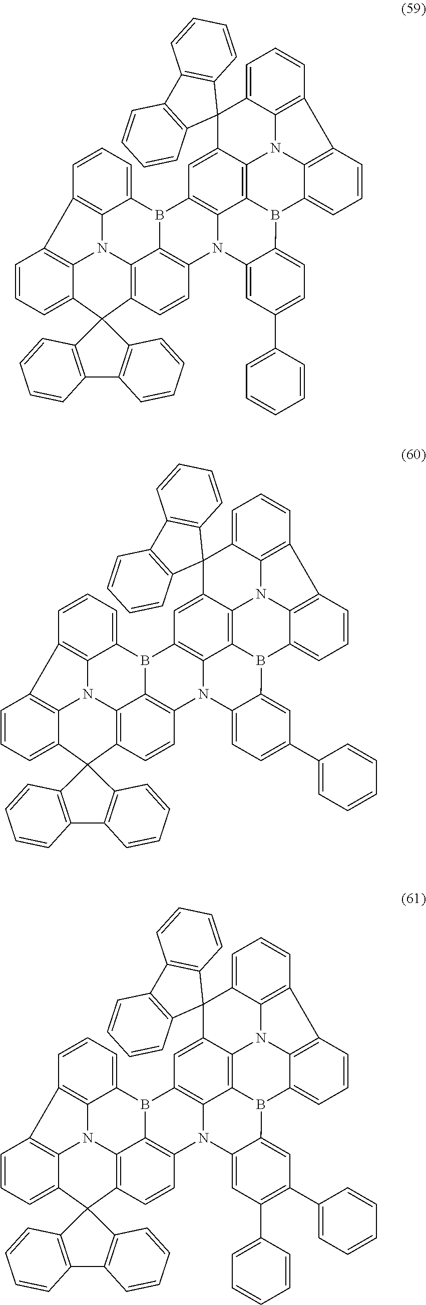 [SMILES: c1ccc(-c2ccc3c(c2)N2c4ccc5c6c4B(c4cc7c8c(c42)B3c2cccc3c4cccc(c4n-8c23)C72c3ccccc3-c3ccccc32)c2cccc3c4cccc(c4n-6c23)C52c3ccccc3-c3ccccc32)cc1 ; c1ccc(-c2ccc3c(c2)B2c4c5c(cc6c4-n4c7c2cccc7c2cccc(c24)C62c4ccccc4-c4ccccc42)B2c4c(ccc6c4-n4c7c2cccc7c2cccc(c24)C62c4ccccc4-c4ccccc42)N35)cc1 ; c1ccc(-c2cc3c(cc2-c2ccccc2)N2c4ccc5c6c4B(c4cc7c8c(c42)B3c2cccc3c4cccc(c4n-8c23)C72c3ccccc3-c3ccccc32)c2cccc3c4cccc(c4n-6c23)C52c3ccccc3-c3ccccc32)cc1]

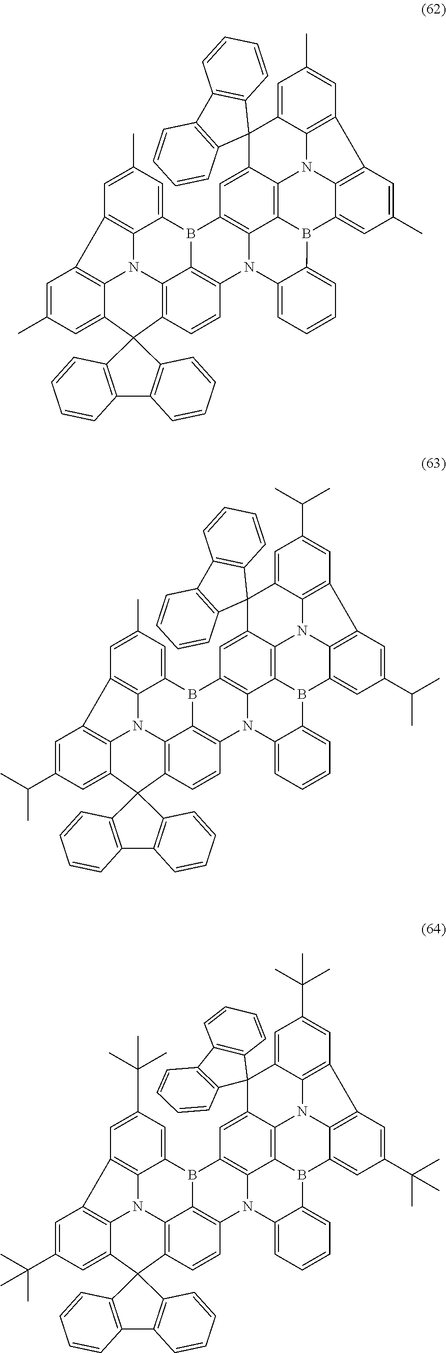

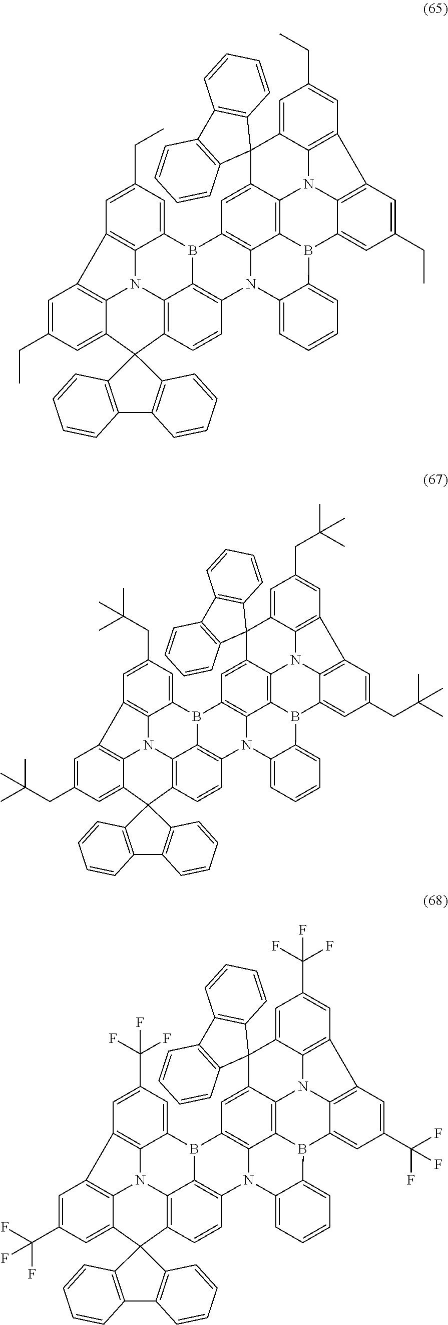

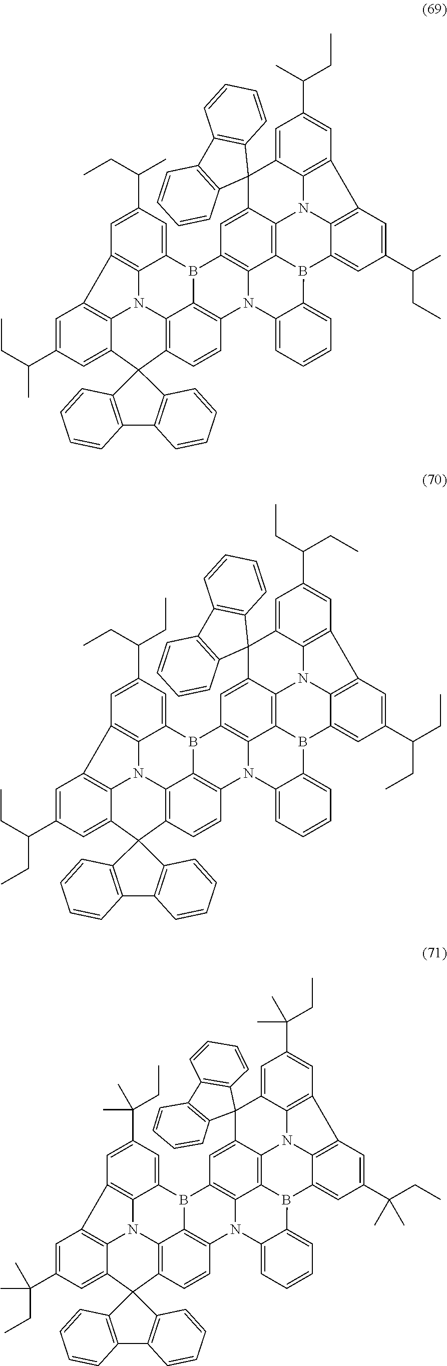

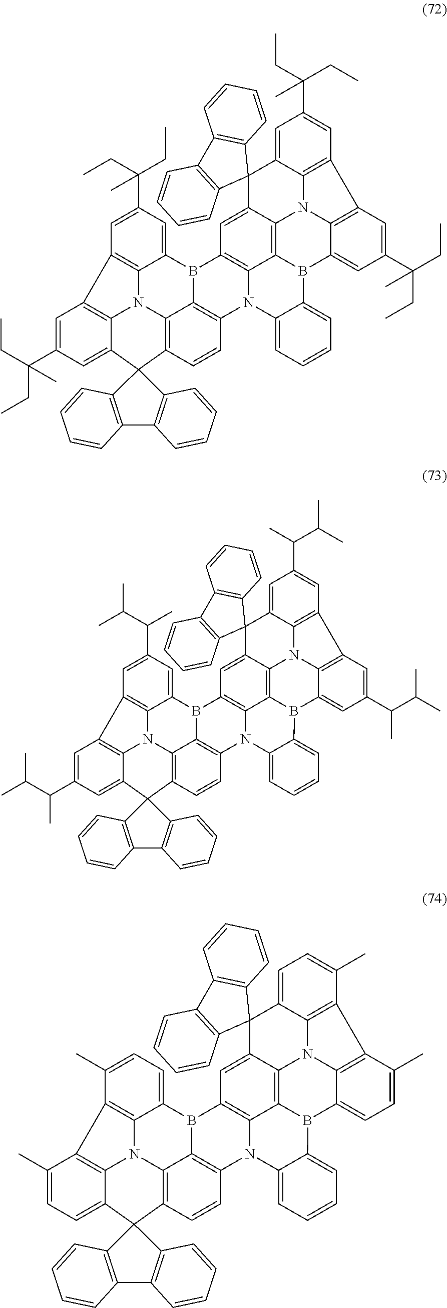

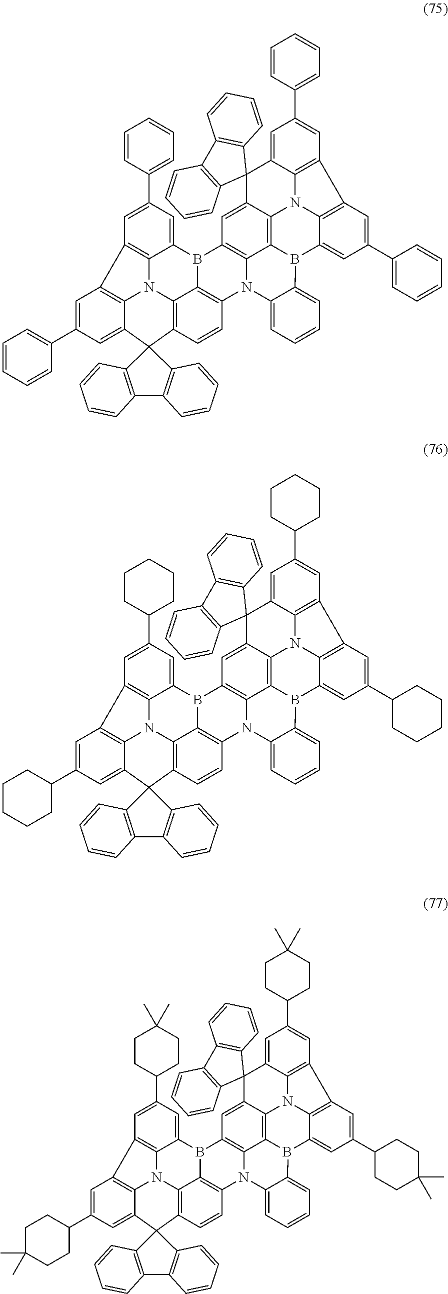

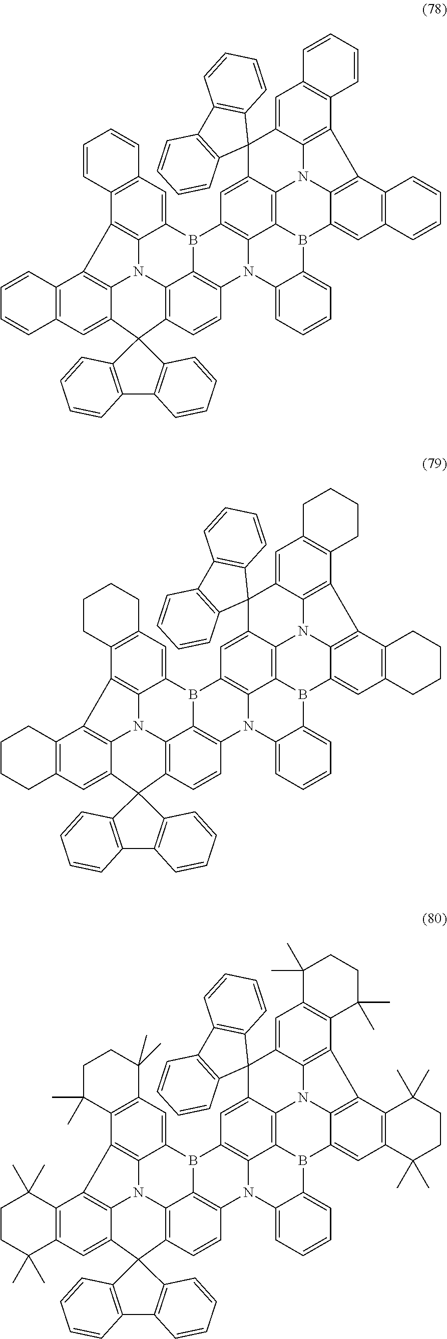

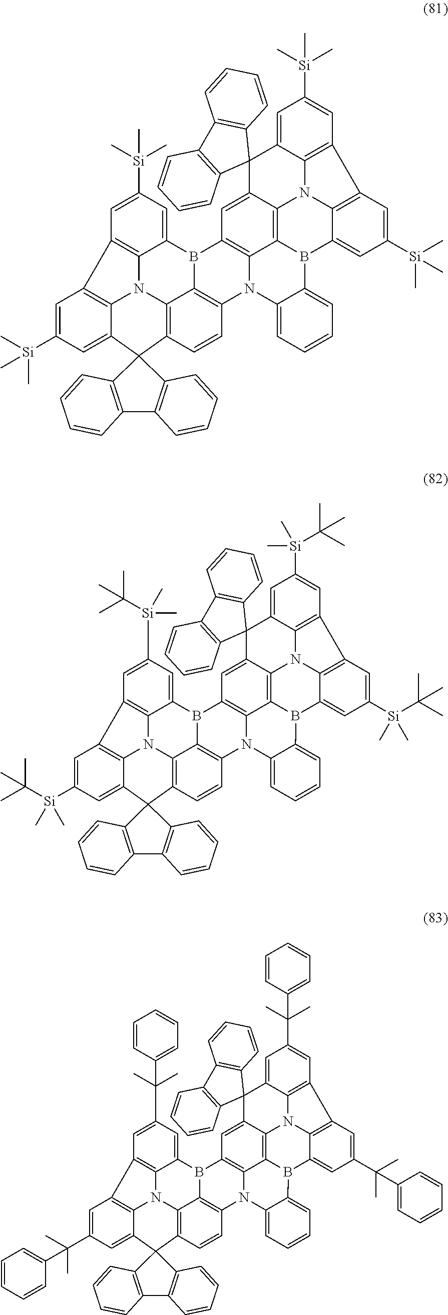

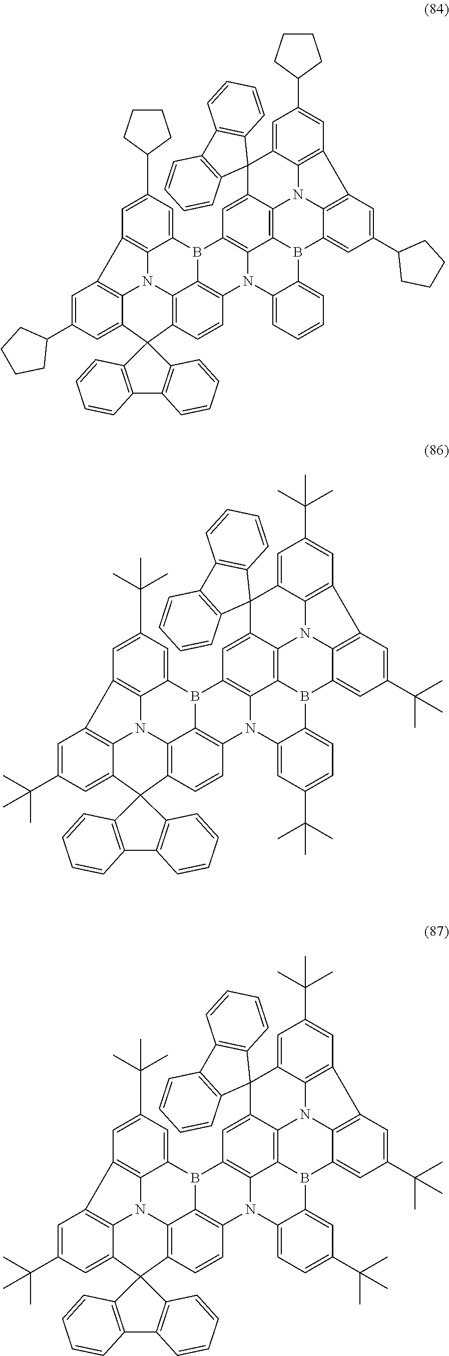

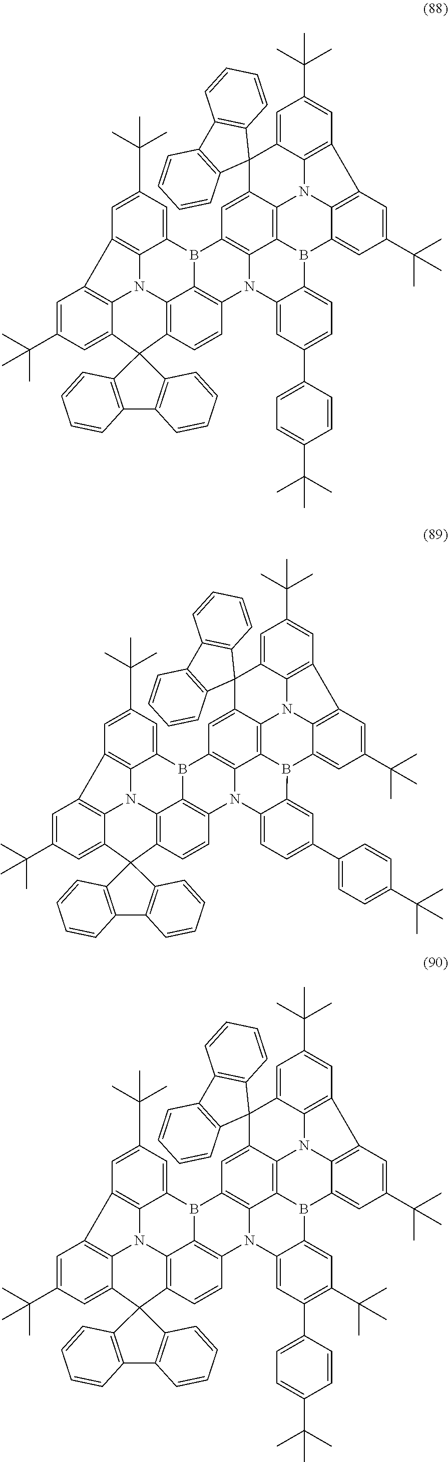

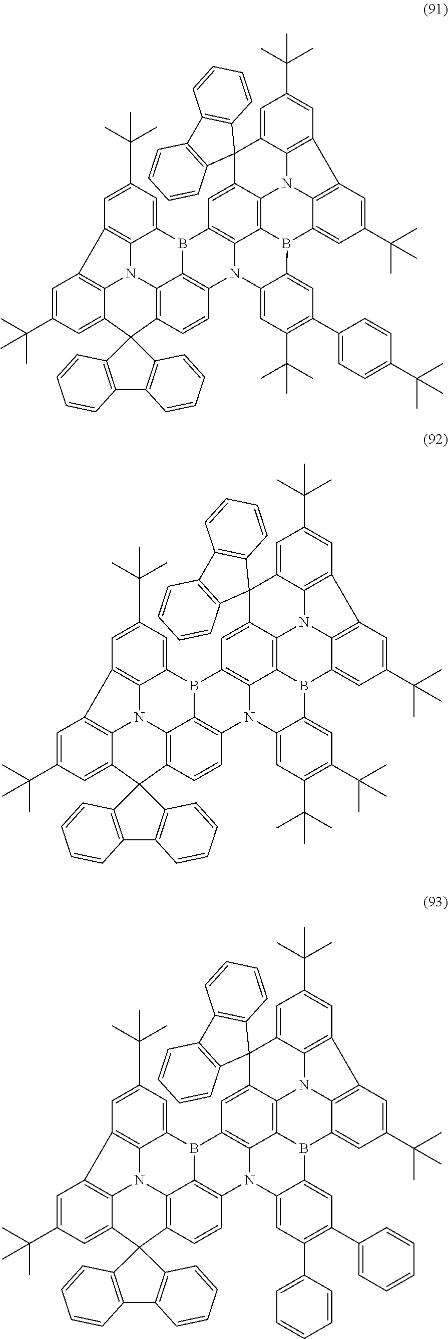

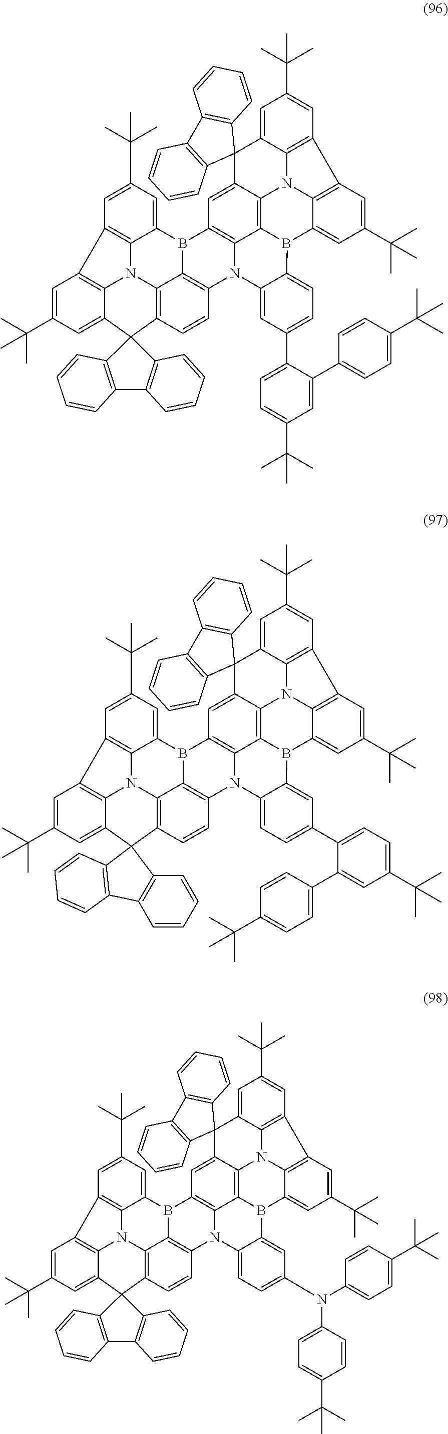

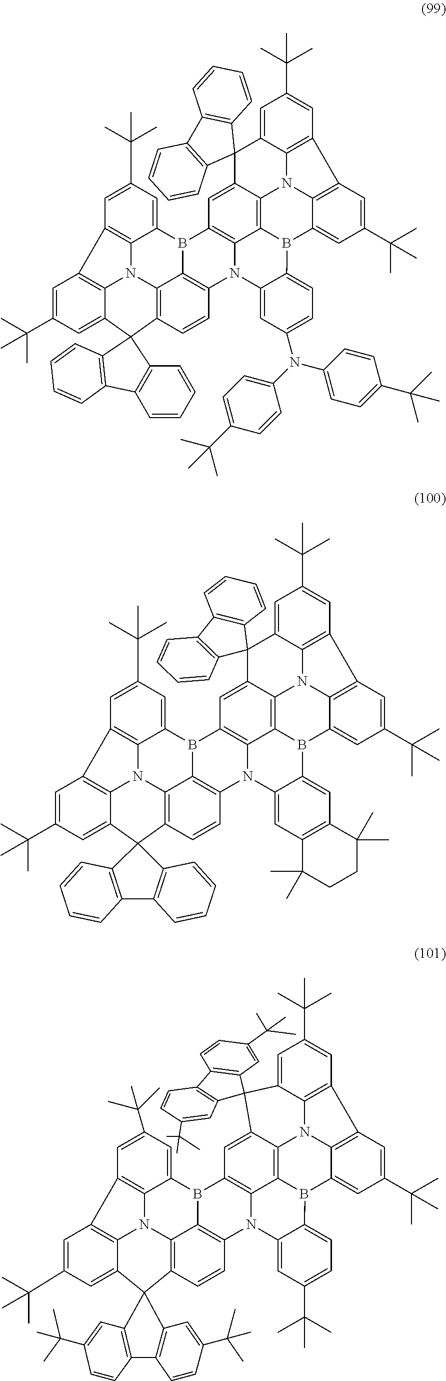

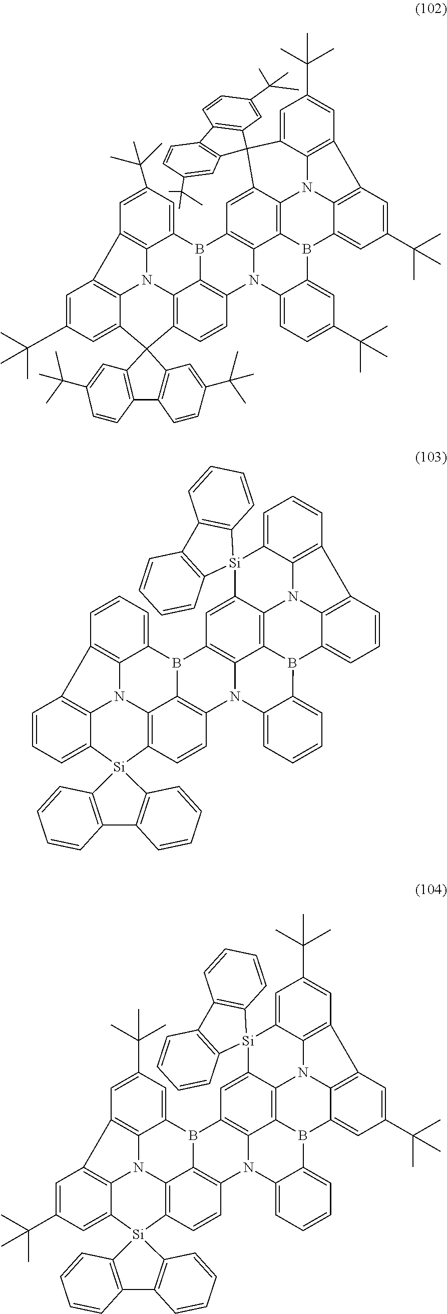

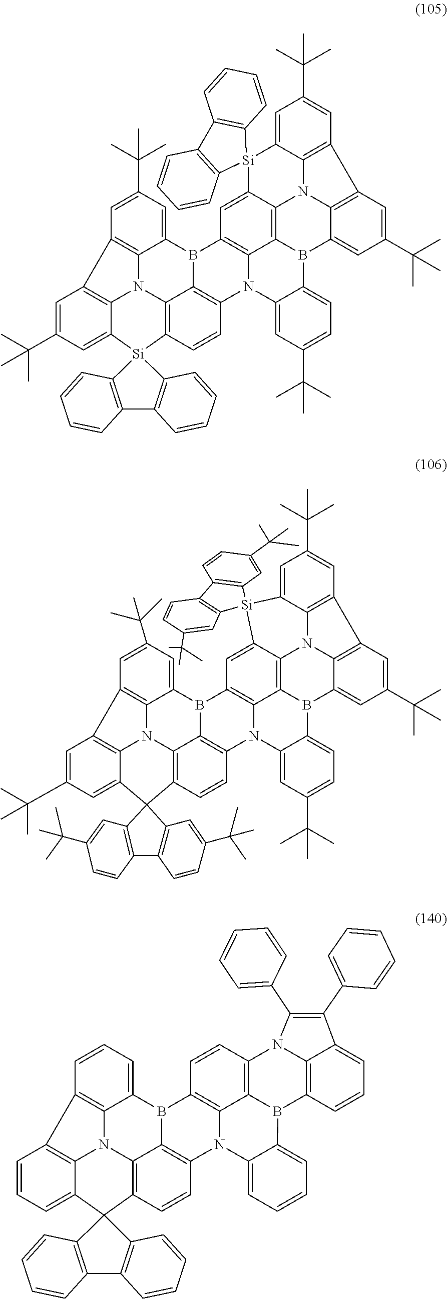

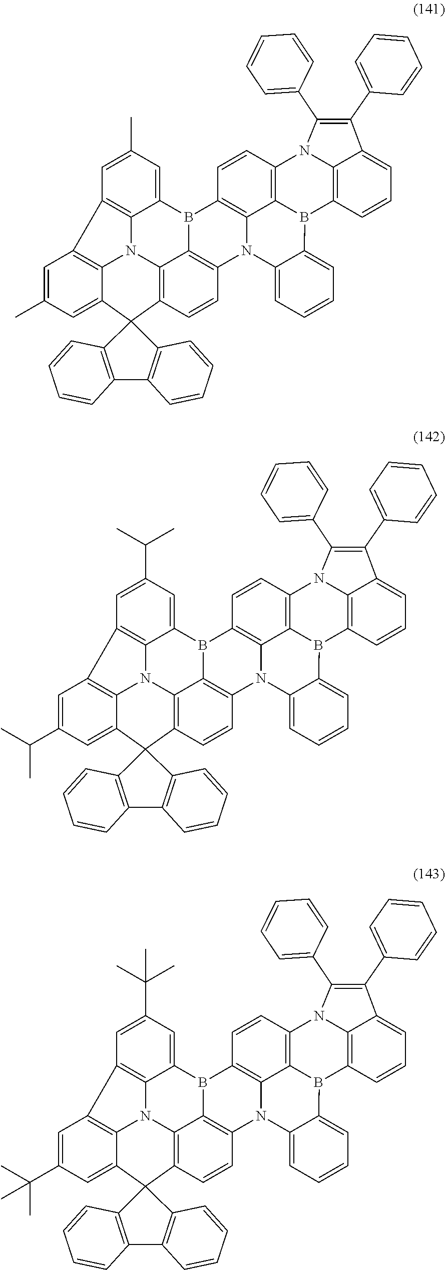 [SMILES: Cc1cc2c3c(c1)c1cc(C)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CC(C)c1cc2c3c(c1)c1cc(C(C)C)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CC(C)(C)c1cc2c3c(c1)c1cc(C(C)(C)C)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21]

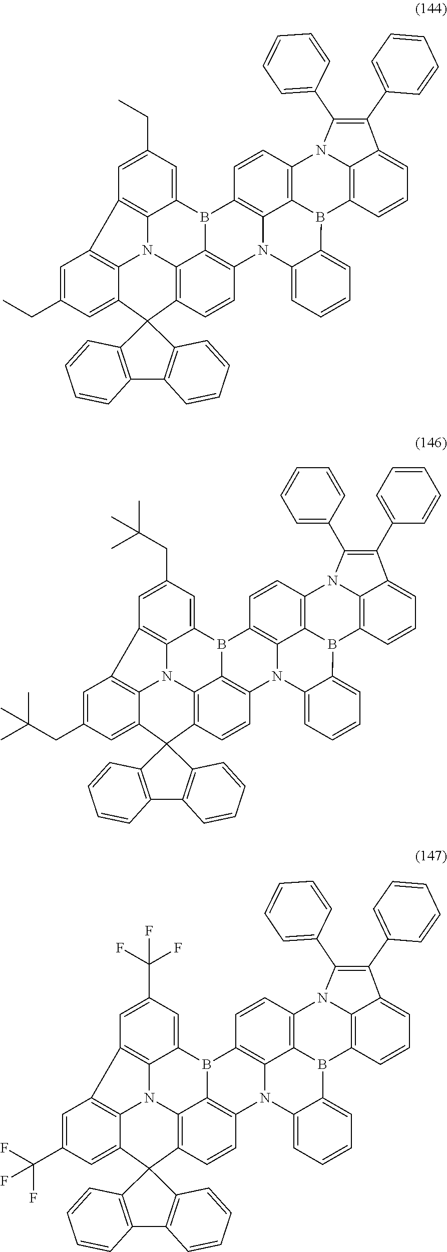 [SMILES: CCc1cc2c3c(c1)c1cc(CC)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CC(C)(C)Cc1cc2c3c(c1)c1cc(CC(C)(C)C)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; FC(F)(F)c1cc2c3c(c1)c1cc(C(F)(F)F)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21]

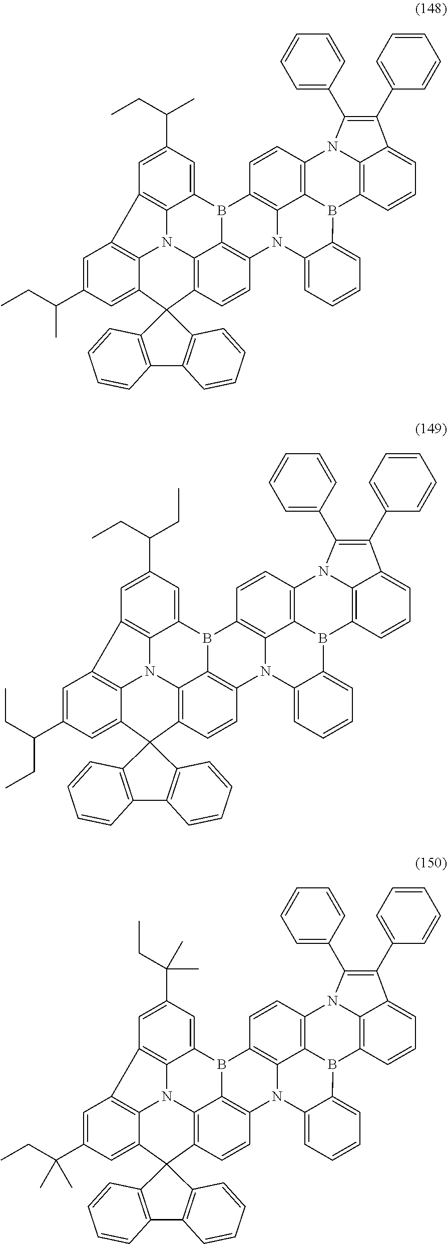 [SMILES: CCC(C)c1cc2c3c(c1)c1cc(C(C)CC)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CCC(CC)c1cc2c3c(c1)c1cc(C(CC)CC)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CCC(C)(C)c1cc2c3c(c1)c1cc(C(C)(C)CC)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21]

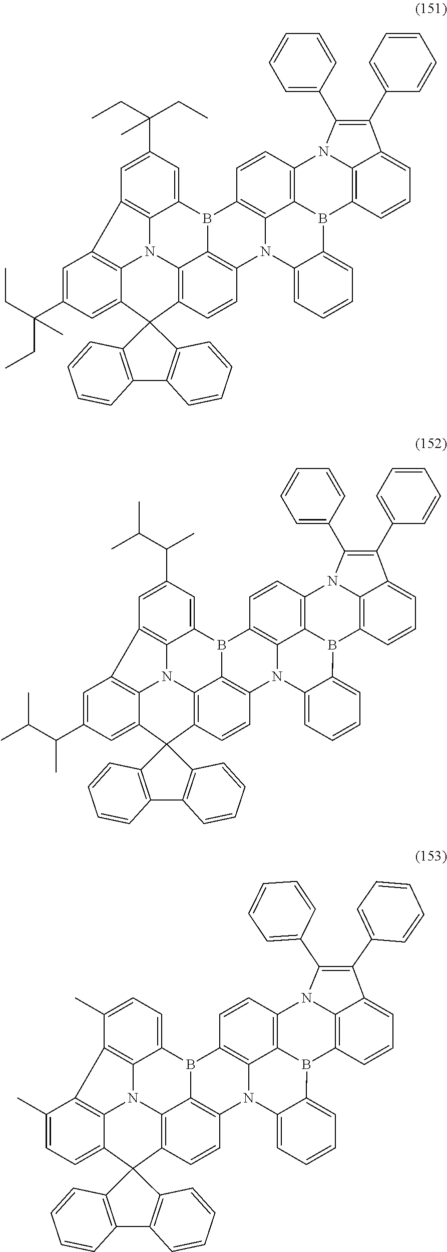 [SMILES: CCC(C)(CC)c1cc2c3c(c1)c1cc(C(C)(CC)CC)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CC(C)C(C)c1cc2c3c(c1)c1cc(C(C)C(C)C)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; Cc1ccc2c3c1c1c(C)ccc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21]

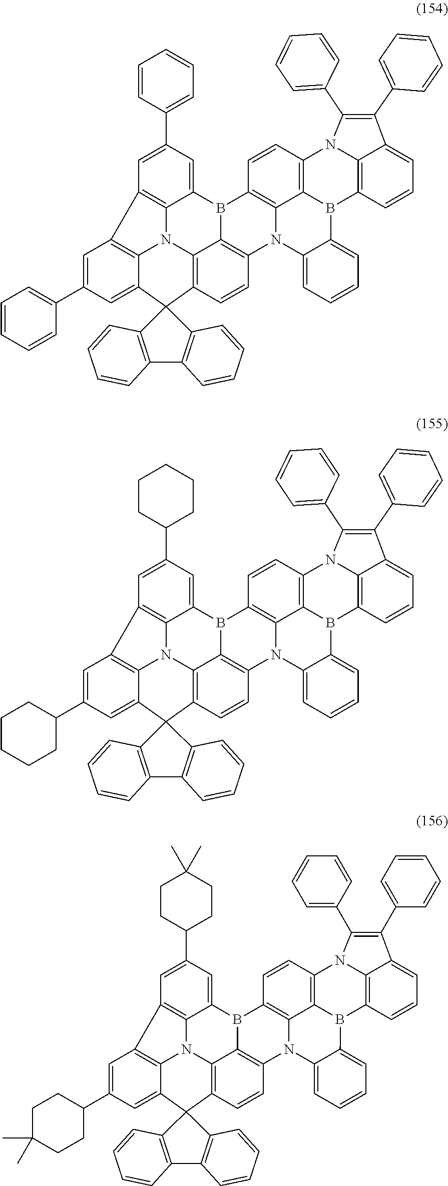 [SMILES: c1ccc(-c2cc3c4c(c2)c2cc(-c5ccccc5)cc5c2n4-c2c(ccc4c2B3c2ccc3c6c2N4c2ccccc2B6c2cccc4c(-c6ccccc6)c(-c6ccccc6)n-3c24)C52c3ccccc3-c3ccccc32)cc1 ; c1ccc(-c2c(-c3ccccc3)n3c4c(cccc24)B2c4ccccc4N4c5ccc6c7c5B(c5ccc-3c2c54)c2cc(C3CCCCC3)cc3c4cc(C5CCCCC5)cc(c4n-7c23)C62c3ccccc3-c3ccccc32)cc1 ; CC1(C)CCC(c2cc3c4c(c2)c2cc(C5CCC(C)(C)CC5)cc5c2n4-c2c(ccc4c2B3c2ccc3c6c2N4c2ccccc2B6c2cccc4c(-c6ccccc6)c(-c6ccccc6)n-3c24)C52c3ccccc3-c3ccccc32)CC1]

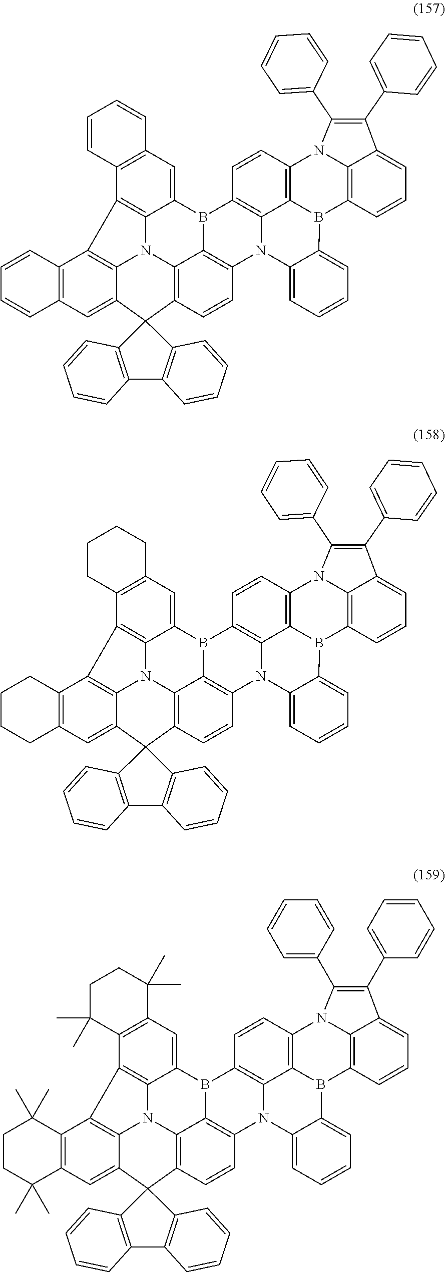 [SMILES: c1ccc(-c2c(-c3ccccc3)n3c4c(cccc24)B2c4ccccc4N4c5ccc6c7c5B(c5ccc-3c2c54)c2cc3ccccc3c3c4c5ccccc5cc(c4n-7c23)C62c3ccccc3-c3ccccc32)cc1 ; c1ccc(-c2c(-c3ccccc3)n3c4c(cccc24)B2c4ccccc4N4c5ccc6c7c5B(c5ccc-3c2c54)c2cc3c(c4c5c8c(cc(c5n-7c24)C62c4ccccc4-c4ccccc42)CCCC8)CCCC3)cc1 ; CC1(C)CCC(C)(C)c2c1cc1c3c2c2c4c(cc5c2n3-c2c(ccc3c2B1c1ccc2c6c1N3c1ccccc1B6c1cccc3c(-c6ccccc6)c(-c6ccccc6)n-2c13)C51c2ccccc2-c2ccccc21)C(C)(C)CCC4(C)C]

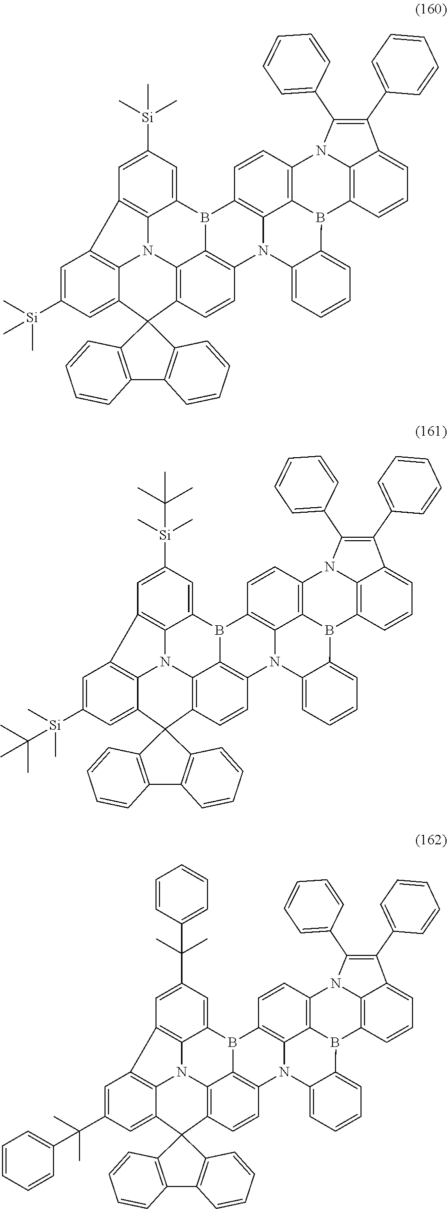 [SMILES: C[Si](C)(C)c1cc2c3c(c1)c1cc([Si](C)(C)C)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CC(C)(C)[Si](C)(C)c1cc2c3c(c1)c1cc([Si](C)(C)C(C)(C)C)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21 ; CC(C)(c1ccccc1)c1cc2c3c(c1)c1cc(C(C)(C)c4ccccc4)cc4c1n3-c1c(ccc3c1B2c1ccc2c5c1N3c1ccccc1B5c1cccc3c(-c5ccccc5)c(-c5ccccc5)n-2c13)C41c2ccccc2-c2ccccc21]

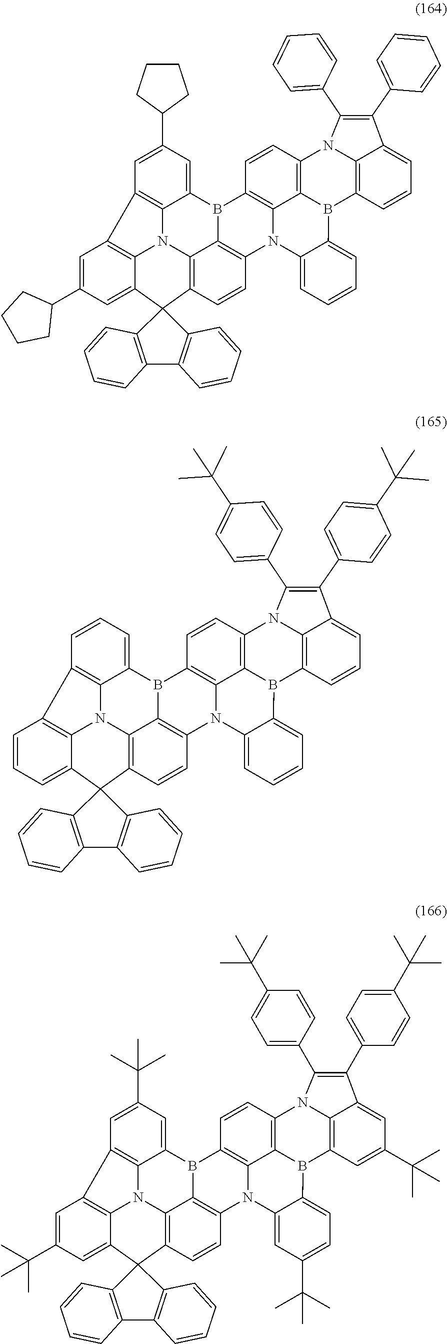

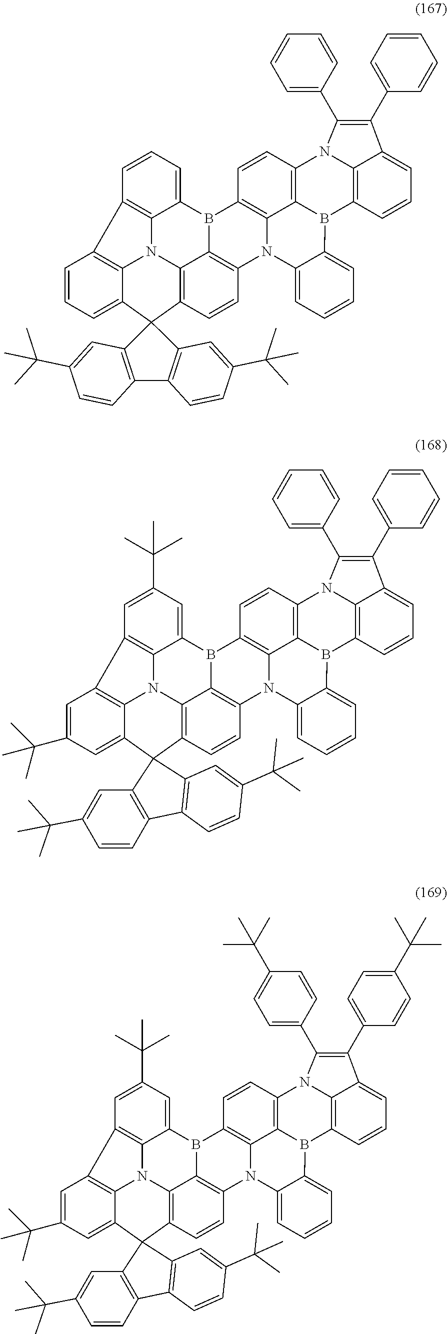 [SMILES: CC(C)(C)c1ccc2c(c1)C1(c3cc(C(C)(C)C)ccc3-2)c2ccc3c4c2-n2c5c(cccc5c5cccc1c52)B4c1ccc2c4c1N3c1ccccc1B4c1cccc3c(-c4ccccc4)c(-c4ccccc4)n-2c13 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccccc1B4c1cccc3c(-c4ccccc4)c(-c4ccccc4)n-2c13 ; CC(C)(C)c1ccc(-c2c(-c3ccc(C(C)(C)C)cc3)n3c4c(cccc24)B2c4ccccc4N4c5ccc6c7c5B(c5ccc-3c2c54)c2cc(C(C)(C)C)cc3c4cc(C(C)(C)C)cc(c4n-7c23)C62c3cc(C(C)(C)C)ccc3-c3ccc(C(C)(C)C)cc32)cc1]

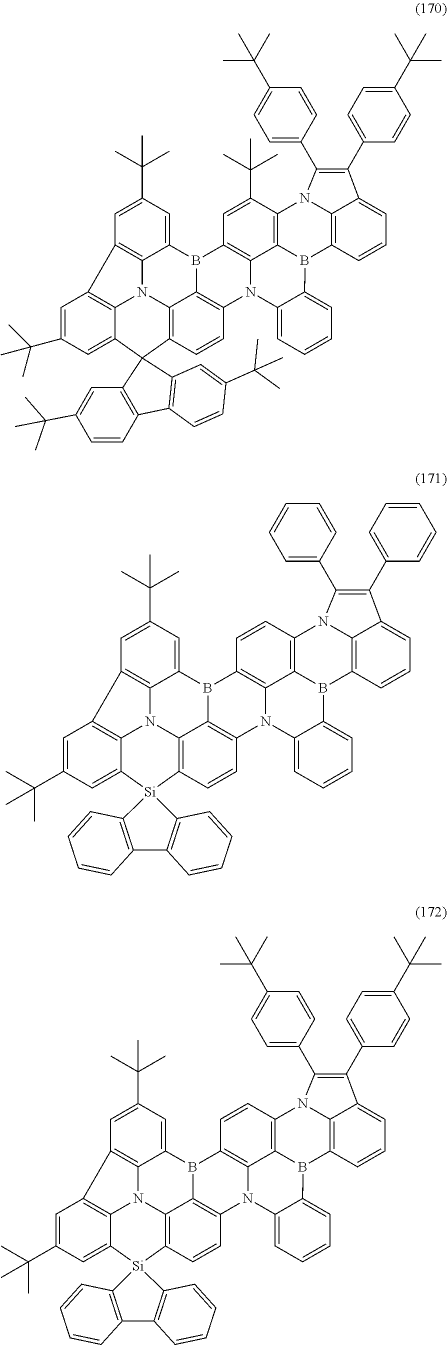

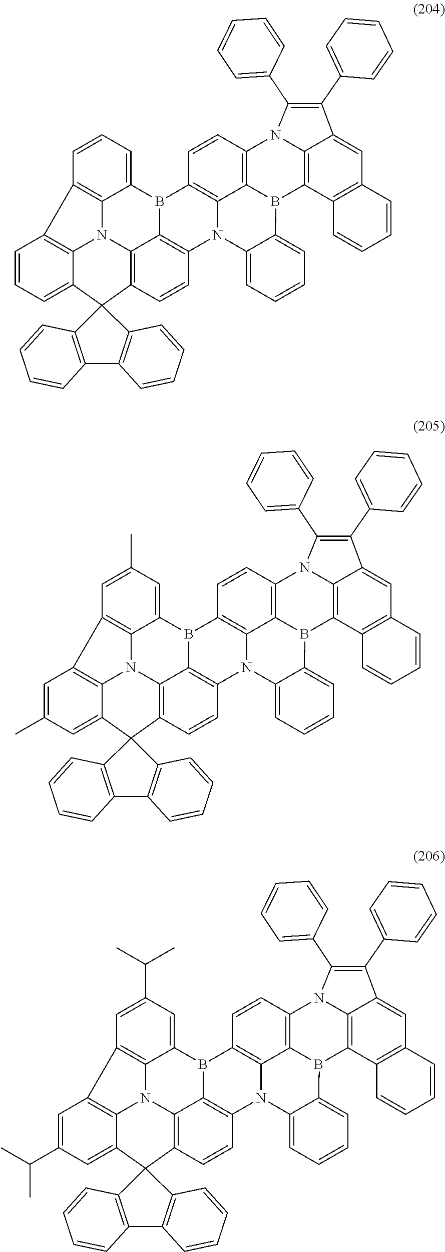 [SMILES: c1ccc(-c2c(-c3ccccc3)n3c4c(c5ccccc5cc24)B2c4ccccc4N4c5ccc6c7c5B(c5ccc-3c2c54)c2cccc3c4cccc(c4n-7c23)C62c3ccccc3-c3ccccc32)cc1 ; Cc1cc2c3c(c1)c1cc(C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CC(C)c1cc2c3c(c1)c1cc(C(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

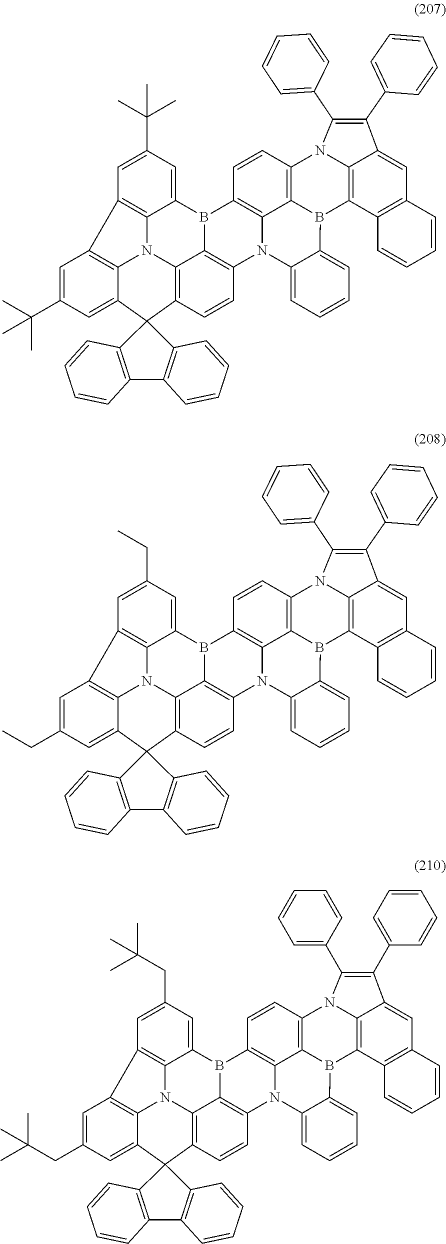 [SMILES: CC(C)(C)c1cc2c3c(c1)c1cc(C(C)(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CCc1cc2c3c(c1)c1cc(CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CC(C)(C)Cc1cc2c3c(c1)c1cc(CC(C)(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

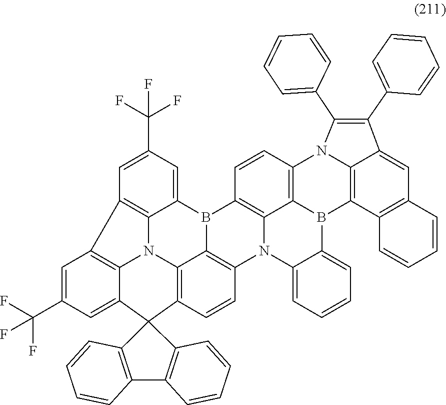 [SMILES: FC(F)(F)c1cc2c3c(c1)c1cc(C(F)(F)F)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

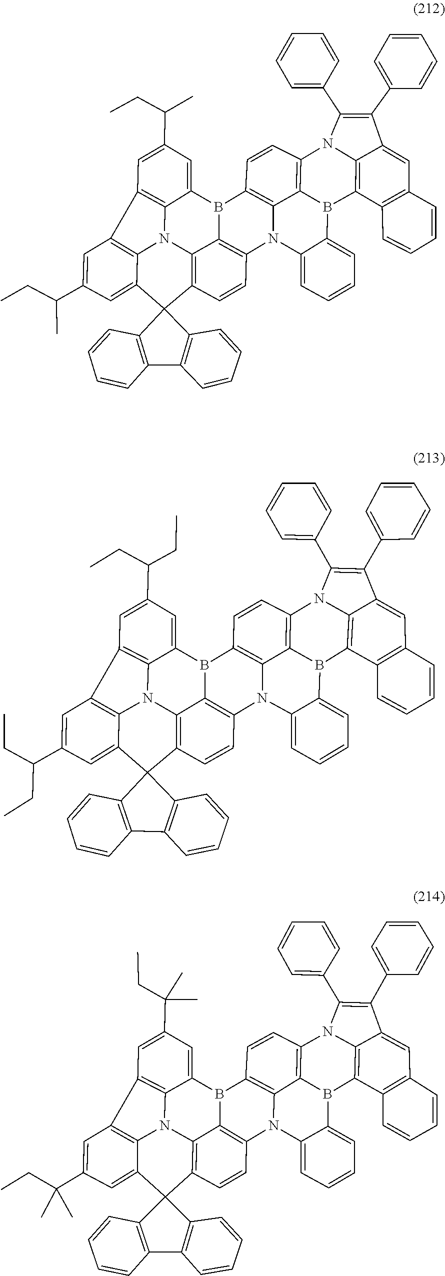 [SMILES: CCC(C)c1cc2c3c(c1)c1cc(C(C)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CCC(CC)c1cc2c3c(c1)c1cc(C(CC)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CCC(C)(C)c1cc2c3c(c1)c1cc(C(C)(C)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

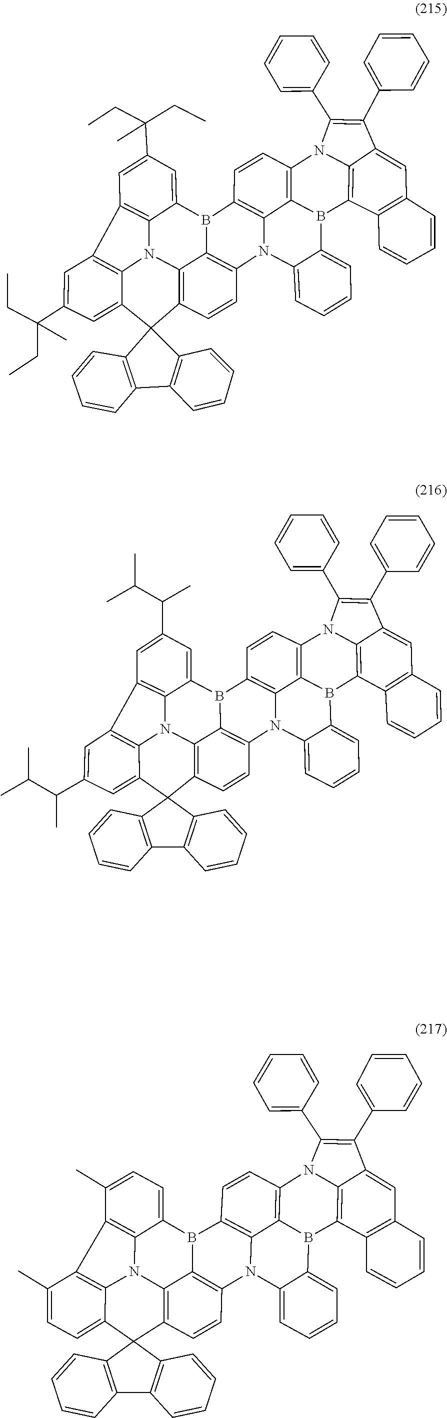 [SMILES: CCC(C)(CC)c1cc2c3c(c1)c1cc(C(C)(CC)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CC(C)C(C)c1cc2c3c(c1)c1cc(C(C)C(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; Cc1ccc2c3c1c1c(C)ccc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

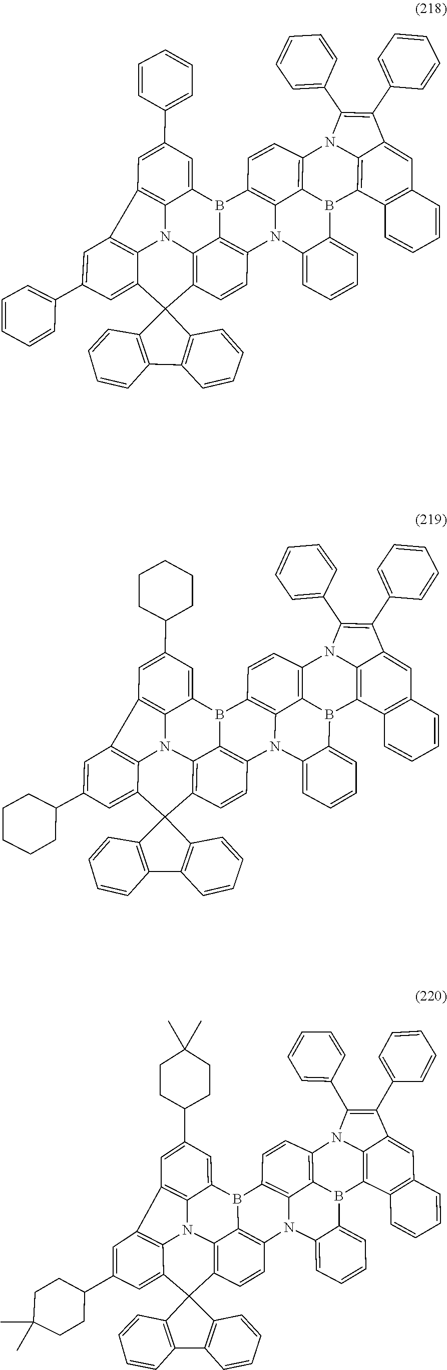 [SMILES: c1ccc(-c2cc3c4c(c2)c2cc(-c5ccccc5)cc5c2n4-c2c(ccc4c2B3c2ccc3c6c2N4c2ccccc2B6c2c4ccccc4cc4c(-c6ccccc6)c(-c6ccccc6)n-3c24)C52c3ccccc3-c3ccccc32)cc1 ; c1ccc(-c2c(-c3ccccc3)n3c4c(c5ccccc5cc24)B2c4ccccc4N4c5ccc6c7c5B(c5ccc-3c2c54)c2cc(C3CCCCC3)cc3c4cc(C5CCCCC5)cc(c4n-7c23)C62c3ccccc3-c3ccccc32)cc1 ; CC1(C)CCC(c2cc3c4c(c2)c2cc(C5CCC(C)(C)CC5)cc5c2n4-c2c(ccc4c2B3c2ccc3c6c2N4c2ccccc2B6c2c4ccccc4cc4c(-c6ccccc6)c(-c6ccccc6)n-3c24)C52c3ccccc3-c3ccccc32)CC1]

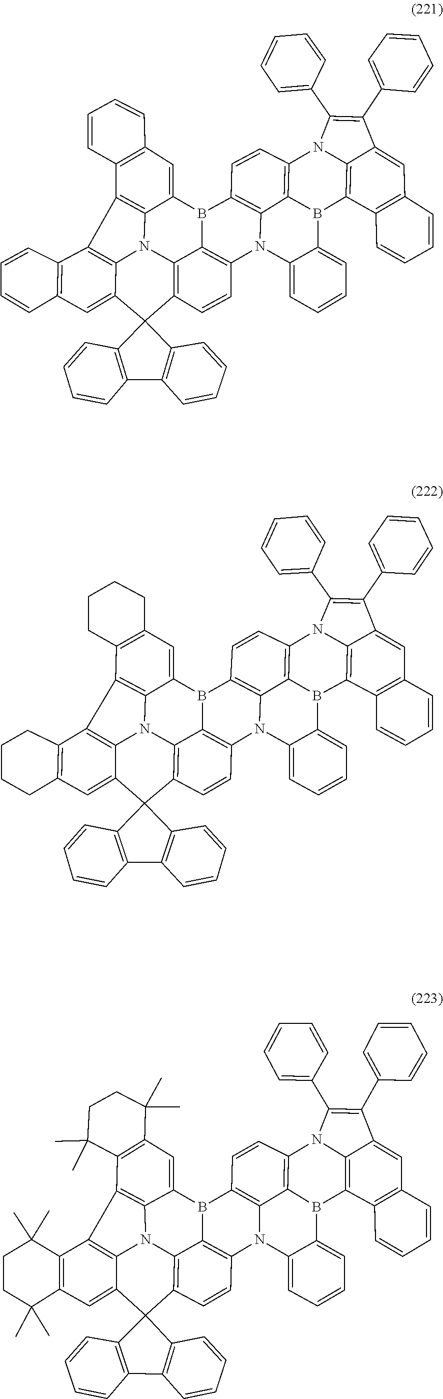 [SMILES: c1ccc(-c2c(-c3ccccc3)n3c4c(c5ccccc5cc24)B2c4ccccc4N4c5ccc6c7c5B(c5ccc-3c2c54)c2cc3ccccc3c3c4c5ccccc5cc(c4n-7c23)C62c3ccccc3-c3ccccc32)cc1 ; c1ccc(-c2c(-c3ccccc3)n3c4c(c5ccccc5cc24)B2c4ccccc4N4c5ccc6c7c5B(c5ccc-3c2c54)c2cc3c(c4c5c8c(cc(c5n-7c24)C62c4ccccc4-c4ccccc42)CCCC8)CCCC3)cc1 ; CC1(C)CCC(C)(C)c2c1cc1c3c2c2c4c(cc5c2n3-c2c(ccc3c2B1c1ccc2c6c1N3c1ccccc1B6c1c3ccccc3cc3c(-c6ccccc6)c(-c6ccccc6)n-2c13)C51c2ccccc2-c2ccccc21)C(C)(C)CCC4(C)C]

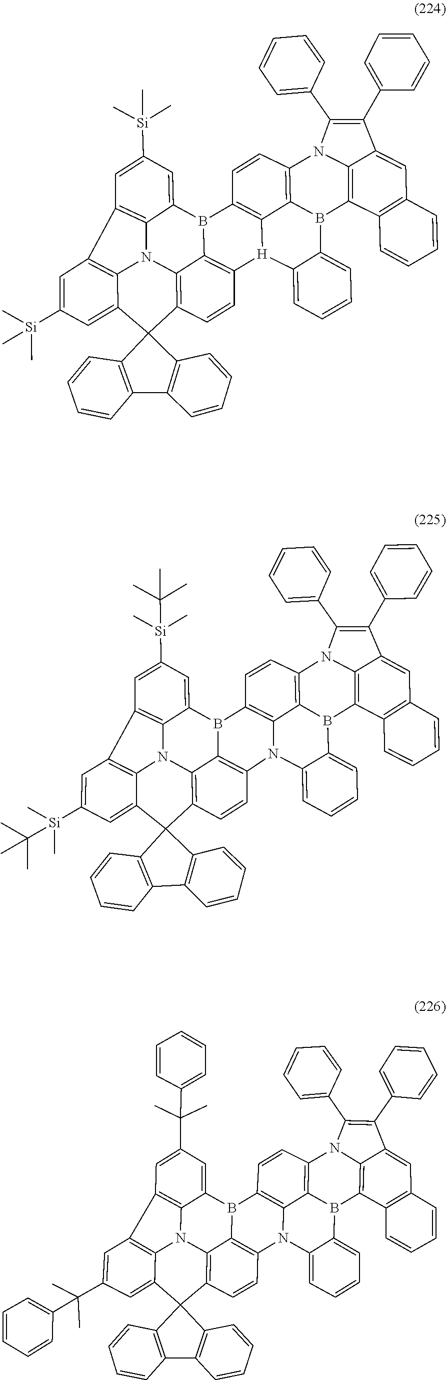

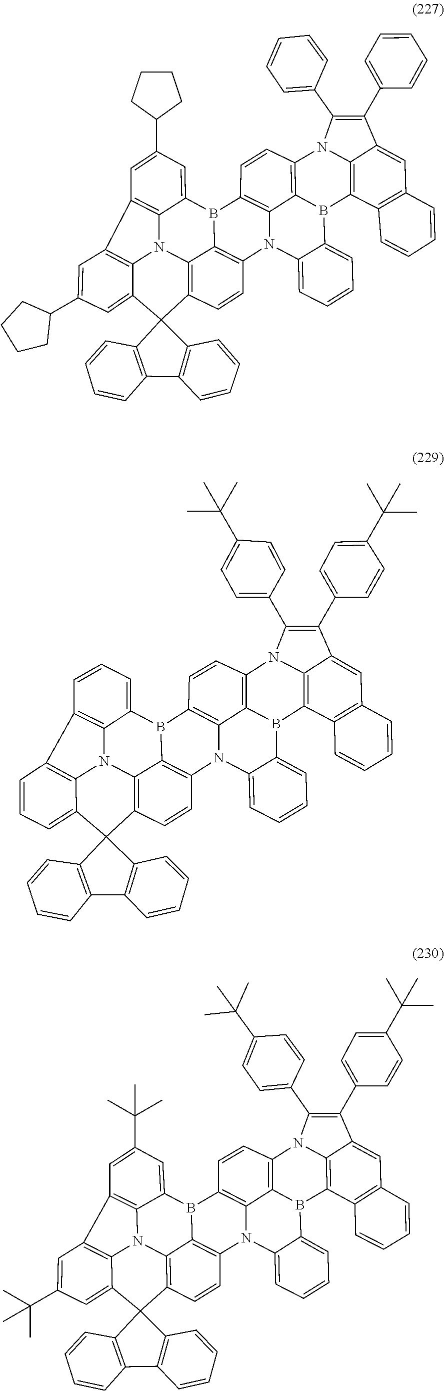

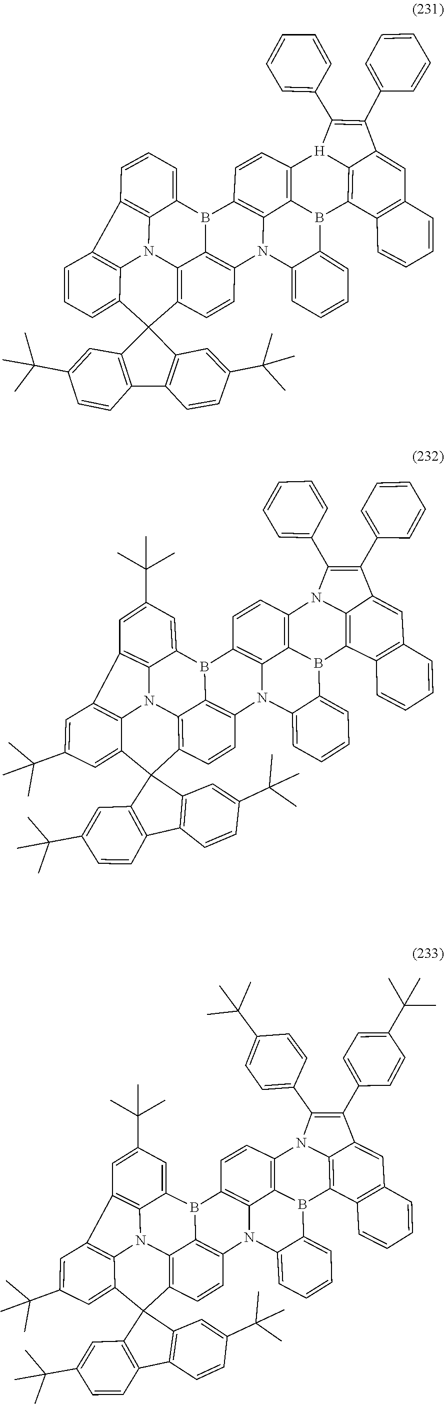

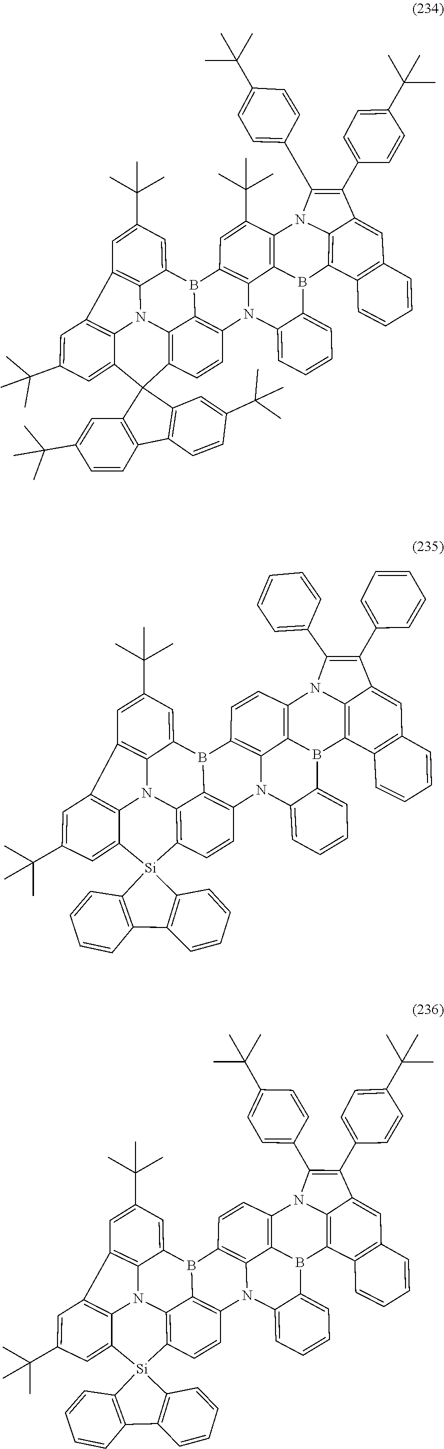

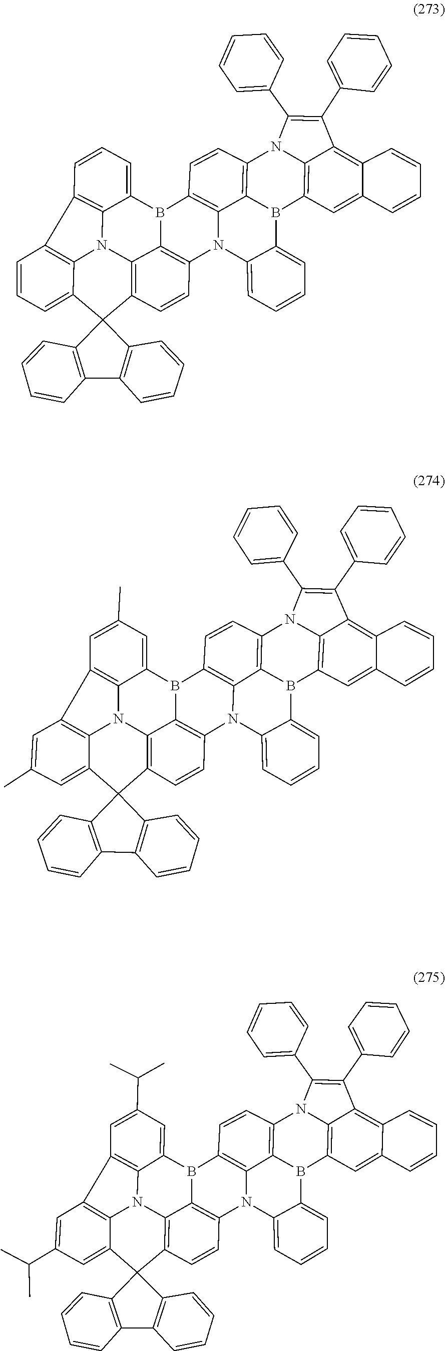 [SMILES: c1ccc(-c2c(-c3ccccc3)n3c4c(cc5ccccc5c24)B2c4ccccc4N4c5ccc6c7c5B(c5ccc-3c2c54)c2cccc3c4cccc(c4n-7c23)C62c3ccccc3-c3ccccc32)cc1 ; Cc1cc2c3c(c1)c1cc(C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CC(C)c1cc2c3c(c1)c1cc(C(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21]

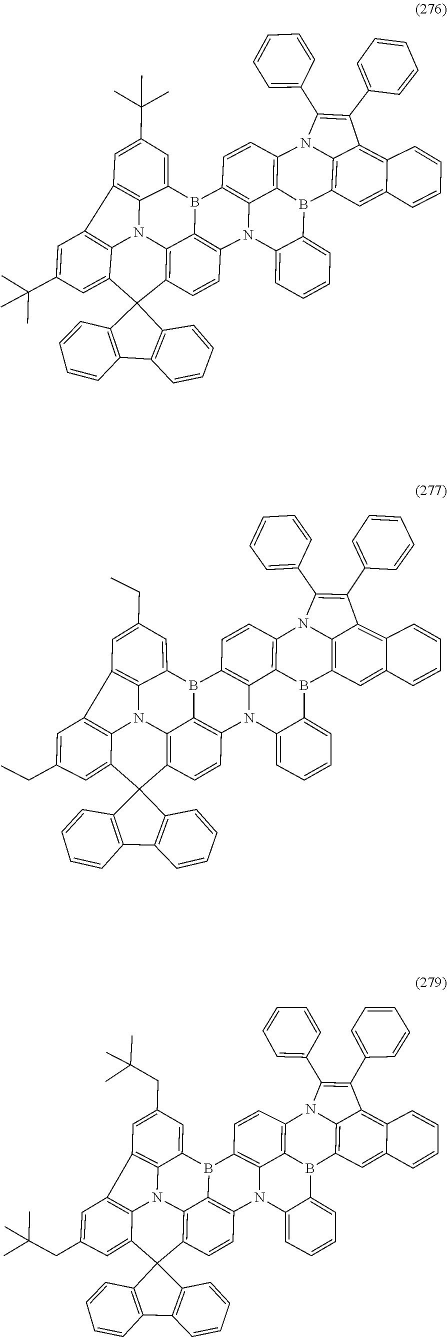 [SMILES: CC(C)(C)c1cc2c3c(c1)c1cc(C(C)(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CCc1cc2c3c(c1)c1cc(CC)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CC(C)(C)Cc1cc2c3c(c1)c1cc(CC(C)(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21]

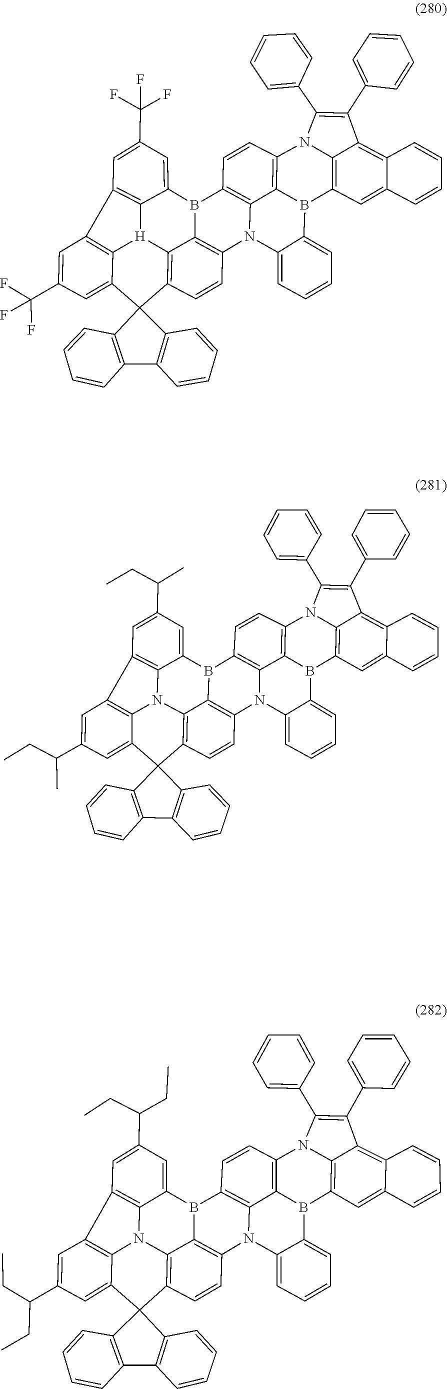

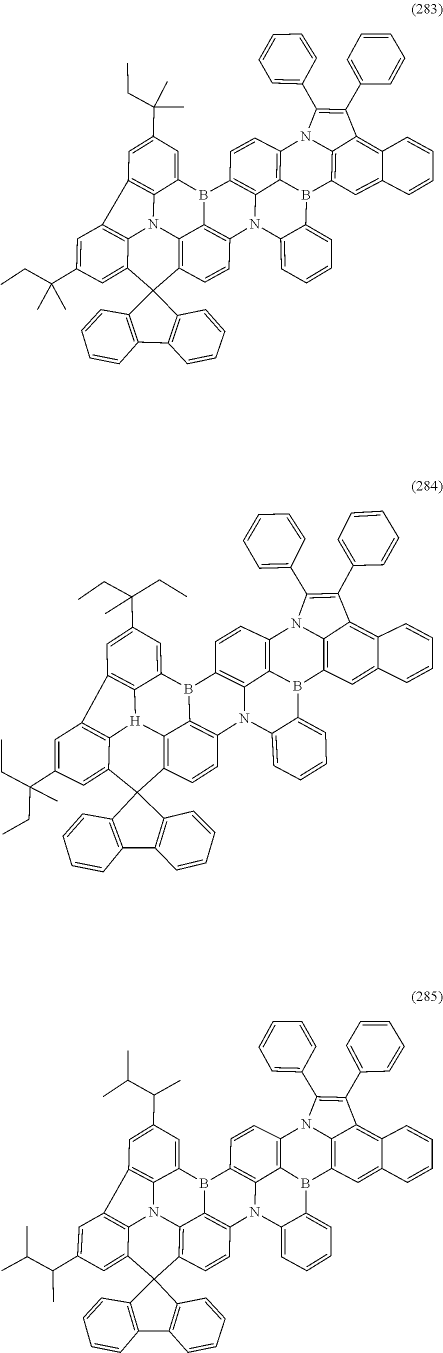

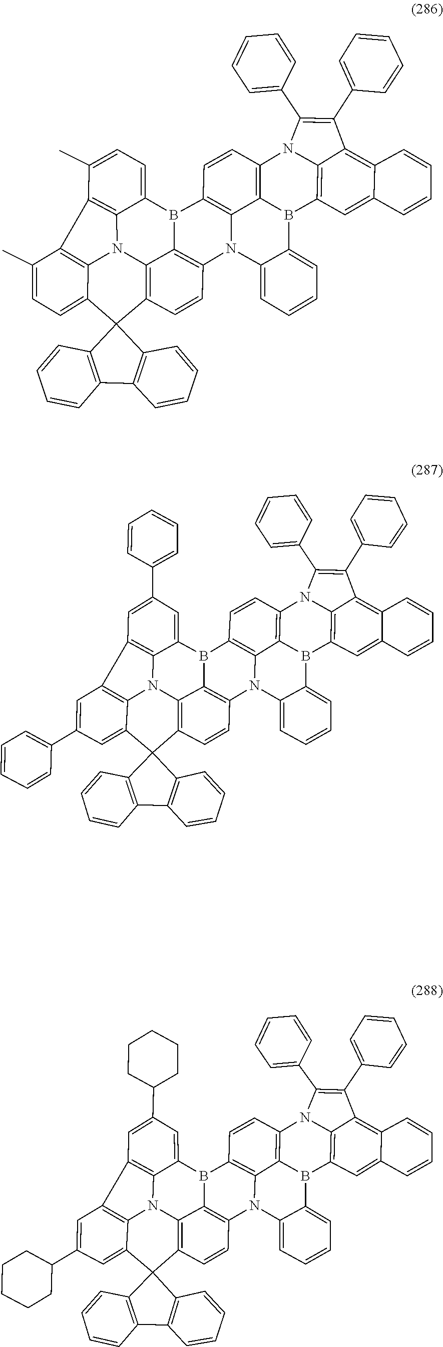 [SMILES: Cc1ccc2c3c1c1c(C)ccc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; c1ccc(-c2cc3c4c(c2)c2cc(-c5ccccc5)cc5c2n4-c2c(ccc4c2B3c2ccc3c6c2N4c2ccccc2B6c2cc4ccccc4c4c(-c6ccccc6)c(-c6ccccc6)n-3c24)C52c3ccccc3-c3ccccc32)cc1 ; c1ccc(-c2c(-c3ccccc3)n3c4c(cc5ccccc5c24)B2c4ccccc4N4c5ccc6c7c5B(c5ccc-3c2c54)c2cc(C3CCCCC3)cc3c4cc(C5CCCCC5)cc(c4n-7c23)C62c3ccccc3-c3ccccc32)cc1]

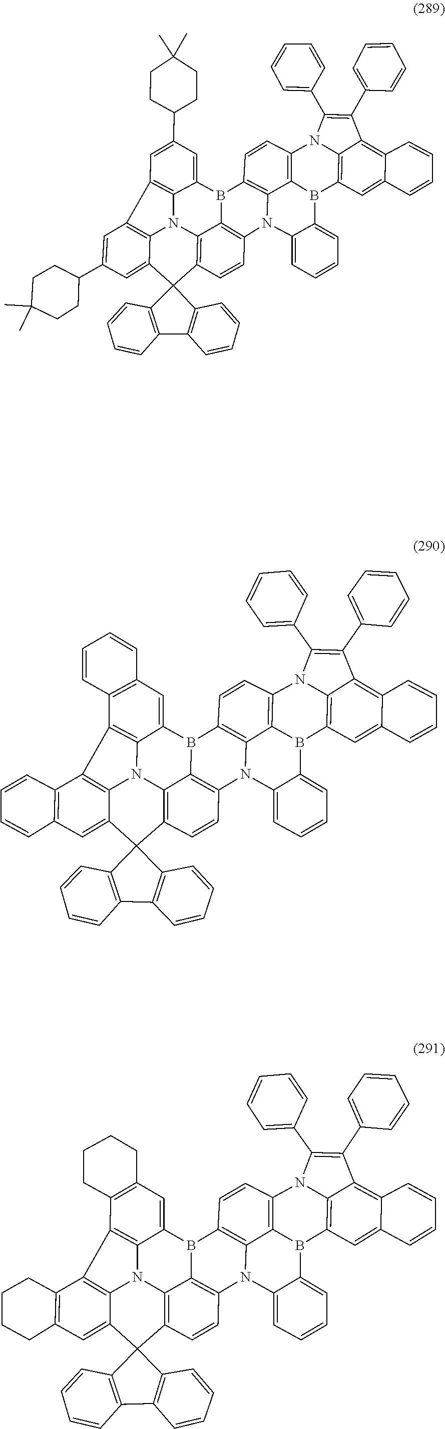 [SMILES: CC1(C)CCC(c2cc3c4c(c2)c2cc(C5CCC(C)(C)CC5)cc5c2n4-c2c(ccc4c2B3c2ccc3c6c2N4c2ccccc2B6c2cc4ccccc4c4c(-c6ccccc6)c(-c6ccccc6)n-3c24)C52c3ccccc3-c3ccccc32)CC1 ; c1ccc(-c2c(-c3ccccc3)n3c4c(cc5ccccc5c24)B2c4ccccc4N4c5ccc6c7c5B(c5ccc-3c2c54)c2cc3ccccc3c3c4c5ccccc5cc(c4n-7c23)C62c3ccccc3-c3ccccc32)cc1 ; c1ccc(-c2c(-c3ccccc3)n3c4c(cc5ccccc5c24)B2c4ccccc4N4c5ccc6c7c5B(c5ccc-3c2c54)c2cc3c(c4c5c8c(cc(c5n-7c24)C62c4ccccc4-c4ccccc42)CCCC8)CCCC3)cc1]

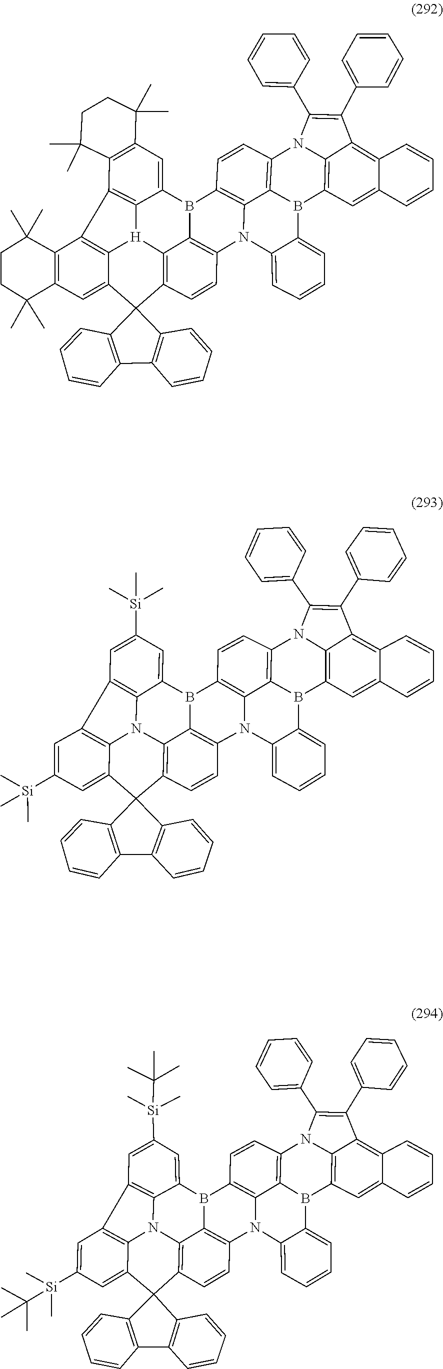

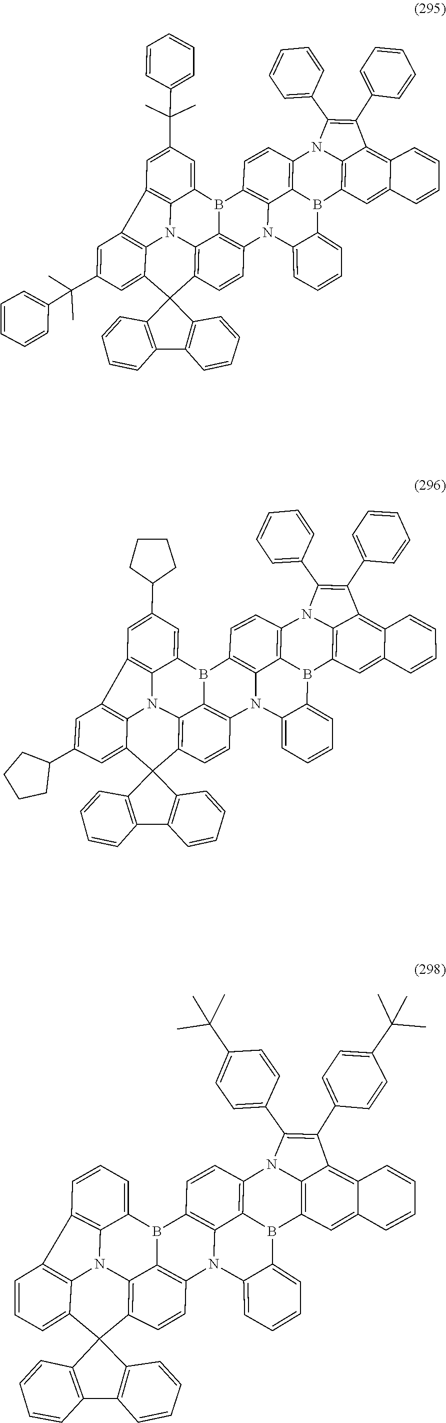 [SMILES: CC(C)(c1ccccc1)c1cc2c3c(c1)c1cc(C(C)(C)c4ccccc4)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; c1ccc(-c2c(-c3ccccc3)n3c4c(cc5ccccc5c24)B2c4ccccc4N4c5ccc6c7c5B(c5ccc-3c2c54)c2cc(C3CCCC3)cc3c4cc(C5CCCC5)cc(c4n-7c23)C62c3ccccc3-c3ccccc32)cc1 ; CC(C)(C)c1ccc(-c2c(-c3ccc(C(C)(C)C)cc3)n3c4c(cc5ccccc5c24)B2c4ccccc4N4c5ccc6c7c5B(c5ccc-3c2c54)c2cccc3c4cccc(c4n-7c23)C62c3ccccc3-c3ccccc32)cc1]

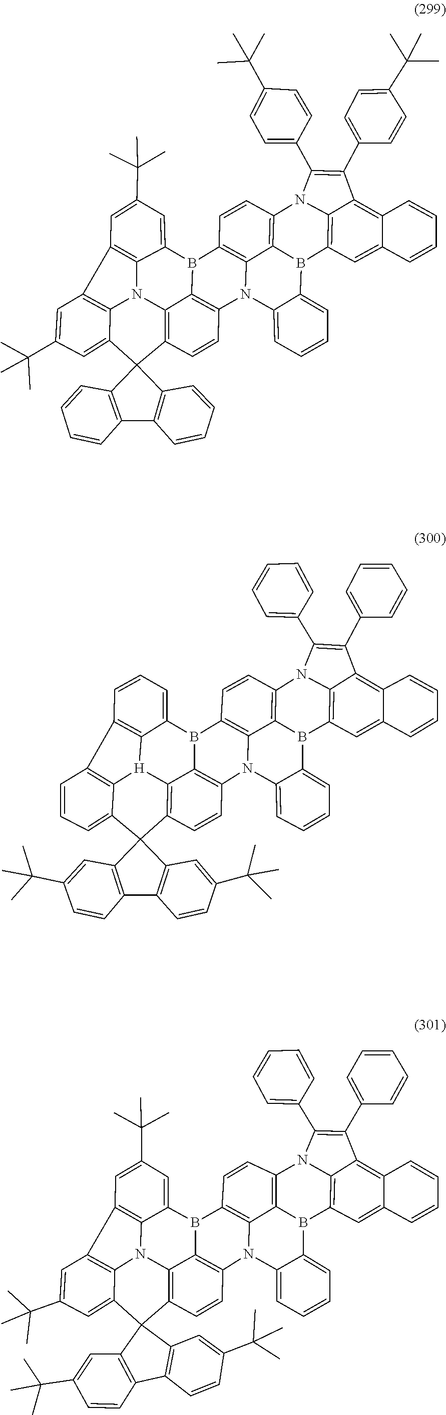

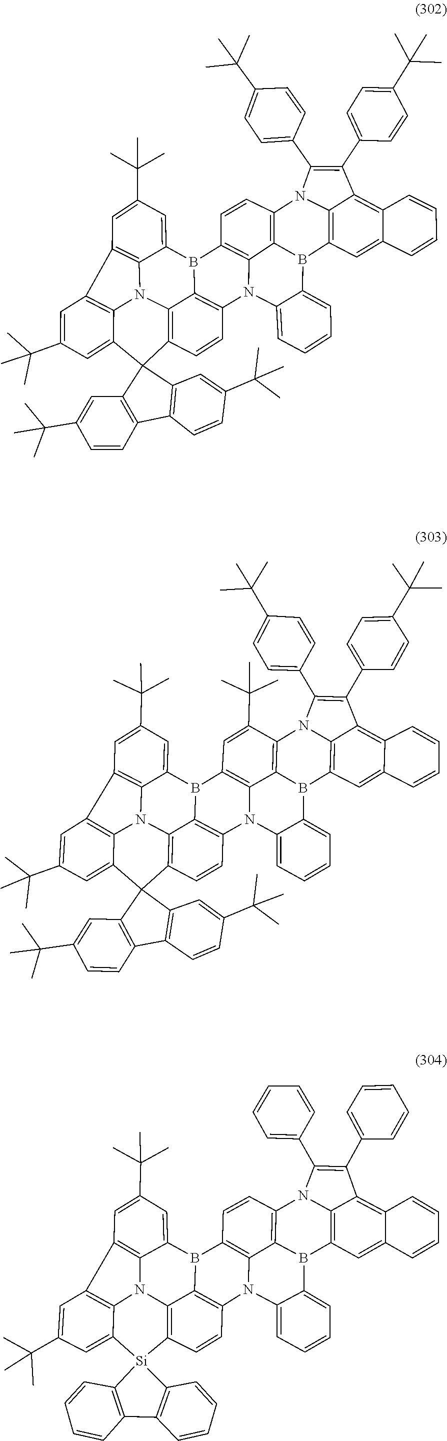

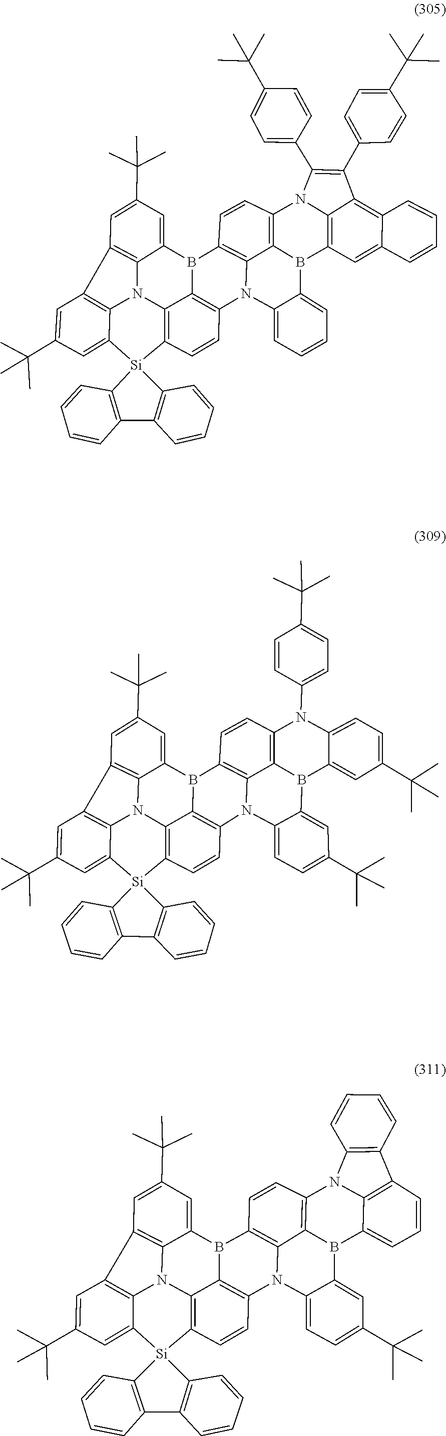

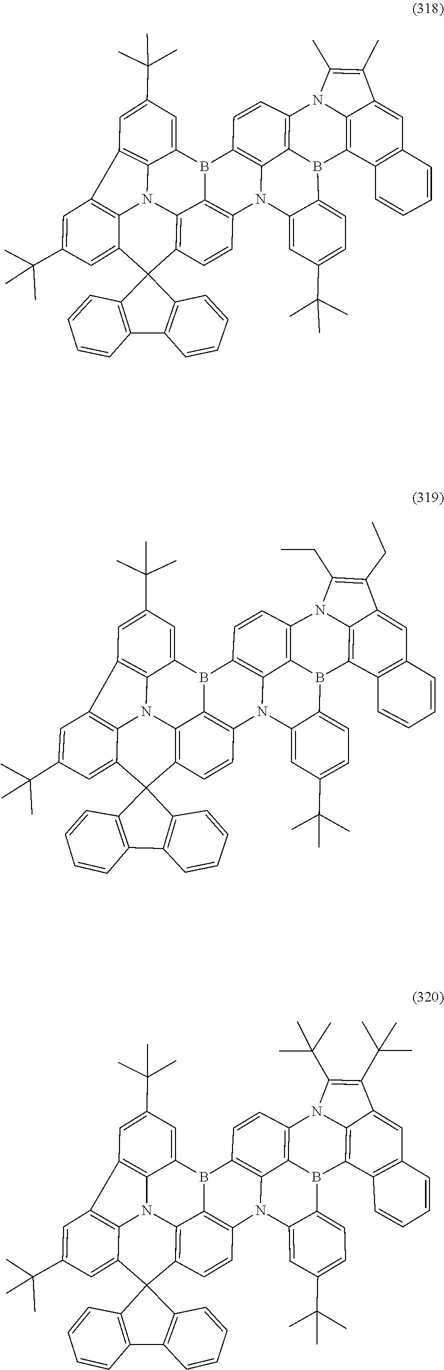 [SMILES: Cc1c(C)n2c3c(c4ccccc4cc13)B1c3ccc(C(C)(C)C)cc3N3c4ccc5c6c4B(c4ccc-2c1c43)c1cc(C(C)(C)C)cc2c3cc(C(C)(C)C)cc(c3n-6c12)C51c2ccccc2-c2ccccc21 ; CCc1c(CC)n2c3c(c4ccccc4cc13)B1c3ccc(C(C)(C)C)cc3N3c4ccc5c6c4B(c4ccc-2c1c43)c1cc(C(C)(C)C)cc2c3cc(C(C)(C)C)cc(c3n-6c12)C51c2ccccc2-c2ccccc21 ; CC(C)(C)c1ccc2c(c1)N1c3ccc4c5c3B(c3ccc6c(c31)B2c1c2ccccc2cc2c(C(C)(C)C)c(C(C)(C)C)n-6c12)c1cc(C(C)(C)C)cc2c3cc(C(C)(C)C)cc(c3n-5c12)C41c2ccccc2-c2ccccc21]

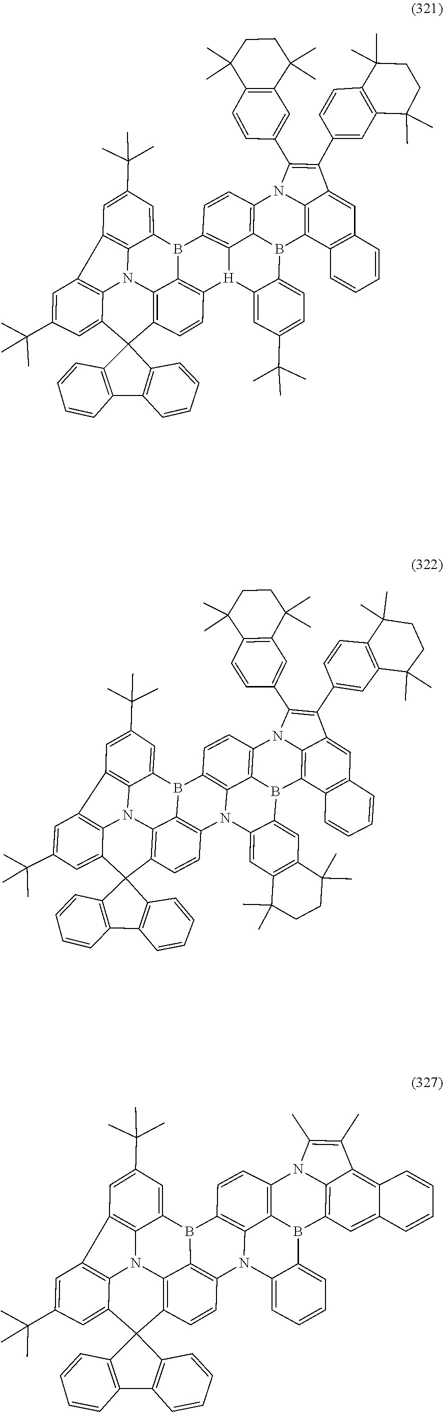

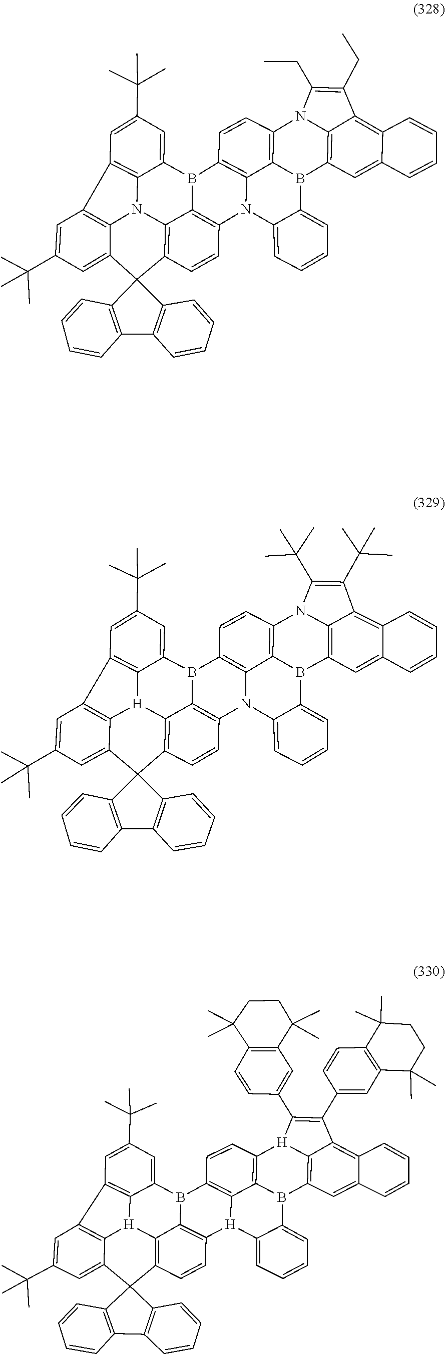

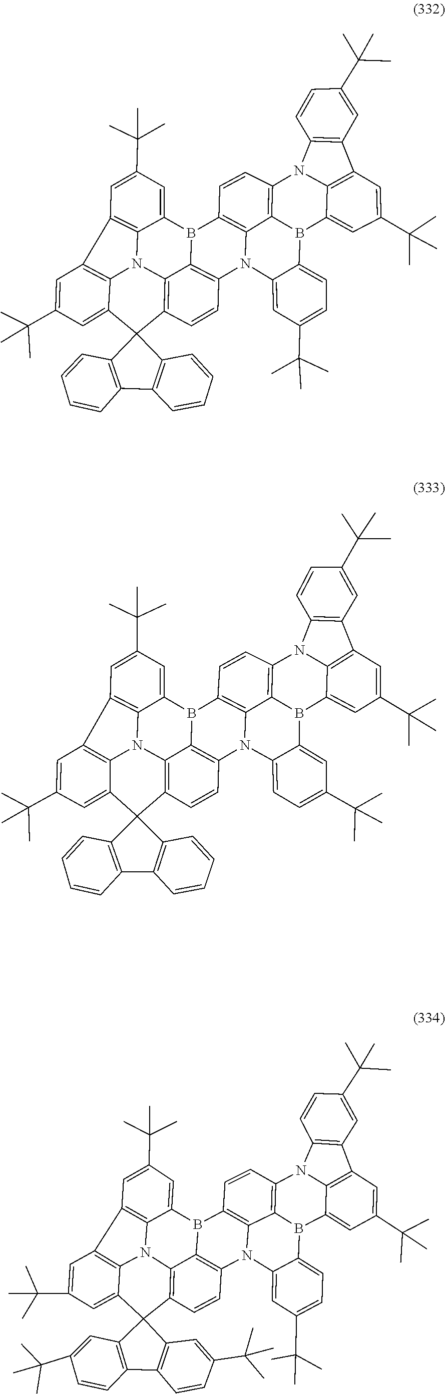

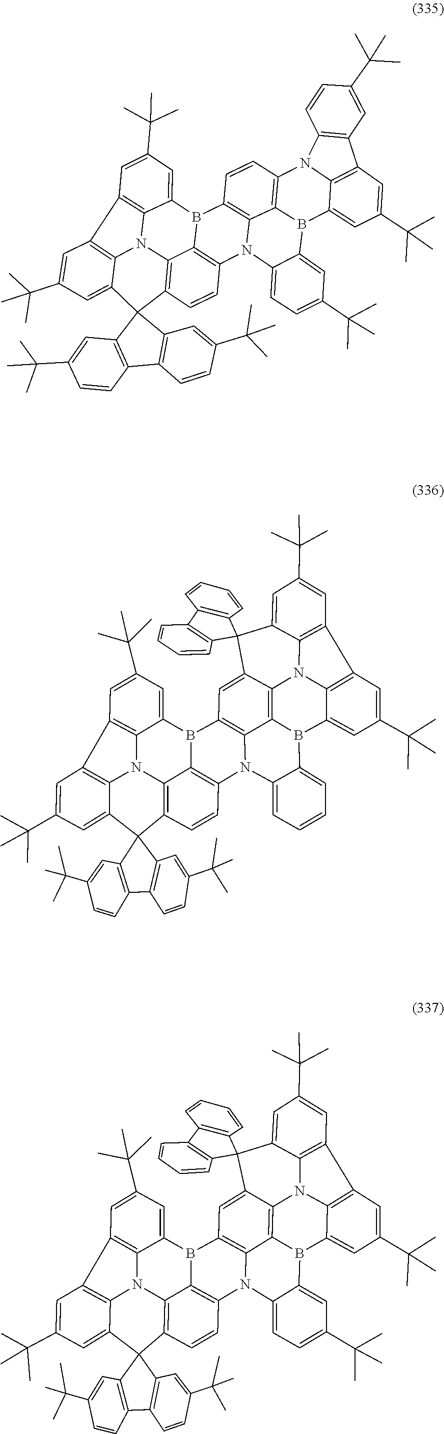

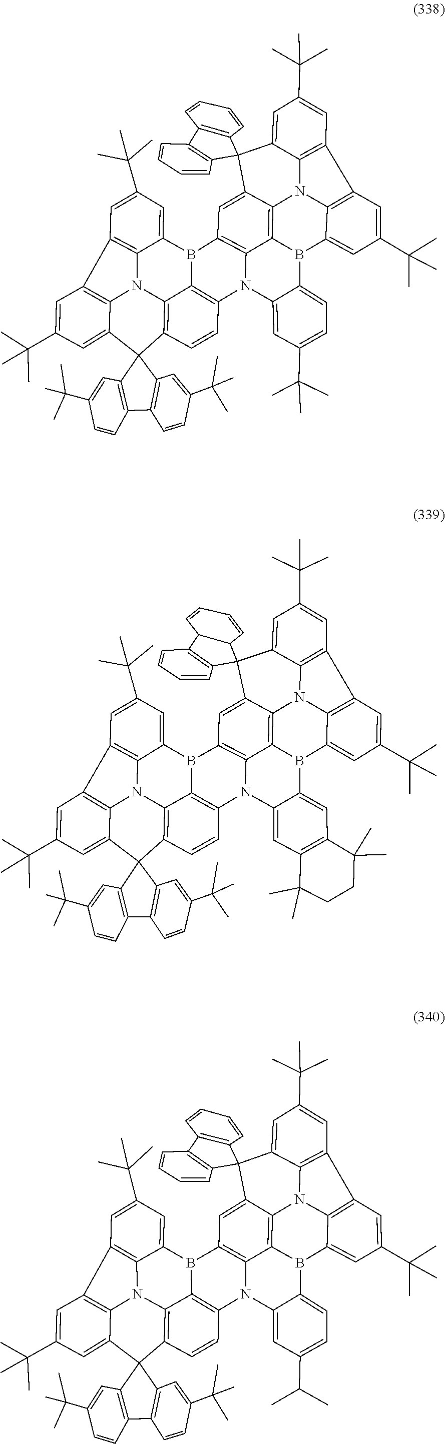

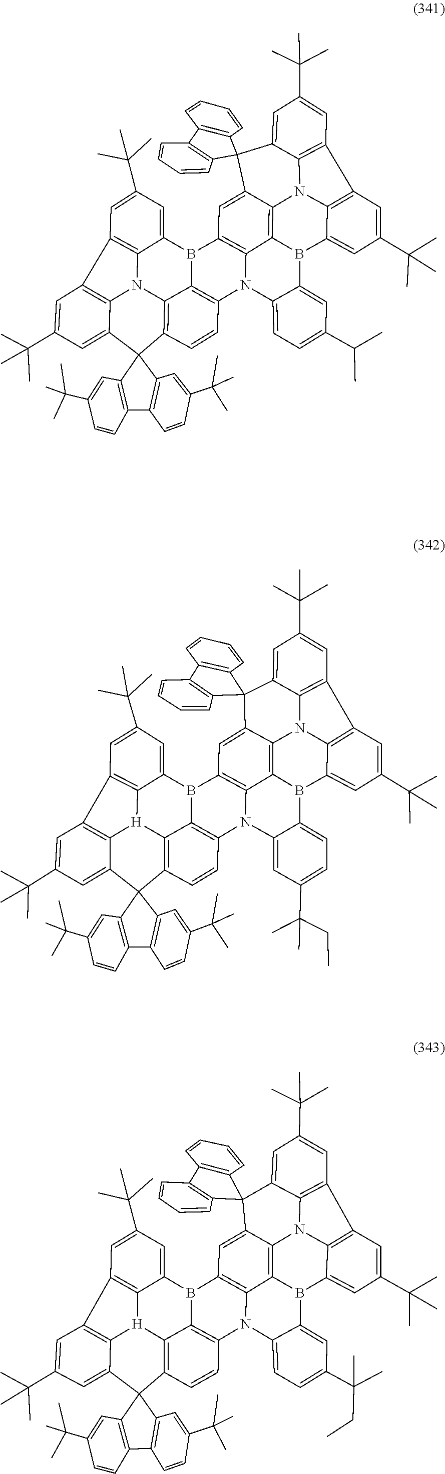

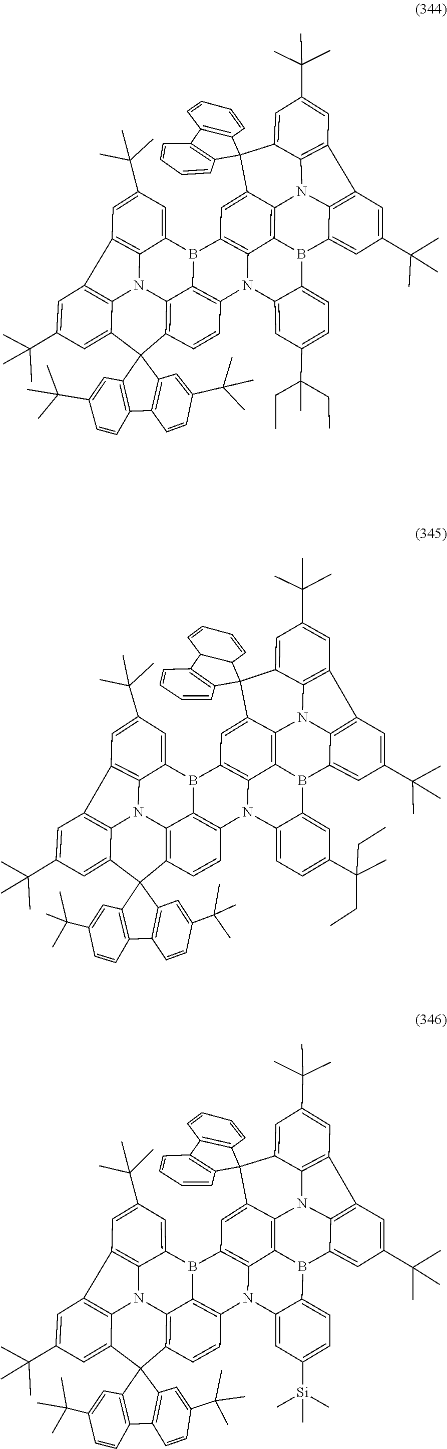

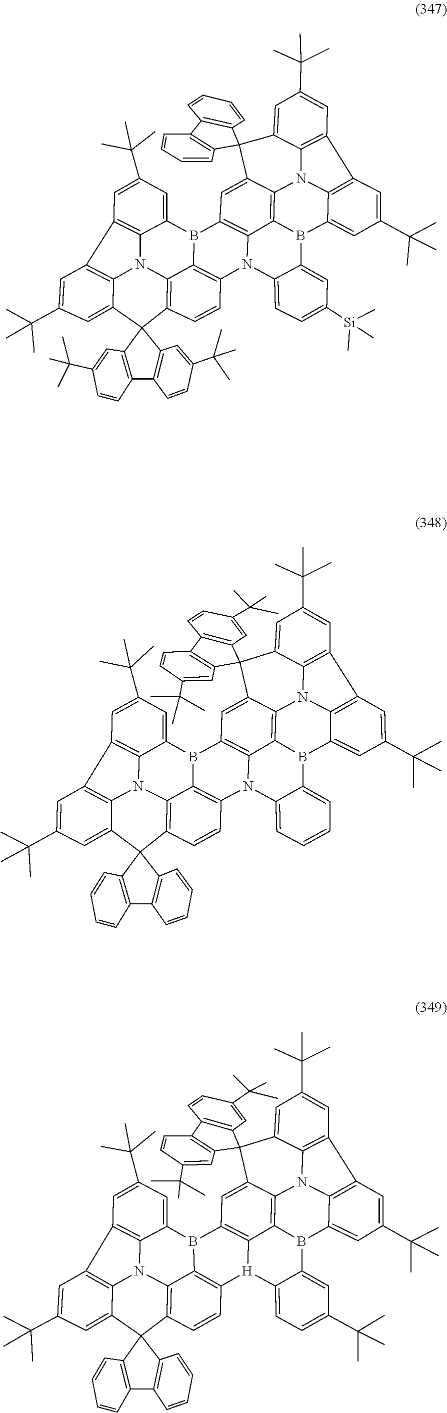

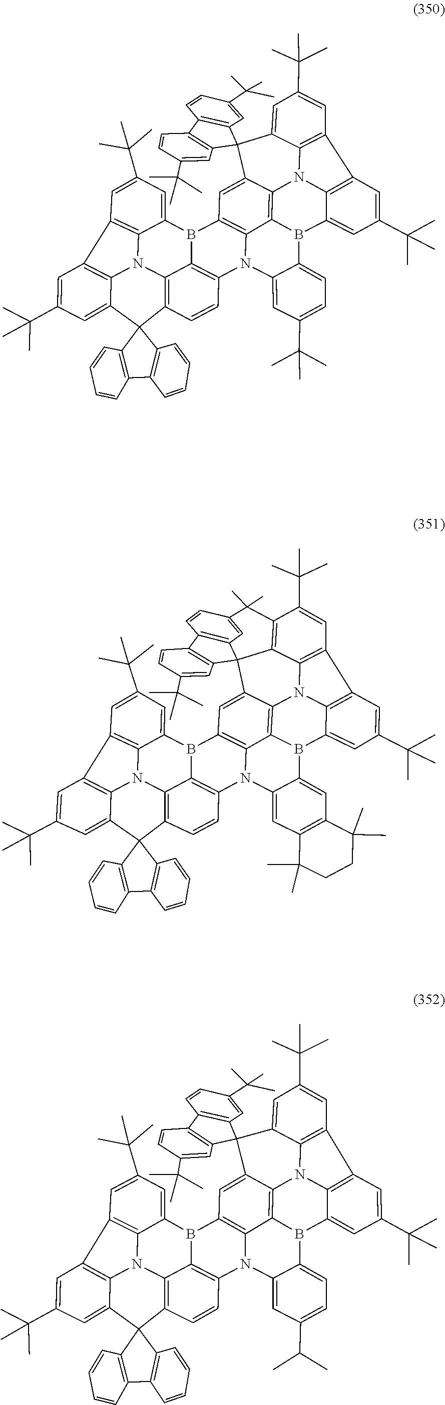

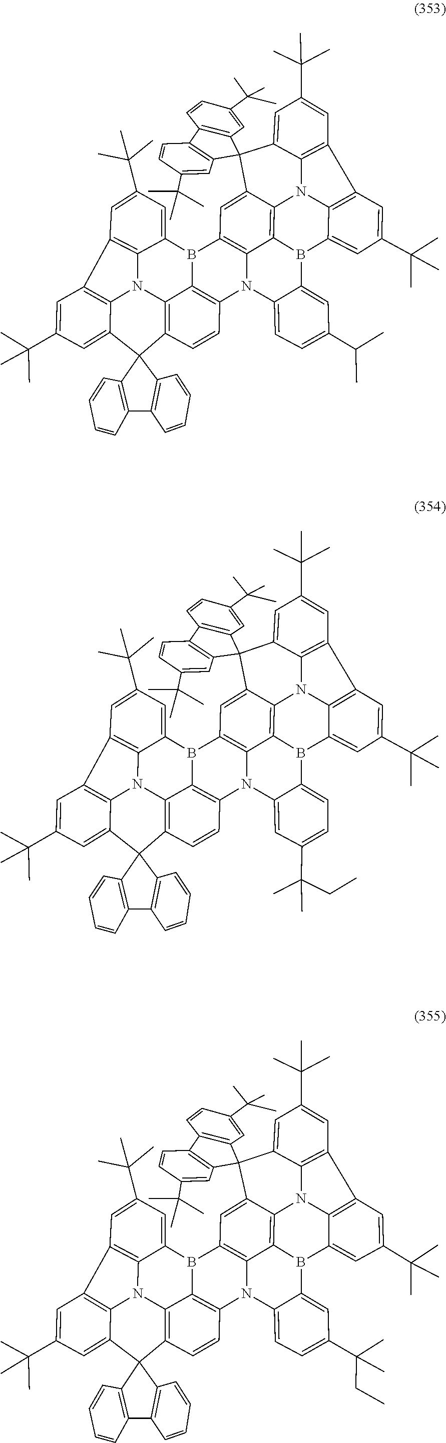

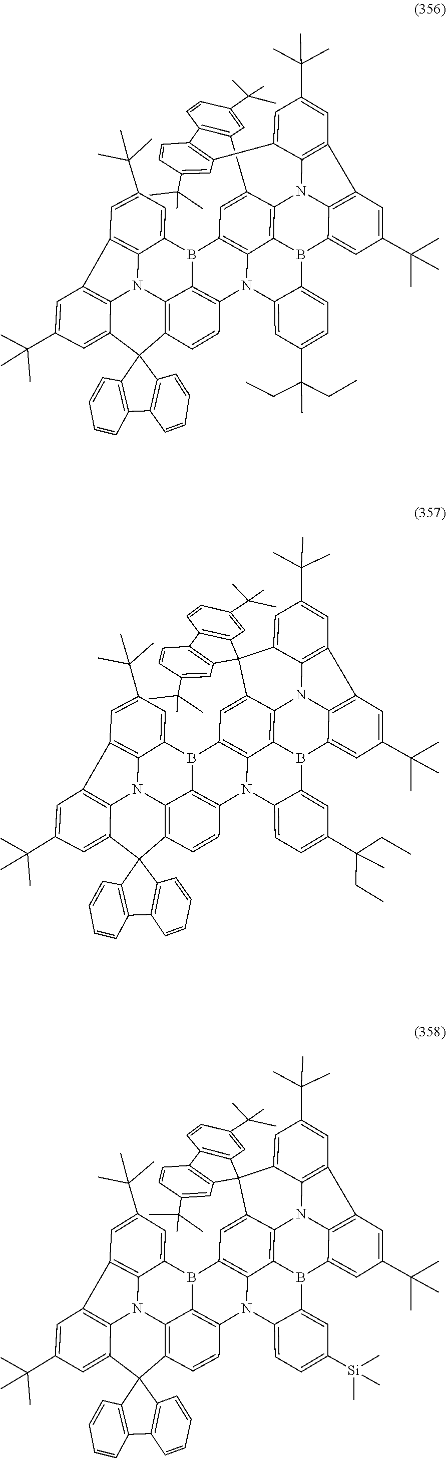

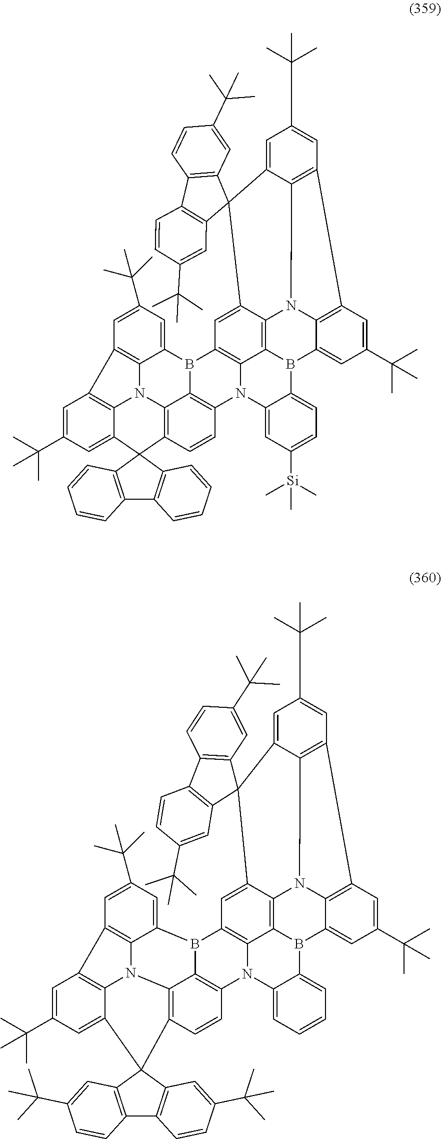

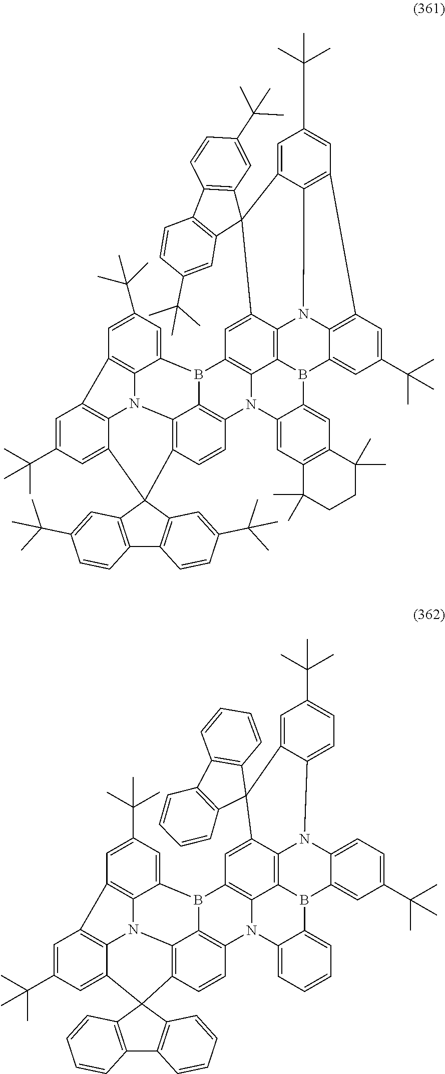

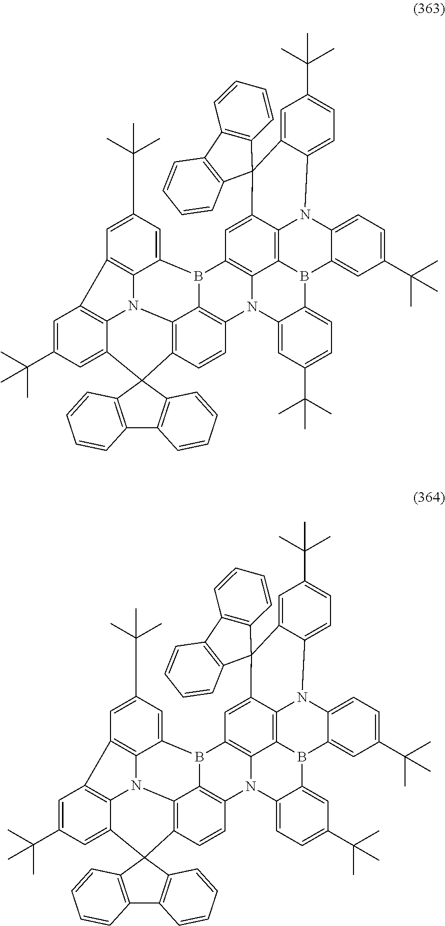

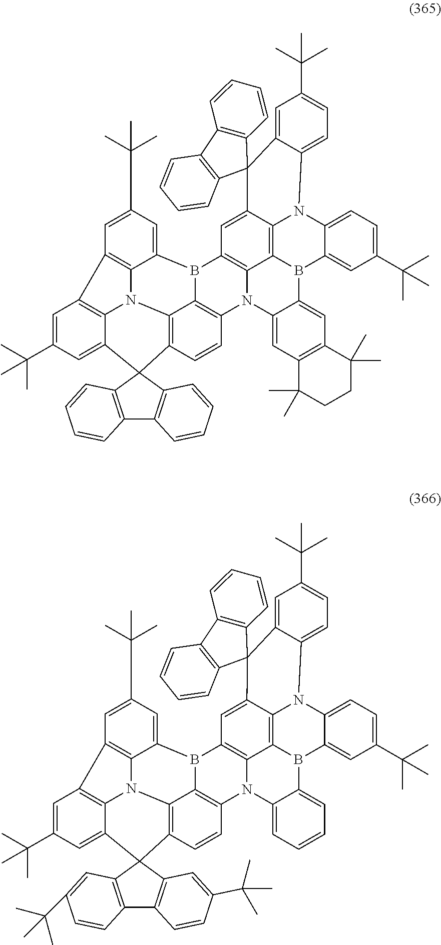

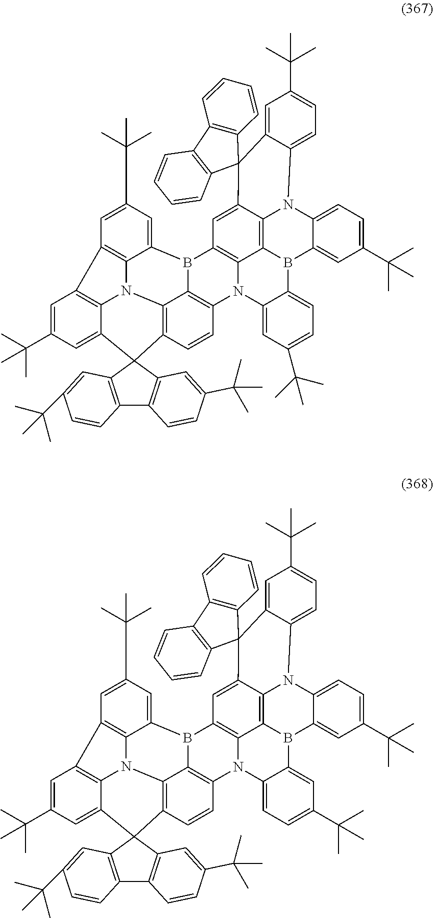

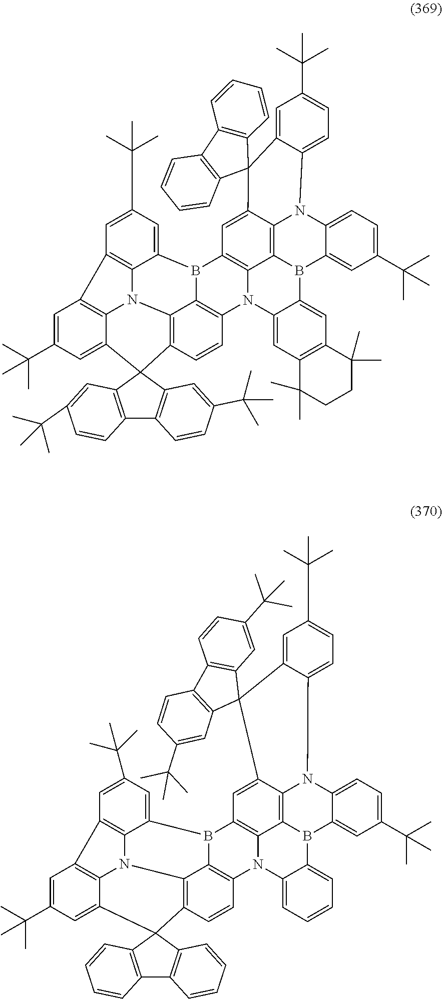

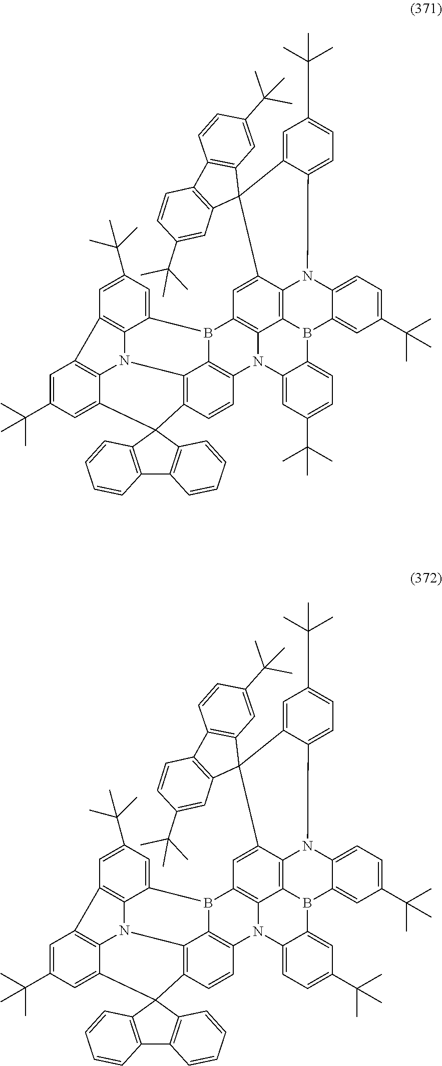

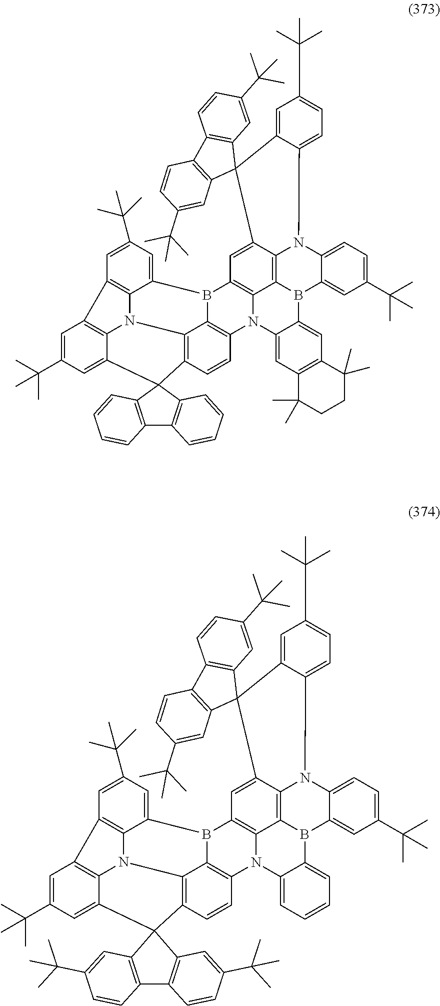

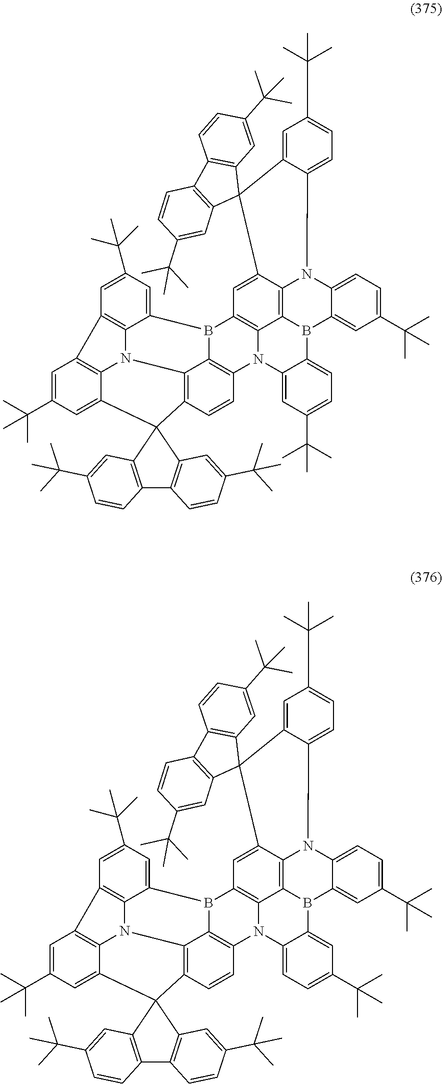

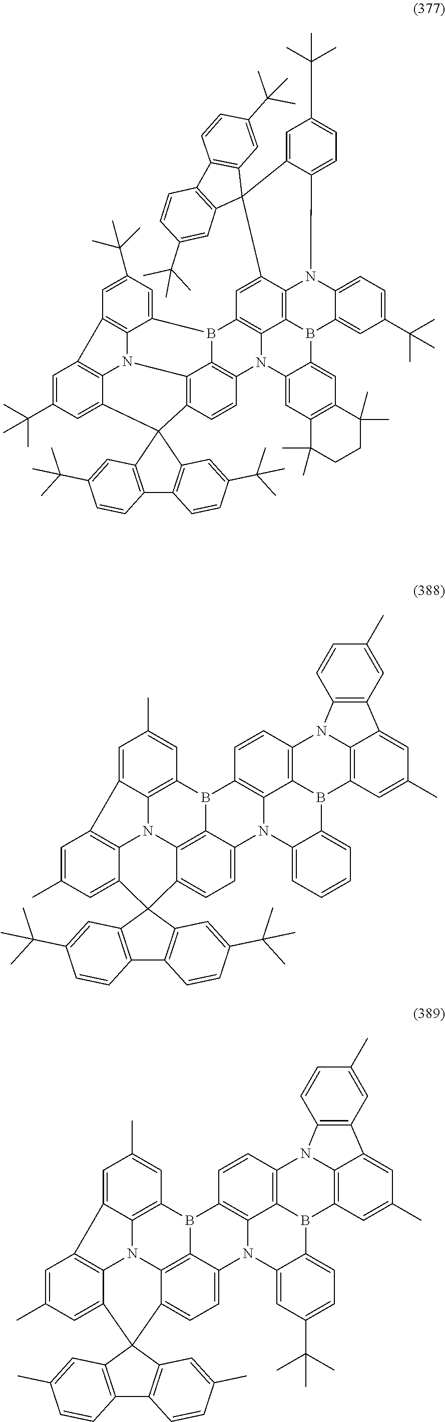

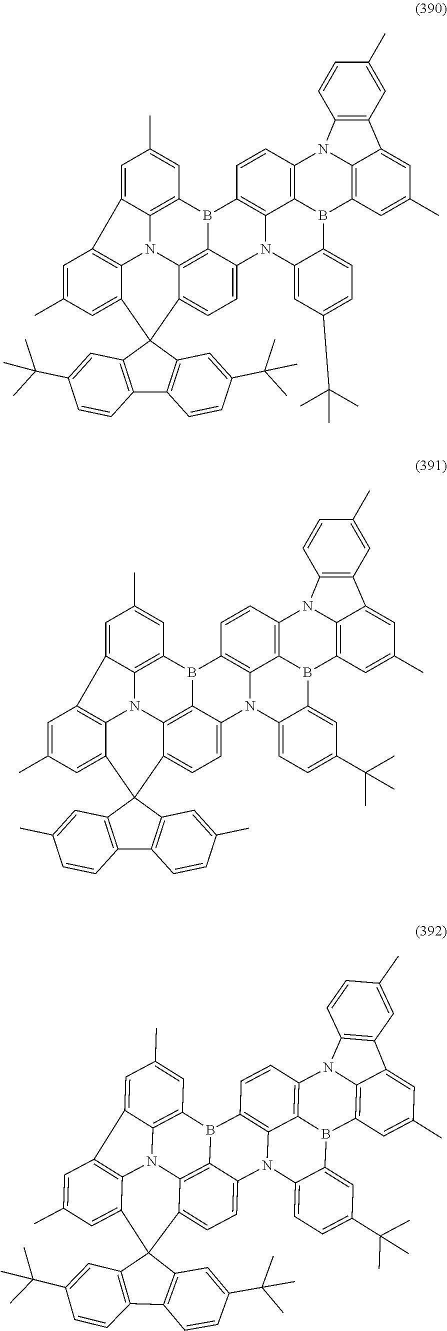

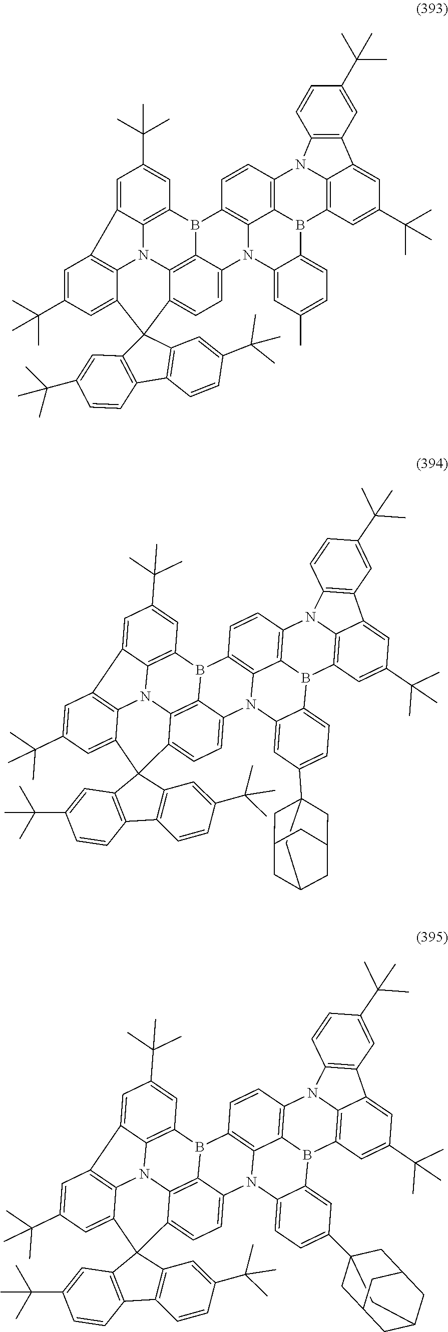

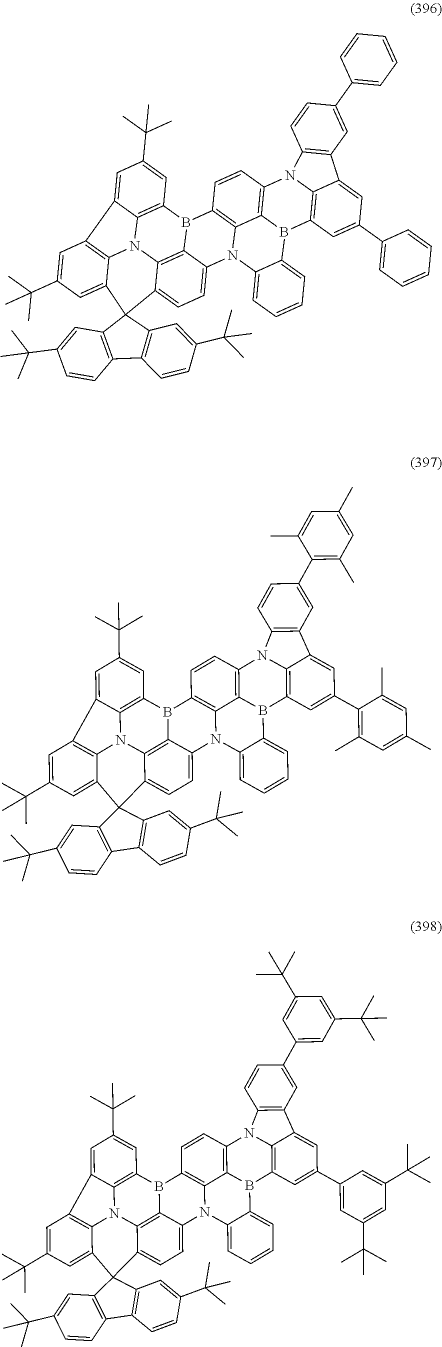

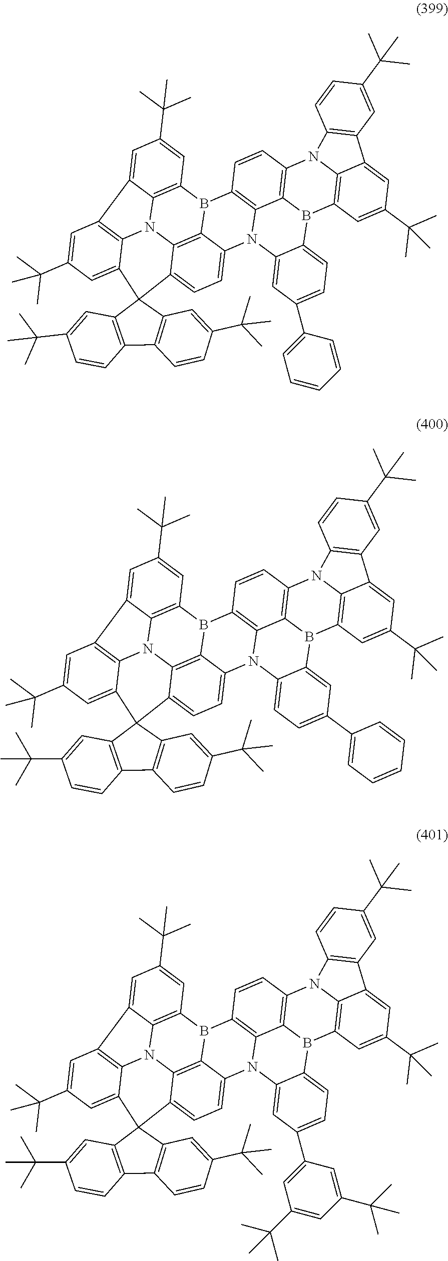

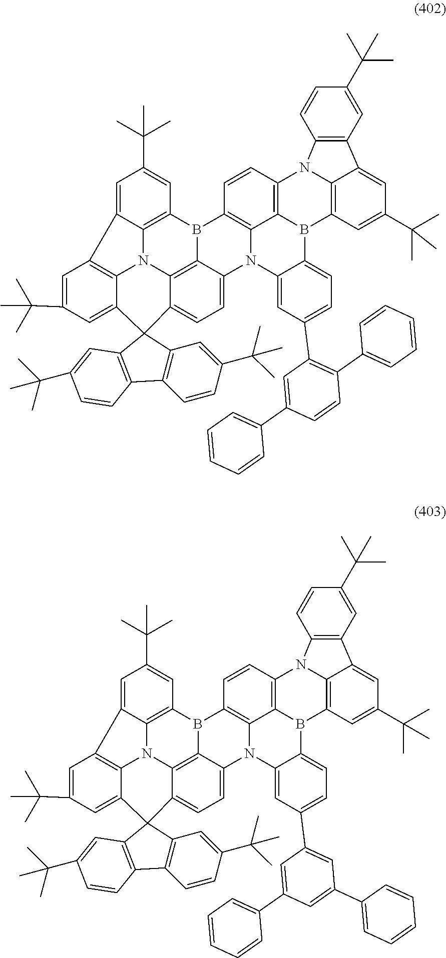

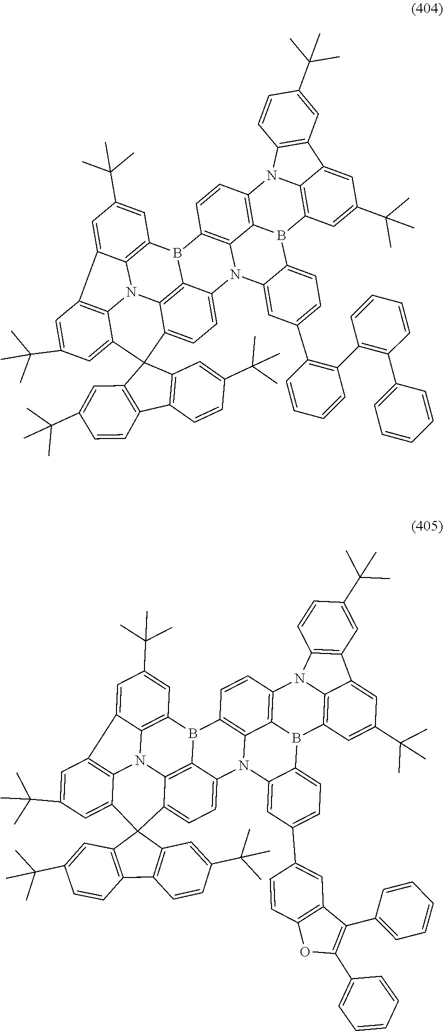 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1cc(-c3ccccc3-c3ccccc3-c3ccccc3)ccc1B4c1cc(C(C)(C)C)cc3c4cc(C(C)(C)C)ccc4n-2c13 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1cc(-c3ccc5oc(-c6ccccc6)c(-c6ccccc6)c5c3)ccc1B4c1cc(C(C)(C)C)cc3c4cc(C(C)(C)C)ccc4n-2c13]

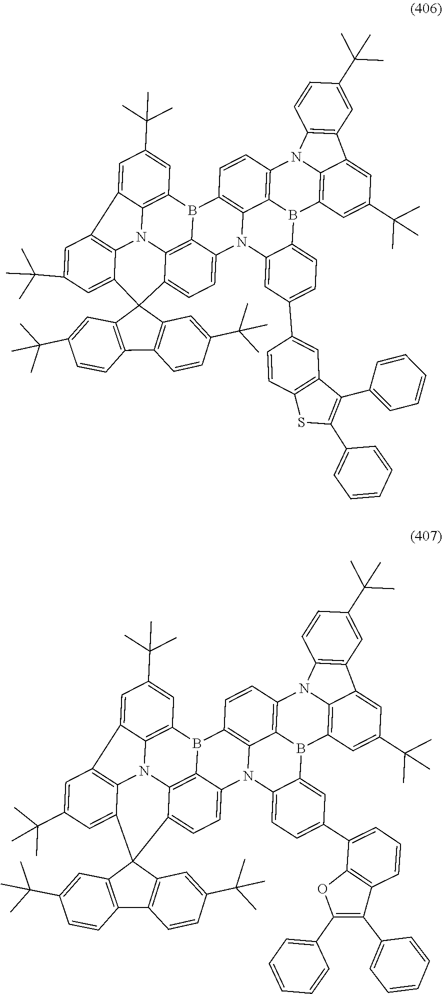 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1cc(-c3ccc5sc(-c6ccccc6)c(-c6ccccc6)c5c3)ccc1B4c1cc(C(C)(C)C)cc3c4cc(C(C)(C)C)ccc4n-2c13 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccc(-c3cccc5c(-c6ccccc6)c(-c6ccccc6)oc35)cc1B4c1cc(C(C)(C)C)cc3c4cc(C(C)(C)C)ccc4n-2c13]

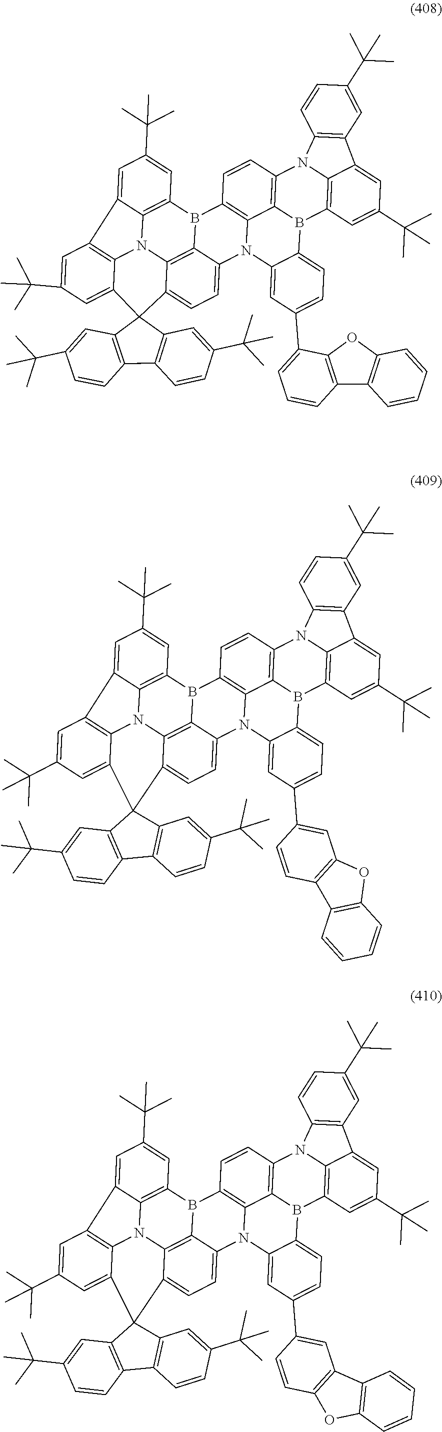

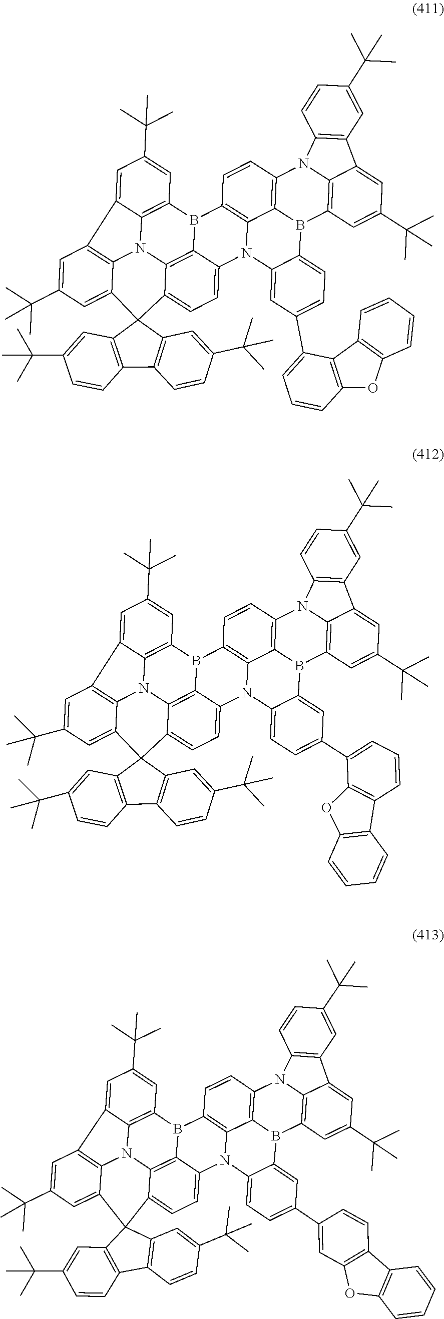

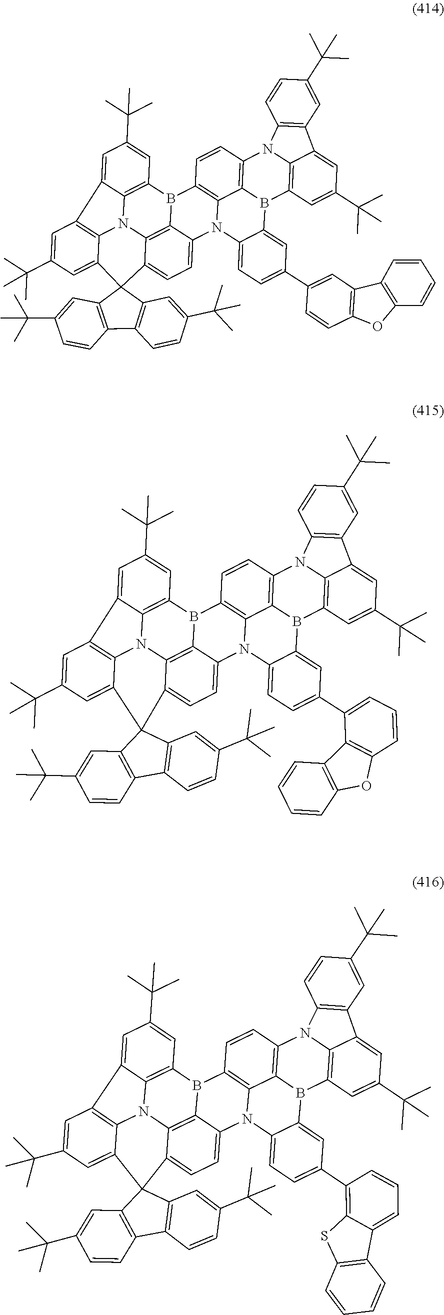

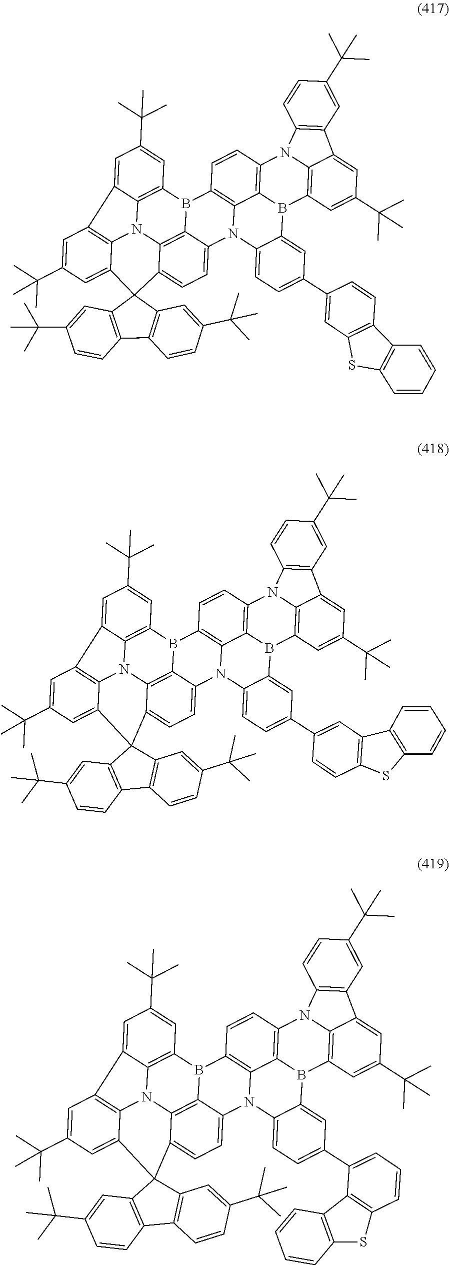

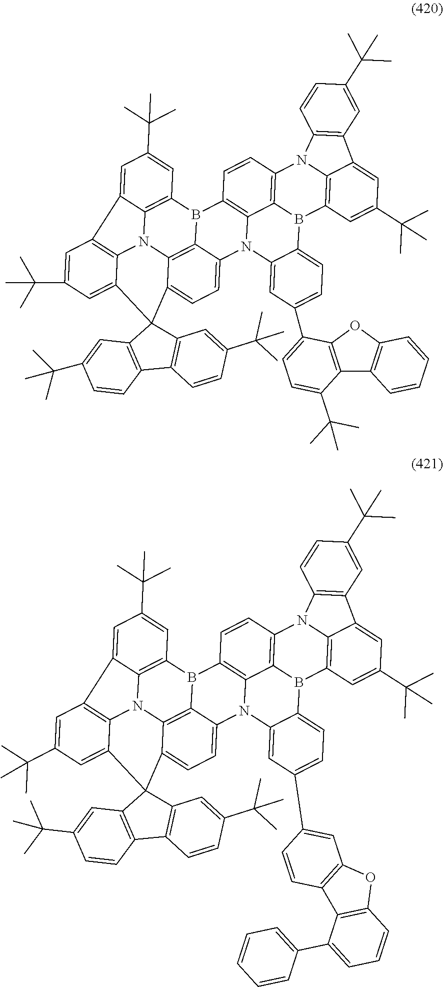

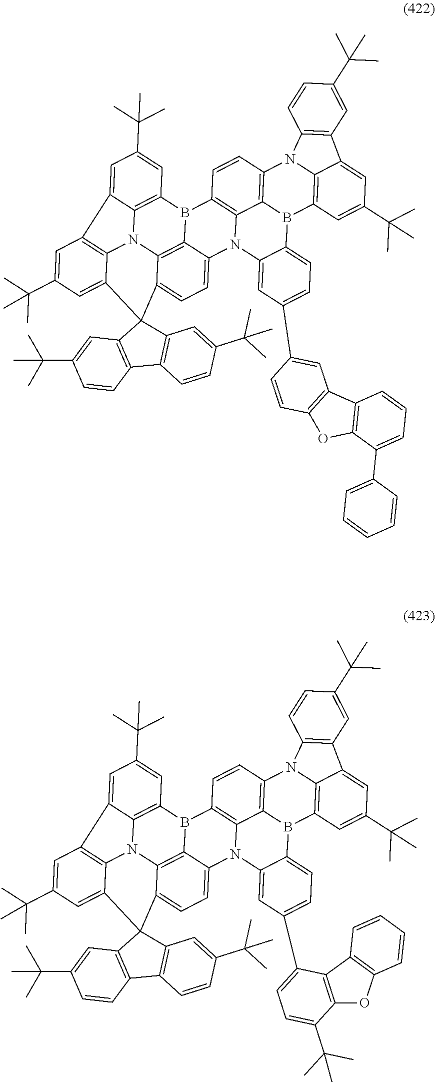

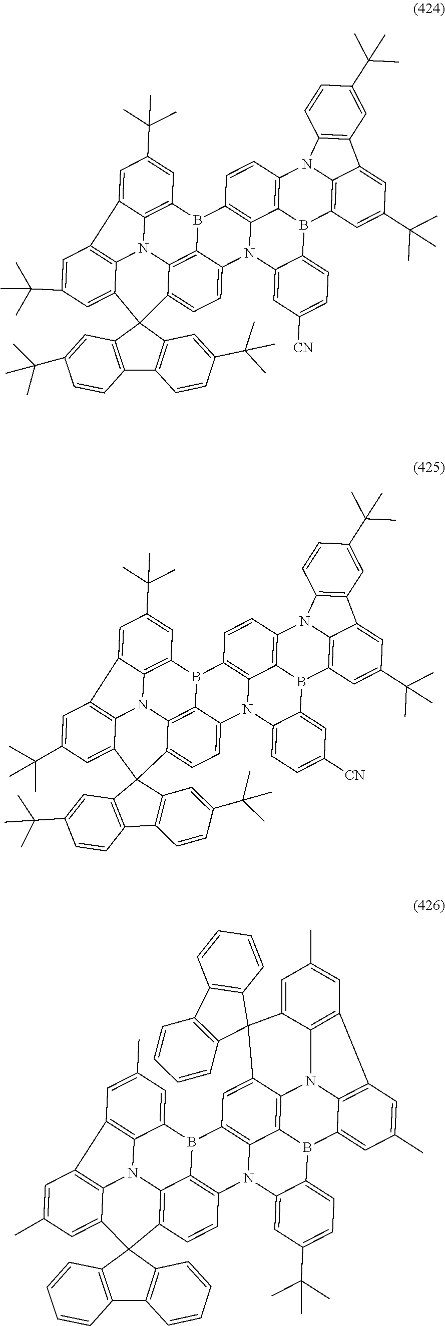

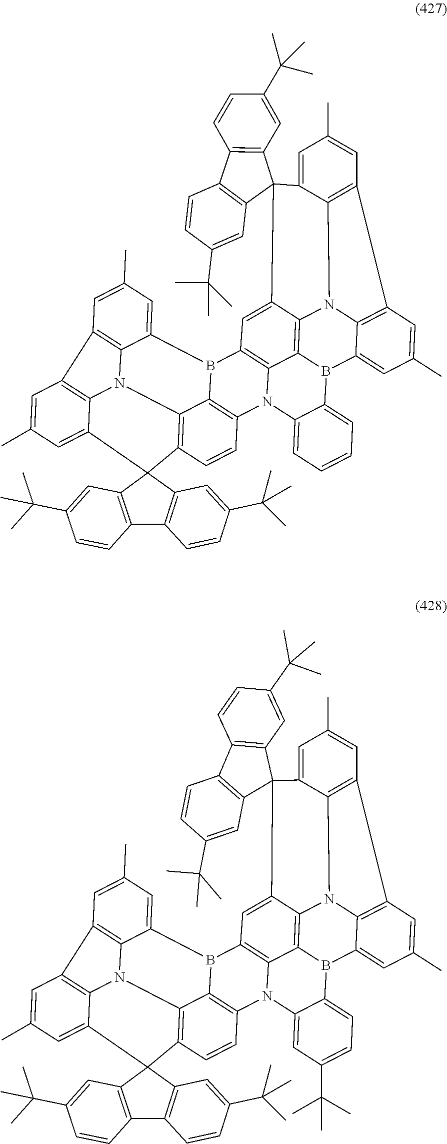

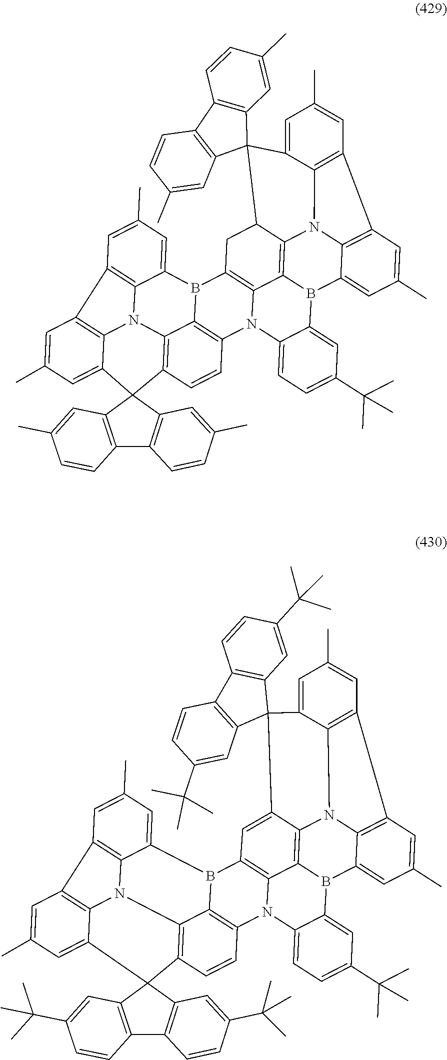

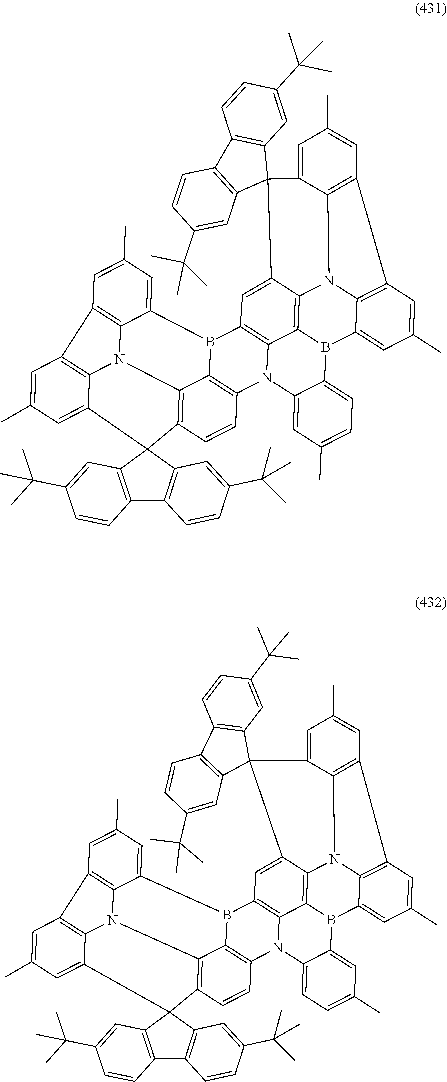

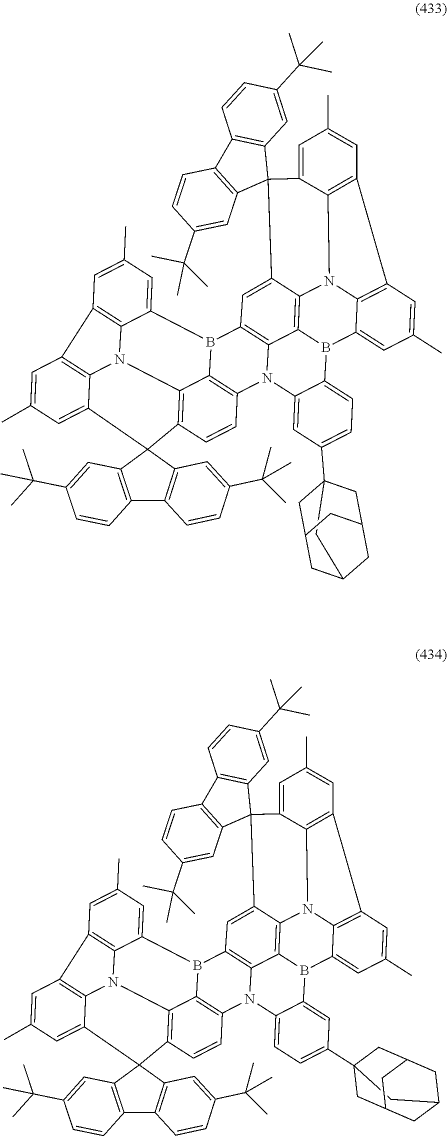

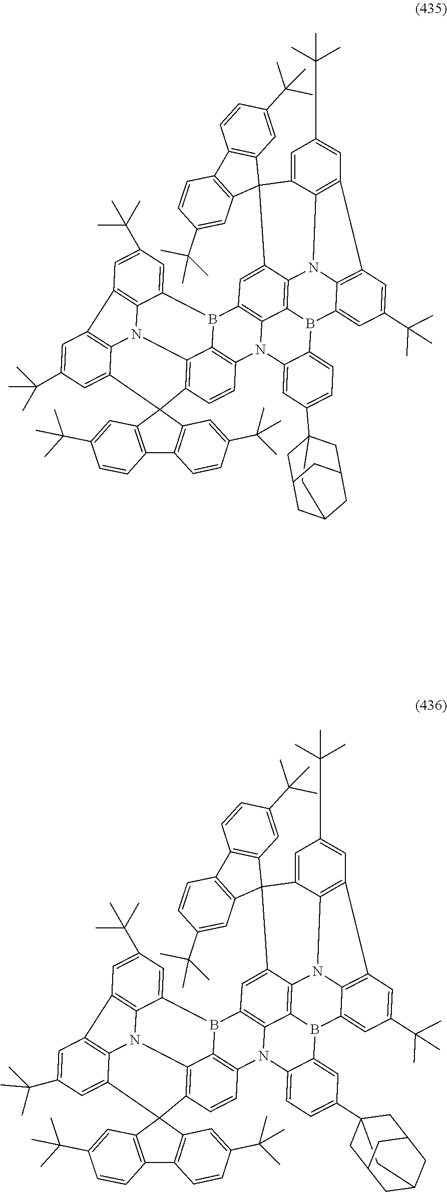

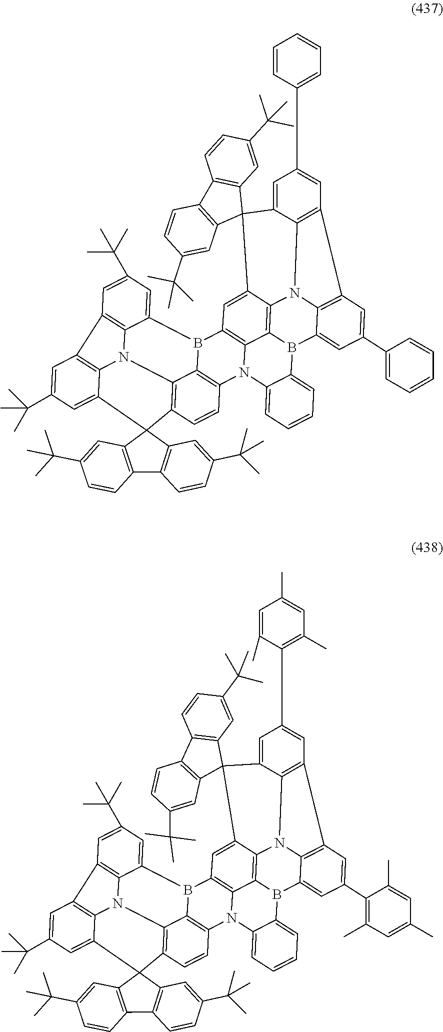 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1cc2c4c5c1N3c1ccccc1B5c1cc(-c3ccccc3)cc3c5cc(-c6ccccc6)cc(c5n-4c13)C21c2cc(C(C)(C)C)ccc2-c2ccc(C(C)(C)C)cc21 ; Cc1cc(C)c(-c2cc3c4c(c2)c2cc(-c5c(C)cc(C)cc5C)cc5c2n4-c2c(cc4c6c2B3c2ccccc2N6c2ccc3c6c2B4c2cc(C(C)(C)C)cc4c7cc(C(C)(C)C)cc(c7n-6c24)C32c3cc(C(C)(C)C)ccc3-c3ccc(C(C)(C)C)cc32)C52c3cc(C(C)(C)C)ccc3-c3ccc(C(C)(C)C)cc32)c(C)c1]

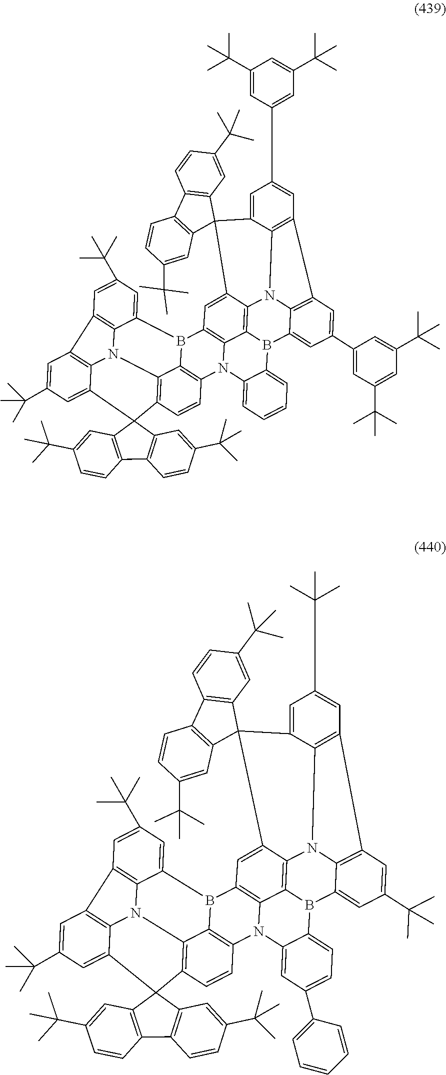

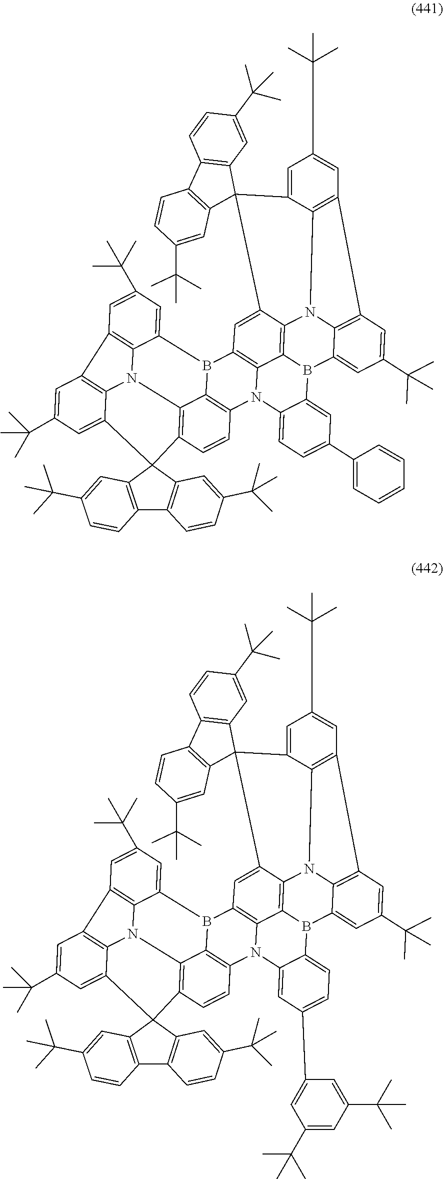

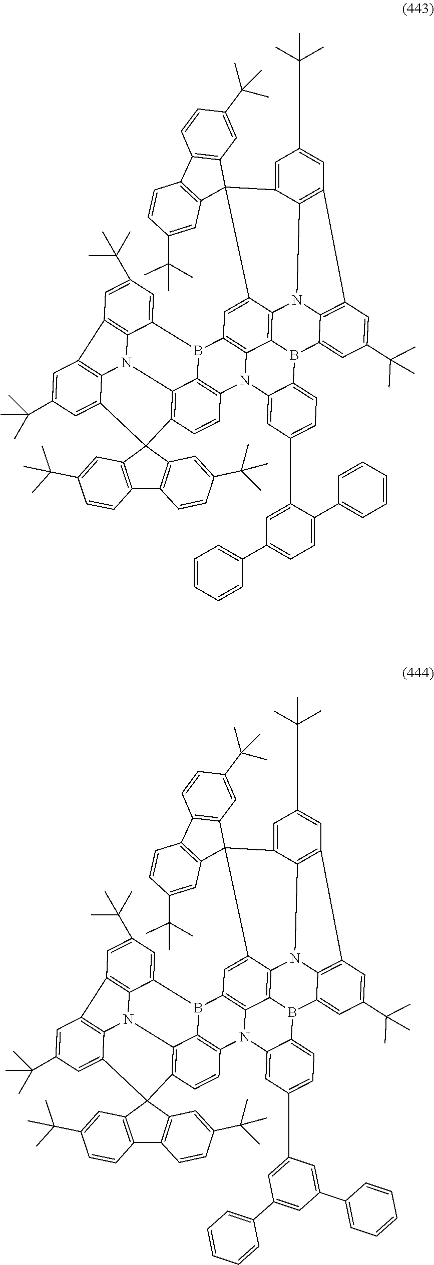

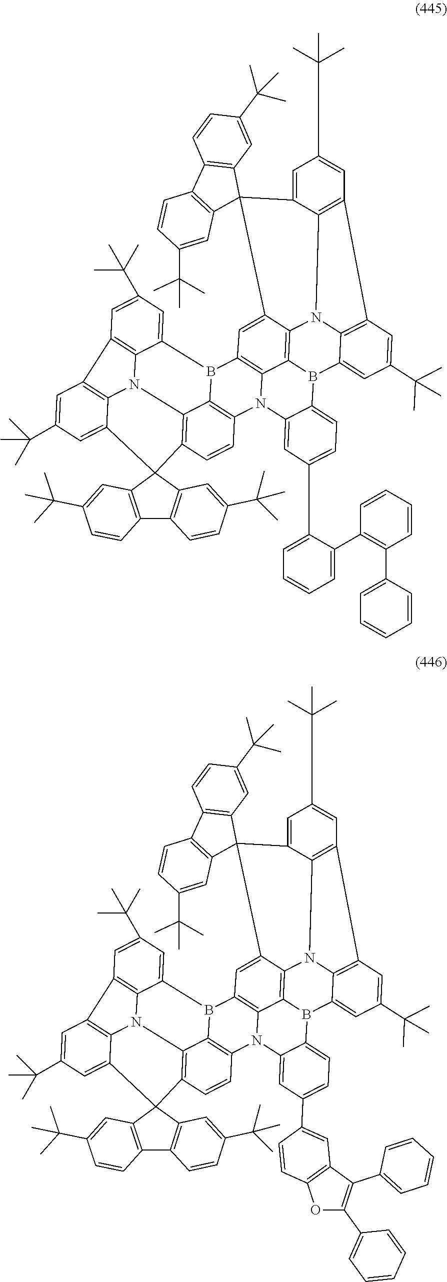

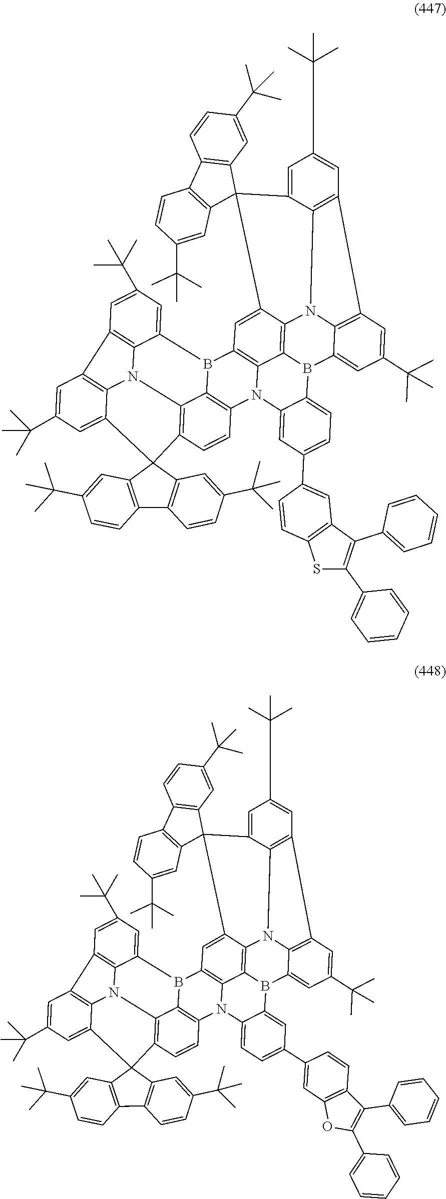 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1cc2c4c5c1N3c1cc(-c3ccc6sc(-c7ccccc7)c(-c7ccccc7)c6c3)ccc1B5c1cc(C(C)(C)C)cc3c5cc(C(C)(C)C)cc(c5n-4c13)C21c2cc(C(C)(C)C)ccc2-c2ccc(C(C)(C)C)cc21 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1cc2c4c5c1N3c1ccc(-c3ccc6c(-c7ccccc7)c(-c7ccccc7)oc6c3)cc1B5c1cc(C(C)(C)C)cc3c5cc(C(C)(C)C)cc(c5n-4c13)C21c2cc(C(C)(C)C)ccc2-c2ccc(C(C)(C)C)cc21]

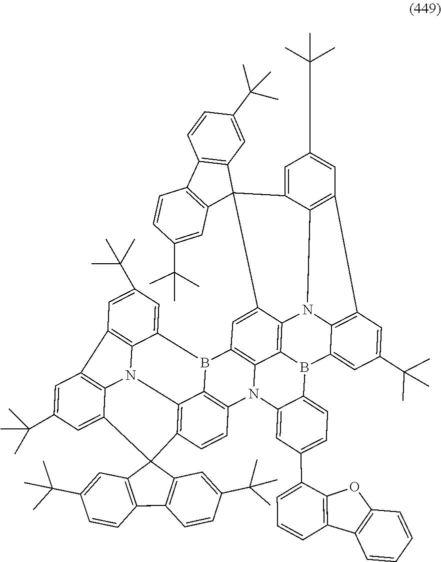 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1cc2c4c5c1N3c1cc(-c3cccc6c3oc3ccccc36)ccc1B5c1cc(C(C)(C)C)cc3c5cc(C(C)(C)C)cc(c5n-4c13)C21c2cc(C(C)(C)C)ccc2-c2ccc(C(C)(C)C)cc21]

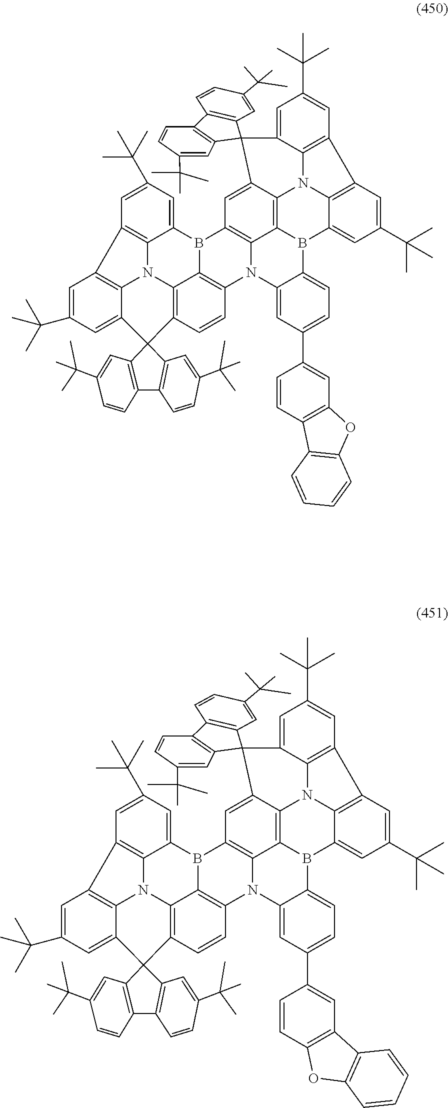

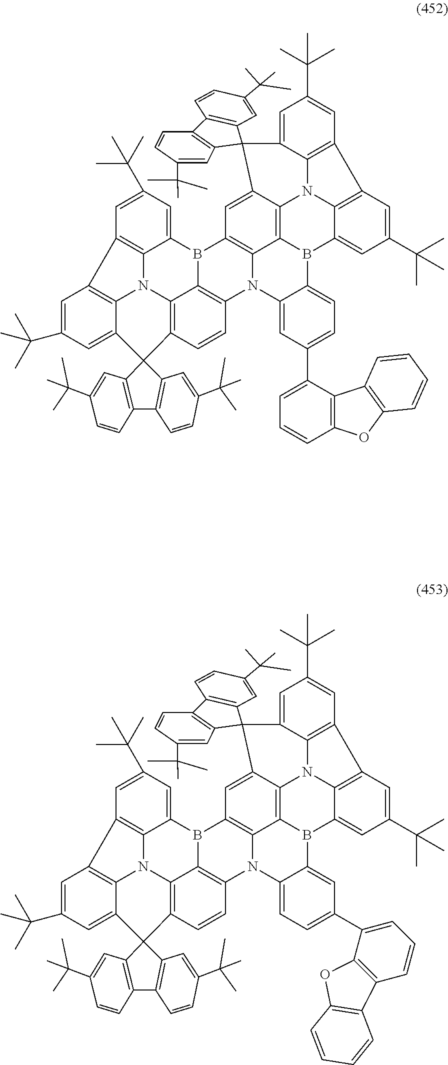

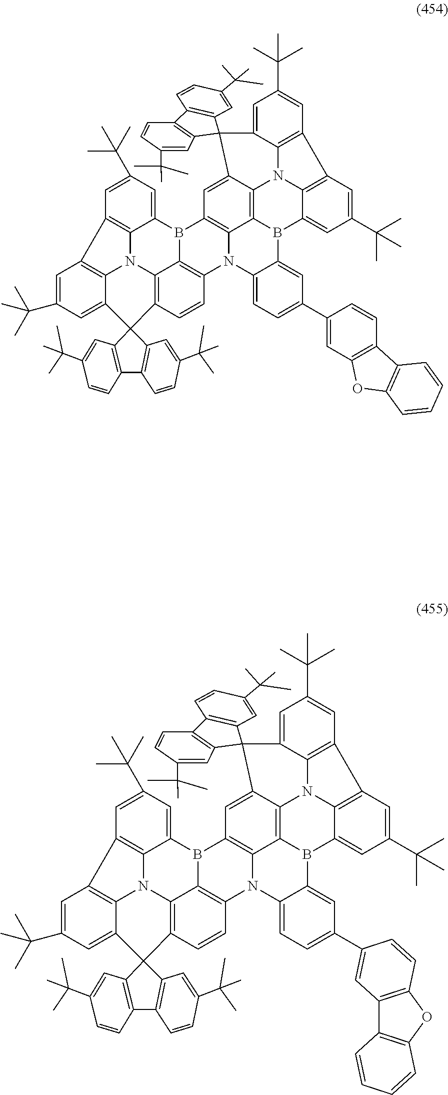 [SMILES: CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4ccc(-c5ccc6c(c5)oc5ccccc56)cc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32 ; CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4ccc(-c5ccc6oc7ccccc7c6c5)cc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32]

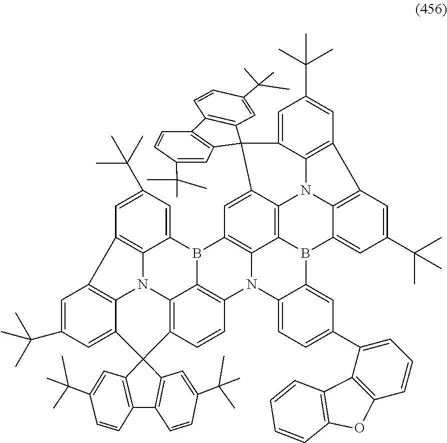 [SMILES: CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4ccc(-c5cccc6oc7ccccc7c56)cc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32]

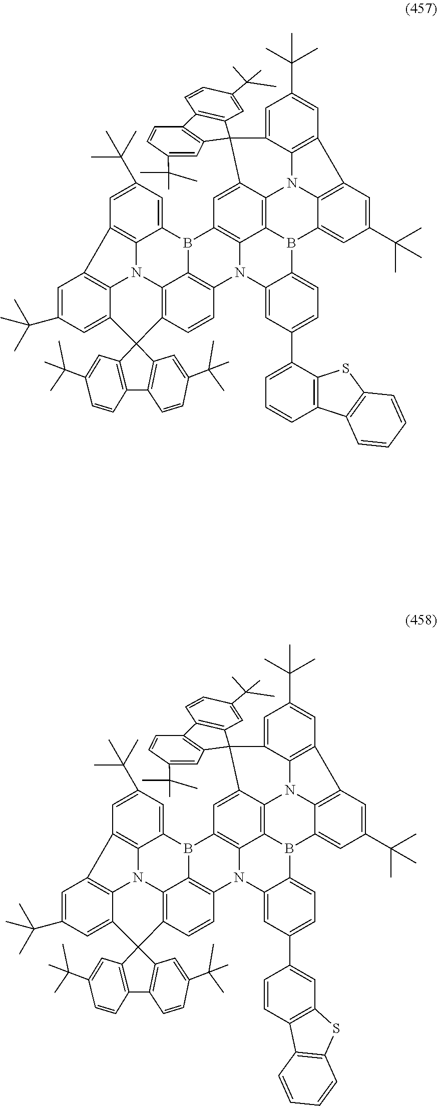

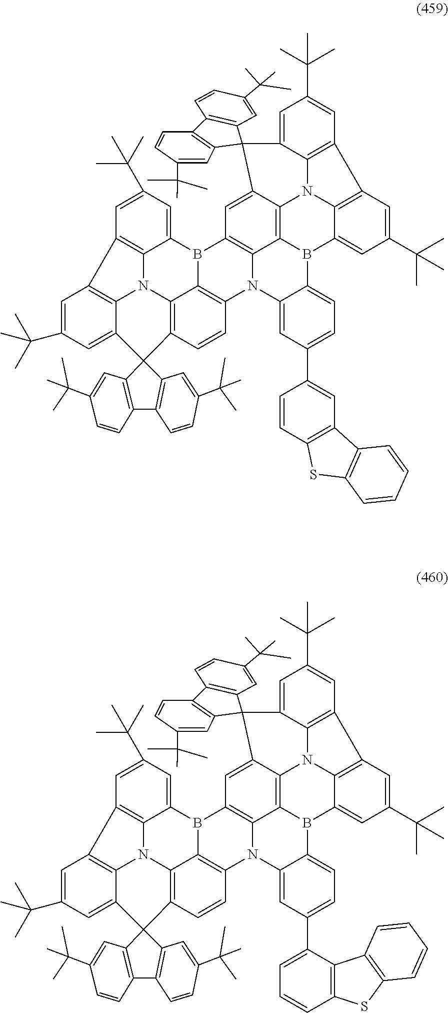

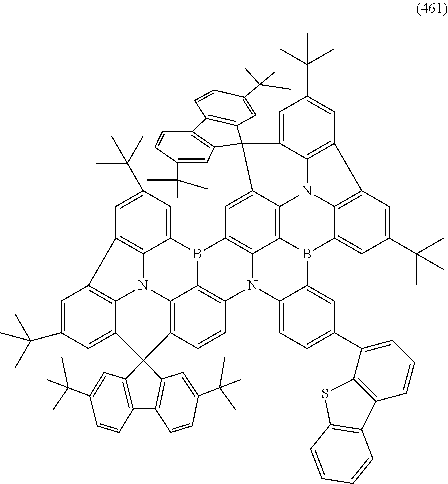 [SMILES: CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4ccc(-c5cccc6c5sc5ccccc56)cc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32]

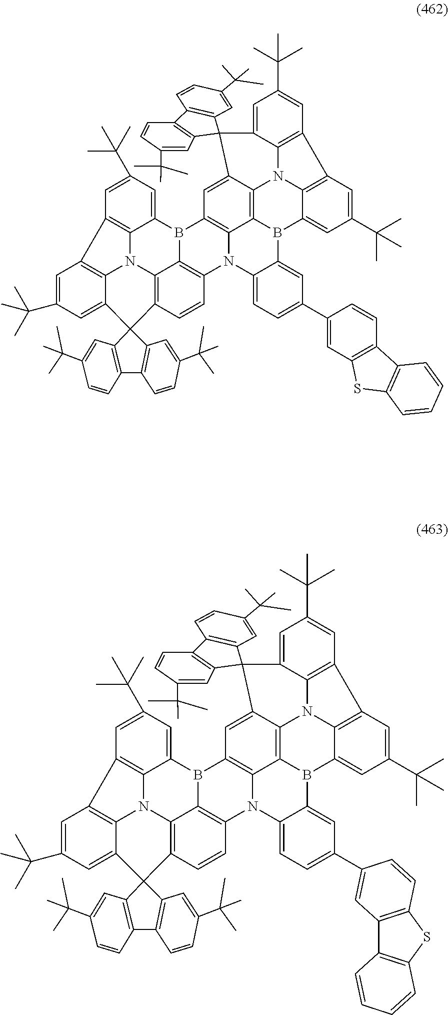 [SMILES: CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4ccc(-c5ccc6c(c5)sc5ccccc56)cc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32 ; CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4ccc(-c5ccc6sc7ccccc7c6c5)cc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32]

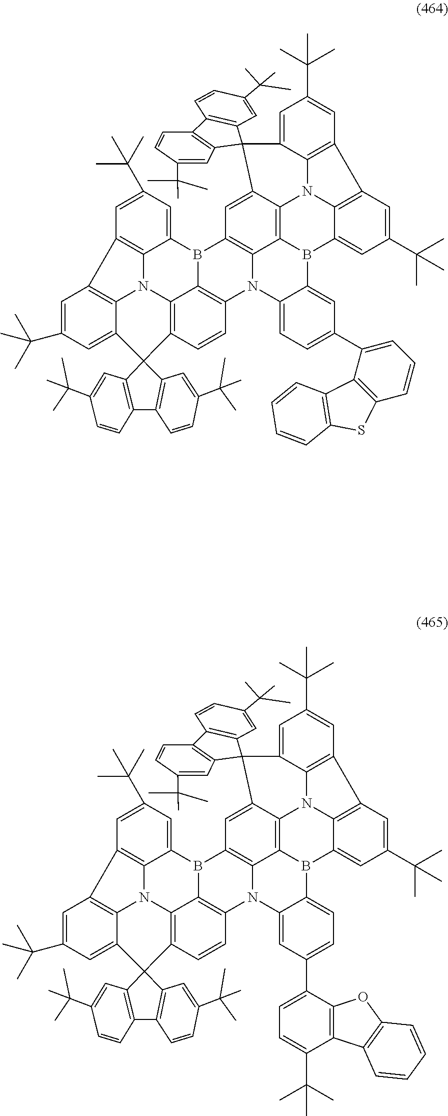

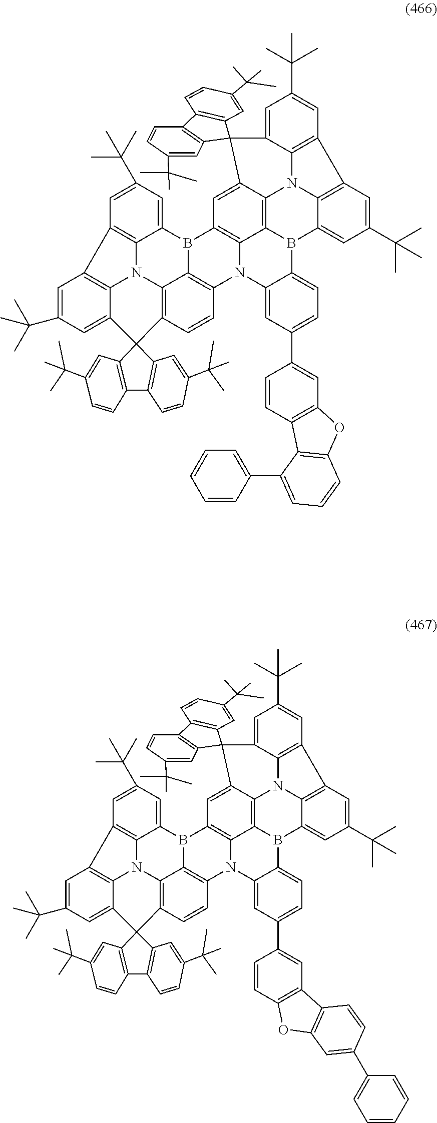

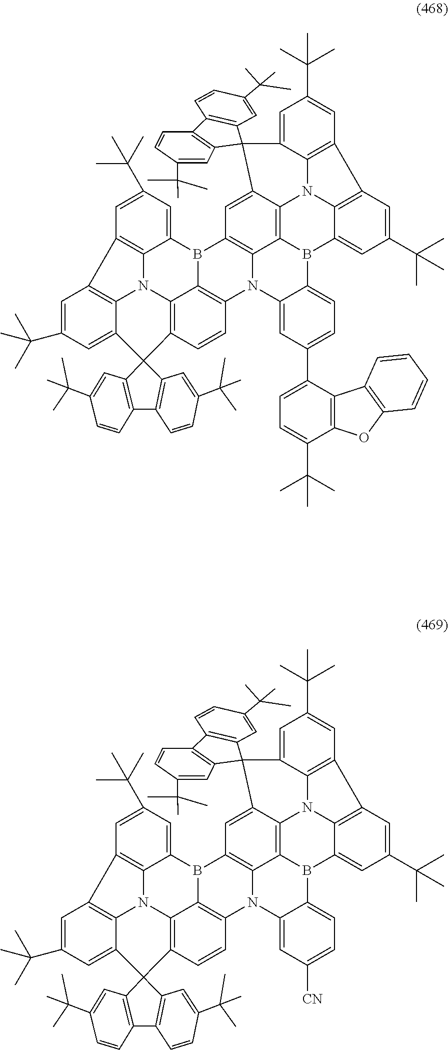

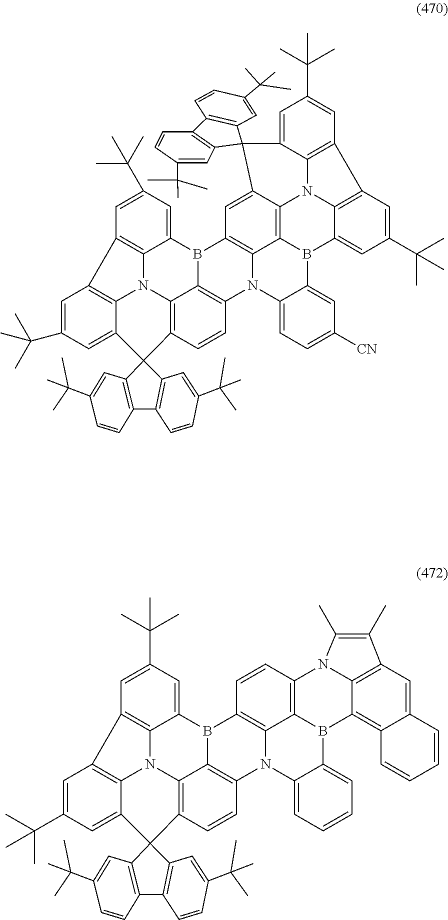

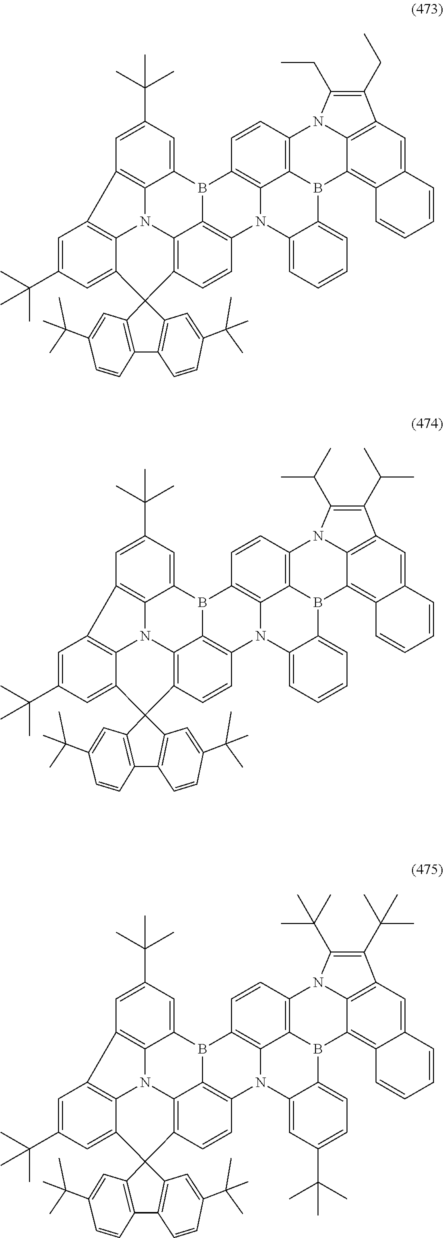 [SMILES: CCc1c(CC)n2c3c(c4ccccc4cc13)B1c3ccccc3N3c4ccc5c6c4B(c4ccc-2c1c43)c1cc(C(C)(C)C)cc2c3cc(C(C)(C)C)cc(c3n-6c12)C51c2cc(C(C)(C)C)ccc2-c2ccc(C(C)(C)C)cc21 ; CC(C)c1c(C(C)C)n2c3c(c4ccccc4cc13)B1c3ccccc3N3c4ccc5c6c4B(c4ccc-2c1c43)c1cc(C(C)(C)C)cc2c3cc(C(C)(C)C)cc(c3n-6c12)C51c2cc(C(C)(C)C)ccc2-c2ccc(C(C)(C)C)cc21 ; CC(C)(C)c1ccc2c(c1)N1c3ccc4c5c3B(c3ccc6c(c31)B2c1c2ccccc2cc2c(C(C)(C)C)c(C(C)(C)C)n-6c12)c1cc(C(C)(C)C)cc2c3cc(C(C)(C)C)cc(c3n-5c12)C41c2cc(C(C)(C)C)ccc2-c2ccc(C(C)(C)C)cc21]

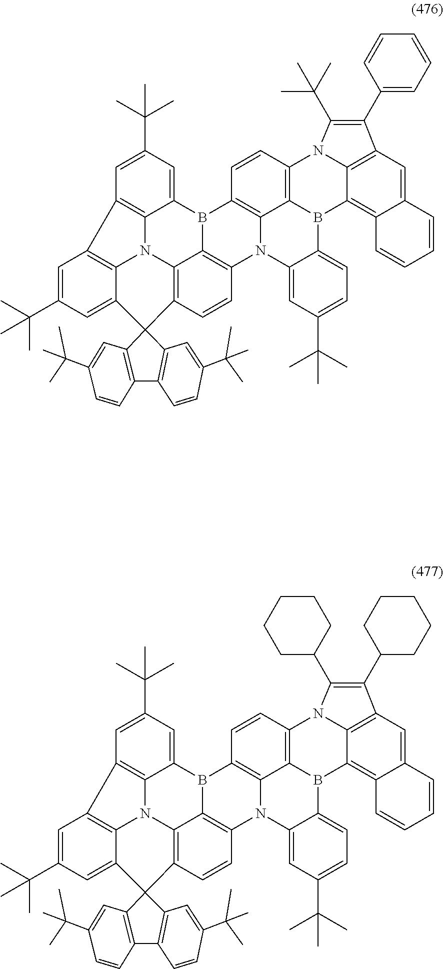 [SMILES: CC(C)(C)c1ccc2c(c1)N1c3ccc4c5c3B(c3ccc6c(c31)B2c1c2ccccc2cc2c(-c3ccccc3)c(C(C)(C)C)n-6c12)c1cc(C(C)(C)C)cc2c3cc(C(C)(C)C)cc(c3n-5c12)C41c2cc(C(C)(C)C)ccc2-c2ccc(C(C)(C)C)cc21 ; CC(C)(C)c1ccc2c(c1)N1c3ccc4c5c3B(c3ccc6c(c31)B2c1c2ccccc2cc2c(C3CCCCC3)c(C3CCCCC3)n-6c12)c1cc(C(C)(C)C)cc2c3cc(C(C)(C)C)cc(c3n-5c12)C41c2cc(C(C)(C)C)ccc2-c2ccc(C(C)(C)C)cc21]

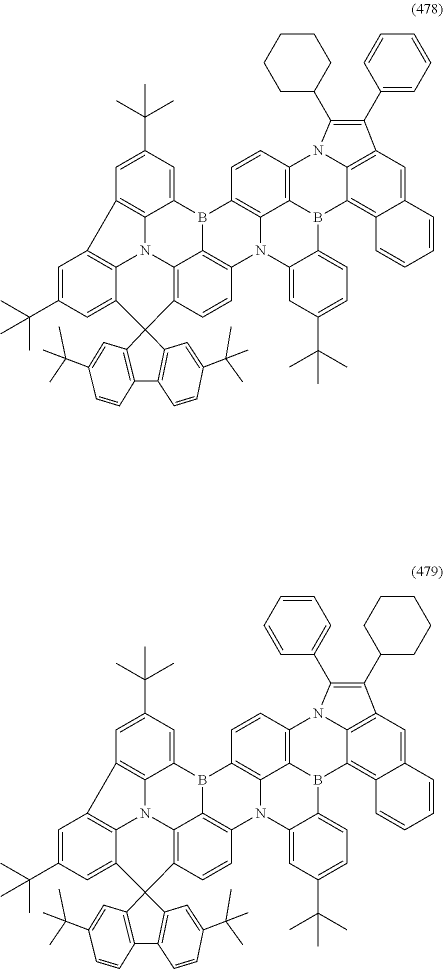 [SMILES: CC(C)(C)c1ccc2c(c1)N1c3ccc4c5c3B(c3ccc6c(c31)B2c1c2ccccc2cc2c(-c3ccccc3)c(C3CCCCC3)n-6c12)c1cc(C(C)(C)C)cc2c3cc(C(C)(C)C)cc(c3n-5c12)C41c2cc(C(C)(C)C)ccc2-c2ccc(C(C)(C)C)cc21 ; CC(C)(C)c1ccc2c(c1)N1c3ccc4c5c3B(c3ccc6c(c31)B2c1c2ccccc2cc2c(C3CCCCC3)c(-c3ccccc3)n-6c12)c1cc(C(C)(C)C)cc2c3cc(C(C)(C)C)cc(c3n-5c12)C41c2cc(C(C)(C)C)ccc2-c2ccc(C(C)(C)C)cc21]

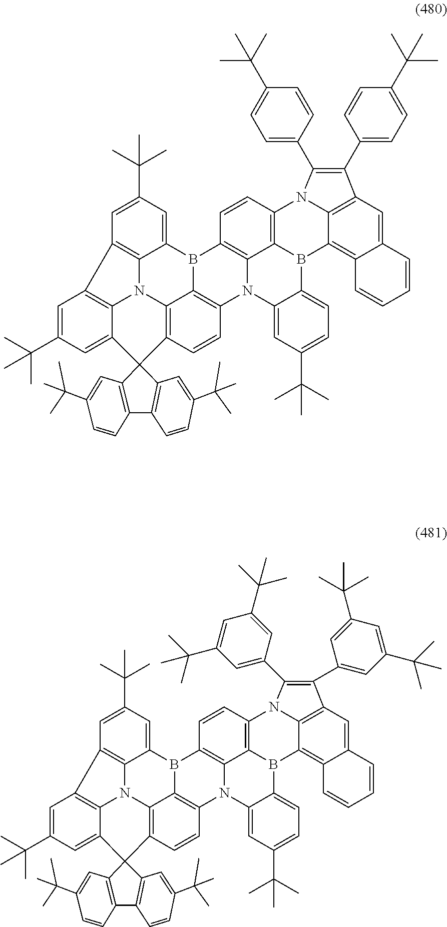

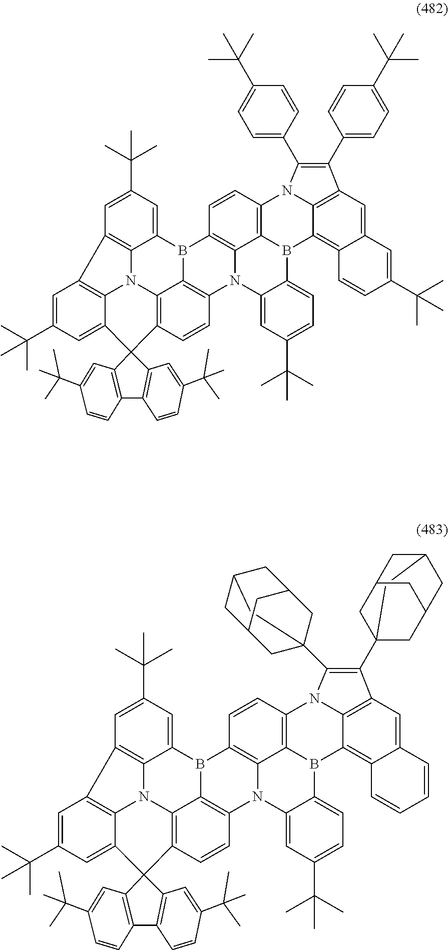

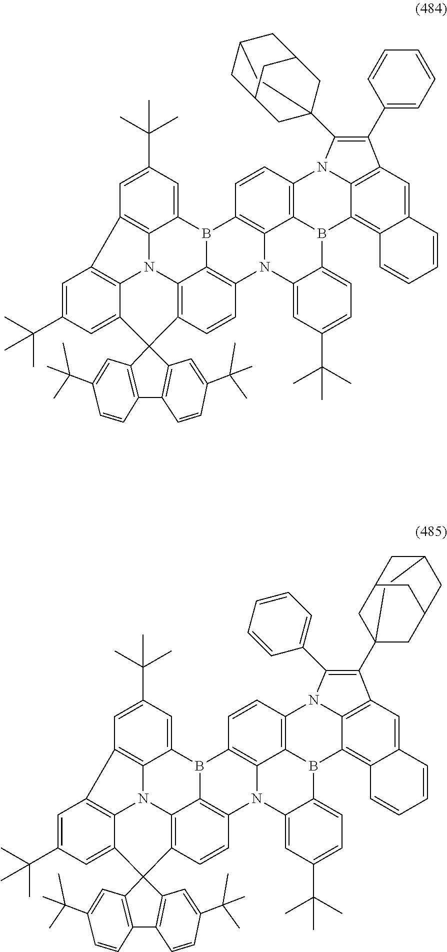 [SMILES: CC(C)(C)c1ccc2c(c1)N1c3ccc4c5c3B(c3ccc6c(c31)B2c1c2ccccc2cc2c(-c3ccccc3)c(C37CC8CC(CC(C8)C3)C7)n-6c12)c1cc(C(C)(C)C)cc2c3cc(C(C)(C)C)cc(c3n-5c12)C41c2cc(C(C)(C)C)ccc2-c2ccc(C(C)(C)C)cc21 ; CC(C)(C)c1ccc2c(c1)N1c3ccc4c5c3B(c3ccc6c(c31)B2c1c2ccccc2cc2c(C37CC8CC(CC(C8)C3)C7)c(-c3ccccc3)n-6c12)c1cc(C(C)(C)C)cc2c3cc(C(C)(C)C)cc(c3n-5c12)C41c2cc(C(C)(C)C)ccc2-c2ccc(C(C)(C)C)cc21]

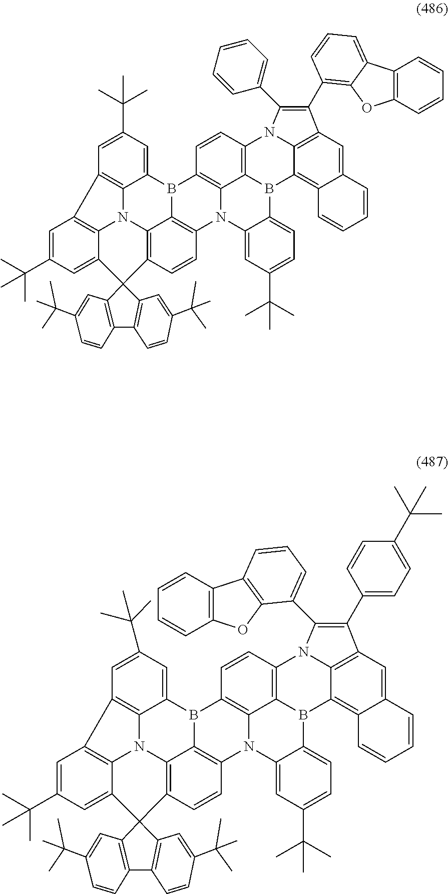 [SMILES: CC(C)(C)c1ccc2c(c1)N1c3ccc4c5c3B(c3ccc6c(c31)B2c1c2ccccc2cc2c(-c3cccc7c3oc3ccccc37)c(-c3ccccc3)n-6c12)c1cc(C(C)(C)C)cc2c3cc(C(C)(C)C)cc(c3n-5c12)C41c2cc(C(C)(C)C)ccc2-c2ccc(C(C)(C)C)cc21 ; CC(C)(C)c1ccc(-c2c(-c3cccc4c3oc3ccccc34)n3c4c(c5ccccc5cc24)B2c4ccc(C(C)(C)C)cc4N4c5ccc6c7c5B(c5ccc-3c2c54)c2cc(C(C)(C)C)cc3c4cc(C(C)(C)C)cc(c4n-7c23)C62c3cc(C(C)(C)C)ccc3-c3ccc(C(C)(C)C)cc32)cc1]

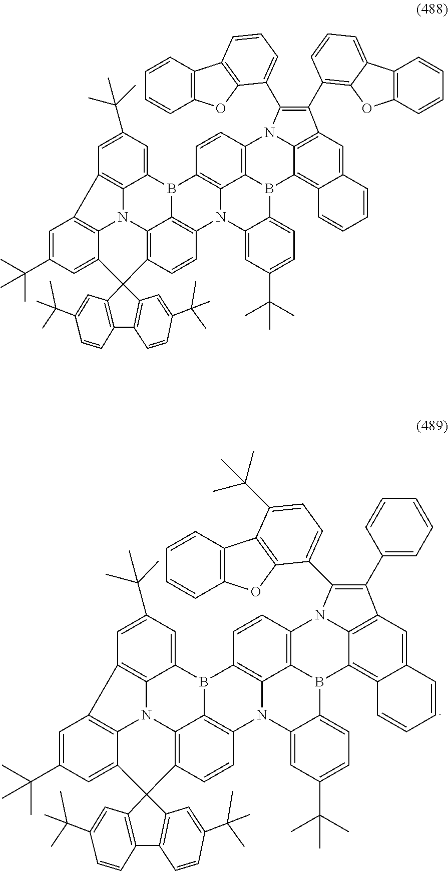 [SMILES: CC(C)(C)c1ccc2c(c1)N1c3ccc4c5c3B(c3ccc6c(c31)B2c1c2ccccc2cc2c(-c3cccc7c3oc3ccccc37)c(-c3cccc7c3oc3ccccc37)n-6c12)c1cc(C(C)(C)C)cc2c3cc(C(C)(C)C)cc(c3n-5c12)C41c2cc(C(C)(C)C)ccc2-c2ccc(C(C)(C)C)cc21 ; CC(C)(C)c1ccc2c(c1)N1c3ccc4c5c3B(c3ccc6c(c31)B2c1c2ccccc2cc2c(-c3ccccc3)c(-c3ccc(C(C)(C)C)c7c3oc3ccccc37)n-6c12)c1cc(C(C)(C)C)cc2c3cc(C(C)(C)C)cc(c3n-5c12)C41c2cc(C(C)(C)C)ccc2-c2ccc(C(C)(C)C)cc21]

The present disclosure also provides an organic light-emitting device comprising a substrate, a first electrode, a second electrode and a functional layer in sequence, wherein the functional layer is located between the first electrode and the second electrode, and the functional layer comprises the boron-containing resonance-type organic compound of the present disclosure.

Preferably, the functional layer comprises a light-emitting layer comprising a host material and a doping material, wherein the doping material is the boron-containing resonance-type organic compound of the present disclosure.

Preferably, the functional layer comprises a light-emitting layer comprising a first host material, a second host material and a doping material, wherein at least one of the first host material and the second host material is a TADF material, and the doping material is the boron-containing resonance-type organic compound of the present disclosure.

Further, the functional layer comprises a light-emitting layer comprising a host material, an exciton sensitizing material and a doping material, wherein the exciton sensitizing material is a complex containing metal elements, and the doping material is the boron-containing resonance-type organic compound of the present disclosure.

Compared with the prior art, the beneficial technical effects of the present disclosure are as follows:
(1) the compound of the present disclosure is applied to OLED devices and can be used as a doping material for the light-emitting layer material. It can emit green fluorescence under the action of an electric field and can be applied in the field of OLED lighting or OLED display;
(2) the compound of the present disclosure is used as a doping material and the introduction of a phosphorescent sensitizer can effectively improve the efficiency and service life of the device;
(3) the spectral FWHM of the compound of the present disclosure is relatively narrow, which can effectively improve the color gamut of the device and improve the light-emitting efficiency of the device;
(4) the compound of the present disclosure is used as a doping material and the introduction of a TADF sensitizer as a second host material can effectively improve the efficiency of the device;
the compound of the present disclosure has a narrow half-peak width characteristic and can be used as the green light doping material for the light-emitting layer of an organic electroluminescent device, so that the efficiency and service life of the device can be improved.

### BRIEF DESCRIPTION OF THE DRAWINGS

FIG. 1 is a structural schematic diagram of application of the materials listed in the present disclosure to OLED devices, where 1 represents a transparent substrate layer, 2 represents an anode layer, 3 represents a hole injection layer, 4 represents a hole transport layer, 5 represents an electron blocking layer, 6 represents a light-emitting layer, 7 represents a hole blocking layer, 8 represents an electron transport layer, 9 represents an electron injection layer, and 10 represents a cathode layer;

FIG. 2 is an emission spectrogram of the compound 87 of the present disclosure in a toluene solution (1×10⁻⁵ M);

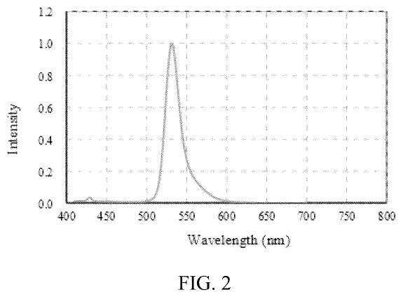

FIG. 3 is a nuclear magnetic resonance hydrogen spectrum (¹H NMR) of the compound 87 of the present disclosure;

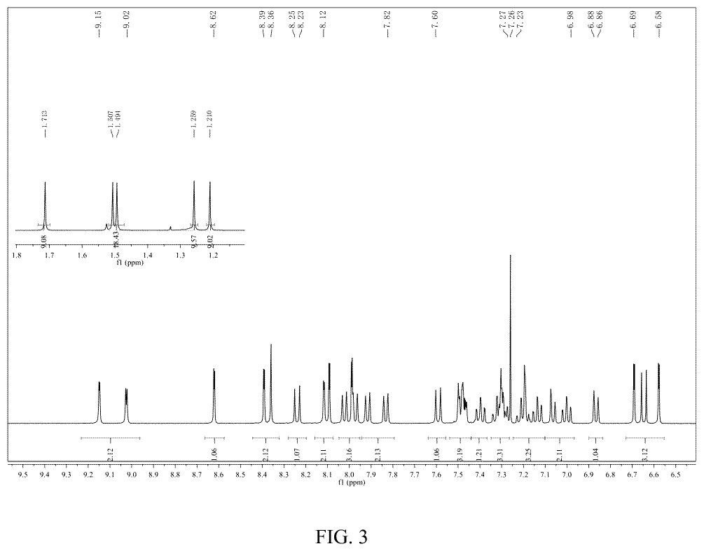

FIG. 4 is an emission spectrogram of the compound 101 of the present disclosure in a toluene solution (1×10⁻⁵ M); and

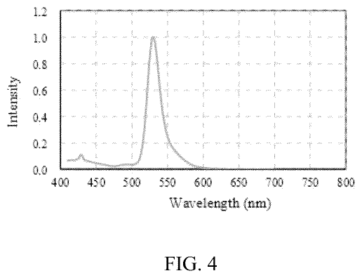

FIG. 5 is a nuclear magnetic resonance hydrogen spectrum (1H NMR) of the compound 101 of the present disclosure.

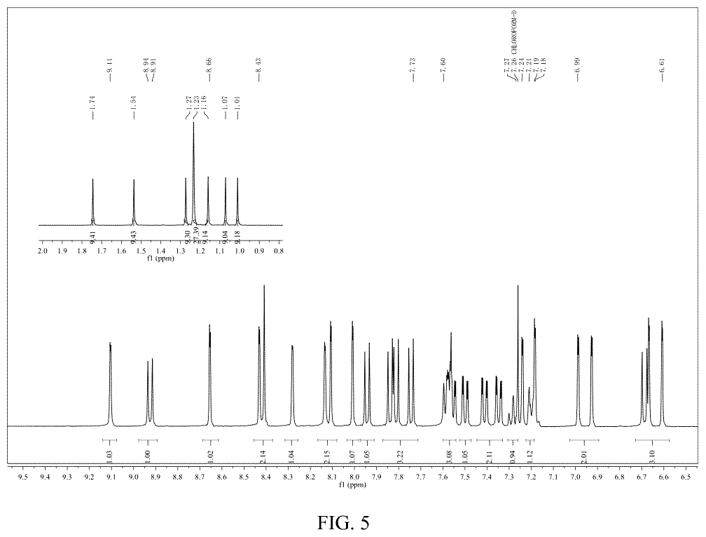

### DETAILED DESCRIPTION

The present disclosure will be described in detail below in conjunction with the accompanying drawings and embodiments.

In the present disclosure, when describing electrodes and organic electroluminescent devices, as well as other structures, the words “upper”, “lower”, “top” and “bottom” used to indicate orientations only indicate orientation in a certain specific state, and do not mean that the relevant structures can only exist in the described orientation; on the contrary, if the structure can change its position, such as inverted, the orientation of the structure is changed accordingly. Specifically, in the present disclosure, the “bottom” or “lower” side of the electrode refers to the side of the electrode close to the substrate during the preparation process, and the opposite side away from the substrate is the “top” or “upper” side.

In the present disclosure, the substituted or unsubstituted arylamino group of the present disclosure refers to

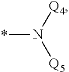

wherein Q₁ and Q₂ represent a substituted or unsubstituted aromatic group, Q₁ and Q₂ preferably represent a substituted or unsubstituted C₆-C₃₀ aryl group or a substituted or unsubstituted C₂-C₃₀ heteroaryl group.

In the present disclosure, the substituted or unsubstituted silyl group of the present disclosure refers to

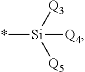

wherein Q₃, Q₄ and Q₅ represent a substituted or unsubstituted C₁-C₁₀ alkyl groups, or C₃-C₁₀ cycloalkyl groups.

In the present disclosure, the substituted or unsubstituted C₂-C₃₀ boranyl group of the present disclosure refers to

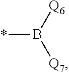

wherein Q₆ and Q₇ represent a substituted or unsubstituted C₁-C₁₀ alkyl groups, or C₃-C₁₀ cycloalkyl groups.

In the present disclosure, the substituted or unsubstituted C₆-C₃₀ aryl group refers to a substituted or unsubstituted aryl group having 6 to 30 carbon atoms, preferably a substituted or unsubstituted aryl group having 6 to 20 carbon atoms, preferably a substituted or unsubstituted aryl group having 6 to 18 carbon atoms, preferably a substituted or unsubstituted aryl group having 6 to 10 carbon atoms, preferably a substituted or unsubstituted aryl group having 8 to 10 carbon atoms, and preferably a substituted or unsubstituted phenyl, a substituted or unsubstituted naphthyl, a substituted or unsubstituted anthracyl, a substituted or unsubstituted fluorenyl, a substituted or unsubstituted dimethylfluorenyl, a substituted or unsubstituted diphenylfluorenyl, a substituted or unsubstituted spirofluorenyl, a substituted or unsubstituted phenanthryl, a substituted or unsubstituted fused tetraphenyl, a substituted or unsubstituted pyrenyl, a substituted or unsubstituted biphenyl, a substituted or unsubstituted p-terphenyl, a substituted or unsubstituted m-terphenyl, a substituted or unsubstituted chrysyl, a substituted or unsubstituted triphenylene, a substituted or unsubstituted peryl, a substituted or unsubstituted indenyl, a substituted or unsubstituted 1,1,4,4-tetramethyl-1,2,3,4-tetrahydronaphthyl, combinations thereof, or fused rings of combinations of the foregoing groups, but is not limited thereto.

In the present disclosure, the C₆-C₃₀ aryl group refers to an aryl group having 6 to 30 carbon atoms, preferably a aryl group having 6 to 20 carbon atoms, preferably a aryl group having 6 to 18 carbon atoms, preferably a aryl group having 6 to 10 carbon atoms, and preferably a phenyl, a naphthyl, a anthracyl, a fluorenyl, a dimethylfluorenyl, a diphenylfluorenyl, a spirofluorenyl, a phenanthryl, a fused tetraphenyl, a pyrenyl, a biphenyl, a p-terphenyl, a m-terphenyl, a chrysyl, a triphenylene, a peryl, a indenyl, a 1,1,4,4-tetramethyl-1,2,3,4-tetrahydronaphthyl, combinations thereof, or fused rings of combinations of the foregoing groups, but is not limited thereto.

In the present disclosure, the deuterium substituted C₆-C₃₀ aryl group refers to a deuterium-substituted aryl group having 6 to 30 carbon atoms, preferably a deuterium-substituted aryl group having 6 to 20 carbon atoms, preferably a deuterium-substituted aryl group having 6 to 18 carbon atoms, preferably a deuterium-substituted aryl group having 6 to 10 carbon atoms, and preferably a deuterium-substituted phenyl, a deuterium-substituted naphthyl, a deuterium-substituted anthracyl, a deuterium-substituted fluorenyl, a deuterium-substituted dimethylfluorenyl, a deuterium-substituted diphenylfluorenyl, a deuterium-substituted spirofluorenyl, a deuterium-substituted phenanthryl, a deuterium-substituted fused tetraphenyl, a deuterium-substituted pyrenyl, a deuterium-substituted biphenyl, a deuterium-substituted p-terphenyl, a deuterium-substituted m-terphenyl, a deuterium-substituted chrysyl, a deuterium-substituted triphenylene, a deuterium-substituted peryl, a deuterium-substituted indenyl, a deuterium-substituted 1,1,4,4-tetramethyl-1,2,3,4-tetrahydronaphthyl, combinations thereof, or fused rings of combinations of the foregoing groups, but is not limited thereto.

In the present disclosure, the substituted or unsubstituted C₂-C₃₀ heteroaryl group refers to a substituted or unsubstituted heteroaryl group having 2 to 30 carbon atoms, preferably a substituted or unsubstituted heteroaryl group having 4 to 20 carbon atoms, preferably a substituted or unsubstituted heteroaryl group having 5 to 20 carbon atoms, preferably a substituted or unsubstituted heteroaryl group having 4 to 10 carbon atoms, preferably a substituted or unsubstituted heteroaryl group having 5 to 10 carbon atoms, preferably a substituted or unsubstituted heteroaryl group having 6 to 18 carbon atoms, preferably a substituted or unsubstituted heteroaryl group having 6 to 12 carbon atoms, and preferably a substituted or unsubstituted furyl, a substituted or unsubstituted thienyl, a substituted or unsubstituted pyrrolyl, a substituted or unsubstituted pyrazolyl, a substituted or unsubstituted imidazolyl, a substituted or unsubstituted triazolyl, a substituted or unsubstituted oxazolyl, a substituted or unsubstituted thiazolyl, a substituted or unsubstituted oxadiazolyl, a substituted or unsubstituted thiadiazolyl, a substituted or unsubstituted pyridinyl, a substituted or unsubstituted pyrimidinyl, a substituted or unsubstituted pyrazinyl, a substituted or unsubstituted triazinyl, a substituted or unsubstituted benzofuranyl, a substituted or unsubstituted benzothiophenyl, a substituted or unsubstituted benzimidazolyl, a substituted or unsubstituted indolyl, a substituted or unsubstituted quinolyl, a substituted or unsubstituted isoquinolyl, a substituted or unsubstituted quinazolinyl, a substituted or unsubstituted quinoxalinyl, a substituted or unsubstituted naphthyridinyl, a substituted or unsubstituted benzoxazinyl, a substituted or unsubstituted benzothiazinyl, a substituted or unsubstituted acridinyl, a substituted or unsubstituted phenazinyl, a substituted or unsubstituted phenathiazinyl, a substituted or unsubstituted phenoxazinyl, a substituted or unsubstituted fluorenyl, a substituted or unsubstituted dibenzofuranyl, a substituted or unsubstituted dibenzothiophenyl, a substituted or unsubstituted carbazolyl, a substituted or unsubstituted benzindolyl, combinations thereof, or fused rings of combinations of the foregoing groups, but is not limited thereto.

In the present disclosure, the number of heteroatoms in the substituted or unsubstituted C₂-C₃₀ heteroaryl group is 1-5, preferably 1-4, preferably 1-3, and preferably 1-2.

In the present disclosure, the C₂-C₃₀ heteroaryl group refers to a heteroaryl group having 2 to 30 carbon atoms, preferably a heteroaryl group having 2 to 20 carbon atoms, preferably a heteroaryl group having 4 to 20 carbon atoms, preferably a heteroaryl group having 4 to 10 carbon atoms, preferably a heteroaryl group having 6 to 18 carbon atoms, preferably a heteroaryl group having 6 to 12 carbon atoms, and preferably a furyl, a thienyl, a pyrrolyl, a pyrazolyl, an imidazolyl, a triazolyl, an oxazolyl, a thiazolyl, an oxadiazolyl, a thiadiazolyl, a pyridinyl, a pyrimidinyl, a pyrazinyl, a triazinyl, a benzofuranyl, a benzothiophenyl, a benzimidazolyl, an indolyl, a quinolyl, an isoquinolyl, a quinazolinyl, a quinoxalinyl, a naphthyridinyl, a benzoxazinyl, a benzothiazinyl, an acridinyl, a phenazinyl, a phenathiazinyl, a phenoxazinyl, a fluorenyl, a dibenzofuranyl, a dibenzothiophenyl, a carbazolyl, a substituted or unsubstituted N-phenylcarbazolyl, a benzindolyl, combinations thereof, or fused rings of combinations of the foregoing groups, but is not limited thereto.

In the present disclosure, the deuterium substituted C₂-C₃₀ heteroaryl group refers to a deuterium-substituted heteroaryl group having 5 to 30 carbon atoms, preferably a deuterium-substituted heteroaryl group having 5 to 20 carbon atoms, preferably a deuterium-substituted heteroaryl group having 5 to 10 carbon atoms, preferably a deuterium-substituted heteroaryl group having 6 to 18 carbon atoms, and preferably a deuterium-substituted heteroaryl group having 6 to 12 carbon atoms, and preferably a deuterium-substituted furyl, a deuterium-substituted thienyl, a deuterium-substituted pyrrolyl, a deuterium-substituted pyrazolyl, a deuterium-substituted imidazolyl, a deuterium-substituted triazolyl, a deuterium-substituted oxazolyl, a deuterium-substituted thiazolyl, a deuterium-substituted oxadiazolyl, a deuterium-substituted thiadiazolyl, a deuterium-substituted pyridinyl, a deuterium-substituted pyrimidinyl, a deuterium-substituted pyrazinyl, a deuterium-substituted triazinyl, a deuterium-substituted benzofuranyl, a deuterium-substituted benzothiophenyl, a deuterium-substituted benzimidazolyl, a deuterium-substituted indolyl, a deuterium-substituted quinolyl, an isoquinolyl, a deuterium-substituted quinazolinyl, a deuterium-substituted quinoxalinyl, a deuterium-substituted naphthyridinyl, a deuterium-substituted benzoxazinyl, a deuterium-substituted benzothiazinyl, a deuterium-substituted acridinyl, a deuterium-substituted phenazinyl, a deuterium-substituted phenathiazinyl, a deuterium-substituted phenoxazinyl, a deuterium-substituted fluorenyl, a deuterium-substituted dibenzofuranyl, a deuterium-substituted dibenzothiophenyl, a deuterium-substituted carbazolyl, a deuterium-substituted substituted or unsubstituted N-phenylcarbazolyl, a deuterium-substituted benzindolyl, combinations thereof, or fused rings of combinations of the foregoing groups, but is not limited thereto.

The substituted or unsubstituted C₁-C₁₀ alkyl group (including a linear alkyl group and a branched alkyl group) of the present disclosure refers to a substituted or unsubstituted alkyl group having 1 to 10 carbon atoms, preferably a substituted or unsubstituted alkyl group having 1 to 5 carbon atoms, and preferably a substituted or unsubstituted alkyl group having 1 to 4 carbon atoms, and preferably a substituted or unsubstituted methyl, a substituted or unsubstituted ethyl, a substituted or unsubstituted propyl, a substituted or unsubstituted isopropyl, a substituted or unsubstituted butyl, a substituted or unsubstituted tert-butyl, a substituted or unsubstituted isobutyl, a substituted or unsubstituted sec-butyl, a substituted or unsubstituted neopentyl, a substituted or unsubstituted n-pentyl, a substituted or unsubstituted isopentyl, a substituted or unsubstituted octyl, a substituted or unsubstituted heptyl, a substituted or unsubstituted n-decyl, a substituted or unsubstituted 1-methylpentyl, a substituted or unsubstituted 2-methylpentyl, a substituted or unsubstituted 3-methylpentyl, a substituted or unsubstituted 1-butylpentyl, etc., but is not limited thereto.

The C₁-C₁₀ alkyl group (including a linear alkyl group and a branched alkyl group) of the present disclosure refers to an alkyl group having 1 to 10 carbon atoms, preferably an alkyl group having 1 to 5 carbon atoms, preferably an alkyl group having 1 to 4 carbon atoms, and preferably a methyl, an ethyl, a propyl, an isopropyl, a butyl, a tert-butyl, an isobutyl, a sec-butyl, a neopentyl, a n-pentyl, an isopentyl, an octyl, a heptyl, a n-decyl, a 1-methylpentyl, a 2-methylpentyl, a 3-methylpentyl, a 1-butylpentyl, etc., but is not limited thereto.

The C₁-C₁₀ alkyl group (including a linear alkyl group and a branched alkyl group) in the present disclosure refers to an alkyl group having 1 to 10 carbon atoms, preferably an alkyl group having 1 to 5 carbon atoms, preferably an alkyl group having 1 to 4 carbon atoms, preferably a methyl, an ethyl, a propyl, an isopropyl, a butyl, a tert-butyl, an isobutyl, a sec-butyl, a neopentyl, an n-pentyl, an isopentyl, an octyl, a heptyl, an n-decyl, a 1-methylpentyl, a 2-methylpentyl, a 3-methylpentyl, a 1-butylpentyl, etc., but is not limited thereto.

The deuterium-substituted C₁-C₁₀ alkyl group (including a linear alkyl group and a branched alkyl group) in the present disclosure refers to a deuterium-substituted alkyl group having 1 to 10 carbon atoms, preferably a deuterium-substituted alkyl group having 1 to 5 carbon atoms, preferably a deuterium-substituted alkyl group having 1 to 4 carbon atoms, and preferably a deuterium-substituted methyl, a deuterium-substituted ethyl, a deuterium-substituted propyl, a deuterium-substituted isopropyl, a deuterium-substituted butyl, a deuterium-substituted tert-butyl, a deuterium-substituted isobutyl, a deuterium-substituted sec-butyl, a deuterium-substituted neopentyl, a deuterium-substituted n-pentyl, a deuterium-substituted isopentyl, a deuterium-substituted octyl, a deuterium-substituted heptyl, a deuterium-substituted n-decyl, a deuterium-substituted 1-methylpentyl, a deuterium-substituted 2-methylpentyl, a deuterium-substituted 3-methylpentyl, a deuterium-substituted 1-butylpentyl, etc., but is not limited thereto.

The substituted or unsubstituted C₃-C₁₀ cycloalkyl group of the present disclosure preferably uses substituted or unsubstituted C₄-C₉ cycloalkyl group, more preferably substituted or unsubstituted C₅-C₈ cycloalkyl group, and particularly preferably substituted or unsubstituted C₅-C₇ cycloalkyl group. The non-limiting examples thereof may include substituted or unsubstituted cyclopropyl, substituted or unsubstituted cyclobutyl, substituted or unsubstituted cyclopentyl, substituted or unsubstituted cyclohexyl, substituted or unsubstituted 4-methylcyclohexyl, substituted or unsubstituted 4,4-dimethylcyclohexyl, substituted or unsubstituted adamantyl, and substituted or unsubstituted cycloheptyl, but are not limited thereto.

The C₃-C₁₀ cycloalkyl group of the present disclosure refers to a monovalent monocyclic saturated hydrocarbon group including 3 to 10 carbon atoms as ring-forming atoms. In this article, C₄-C₉ cycloalkyl groups are preferably used, C₅-C₈ cycloalkyl groups are more preferably used, and C₅-C₇ cycloalkyl groups are particularly preferably used. The non-limiting examples thereof may include cyclopropyl, cyclobutyl, cyclopentyl, cyclohexyl, 4-methylcyclohexyl, 4,4-dimethylcyclohexyl, adamantyl, and cycloheptyl, but are not limited thereto.

The deuterium-substituted C₃-C₁₀ cycloalkyl group of the present disclosure preferably uses deuterium-substituted C₄-C₉ cycloalkyl group, more preferably deuterium-substituted C₅-C₈ cycloalkyl group, and particularly preferably deuterium-substituted C₅-C₇ cycloalkyl group. The non-limiting examples thereof may include a deuterium-substituted cyclopropyl, a deuterium-substituted cyclobutyl, a deuterium-substituted cyclopentyl, a deuterium-substituted cyclohexyl, a deuterium-substituted 4-methylcyclohexyl, a deuterium-substituted 4,4-dimethylcyclohexyl, a deuterium-substituted adamantyl, and a deuterium-substituted cycloheptyl, but are not limited thereto.

The halogen atom in the present disclosure refers to a fluorine atom, a chlorine atom, a bromine atom or an iodine atom.

The C₁-C₁₀ alkoxy group in the present disclosure refers to a methoxy, an ethoxy, a propoxy, a butoxy, a pentyloxy, a hexyloxy or an isopropoxy, but is not limited thereto.

The C₂-C₁₀ alkenyl group in the present disclosure refers to a vinyl, an allyl, a 1-butenyl, a 2-butenyl, a 3-butenyl, a 1,3-butadienyl, a 1-methylvinyl, a styryl, a 2,2-diphenylvinyl, a 1,2-diphenylvinyl, a 1,1-dimethylallyl, a 1-methylallyl, a 2-methylallyl, a 1-phenylallyl, a 2-phenylallyl, a 3,3-diphenylallyl, a 1,2-dimethylallyl, a 1-phenyl-1-butenyl and a 3-phenyl-1-butenyl, etc., but is not limited thereto.

The substituent is optionally selected from one or more of a deuterium atom, a chlorine atom, a fluorine atom, a trifluoromethyl, an adamantyl, a cyano, a methyl, an ethyl, a propyl, an isopropyl, a tert-amyl, a tert-butyl, a butyl, a methoxy, a phenyl, a biphenyl, a naphthyl, an anthracyl, a phenanthryl, a pyridyl, a pyrimidyl, a pyrazinyl, a pyridazinyl, a benzoxazolyl, a benzothiazolyl, a quinoxalinyl, a quinolyl, an isoquinolyl, a furyl, a thienyl, an indolyl, a pyrrolyl, a dibenzofuranyl, a dibenzothienyl, a 9,9-dimethylfluorenyl, a spirofluorenyl, a carbazolyl, an N-phenylcarbazolyl, a carbazolinyl, an azaphenanthryl, a diphenylamino, a 1,1,4,4-tetramethyl-1,2,3,4-tetrahydronaphthyl, a methyl-substituted phenyl, an ethyl-substituted phenyl, an isopropyl-substituted phenyl, a tert-butyl-substituted phenyl, an adamantyl-substituted phenyl, a methyl-substituted biphenyl, an ethyl-substituted biphenyl, an isopropyl-substituted biphenyl, a tert-butyl-substituted biphenyl, a deuterated methyl-substituted phenyl, a deuterated ethyl-substituted phenyl, a deuterated isopropyl-substituted phenyl, a deuterated tert-butyl-substituted phenyl, a deuterated methyl-substituted biphenyl, a deuterated ethyl-substituted biphenyl, a deuterated isopropyl-substituted biphenyl, and a deuterated tert-butyl-substituted biphenyl.

As substrate of the organic electroluminescent device of the present disclosure, any substrate commonly used in organic electroluminescent devices can be used. Examples include transparent substrates such as glass or transparent PI film substrates; opaque substrates such as silicon substrates. Different substrates have different mechanical strength, thermal stability, transparency, surface smoothness, and water resistance. Depending on different properties of the substrate, it has different directions of use. In the present disclosure, a transparent PI film substrate is preferably used. The thickness of the substrate is not particularly limited.

A first electrode is formed on the substrate, and the first electrode and the second electrode may be opposite to each other. The first electrode may be an anode. The first electrode may be a transmissive electrode, a semi-transmissive electrode or a reflective electrode. When the first electrode is a transmissive electrode, it can be formed by using a transparent metal oxide, such as indium tin oxide (ITO), indium zinc oxide (IZO), zinc oxide (ZnO) or indium tin zinc oxide (ITZO). When the first electrode is a semi-transmissive electrode or a reflective electrode, it may include metals such as Ag, Mg, Al, Pt, Pd, Au, Ni, Nd, Ir or Cr, etc., or an alloy of several metals, or combinations of metals, metal oxides and metal alloys. The thickness of the first electrode layer depends on the material used, and is generally 50-500 nm, preferably 70-300 nm and more preferably 100-200 nm.

An organic functional material layer arranged between the first and second electrodes sequentially comprises a hole transport region, a light-emitting layer and an electrode transport region from bottom to top.

In the present disclosure, the hole transport region constituting the organic electroluminescent device can be listed as a hole injection layer, a hole transport layer, an electron blocking layer, etc.

As the materials for the hole injection layer, the hole transport layer, and the electron blocking layer, any materials that are known as the related materials used for organic electroluminescent devices can be selected for use.

The hole injection layer contains a host organic material that can conduct holes, and further contains a P-type doping material with a deep HOMO energy level (the corresponding LUMO energy level will also be very deep). Based on empirical summaries, in order to achieve smooth injection of holes from the anode to the organic film layer, the HOMO energy level of the host organic material that conducts holes used in the anode interface buffer layer must have certain characteristics with the P-type doping material, so that the charge transfer state between the host material and the doping material can be realized, the ohmic contact between the buffer layer and the anode can be achieved, and the efficient injection of the injection conduction from the electrode to the hole can be achieved.

In view of the above empirical summaries, for hole-based host organic materials with different HOMO energy levels, different P-type doping materials need to be selected to match them in order to achieve interfacial ohmic contact and improve the hole injection effect.

Preferably, the host organic material of the hole injection layer of the present disclosure can be optionally selected from the compounds disclosed in the following prior arts: JP1996048656A, JP1996048656A, CN1702065A, CN101535256A, CN103108859A, US20120112176A1, JP1989142657A, CN105439999A or CN103108859A.

Preferably, the P-type doping material is selected from the compounds with charge conductivity disclosed in the prior art, and the P-type dopant can be selected from the compounds disclosed in any one of the following documents: WO2011073149A, EP1968131A1, EP2276085A1, EP2213662A1, EP1722602A1, EP2045848A1, DE10200703122 0A1, US20100181555A1, US20100102709A1, WO2009003455A1, WO2010094378A1, WO2011120709A1, US20100096600A1, DE102012209523A1, CN101728485A and WO2012095143A1, but are not limited thereto.

In one embodiment of the present disclosure, the hole injection layer comprises a P-type doping material with charge conductivity selected from the following: quinone derivatives, such as tetracyanoquinodimethane (TCNQ) and 2,3,5,6-tetrafluoro-tetracyano-1,4-benzoquinodimethane (F4-TCNQ); or hexaazatriphenylene derivatives, such as 2,3,6,7,10,11-hexacyano-1,4,5,8,9,12-hexaazatriphenylene (HAT-CN); or cyclopropane derivatives, such as 4,4′,4″-((1E,1′E,1″E)-cyclopropane-1,2,3-trimethylenetris(cyanoformylidene))tris(2,3,5,6-tetrafluorobenzyl); or metal oxides, such as tungsten oxide and molybdenum oxide, but are not limited thereto.

In the hole injection layer of the present disclosure, the ratio of the used hole transport material to the P-type doping material is 99:1-95:5, preferably 99:1-97:3, calculated by mass.

The thickness of the hole injection layer of the present disclosure can be 5-100 nm, preferably 5-50 nm, and more preferably 5-20 nm, but the thickness is not limited to this range.

Preferably, as the hole transport layer material of the present disclosure, it can be optionally selected from the compounds disclosed in the following prior art:
JP1996048656A, JP1996048656A, CN1702065A, CN101535256A, CN103108859A, US20120112176A1, JP1989142657A, and CN103108859A.

Preferably, the hole transport layer material of the present disclosure and the host organic material in the hole injection layer are selected from the same compound.

The thickness of the hole transport layer of the present disclosure can be 5-200 nm, preferably 10-150 nm, and more preferably 20-100 nm, but the thickness is not limited to this range.

In one embodiment of the present disclosure, as the electron blocking layer material of the present disclosure, the compounds disclosed in the following prior art can be optionally selected:
CN102046613A, CN105408448A, KR1020160049955A, CN103108859A, KR1020130106255A, EP2922932A1, CN102224150A, and US20170018710A1.

The thickness of the electron blocking layer of the present disclosure can be 1-50 nm, preferably 5-40 nm, but the thickness is not limited to this range.

After forming the hole injection layer, the hole transport layer and the electron blocking layer, a corresponding light-emitting layer is formed on the electron blocking layer.

The light-emitting layer may include a host material and a doping material. The host material may be a common green light host material in the field, and the doping material may be a boron-containing resonance-type organic compound as shown in the general formula (1) of the present disclosure.

The light-emitting layer may include a single host material or a dual host material;

The dual host material includes a first host material and a second host material, and preferably at least one of the first host material and the second host material is a TADF material;

The TADF material refers to a material having a thermally activated delayed fluorescence property, characterized by having a small energy level difference between the first excited singlet state and the first excited triplet state, so that the generated singlet excitons and triplet excitons can be simultaneously utilized in the device, making the utilization rate of the excitons generated electrically inside the device be as close to 100% as possible. Compared with the traditional fluorescent materials, the TADF materials have a higher exciton utilization rate.

The light-emitting layer may include a host material, an exciton sensitizing material and a doping material;

The exciton sensitizing material refers to a material that can make the light-emitting material in the light-emitting layer fully utilize the electrically generated excitons, so that the light-emitting layer finally produces the emission spectrum of the sensitized material. The exciton sensitizers may assume functions such as exciton capture, exciton conversion, and exciton transfer, etc., in electroluminescent devices. The boron-containing resonance-type organic compound as shown in the general formula (1) of the present disclosure and the exciton sensitizing material are used in combination, which has a significant improvement effect on the problems of device efficiency improvement, and annihilation and efficiency reduction of excitons in the device, etc.

In the light-emitting layer of the present disclosure, the ratio of the host material to the doping material used is 99:1-70:30, preferably 99:1-85:15 and more preferably 97:3-87:13, calculated by mass.

The thickness of the light-emitting layer can be adjusted to optimize the luminous efficiency and driving voltage. The preferred thickness range is 5 nm to 50 nm, further preferably 10-50 nm, and more preferably 15-40 nm, but the thickness is not limited to this range.

In the present disclosure, the electron transport region may sequentially include, from bottom to top, a hole blocking layer, an electron transport layer, and an electron injection layer arranged on the light-emitting layer, but is not limited thereto.

The hole blocking layer is a layer that blocks holes injected from the anode from passing through the light-emitting layer and entering the cathode, thereby extending the service life of the device and improving the efficiency of the device. The hole blocking layer of the present disclosure can be arranged on the light-emitting layer. As the hole blocking layer material of the organic electroluminescent device of the present disclosure, compounds with hole blocking function known in the prior art can be used, such as the compounds disclosed in the following prior arts: Appl. Phys. Lett. 75, 4 (1999), Appl. Phys. Lett. 83, 3858 (2003), JP2015111679A, KR1020180043220A, CN109564982A, and KR1020180065246A.

The thickness of the hole blocking layer of the present disclosure can be 2-200 nm, preferably 5-150 nm, more preferably 5-50 nm, but the thickness is not limited to this range.

The electron transport layer may be disposed on the light-emitting layer or (if present) the hole blocking layer. The electron transport layer material is a material that easily receives electrons from the cathode and transfers the received electrons to the light-emitting layer. Preferably, the material with a high electron mobility can be selected. As the electron transport layer of the organic electroluminescent device of the present disclosure, the electron transport layer materials for organic electroluminescent devices disclosed in the prior art can be used, such as the following compounds disclosed in the prior art: CN1784388A, CN1625552A, CN107431141A, CN107431141A, KR1020160149041A, KR1020160149041A, CN103827256A, KR101847347B1, KR1020190050658A, CN102574813A, CN107721979A, and KR1020100073954A.

In a preferred embodiment of the present disclosure, the electron transport layer also includes other compounds conventionally used for electron transport layers, such as Alq3, LiQ, preferably LiQ.

The thickness of the electron transport layer of the present disclosure may be 10-80 nm, preferably 20-60 nm, and more preferably 25-45 nm, but the thickness is not limited to this range.

The electron injection layer may be disposed above the electron transport layer. The electron injection layer material is generally preferably a material having a low work function, so that electrons are easily injected into the organic functional material layer. As the electron injection layer material of the organic electroluminescent device of the present disclosure, the electron injection layer material for organic electroluminescent devices disclosed in the prior art can be used, for example: LiF, Cs₂CO₃, CsF, Csq, NaF, MgF₂, CaF₂, Al₂O₃, Yb, etc.

The thickness of the electron injection layer of the present disclosure may be 0.1-5 nm, preferably 0.5-3 nm, and more preferably 0.8-1.5 nm, but the thickness is not limited to this range.

The second electrode may be disposed above the electron transport region. The second electrode may be a cathode. The second electrode may be a transmissive electrode, a semi-transmissive electrode or a reflective electrode. When the second electrode is a transmissive electrode, the second electrode may include, for example, Li, Yb, Ca, LiF/Ca, LiF/Al, Al, Mg, BaF, Ba, Ag, or a compound or mixture thereof; when the second electrode is a semi-transmissive electrode or a reflective electrode, the second electrode may include, but is not limited to, Ag, Mg, Yb, Al, Pt, Pd, Au, Ni, Nd, Ir, Cr, Li, Ca, LiF/Ca, LiF/Al, Mo, Ti, or a compound or mixture thereof, but is not limited thereto. The thickness of the cathode depends on the material used.

The organic electroluminescent device of the present disclosure may also include an encapsulation structure. The encapsulation structure may be a protective structure for preventing foreign substances such as moisture and oxygen from entering the organic layer of the organic electroluminescent device. The encapsulation structure may be, for example, a can, such as a glass can or a metal can; or a thin film covering the entire surface of the organic layer.

A method for preparing the organic electroluminescent device of the present disclosure comprises successively laminating an anode, a hole injection layer, a hole transport layer, an electron blocking layer, an organic film layer, an electron transport layer, an electron injection layer and a cathode, and optionally a covering layer on a substrate. In this regard, methods such as vacuum deposition, vacuum evaporation, spin coating, casting, LB method, ink-jet printing, laser printing or LITI and the like may be used, but are not limited thereto. In the present disclosure, it is preferred to use a vacuum evaporation method to form the various layers. Those skilled in the art may conventionally select various process conditions in the vacuum evaporation method according to actual needs.

### Preparation of Compounds

### 1. Synthesis of Intermediate P

### Synthesis of Intermediate P1:

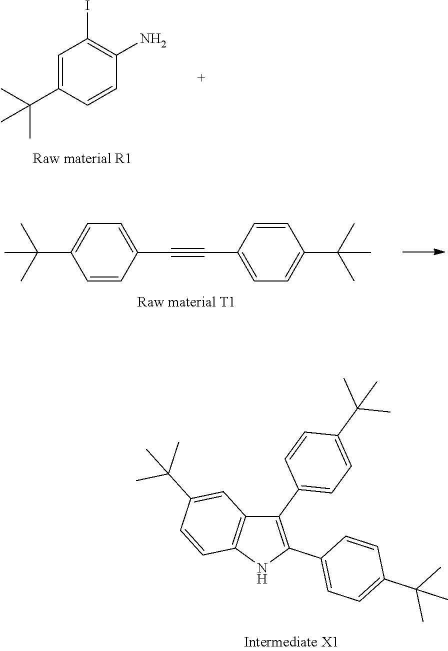

Raw material T1 (25 mmol, 7.3 g), potassium carbonate (62.5 mmol, 8.6 g), tricyclohexylphosphine (1.25 mmol, 0.35 g), and palladium acetate (0.4 mmol, 90 mg) were added into a two-necked flask, then 100 mL of anhydrous DMF was added under nitrogen protection, and the mixture was stirred at room temperature for 30 minutes. Raw material R1 (25 mmol, 6.9 g) was added under nitrogen protection, and the mixture was refluxed under stirring for 12 hours under nitrogen protection, filtered, washed with water, dried, and passed through a column to obtain intermediate X1.

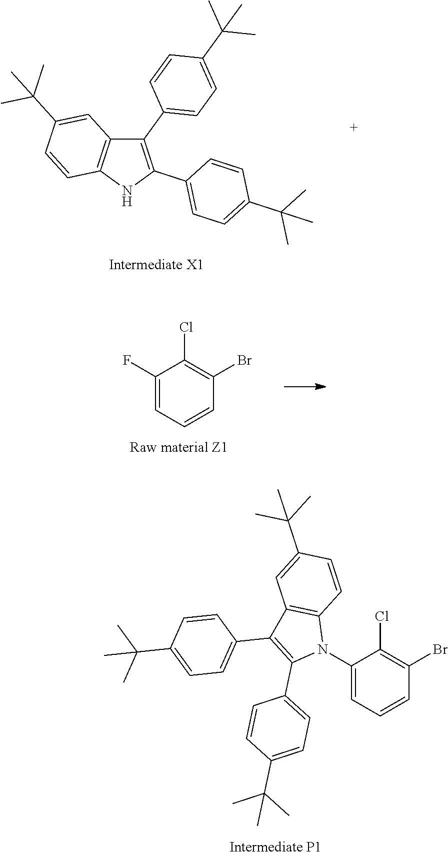

Raw material Z1 (18.4 mmol, 3.9 g) and cesium carbonate (55.2 mmol, 18.0 g) were added to a two-necked flask, then 120 mL of anhydrous DMF was added under nitrogen protection, and the mixture was stirred at room temperature for 30 minutes. The intermediate X1 (20.2 mmol, 8.8 g) was added under nitrogen protection, and the solution was refluxed under magnetic stirring for 27 hours, cooled, filtered, washed with water, dried, and passed through a column to obtain intermediate P1.

### Synthesis of Intermediate P2:

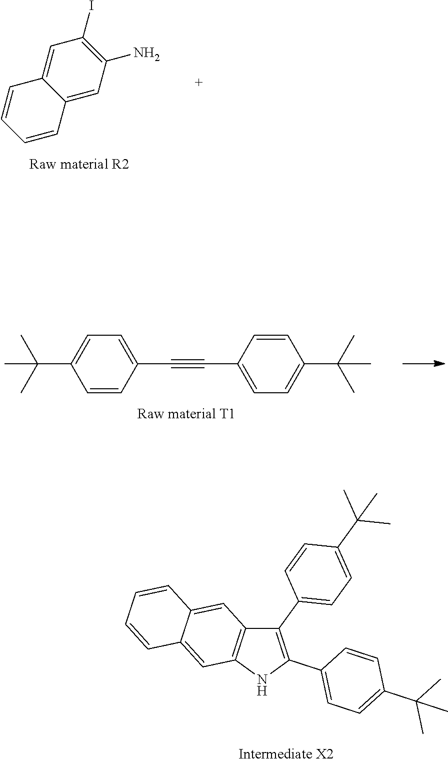

Raw material T1 (25 mmol, 7.3 g), potassium carbonate (62.5 mmol, 8.6 g), tricyclohexylphosphine (1.25 mmol, 0.35 g) and palladium acetate (0.4 mmol, 90 mg) were added into a two-necked bottle, then 100 mL of anhydrous DMF was added under nitrogen protection, and the mixture was stirred at room temperature for 30 minutes. Raw material R2 (25 mmol, 6.7 g) was added under nitrogen protection, and the mixture was stirred at 140° C. for 13 hours under nitrogen protection, filtered, washed with water, dried and passed through a column to obtain intermediate X2.

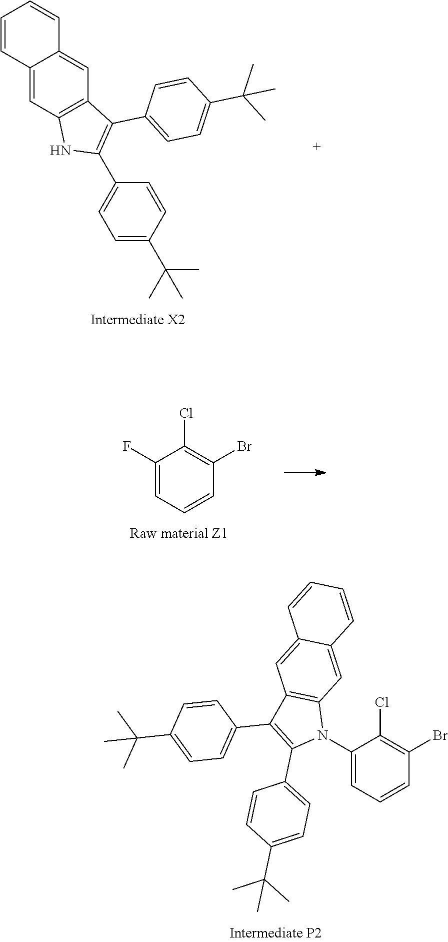

Raw material Z1 (18.4 mmol, 3.9 g) and cesium carbonate (55.2 mmol, 18.0 g) were added to a two-necked flask, then 120 mL of anhydrous DMF was added under nitrogen protection, and the mixture was stirred at room temperature for 30 minutes. Intermediate X2 (20.2 mmol, 8.7 g) was added under nitrogen protection, and the solution was refluxed under magnetic stirring for 25 hours, cooled, filtered, washed with water, dried, and passed through a column to obtain intermediate P2.

### Synthesis of Intermediate P3:

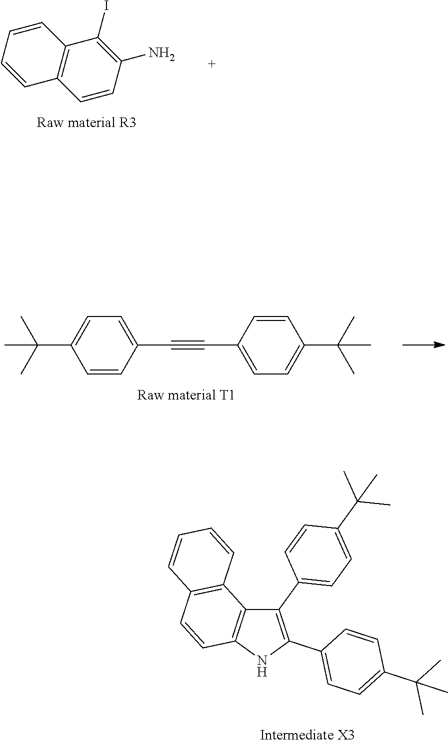

Raw material T1 (25 mmol, 7.3 g), potassium carbonate (62.5 mmol, 8.6 g), tricyclohexylphosphine (1.25 mmol, 0.35 g), and palladium acetate (0.4 mmol, 90 mg) were added into a two-necked flask, then 100 mL of anhydrous DMF was added under nitrogen protection, and the mixture was stirred at room temperature for 30 minutes. Raw material R3 (25 mmol, 6.7 g) was added under nitrogen protection, and the mixture was stirred at 140° C. for 12 hours under nitrogen protection, filtered, washed with water, dried, and passed through a column to obtain intermediate X3.

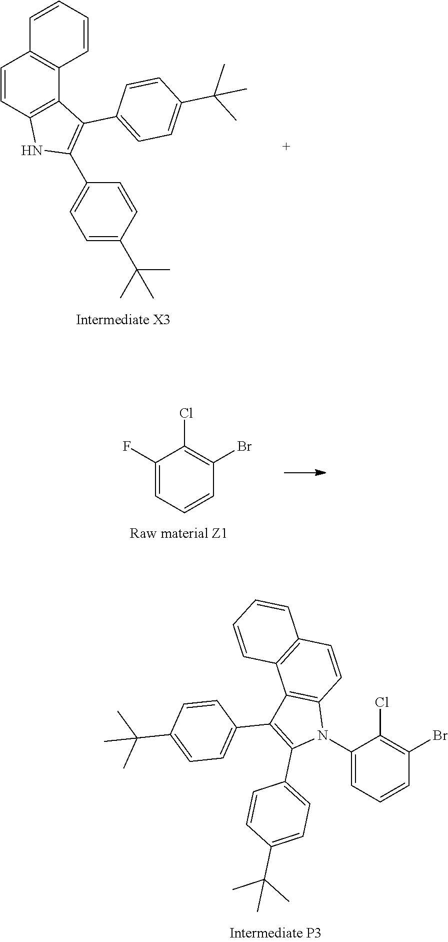 [SMILES: CC(C)(C)c1ccc(-c2[nH]c3ccc4ccccc4c3c2-c2ccc(C(C)(C)C)cc2)cc1 ; Fc1cccc(Br)c1Cl ; CC(C)(C)c1ccc(-c2c(-c3ccc(C(C)(C)C)cc3)n(-c3cccc(Br)c3Cl)c3ccc4ccccc4c23)cc1]

Raw material Z1 (18.4 mmol, 3.9 g) and cesium carbonate (55.2 mmol, 18.0 g) were added to a two-necked flask, then 120 mL of anhydrous DMF was added under nitrogen protection, and the mixture was stirred at room temperature for 30 minutes. The intermediate X3 (20.2 mmol, 8.7 g) was added under nitrogen protection, and the solution was refluxed under magnetic stirring for 24 hours. The mixture was cooled, filtered, washed with water, dried, and passed through a column to obtain intermediate P3.

### 2. Synthesis of Intermediate Q

### Synthesis of Intermediate Q1:

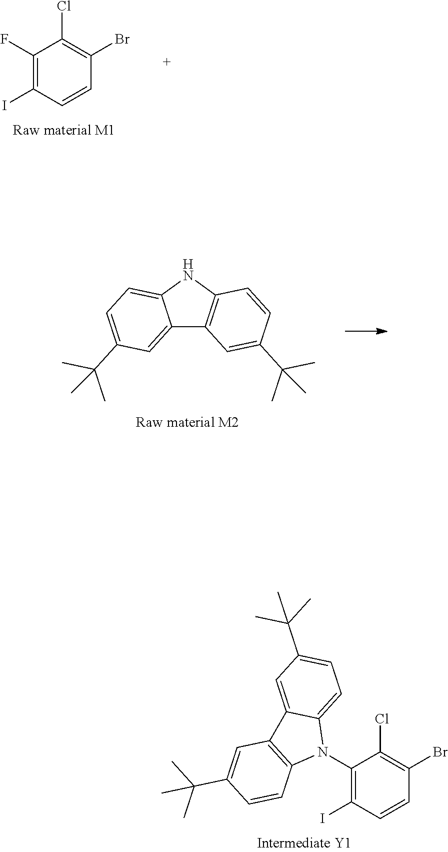 [SMILES: Fc1c(I)ccc(Br)c1Cl ; CC(C)(C)c1ccc2[nH]c3ccc(C(C)(C)C)cc3c2c1 ; CC(C)(C)c1ccc2c(c1)c1cc(C(C)(C)C)ccc1n2-c1c(I)ccc(Br)c1Cl]

Raw material M1 (18.4 mmol, 6.2 g) and cesium carbonate (55.2 mmol, 18.0 g) were added to a two-necked flask, then 120 mL of anhydrous DMF was added under nitrogen protection, and the mixture was stirred at room temperature for 30 minutes. Raw material M2 (20.2 mmol, 5.6 g) was added under nitrogen protection, and the solution was refluxed under magnetic stirring for 24 hours. The mixture was cooled, filtered, washed with water, dried, and passed through a column to obtain intermediate Y1.

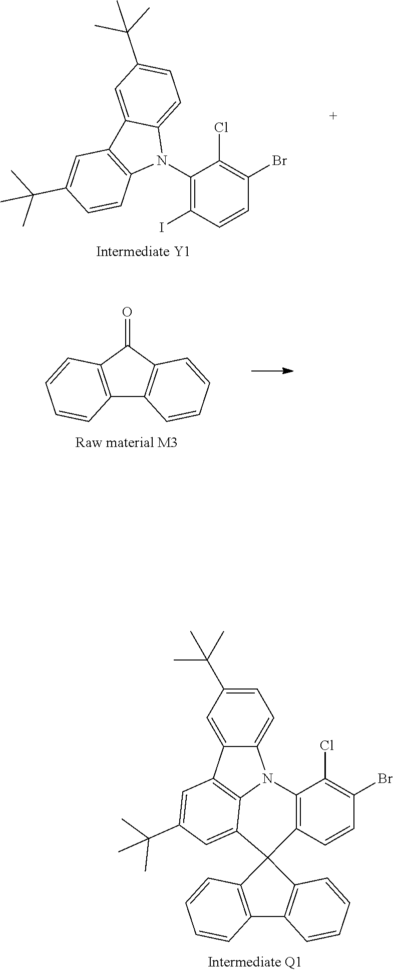 [SMILES: CC(C)(C)c1ccc2c(c1)c1cc(C(C)(C)C)ccc1n2-c1c(I)ccc(Br)c1Cl ; O=C1c2ccccc2-c2ccccc21 ; CC(C)(C)c1ccc2c(c1)c1cc(C(C)(C)C)cc3c1n2-c1c(ccc(Br)c1Cl)C31c2ccccc2-c2ccccc21]

The intermediate Y1 (5.1 mmol, 3.0 g) was dissolved in 50 mL of tetrahydrofuran (THF) solution. Under the condition of introducing nitrogen gas at −78° C., 4.7 mL of a solution of n-butyl lithium (2.5 M, 11.7 mmol) in n-hexane was slowly added; after stirring at −78° C. for 2 hours, 15 mL of a solution of raw material M3 (5.5 mmol, 1.0 g) in tetrahydrofuran was slowly added. The reaction mixture was then slowly heated to room temperature and stirred overnight. 20 mL of dilute hydrochloric acid (1.0 M) solution, distilled water and ethyl acetate were added to the reaction mixture, the aqueous layer was separated, and extracted three times with ethyl acetate. The combined organic layer was dried over sodium sulfate and filtered. After the solvent was removed under reduced pressure, the crude product was dissolved in anhydrous dichloromethane, and then 47% boron trifluoride-diethyl ether was slowly added. The reaction mixture was stirred overnight and then slowly quenched with sodium bicarbonate (NaHCO₃) aqueous solution. Then the aqueous layer was separated, extracted with dichloromethane, dried over sodium sulfate, filtered, distilled under reduced pressure, and passed through a column to obtain intermediate Q1.

### Synthesis of Intermediate Q2:

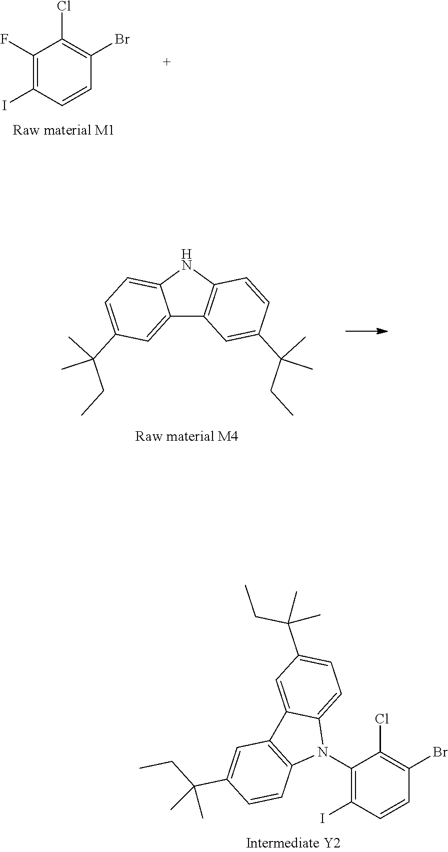 [SMILES: Fc1c(I)ccc(Br)c1Cl ; CCC(C)(C)c1ccc2[nH]c3ccc(C(C)(C)CC)cc3c2c1 ; CCC(C)(C)c1ccc2c(c1)c1cc(C(C)(C)CC)ccc1n2-c1c(I)ccc(Br)c1Cl]

Raw material M1 (18.4 mmol, 6.2 g) and cesium carbonate (55.2 mmol, 18.0 g) were added to a two-necked flask, then 120 mL of anhydrous DMF was added under nitrogen protection, and the mixture was stirred at room temperature for 30 minutes. Raw material M4 (20.2 mmol, 6.2 g) was added under nitrogen protection, and the solution was refluxed under magnetic stirring for 25 hours. The mixture was cooled, filtered, washed with water, dried, and passed through a column to obtain intermediate Y2.

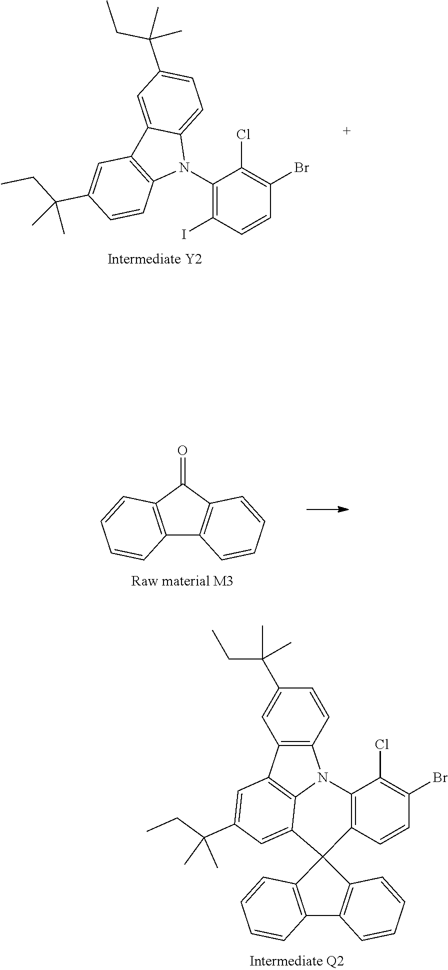 [SMILES: CCC(C)(C)c1ccc2c(c1)c1cc(C(C)(C)CC)ccc1n2-c1c(I)ccc(Br)c1Cl ; O=C1c2ccccc2-c2ccccc21 ; CCC(C)(C)c1ccc2c(c1)c1cc(C(C)(C)CC)cc3c1n2-c1c(ccc(Br)c1Cl)C31c2ccccc2-c2ccccc21]

The intermediate Y2 (5.1 mmol, 3.2 g) was dissolved in 50 mL of tetrahydrofuran (THF) solution. Under the condition of introducing nitrogen gas at −78° C., 4.7 mL of a solution of n-hexane in n-butyl lithium (2.5 M, 11.7 mmol) was slowly added; after stirring at −78° C. for 3 hours, 15 mL of a solution of raw material M3 (5.5 mmol, 1.0 g) in tetrahydrofuran was slowly added. The reaction mixture was then slowly heated to room temperature and stirred overnight. 20 mL of dilute hydrochloric acid (1.0 M) solution, distilled water and ethyl acetate were added to the reaction mixture, the aqueous layer was separated, and extracted three times with ethyl acetate. The combined organic layer was dried over sodium sulfate and filtered. After the solvent was removed under reduced pressure, the crude product was dissolved in anhydrous dichloromethane, and then 47% boron trifluoride-diethyl ether was slowly added. The reaction mixture was stirred overnight and then slowly quenched with sodium bicarbonate (NaHCO₃) aqueous solution. Then the aqueous layer was separated, extracted with dichloromethane, dried over sodium sulfate, filtered, distilled under reduced pressure, and passed through a column to obtain intermediate Q2.

### Synthesis of Intermediate Q3:

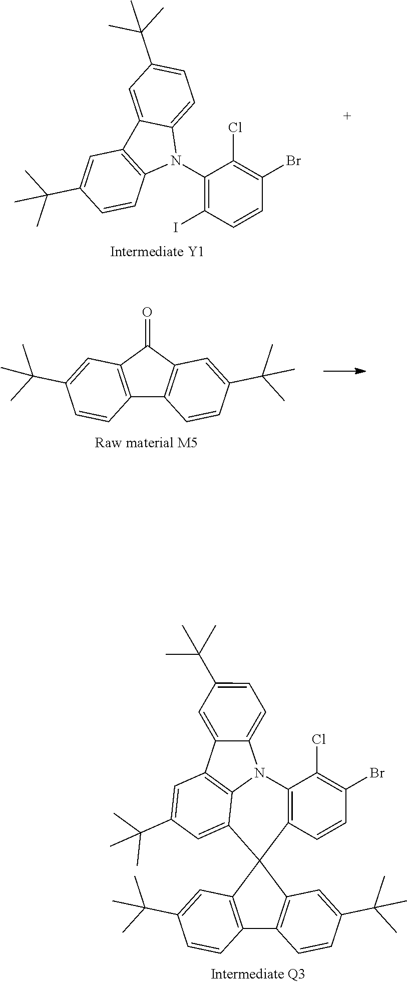

The intermediate Y1 (5.1 mmol, 3.0 g) was dissolved in 50 mL of tetrahydrofuran (THF) solution. Under the condition of introducing nitrogen gas at −78° C., 4.7 mL of a solution of n-butyl lithium (2.5 M, 11.7 mmol) in n-hexane was slowly added; after stirring at −78° C. for 2 hours, 15 mL of a solution of raw material M5 (5.5 mmol, 1.6 g) in tetrahydrofuran was slowly added. The reaction mixture was then slowly heated to room temperature and stirred overnight. 20 mL of dilute hydrochloric acid (1.0 M) solution, distilled water and ethyl acetate were added to the reaction mixture, the aqueous layer was separated, and extracted three times with ethyl acetate. The combined organic layer was dried over sodium sulfate and filtered. After the solvent was removed under reduced pressure, the crude product was dissolved in anhydrous dichloromethane, and then 47% boron trifluoride-diethyl ether was slowly added. The reaction mixture was stirred overnight and then slowly quenched with sodium bicarbonate (NaHCO₃) aqueous solution. Then the aqueous layer was separated, extracted with dichloromethane, dried over sodium sulfate, filtered, distilled under reduced pressure, and passed through a column to obtain intermediate Q3.

### Synthesis of Intermediate Q4:

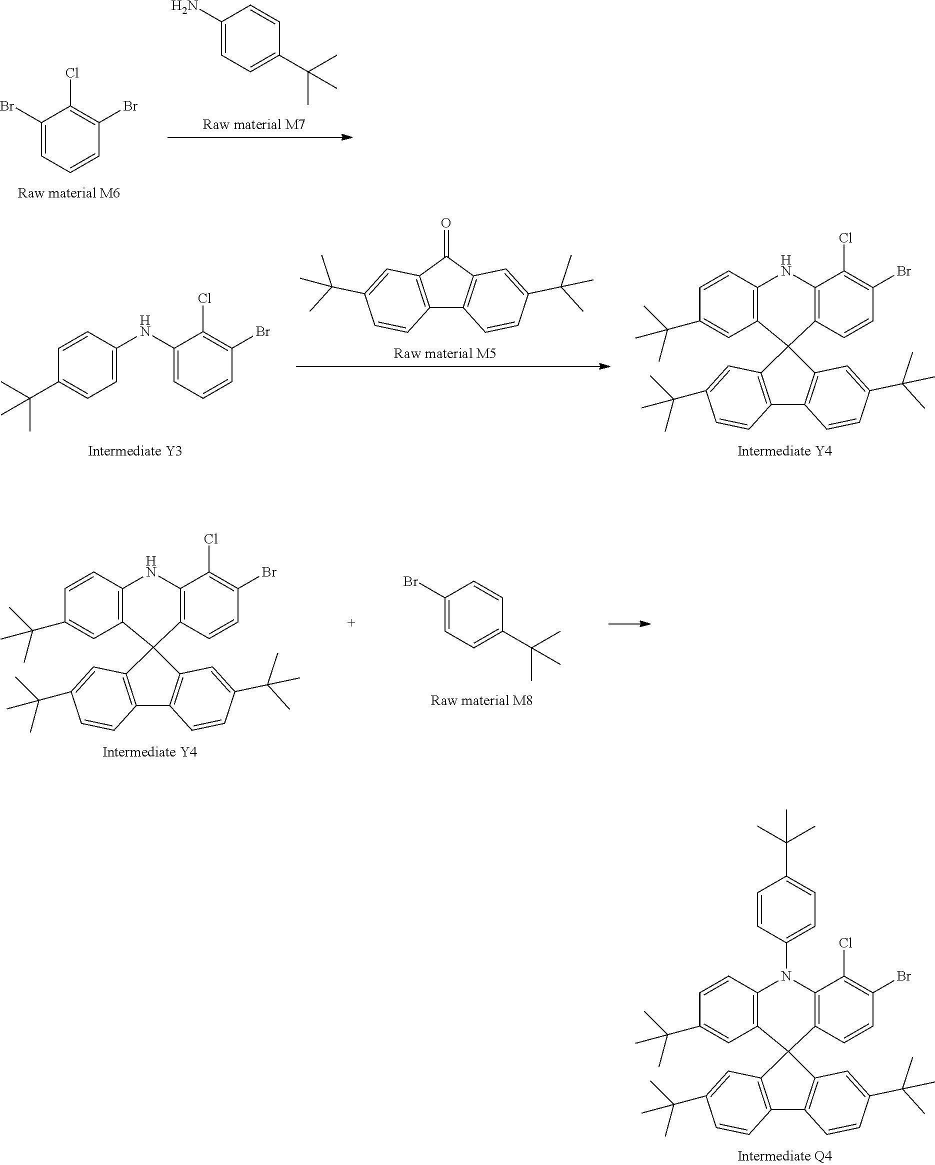

Under nitrogen protection, raw material M6 (0.68 g, 2.5 mmol) was dissolved in 60 mL of toluene solution, and raw material M7 (0.37 g, 2.5 mmol), tri-tert-butylphosphine (0.025 g, 0.125 mmol), sodium tert-butoxide (0.62 g, 6.5 mmol) and palladium acetate (0.01 g, 0.05 mmol) were added, and stirred vigorously. The obtained mixture was heated to reflux for 4 hours and then allowed to reach room temperature. Ethyl acetate (100 mL) was then added. The mixture was washed with deionized water (100 mL), dried over anhydrous magnesium sulfate, cooled to room temperature, filtered, concentrated, and subjected to column chromatography to obtain intermediate Y3.

Under nitrogen protection, the intermediate Y3 (3.39 g, 10 mmol) and p-toluenesulfonic acid (0.17 g, 1 mmol) were added to a two-necked flask, heated to 150° C. and stirred for 0.5 hours, and then raw material M5 (3.51 g, 12 mmol) was added, and the reaction was heated to 200° C. and reacted for 1 hour. After the reaction was cooled to room temperature, it was concentrated and subjected to column chromatography to obtain intermediate Y4.

The intermediate Y4 (1.53 g, 2.5 mmol) was dissolved in 100 mL of toluene solution, and raw material M8 (0.53 g, 2.5 mmol), tri-tert-butylphosphine (0.025 g, 0.125 mmol), sodium tert-butoxide (0.62 g, 6.5 mmol) and palladium acetate (0.01 g, 0.04 mmol) were added, and stirred vigorously. The obtained mixture was refluxed at 105° C. for 12 hours, and then allowed to reach room temperature. Then it was concentrated under reduced pressure and separated by column chromatography to obtain the intermediate Q4.

### 3. Synthesis of Examples

### Example 1 Synthesis of Compound 18

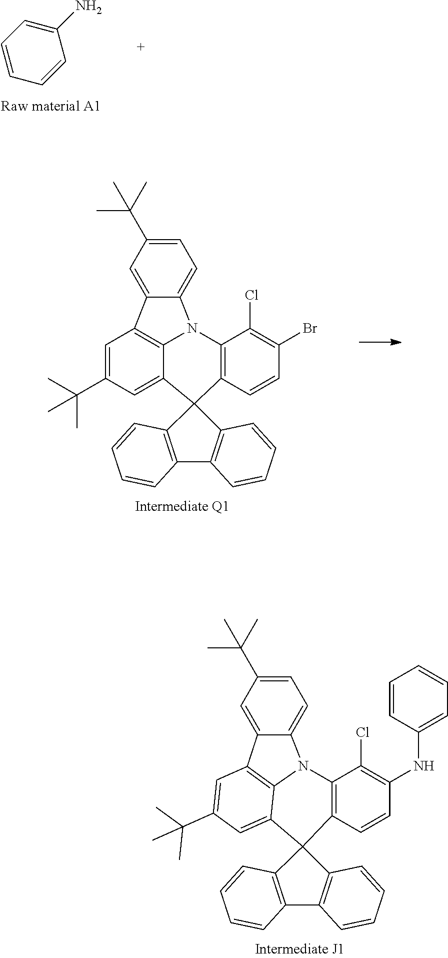 [SMILES: Nc1ccccc1 ; CC(C)(C)c1ccc2c(c1)c1cc(C(C)(C)C)cc3c1n2-c1c(ccc(Br)c1Cl)C31c2ccccc2-c2ccccc21 ; CC(C)(C)c1ccc2c(c1)c1cc(C(C)(C)C)cc3c1n2-c1c(ccc(Nc2ccccc2)c1Cl)C31c2ccccc2-c2ccccc21]

Intermediate Q1 (5.5 mmol, 3.47 g), raw material A1 (5 mmol, 0.47 g), Pd₂(dba)₃ (0.5 mmol, 0.46 g), tri-tert-butylphosphine tetrafluoroborate (1 mmol, 0.29 g), sodium tert-butoxide (15 mmol, 1.44 g), and toluene (80 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered through a silica gel pad and then concentrated under vacuum. The crude product was further purified by a chromatography column and dried under vacuum to obtain intermediate J1.

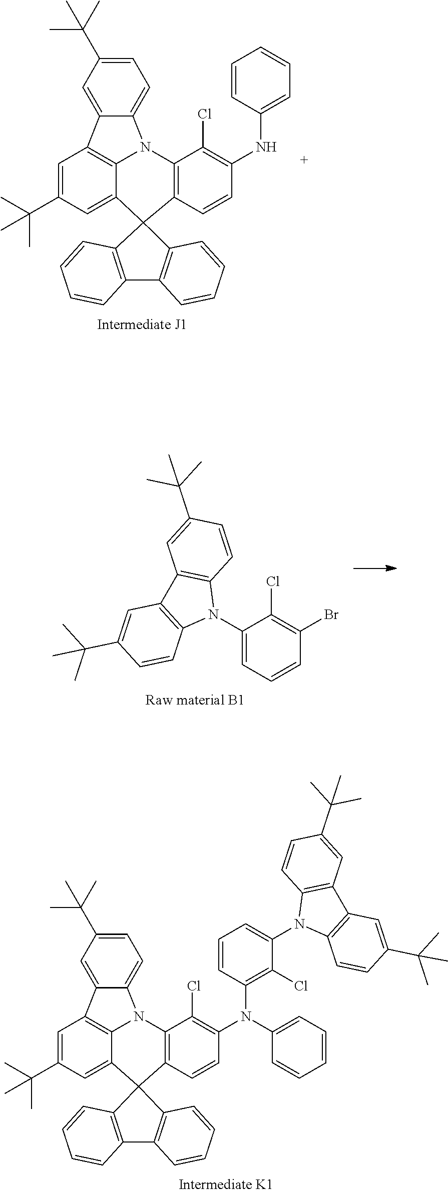 [SMILES: CC(C)(C)c1ccc2c(c1)c1cc(C(C)(C)C)cc3c1n2-c1c(ccc(Nc2ccccc2)c1Cl)C31c2ccccc2-c2ccccc21 ; CC(C)(C)c1ccc2c(c1)c1cc(C(C)(C)C)ccc1n2-c1cccc(Br)c1Cl ; CC(C)(C)c1ccc2c(c1)c1cc(C(C)(C)C)ccc1n2-c1cccc(N(c2ccccc2)c2ccc3c(c2Cl)-n2c4ccc(C(C)(C)C)cc4c4cc(C(C)(C)C)cc(c42)C32c3ccccc3-c3ccccc32)c1Cl]

Raw material B1 (5.5 mmol, 2.58 g), intermediate J1 (5 mmol, 3.22 g), Pd₂(dba)₃ (0.5 mmol, 0.46 g), tri-tert-butylphosphine tetrafluoroborate (1 mmol, 0.29 g), sodium tert-butoxide (15 mmol, 1.44 g), and toluene (100 mL) were added to a three-necked flask in sequence. The mixture was degassed by a “vacuumization-nitrogen introduction” cycle and then heated to reflux for 28 hours. After the reaction system was cooled to room temperature, the reaction mixture was filtered through a silica gel pad and then concentrated under vacuum. The crude product was further purified by a chromatographic column and dried under vacuum to obtain intermediate K1.

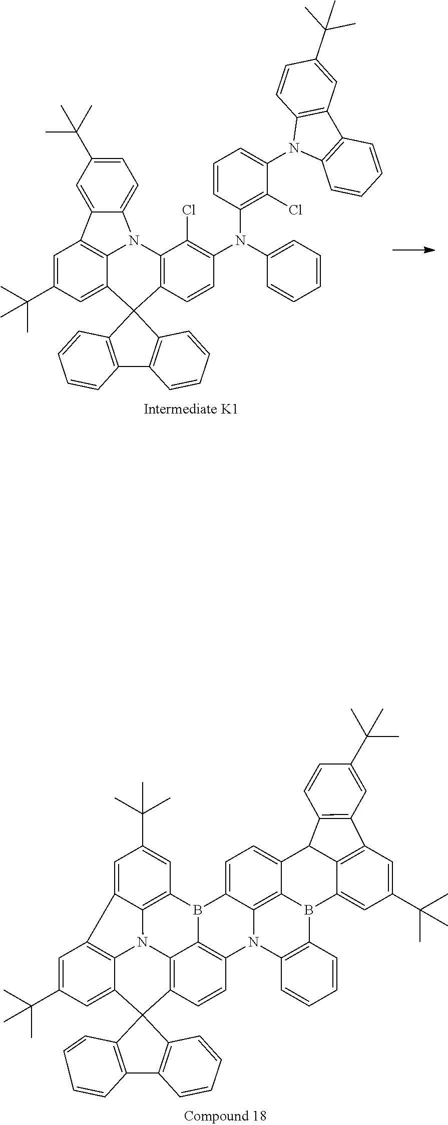 [SMILES: CC(C)(C)c1ccc2c(c1)c1ccccc1n2-c1cccc(N(c2ccccc2)c2ccc3c(c2Cl)-n2c4ccc(C(C)(C)C)cc4c4cc(C(C)(C)C)cc(c42)C32c3ccccc3-c3ccccc32)c1Cl ; CC(C)(C)c1ccc2c(c1)-c1cc(C(C)(C)C)cc3c1C2c1ccc2c4c1B3c1ccccc1N4c1ccc3c4c1B2c1cc(C(C)(C)C)cc2c5cc(C(C)(C)C)cc(c5n-4c12)C31c2ccccc2-c2ccccc21]

The intermediate K1 (2 mmol, 2.06 g) and 60 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 6 hours, then boron tribromide (5 mmol, 0.5 mL) was added at −40° C., and the mixture was slowly raised to room temperature and continued to react for 6 hours, then N,N-diisopropylethylamine (5 mmol, 0.9 mL) was added to the system at 0° C., then the system was heated to 120° C. and continued to react for 12 hours. After the reaction was completed, the reaction system was cooled to room temperature, the reaction was quenched with methanol, the organic layer was concentrated under reduced pressure, and then purified by silica gel column chromatography and dried under vacuum to obtain compound 18.

### Example 2 Synthesis of Compound 64

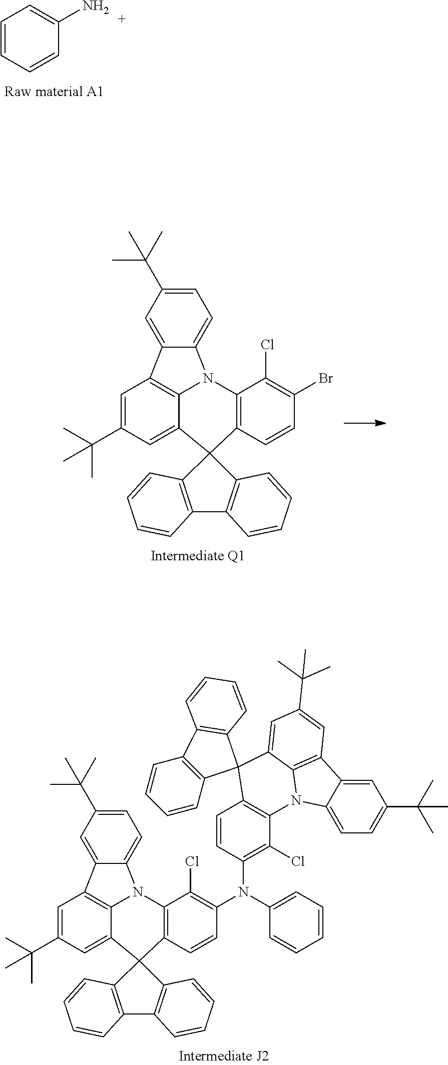 [SMILES: Nc1ccccc1 ; CC(C)(C)c1ccc2c(c1)c1cc(C(C)(C)C)cc3c1n2-c1c(ccc(Br)c1Cl)C31c2ccccc2-c2ccccc21 ; CC(C)(C)c1ccc2c(c1)c1cc(C(C)(C)C)cc3c1n2-c1c(ccc(N(c2ccccc2)c2ccc4c(c2Cl)-n2c5ccc(C(C)(C)C)cc5c5cc(C(C)(C)C)cc(c52)C42c4ccccc4-c4ccccc42)c1Cl)C31c2ccccc2-c2ccccc21]

Intermediate Q1 (11 mmol, 6.94 g), raw material A1 (5 mmol, 0.47 g), Pd₂(dba)₃ (0.5 mmol, 0.46 g), tri-tert-butylphosphine tetrafluoroborate (1 mmol, 0.29 g), sodium tert-butoxide (30 mmol, 2.88 g), and toluene (140 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered through a silica gel pad and then concentrated under vacuum. The crude product was further purified by a chromatography column and dried under vacuum to obtain intermediate J2.

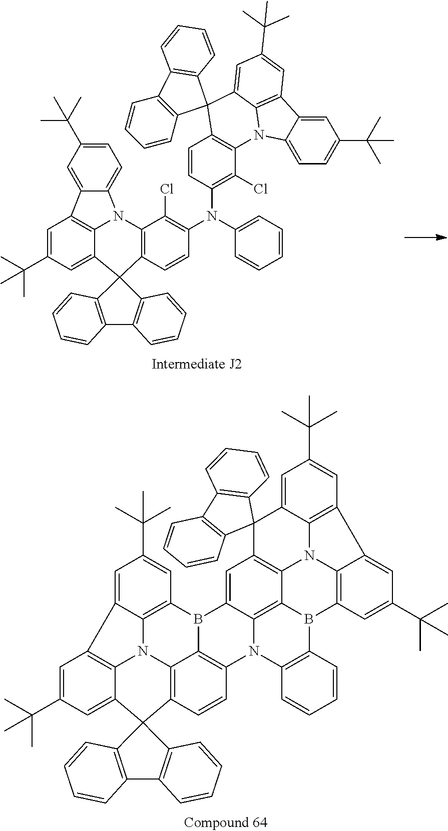

Intermediate J2 (2 mmol, 2.39 g) and 60 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 5 hours, then boron tribromide (5 mmol, 0.5 mL) was added at −40° C., and the mixture was slowly raised to room temperature and continued to react for 6 hours, then N,N-diisopropylethylamine (5 mmol, 0.9 mL) was added to the system at 0° C., the system was heated to 120° C. and continued to react for 12 hours. After the reaction was completed, the reaction system was cooled to room temperature, the reaction was quenched with methanol, the organic layer was concentrated under reduced pressure, and then purified by silica gel column chromatography and dried under vacuum to obtain compound 64.

### Example 3 Synthesis of Compound 71

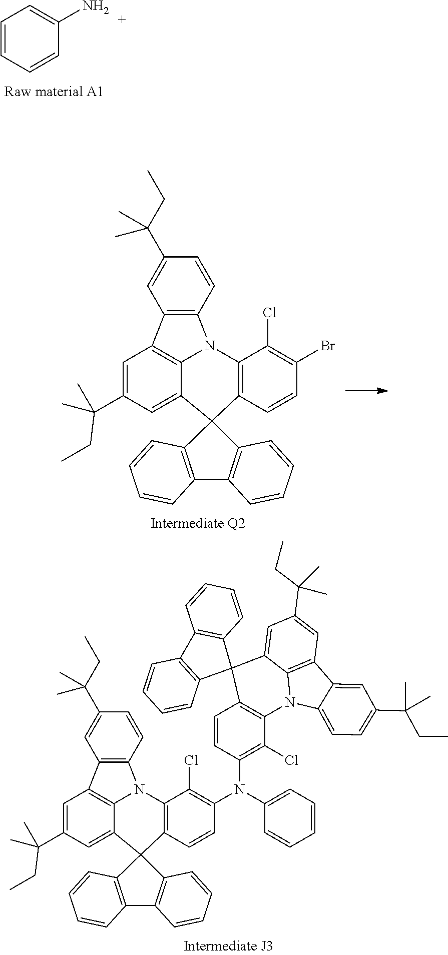 [SMILES: Nc1ccccc1 ; CCC(C)(C)c1ccc2c(c1)c1cc(C(C)(C)CC)cc3c1n2-c1c(ccc(Br)c1Cl)C31c2ccccc2-c2ccccc21 ; CCC(C)(C)c1ccc2c(c1)c1cc(C(C)(C)CC)cc3c1n2-c1c(ccc(N(c2ccccc2)c2ccc4c(c2Cl)-n2c5ccc(C(C)(C)CC)cc5c5cc(C(C)(C)CC)cc(c52)C42c4ccccc4-c4ccccc42)c1Cl)C31c2ccccc2-c2ccccc21]

Intermediate Q2 (11 mmol, 7.25 g), raw material A1 (5 mmol, 0.47 g), Pd₂(dba)₃ (0.5 mmol, 0.46 g), tri-tert-butylphosphine tetrafluoroborate (1 mmol, 0.29 g), sodium tert-butoxide (30 mmol, 2.88 g), and toluene (150 mL) were added into a three-necked flask in sequence. The mixture was degassed by a “vacuumization-nitrogen introduction” cycle, and then heated to reflux for 28 hours. After the reaction system was cooled to room temperature, the reaction mixture was filtered through a silica gel pad and then concentrated under vacuum. The crude product was further purified by a chromatography column and dried under vacuum to obtain intermediate J3.

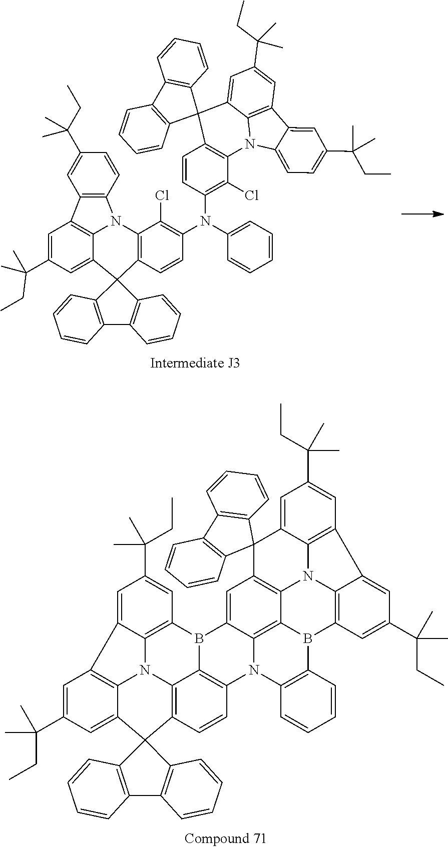

Intermediate J3 (2 mmol, 2.5 g) and 60 mL of tert-butylbenzene were added into a three-necked flask under nitrogen protection. A solution of 1.6 M tert-butyl lithium in pentane solution (5 mmol, 3.1 mL) was slowly added at −40° C., the system was heated to 60° C. and reacted for 5 hours, then boron tribromide (5 mmol, 0.5 mL) was added at −40° C., and the mixture was slowly raised to room temperature and continued to react for 6 hours, then N,N-diisopropylethylamine (5 mmol, 0.9 mL) was added to the system at 0° C., heated to 120° C. and continued to react for 12 hours. After the reaction was completed, the reaction system was cooled to room temperature, the reaction was quenched with methanol, the organic layer was concentrated under reduced pressure, and then purified by silica gel column chromatography and dried under vacuum to obtain compound 71.

### Example 4 Synthesis of Compound 100

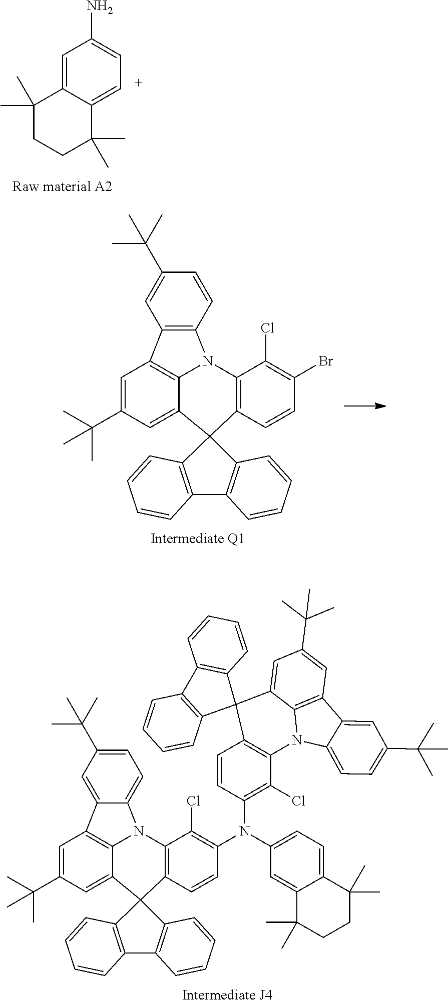

Intermediate Q1 (11 mmol, 6.94 g), raw material A2 (5 mmol, 1.02 g), Pd₂(dba)₃ (0.5 mmol, 0.46 g), tri-tert-butylphosphine tetrafluoroborate (1 mmol, 0.29 g), sodium tert-butoxide (30 mmol, 2.88 g), and toluene (150 mL) were added into a three-necked flask in sequence. The mixture was degassed by a “vacuumization-nitrogen introduction” cycle, and then heated to reflux for 26 hours. After the reaction system was cooled to room temperature, the reaction mixture was filtered through a silica gel pad and then concentrated under vacuum. The crude product was further purified by a chromatography column and dried under vacuum to obtain intermediate J4.

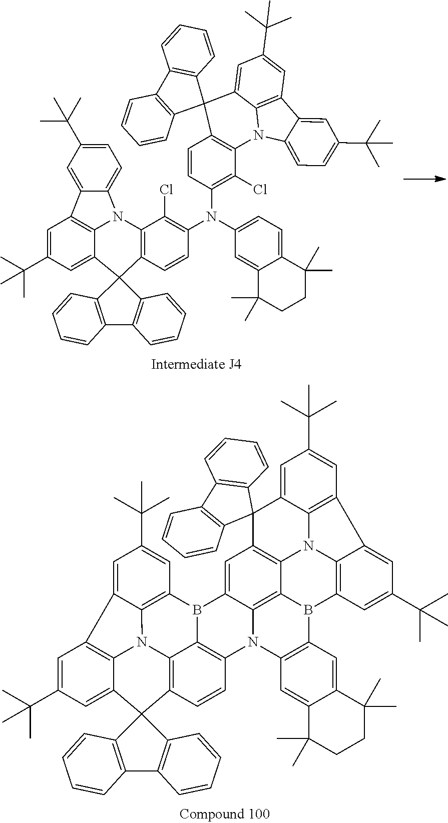

Intermediate J4 (2 mmol, 2.61 g) and 60 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 8 hours, then boron tribromide (5 mmol, 0.5 mL) was added at −40° C., and the mixture was slowly raised to room temperature and continued to react for 10 hours, then N,N-diisopropylethylamine (5 mmol, 0.9 mL) was added to the system at 0° C., heated to 120° C. and continued to react for 14 hours. After the reaction was completed, the reaction system was cooled to room temperature, the reaction was quenched with methanol, the organic layer was concentrated under reduced pressure, and then purified by silica gel column chromatography and dried under vacuum to obtain compound 100.

### Example 5 Synthesis of Compound 102

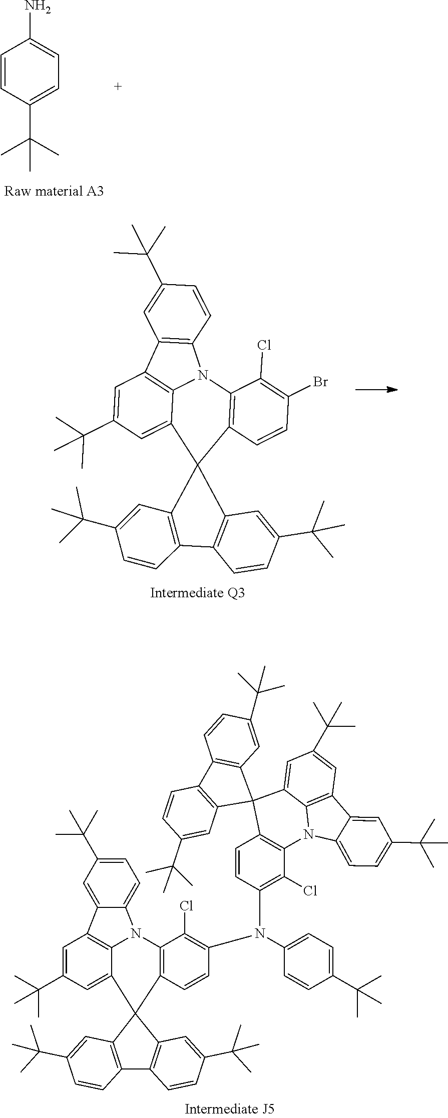

Intermediate Q3 (11 mmol, 8.18 g), raw material A3 (5 mmol, 0.75 g), Pd₂(dba)₃ (0.5 mmol, 0.46 g), tri-tert-butylphosphine tetrafluoroborate (1 mmol, 0.29 g), sodium tert-butoxide (30 mmol, 2.88 g), and toluene (160 mL) were added into a three-necked flask in sequence. The mixture was degassed by a “vacuumization-nitrogen introduction” cycle, and then heated to reflux for 25 hours. After the reaction system was cooled to room temperature, the reaction mixture was filtered through a silica gel pad and then concentrated under vacuum. The crude product was further purified by a chromatography column and dried under vacuum to obtain intermediate J5.

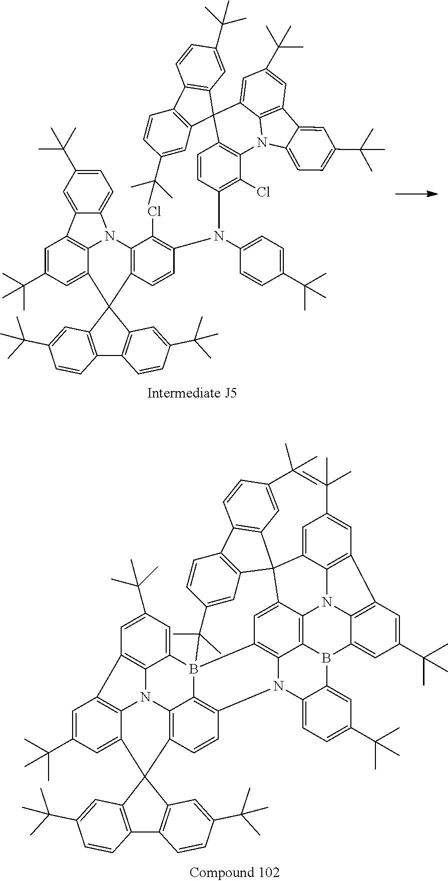

Intermediate J5 (2 mmol, 2.95 g) and 60 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 10 hours, then boron tribromide (5 mmol, 0.5 mL) was added at −40° C., and the mixture was slowly raised to room temperature and continued to react for 10 hours, then N,N-diisopropylethylamine (5 mmol, 0.9 mL) was added to the system at 0° C., the system was heated to 120° C. and continued to react for 15 hours. After the reaction was completed, the reaction system was cooled to room temperature, the reaction was quenched with methanol, the organic layer was concentrated under reduced pressure, and then purified by silica gel column chromatography and dried under vacuum to obtain compound 102.

### Example 6 Synthesis of Compound 166

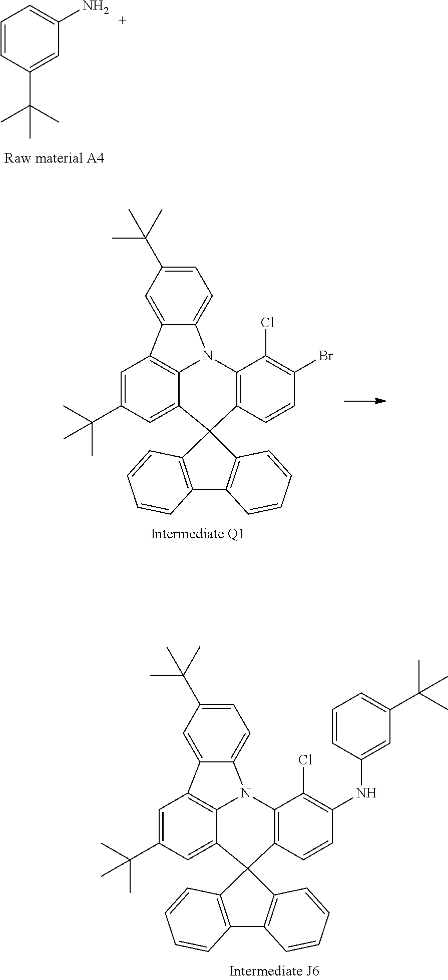 [SMILES: CC(C)(C)c1cccc(N)c1 ; CC(C)(C)c1ccc2c(c1)c1cc(C(C)(C)C)cc3c1n2-c1c(ccc(Br)c1Cl)C31c2ccccc2-c2ccccc21 ; CC(C)(C)c1cccc(Nc2ccc3c(c2Cl)-n2c4ccc(C(C)(C)C)cc4c4cc(C(C)(C)C)cc(c42)C32c3ccccc3-c3ccccc32)c1]

Intermediate Q1 (5.5 mmol, 3.47 g), raw material A4 (5 mmol, 0.75 g), Pd₂(dba)₃ (0.5 mmol, 0.46 g), tri-tert-butylphosphine tetrafluoroborate (1 mmol, 0.29 g), sodium tert-butoxide (15 mmol, 1.44 g), and toluene (80 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered through a silica gel pad and then concentrated under vacuum. The crude product was further purified by a chromatography column and dried under vacuum to obtain intermediate J6.

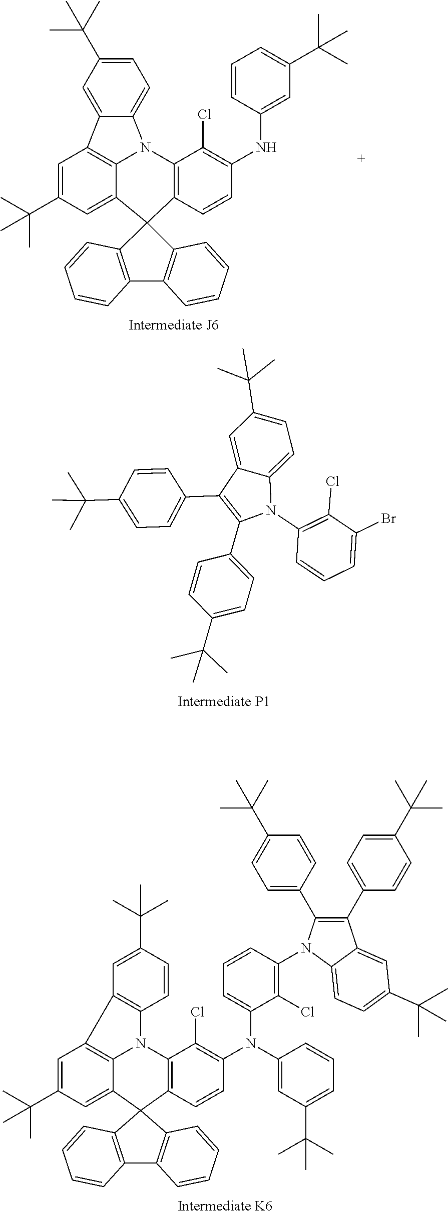

Intermediate P1 (5.5 mmol, 3.45 g), intermediate J6 (5 mmol, 3.5 g), Pd₂(dba)₃ (0.5 mmol, 0.46 g), tri-tert-butylphosphine tetrafluoroborate (1 mmol, 0.29 g), sodium tert-butoxide (15 mmol, 1.44 g), and toluene (150 mL) were added into a three-necked flask in sequence. The mixture was degassed by a “vacuumization-nitrogen introduction” cycle, and then heated to reflux for 26 hours. After the reaction system was cooled to room temperature, the reaction mixture was filtered through a silica gel pad and then concentrated under vacuum. The crude product was further purified by a chromatography column and dried under vacuum to obtain intermediate K6.

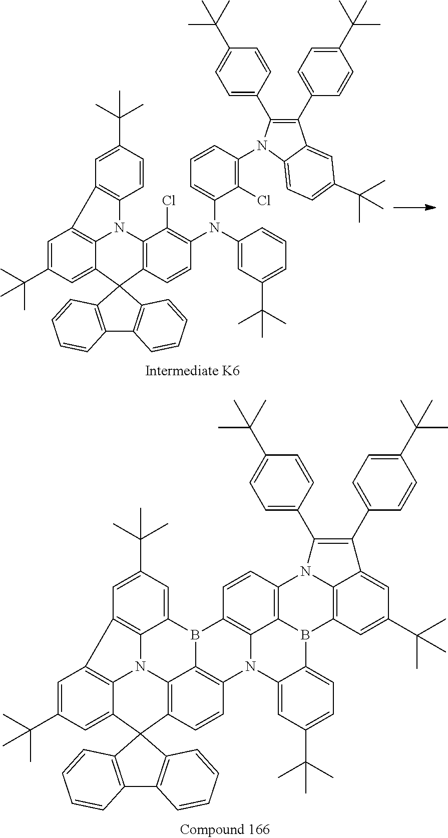

Intermediate K6 (2 mmol, 2.49 g) and 60 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 6 hours, then boron tribromide (5 mmol, 0.5 mL) was added at −40° C., and the mixture was slowly raised to room temperature and continued to react for 6 hours, then N,N-diisopropylethylamine (5 mmol, 0.9 mL) was added to the system at 0° C., and the system was heated to 120° C. and continued to react for 14 hours. After the reaction was completed, the reaction system was cooled to room temperature, the reaction was quenched with methanol, the organic layer was concentrated under reduced pressure, and then purified by silica gel column chromatography and dried under vacuum to obtain compound 166.

### Example 7 Synthesis of Compound 230

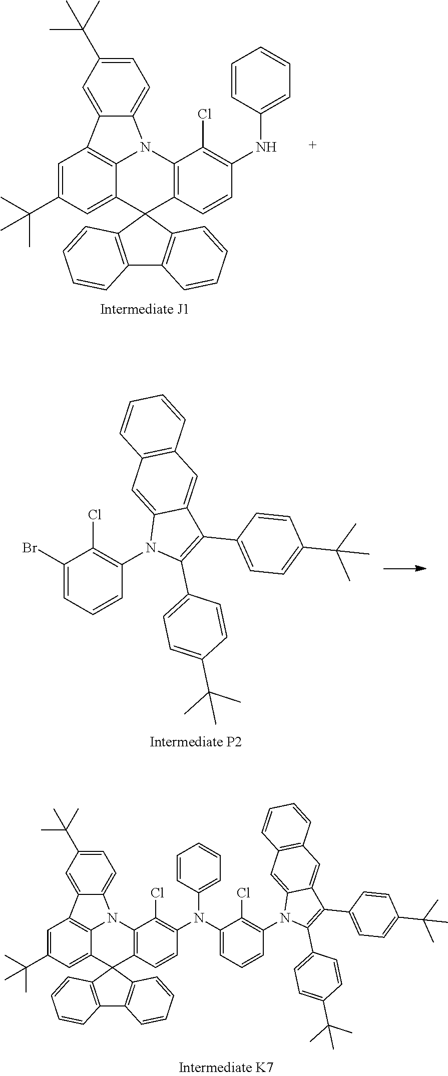

Intermediate P2 (5.5 mmol, 3.42 g), intermediate J1 (5 mmol, 3.22 g), Pd₂(dba)₃ (0.5 mmol, 0.46 g), tri-tert-butylphosphine tetrafluoroborate (1 mmol, 0.29 g), sodium tert-butoxide (15 mmol, 1.44 g), and toluene (150 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered with a silica gel pad, and then concentrated under vacuum. The crude product was further purified by a chromatography column and dried under vacuum to obtain intermediate K7.

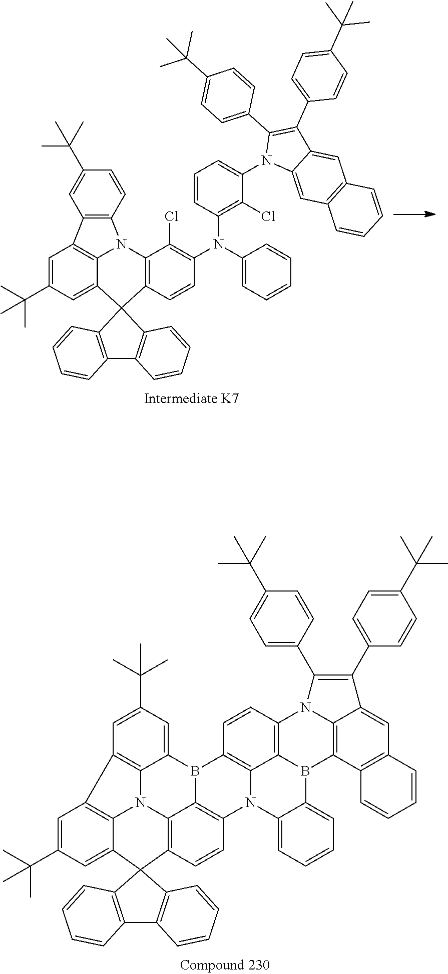 [SMILES: CC(C)(C)c1ccc(-c2c(-c3ccc(C(C)(C)C)cc3)n(-c3cccc(N(c4ccccc4)c4ccc5c(c4Cl)-n4c6ccc(C(C)(C)C)cc6c6cc(C(C)(C)C)cc(c64)C54c5ccccc5-c5ccccc54)c3Cl)c3cc4ccccc4cc23)cc1 ; CC(C)(C)c1ccc(-c2c(-c3ccc(C(C)(C)C)cc3)n3c4c(c5ccccc5cc24)B2c4ccccc4N4c5ccc6c7c5B(c5ccc-3c2c54)c2cc(C(C)(C)C)cc3c4cc(C(C)(C)C)cc(c4n-7c23)C62c3ccccc3-c3ccccc32)cc1]

Intermediate K7 (2 mmol, 2.37 g) and 60 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 6 hours, then boron tribromide (5 mmol, 0.5 mL) was added at −40° C., and the mixture was slowly raised to room temperature and continued to react for 8 hours, then N,N-diisopropylethylamine (5 mmol, 0.9 mL) was added to the system at 0° C., and the system was heated to 120° C. and continued to react for 12 hours. After the reaction was completed, the reaction system was cooled to room temperature, the reaction was quenched with methanol, the organic layer was concentrated under reduced pressure, and then purified by silica gel column chromatography and dried under vacuum to obtain compound 230.

### Example 8 Synthesis of Compound 299

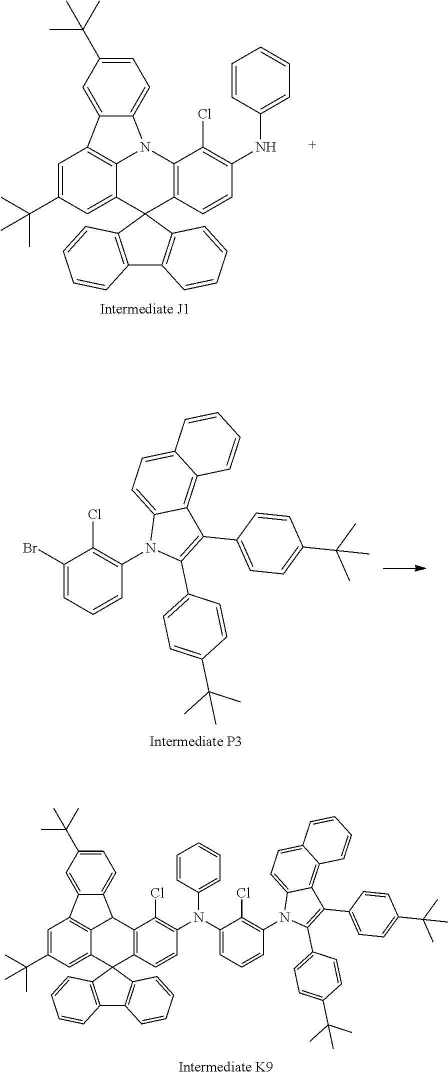

Intermediate P3 (5.5 mmol, 3.42 g), intermediate J1 (5 mmol, 3.22 g), Pd₂(dba)₃ (0.5 mmol, 0.46 g), tri-tert-butylphosphine tetrafluoroborate (1 mmol, 0.29 g), sodium tert-butoxide (15 mmol, 1.44 g), and toluene (150 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered with a silica gel pad, and then concentrated under vacuum. The crude product was further purified by a chromatography column and dried under vacuum to obtain intermediate K9.

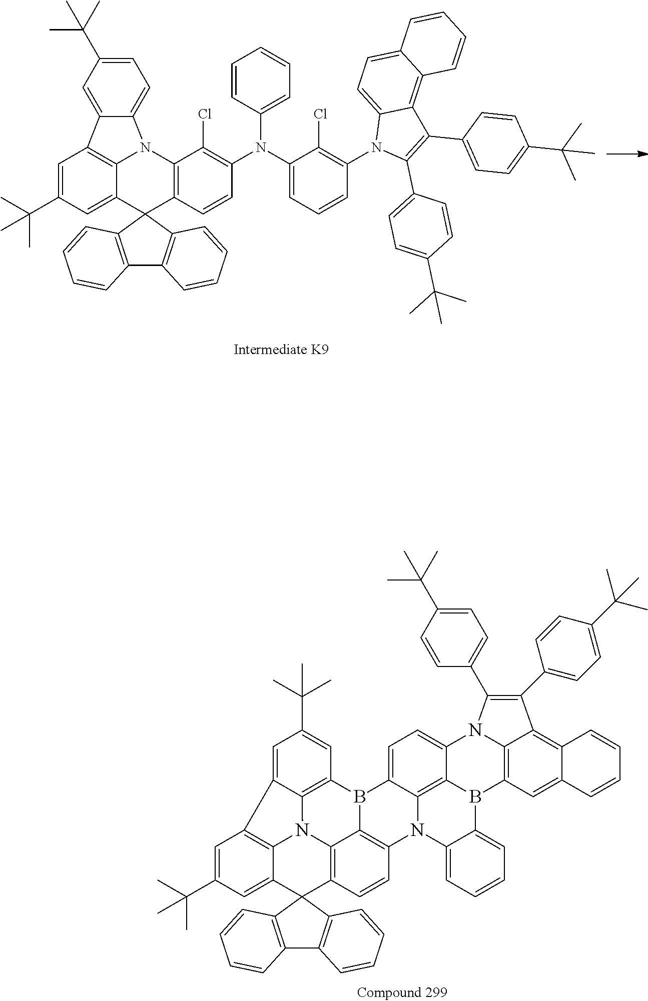

Intermediate K9 (7 mmol, 8.28 g) and 120 mL of tert-butylbenzene were added into a three-necked flask under nitrogen protection. A solution of 1.3 M tert-butyl lithium in pentane (28 mmol, 21.5 mL) was slowly added at −78° C. After the mixture was stirred and reacted at 0° C. for 12 hours, the system was heated to 60° C. to remove pentane, then boron tribromide (21 mmol, 2 mL) was added at 0° C., and the mixture was slowly heated to room temperature and continued to react for 6 hours, then 1,2,2,6,6-pentamethylpiperidine (42 mmol, 6.52 g) was added at 0° C., the reaction system was heated to room temperature and then heated to 160° C. and continued to react for 24 hours. After the reaction was completed, the reaction system was cooled to room temperature, the resulting solution was extracted with dichloromethane/water, the organic layer was concentrated under reduced pressure, and then purified by silica gel column chromatography and dried under vacuum to obtain compound 299.

### Example 9 Synthesis of Compound 87

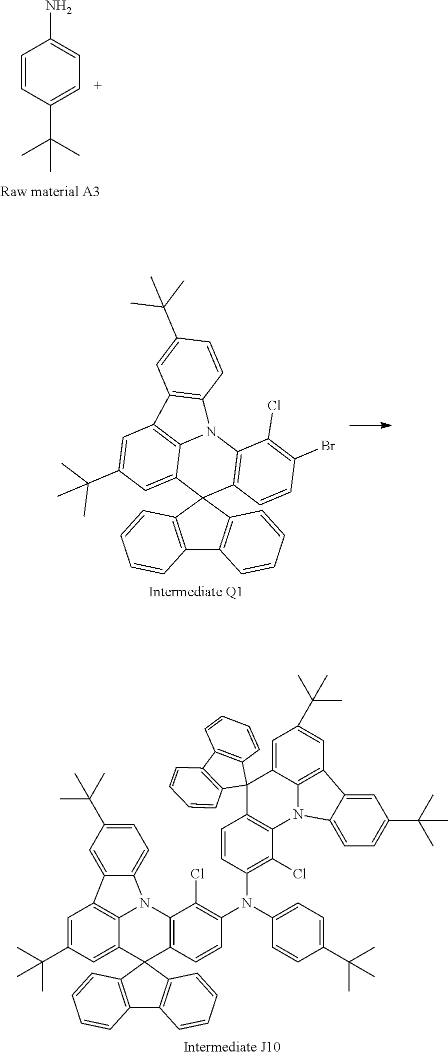 [SMILES: CC(C)(C)c1ccc(N)cc1 ; CC(C)(C)c1ccc2c(c1)c1cc(C(C)(C)C)cc3c1n2-c1c(ccc(Br)c1Cl)C31c2ccccc2-c2ccccc21 ; CC(C)(C)c1ccc(N(c2ccc3c(c2Cl)-n2c4ccc(C(C)(C)C)cc4c4cc(C(C)(C)C)cc(c42)C32c3ccccc3-c3ccccc32)c2ccc3c(c2Cl)-n2c4ccc(C(C)(C)C)cc4c4cc(C(C)(C)C)cc(c42)C32c3ccccc3-c3ccccc32)cc1]

Intermediate Q1 (11 mmol, 6.94 g), raw material A3 (5 mmol, 0.75 g), Pd₂(dba)₃ (0.5 mmol, 0.46 g), tri-tert-butylphosphine tetrafluoroborate (1 mmol, 0.29 g), sodium tert-butoxide (30 mmol, 2.88 g), and toluene (160 mL) were added into a three-necked flask in sequence. The mixture was degassed by a “vacuumization-nitrogen introduction” cycle, and then heated to reflux for 25 hours. After the reaction system was cooled to room temperature, the reaction mixture was filtered through a silica gel pad and then concentrated under vacuum. The crude product was further purified by a chromatography column and dried under vacuum to obtain intermediate J10.

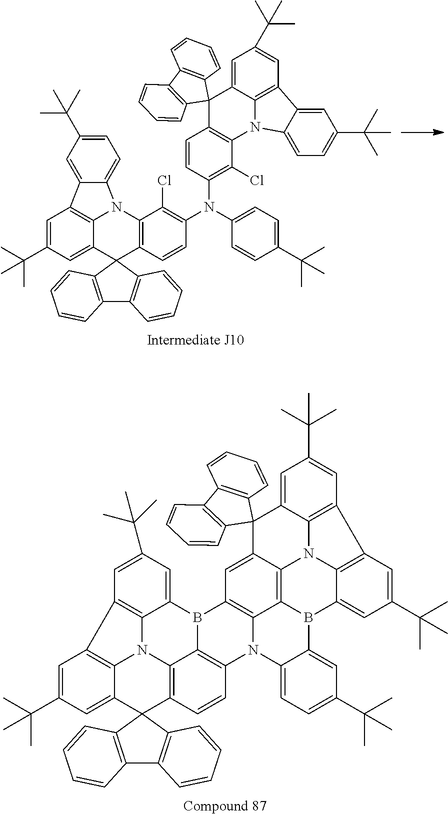

Intermediate J10 (2 mmol, 2.50 g) and 60 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 6 hours, then boron tribromide (5 mmol, 0.5 mL) was added at −40° C., and the mixture was slowly raised to room temperature and continued to react for 8 hours, then N,N-diisopropylethylamine (5 mmol, 0.9 mL) was added to the system at 0° C., and the system was heated to 120° C. and continued to react for 12 hours. After the reaction was completed, the reaction system was cooled to room temperature, the reaction was quenched with methanol, the organic layer was concentrated under reduced pressure, and then purified by silica gel column chromatography and dried under vacuum to obtain compound 87.

### Example 10 Synthesis of Compound 101

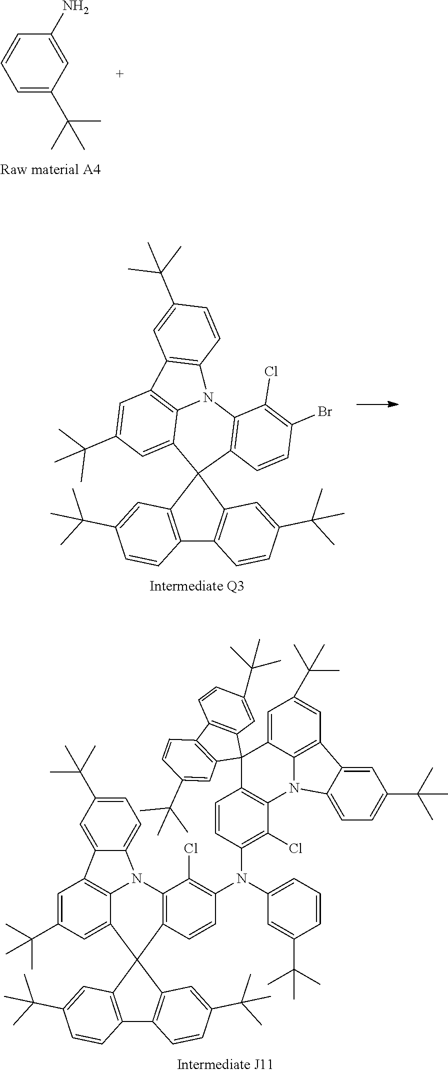

Intermediate Q3 (11 mmol, 8.18 g), raw material A4 (5 mmol, 0.75 g), Pd₂(dba)₃ (0.5 mmol, 0.46 g), tri-tert-butylphosphine tetrafluoroborate (1 mmol, 0.29 g), sodium tert-butoxide (30 mmol, 2.88 g), and toluene (160 mL) were added into a three-necked flask in sequence. The mixture was degassed by a “vacuumization-nitrogen introduction” cycle, and then heated to reflux for 25 hours. After the reaction system was cooled to room temperature, the reaction mixture was filtered with a silica gel pad, and then concentrated under vacuum. The crude product was further purified by a chromatography column and dried under vacuum to obtain intermediate J11.

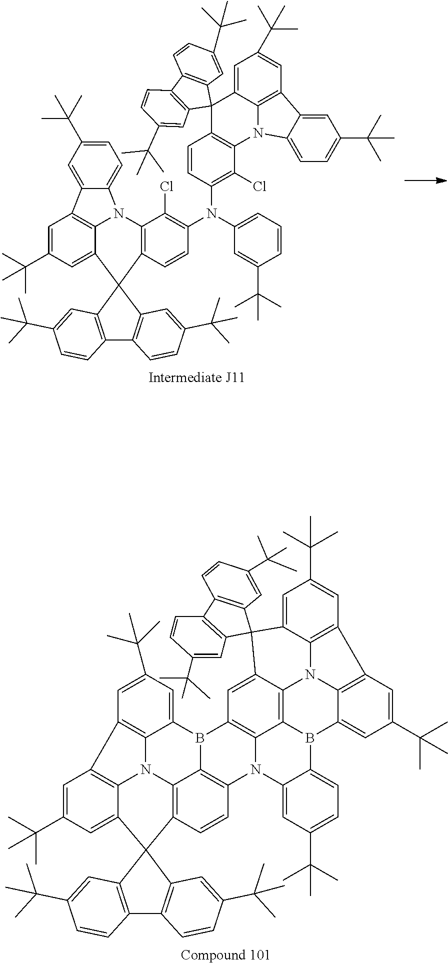

Intermediate J11 (2 mmol, 2.95 g) and 75 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 8 hours, then boron tribromide (5 mmol, 0.5 mL) was added at −40° C., and the mixture was slowly raised to room temperature and continued to react for 8 hours, then N,N-diisopropylethylamine (5 mmol, 0.9 mL) was added to the system at 0° C., and the system was heated to 120° C. and continued to react for 12 hours. After the reaction was completed, the reaction system was cooled to room temperature, the reaction was quenched with methanol, the organic layer was concentrated under reduced pressure, and then purified by silica gel column chromatography and dried under vacuum to obtain compound 101.

### Example 11 Synthesis of Compound 334

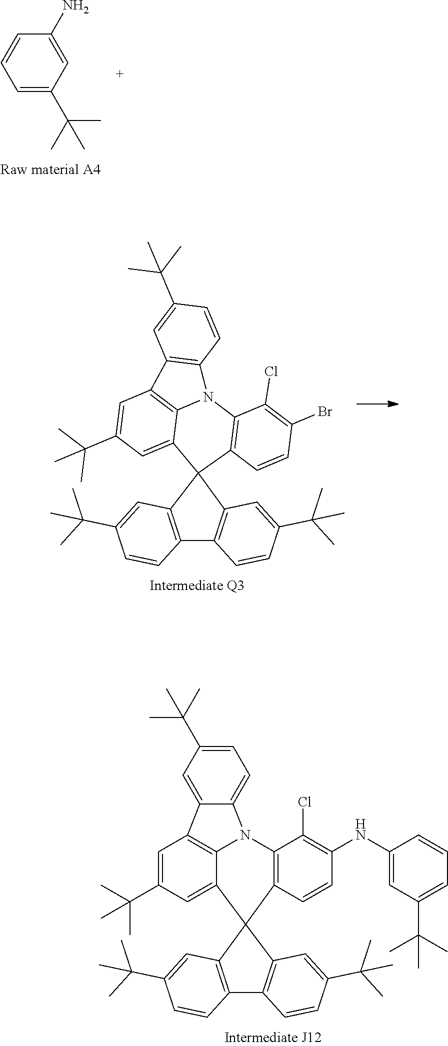

Intermediate Q3 (5.5 mmol, 4.09 g), raw material A4 (5 mmol, 0.75 g), Pd₂(dba)₃ (0.5 mmol, 0.46 g), tri-tert-butylphosphine tetrafluoroborate (1 mmol, 0.29 g), sodium tert-butoxide (15 mmol, 1.44 g) and toluene (120 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered with a silica gel pad, and then concentrated under vacuum. The crude product was further purified by a chromatography column and dried under vacuum to obtain intermediate J12.

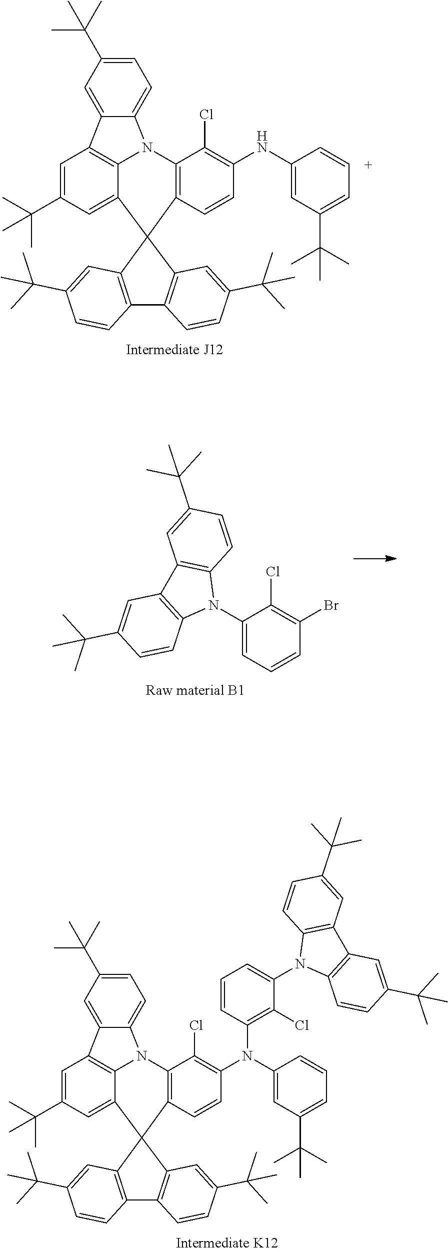

Raw material B1 (5.5 mmol, 2.58 g), intermediate J12 (5 mmol, 4.06 g), Pd₂(dba)₃ (0.5 mmol, 0.46 g), tri-tert-butylphosphine tetrafluoroborate (1 mmol, 0.29 g), sodium tert-butoxide (15 mmol, 1.44 g) and toluene (120 mL) were added into a three-necked flask in sequence. The mixture was degassed by a “vacuumization-nitrogen introduction” cycle, and then heated to reflux for 25 hours. After the reaction system was cooled to room temperature, the reaction mixture was filtered with a silica gel pad, and then concentrated under vacuum. The crude product was further purified by a chromatography column and dried under vacuum to obtain intermediate K12.

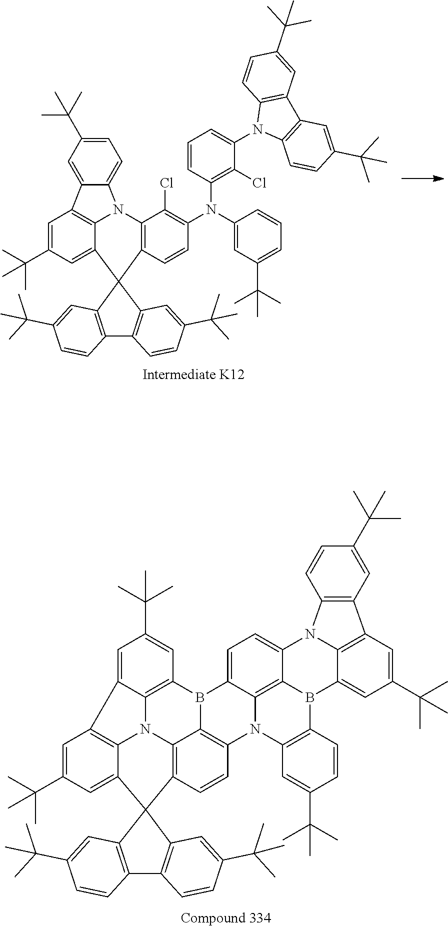

Intermediate K12 (2 mmol, 2.40 g) and 80 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 8 hours, then boron tribromide (5 mmol, 0.5 mL) was added at −40° C., and the mixture was slowly raised to room temperature and continued to react for 5 hours, then N,N-diisopropylethylamine (5 mmol, 0.9 mL) was added to the system at 0° C., and the system was heated to 120° C. and continued to react for 8 hours. After the reaction was completed, the reaction system was cooled to room temperature, the reaction was quenched with methanol, the organic layer was concentrated under reduced pressure, and then purified by silica gel column chromatography and dried under vacuum to obtain compound 334.

### Example 12 Synthesis of Compound 348

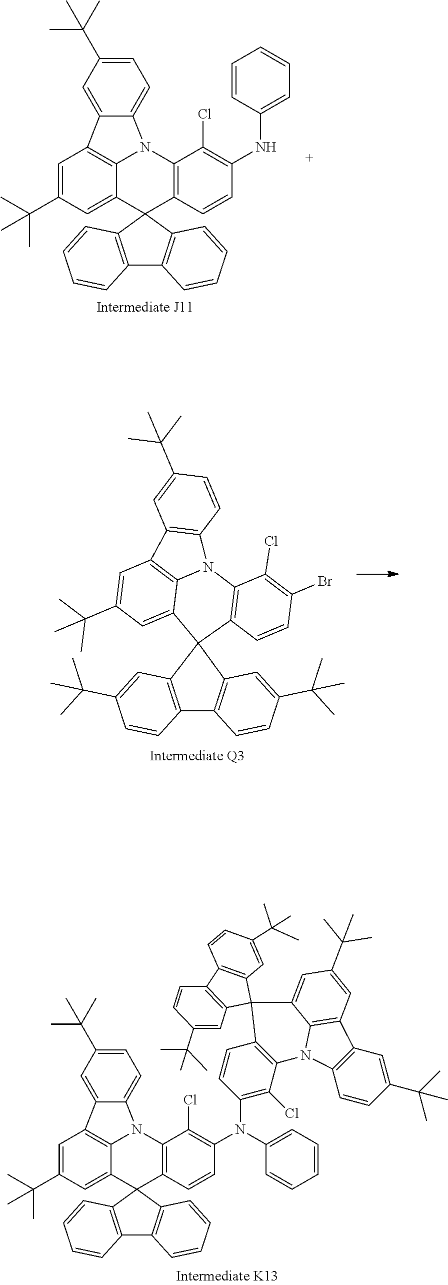

Intermediate Q3 (5.5 mmol, 4.09 g), intermediate J1 (5 mmol, 3.22 g), Pd₂(dba)₃ (0.5 mmol, 0.46 g), tri-tert-butylphosphine tetrafluoroborate (1 mmol, 0.29 g), sodium tert-butoxide (15 mmol, 1.44 g) and toluene (160 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered with a silica gel pad, and then concentrated under vacuum. The crude product was further purified by a chromatography column and dried under vacuum to obtain intermediate K13.

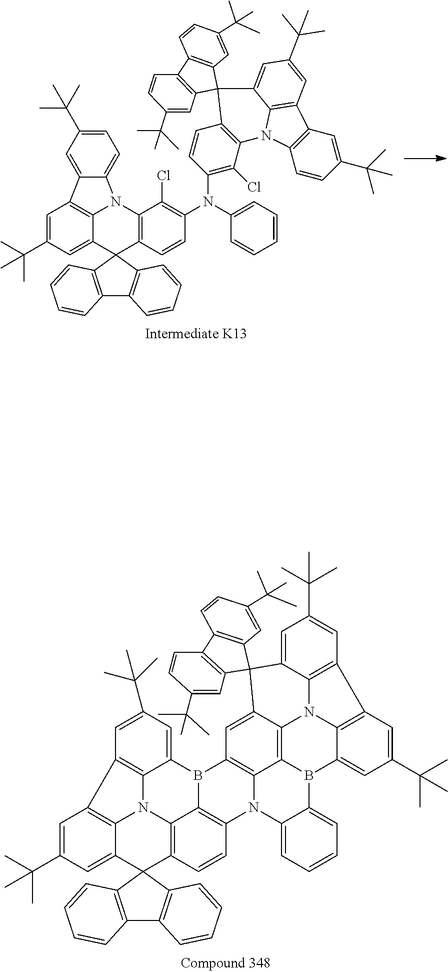

Intermediate K13 (2 mmol, 2.61 g) and 100 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 9 hours, then boron tribromide (5 mmol, 0.5 mL) was added at −40° C., and the mixture was slowly raised to room temperature and continued to react for 6 hours, then N,N-diisopropylethylamine (5 mmol, 0.9 mL) was added to the system at 0° C., and the system was heated to 120° C. and continued to react for 10 hours. After the reaction was completed, the reaction system was cooled to room temperature, the reaction was quenched with methanol, the organic layer was concentrated under reduced pressure, and then purified by silica gel column chromatography and dried under vacuum to obtain compound 348.

### Example 13 Synthesis of Compound 370

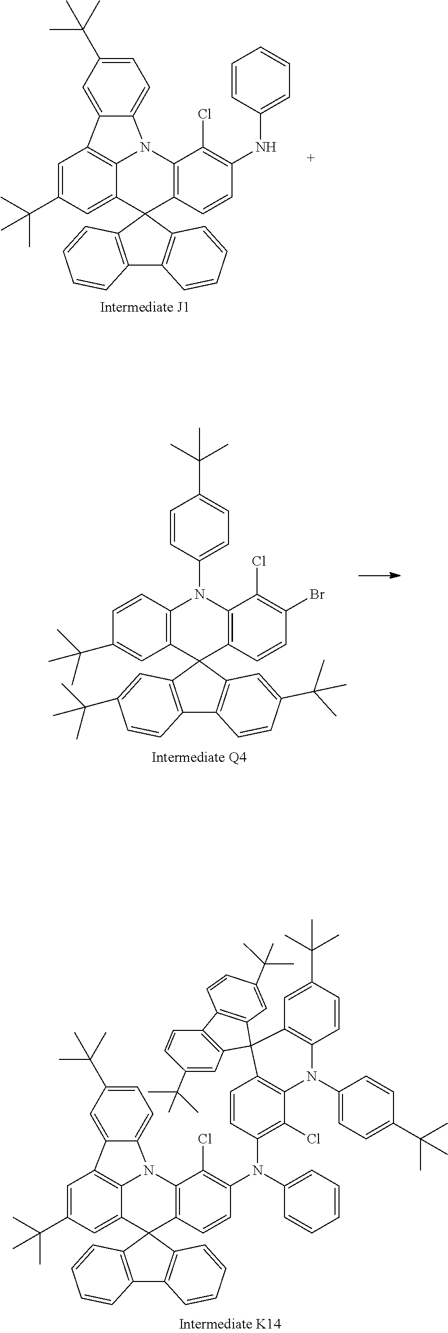

Intermediate Q4 (5.5 mmol, 4.10 g), intermediate J1 (5 mmol, 3.22 g), Pd₂(dba)₃ (0.5 mmol, 0.46 g), tri-tert-butylphosphine tetrafluoroborate (1 mmol, 0.29 g), sodium tert-butoxide (15 mmol, 1.44 g) and toluene (160 mL) were added into a three-necked flask in sequence. The mixture was degassed by a “vacuumization-nitrogen introduction” cycle, and then heated to reflux for 24 hours. After the reaction system was cooled to room temperature, the reaction mixture was filtered with a silica gel pad, and then concentrated under vacuum. The crude product was further purified by a chromatography column and dried under vacuum to obtain intermediate K14.

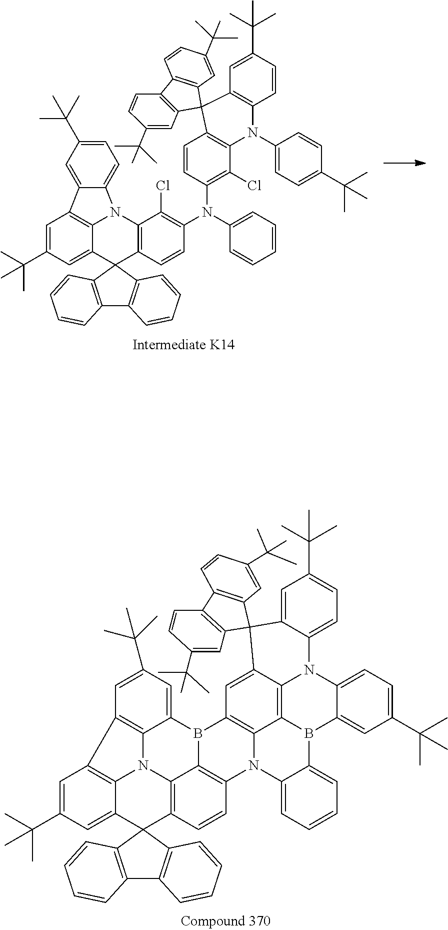

Intermediate K14 (2 mmol, 2.61 g) and 100 mL of tert-butylbenzene were added into a three-necked flask under nitrogen protection. A solution of 1.6 M tert-butyl lithium in pentane (5 mmol, 3.1 mL) was slowly added at −40° C., the system was heated to 60° C. and reacted for 9 hours, then boron tribromide (5 mmol, 0.5 mL) was added at −40° C., and the mixture was slowly raised to room temperature and continued to react for 6 hours, then N,N-diisopropylethylamine (5 mmol, 0.9 mL) was added to the system at 0° C., and the system was heated to 120° C. and continued to react for 10 hours. After the reaction was completed, the reaction system was cooled to room temperature, the reaction was quenched with methanol, the organic layer was concentrated under reduced pressure, and then purified by silica gel column chromatography and dried under vacuum to obtain compound 370.

The structural characterizations of the compounds obtained in examples are shown in Table 1.

TABLE 1

| Compounds | Structural Characterizations |
|---|---|
| 18 | LC-MS: Measured value: 978.63([M + H]⁺), Accurate mass: 977.51. |
| 64 | LC-MS: Measured value: 1140.46([M + H]⁺), Accurate mass: 1139.55. |
| 71 | LC-MS: Measured value: 1196.52([M + H]⁺), Accurate mass: 1195.61. |
| 100 | LC-MS: Measured value: 1250.72([M + H]⁺), Accurate mass: 1249.66. |
| 102 | LC-MS: Measured value: 1420.92([M + H]⁺), Accurate mass: 1419.87. |
| 166 | LC-MS: Measured value: 1192.77([M + H]⁺), Accurate mass: 1191.68. |
| 230 | LC-MS: Measured value: 1130.53([M + H]⁺), Accurate mass: 1129.57. |
| 299 | LC-MS: Measured value: 1130.70([M + H]⁺), Accurate mass: 1129.57. |
| 87 | LC-MS: Measured value: 1196.78([M + H]⁺), Accurate mass: 1195.61. |
| 101 | LC-MS: Measured value: 1420.93([M + H]⁺), Accurate mass: 1419.87. |
| 334 | LC-MS: Measured value: 1146.77([M + H]⁺), Accurate mass: 1145.69. |
| 348 | LC-MS: Measured value: 1252.81([M + H]⁺), Accurate mass: 1251.68. |
| 370 | LC-MS: Measured value: 1254.72([M + H]⁺), Accurate mass: 1253.69. |

The application effect of the OLED materials synthesized in the present disclosure in devices will be described in detail below through Device Examples 1-35 and Device Comparative Examples 1-5. The device manufacturing processes of the Device Examples 2-35 and Device Comparative Examples 1-5 of the present disclosure were exactly the same as that of the Device Example 1, and the same substrate materials and electrode materials were used, and the film thickness of the electrode material was also the same. The difference lied in that the doping materials of the light-emitting layer in the device was replaced. The layer structure and test results of the Device Examples were as shown in Table 2-1 and Table 3, respectively.

### Device Example 1

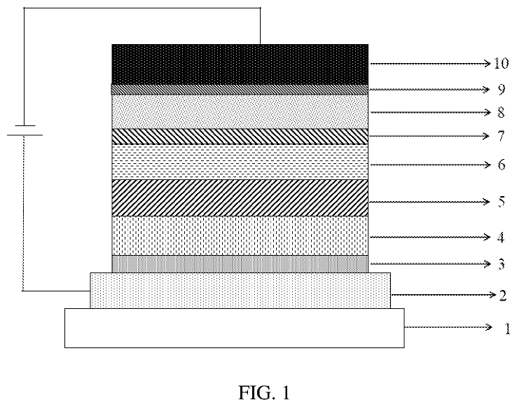

As shown in FIG. 1, the transparent substrate layer 1 was a transparent PI film, and the ITO anode layer 2 (with a film thickness of 150 nm) was washed, that was, sequentially washed with a cleaning agent (SemicleanM-L20), washed with pure water, dried, and then washed with ultraviolet-ozone to remove the organic residues on the surface of the transparent ITO. On the ITO anode layer 2 after the above washing was conducted, a vacuum evaporation device was used to evaporate HT-1 and HI-1 with a film thickness of 10 nm as the hole injection layer 3, and the mass ratio of HT-1 to HI-1 was 97:3. Then, HT-1 with a thickness of 60 nm was evaporated as the hole transport layer 4. Then, EB-1 with a thickness of 30 nm was evaporated as the electron blocking layer 5. After the above evaporation of the electron blocking material was completed, the light-emitting layer 6 of the OLED light-emitting device was prepared by using GH-1 and GH-2 as the host materials, and compound 18 as the doping material, the mass ratio of GH-1, GH-2 and compound 18 was 69:30:1, and the film thickness of the light-emitting layer was 30 nm. After the above-mentioned light-emitting layer 6, HB-1 was continuously vacuum-evaporated to obtain a film with a thickness of 5 nm, which was the hole blocking layer 7. After the above-mentioned hole blocking layer 7, ET-1 and Liq were continuously vacuum-evaporated to obtain a film with a thickness of 30 nm, which was the electron transport layer 8, wherein the mass ratio of ET-1 to Liq was 1:1. On the electron transport layer 8, a LiF layer with a film thickness of 1 nm was made by a vacuum evaporation device, this layer was the electron injection layer 9. On the electron injection layer 9, a Mg:Ag electrode layer with a film thickness of 80 nm was made by a vacuum evaporation device, the mass ratio of Mg to Ag was 1:9, and this layer was used as the cathode layer 10.

The application effect of the OLED materials synthesized in the present disclosure in devices will be described in detail below through Device Examples 36-48 and Device Comparative Examples 6-10. The device manufacturing processes of Device Examples 37-48 and Device Comparative Examples 6-10 of the present disclosure were exactly the same as that of Device Example 36, and the same substrate materials and electrode materials were used, and the film thickness of the electrode materials was also the same. The difference lied in that the doping material of the light-emitting layer in the device was replaced. The layer structure and test results of the Device Examples were as shown in Table 2-2 and Table 3, respectively.

### Device Example 36

The transparent substrate layer 1 was a transparent PI film, and the ITO anode layer 2 (with a film thickness of 150 nm) was washed, that was, sequentially washed with a cleaning agent (SemicleanM-L20), washed with pure water, dried, and then washed with ultraviolet-ozone to remove organic residues on the surface of the transparent ITO. On the ITO anode layer 2 after the above washing was conducted, a vacuum evaporation device was used to evaporate HT-1 and HI-1 with a film thickness of 10 nm as the hole injection layer 3, and the mass ratio of HT-1 to HI-1 was 97:3. Then, HT-1 with a thickness of 60 nm was evaporated as the hole transport layer 4. Then, EB-1 with a thickness of 30 nm was evaporated as the electron blocking layer 5. After the above evaporation of the electron blocking material was completed, the light-emitting layer 6 of the OLED light-emitting device was prepared by using GH-1 and GH-2 as the host materials, and GD-1 was used as the first doping material, compound 18 as the second doping material, the mass ratio of GH-1, GH-2, GD-1 and compound 18 was 66.5:30:3:0.5, and the film thickness of the light-emitting layer was 30 nm. After the above-mentioned light-emitting layer 6, HB-1 was continuously vacuum-evaporated to obtain a film with a thickness of 5 nm, which was the hole blocking layer 7. After the above-mentioned hole blocking layer 7, ET-1 and Liq were continuously vacuum-evaporated to obtain a film with a thickness of 30 nm, which was the electron transport layer 8, wherein the mass ratio of ET-1 to Liq was 1:1. On the electron transport layer 8, a LiF layer with a film thickness of 1 nm was made by a vacuum evaporation device, this layer was the electron injection layer 9. On the electron injection layer 9, a Mg:Ag electrode layer with a film thickness of 80 nm was made by a vacuum evaporation device, the mass ratio of Mg to Ag was 1:9, and this layer was used as the cathode layer 10.

The molecular structure formulas of the relevant materials are shown below:

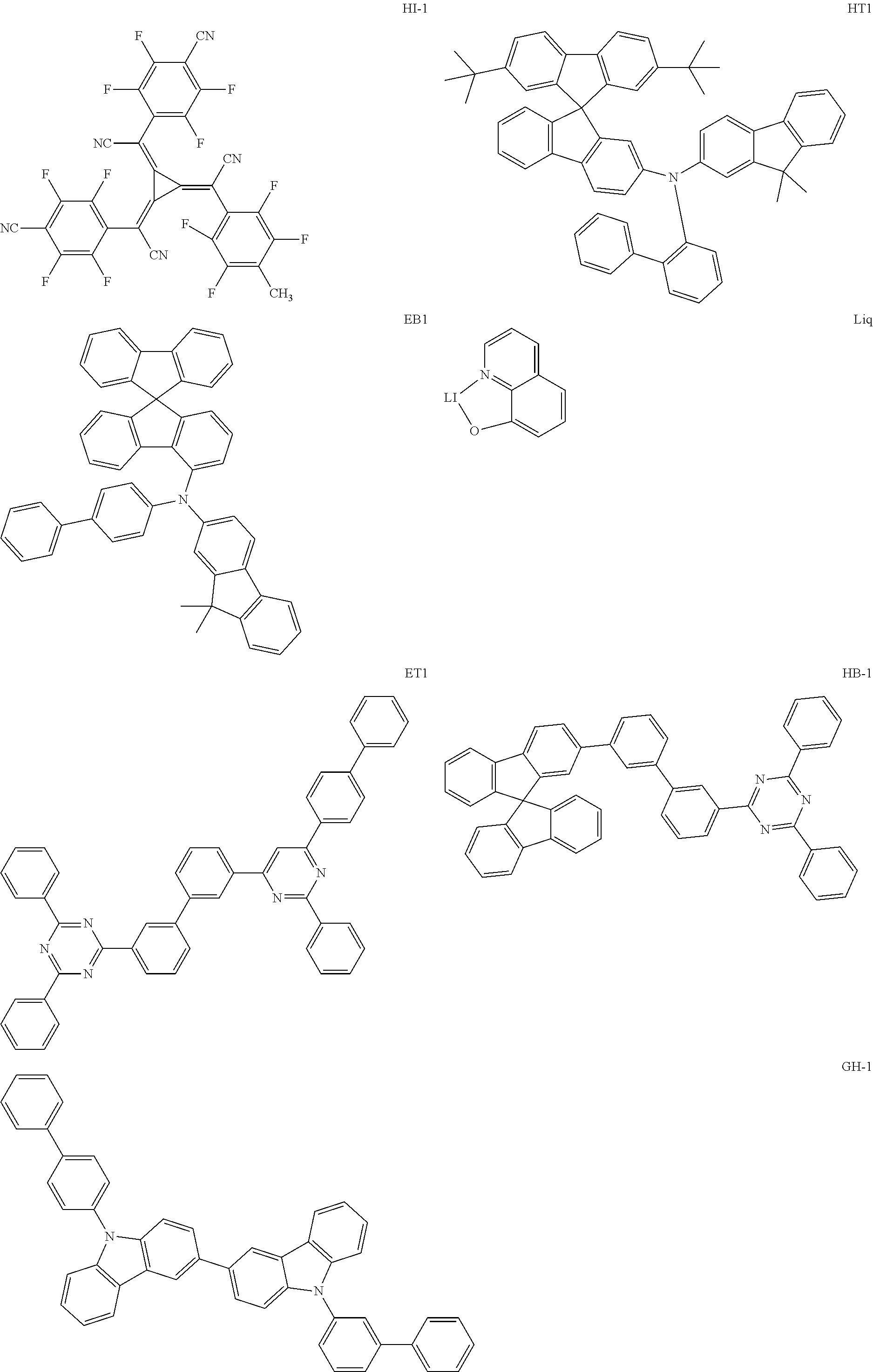

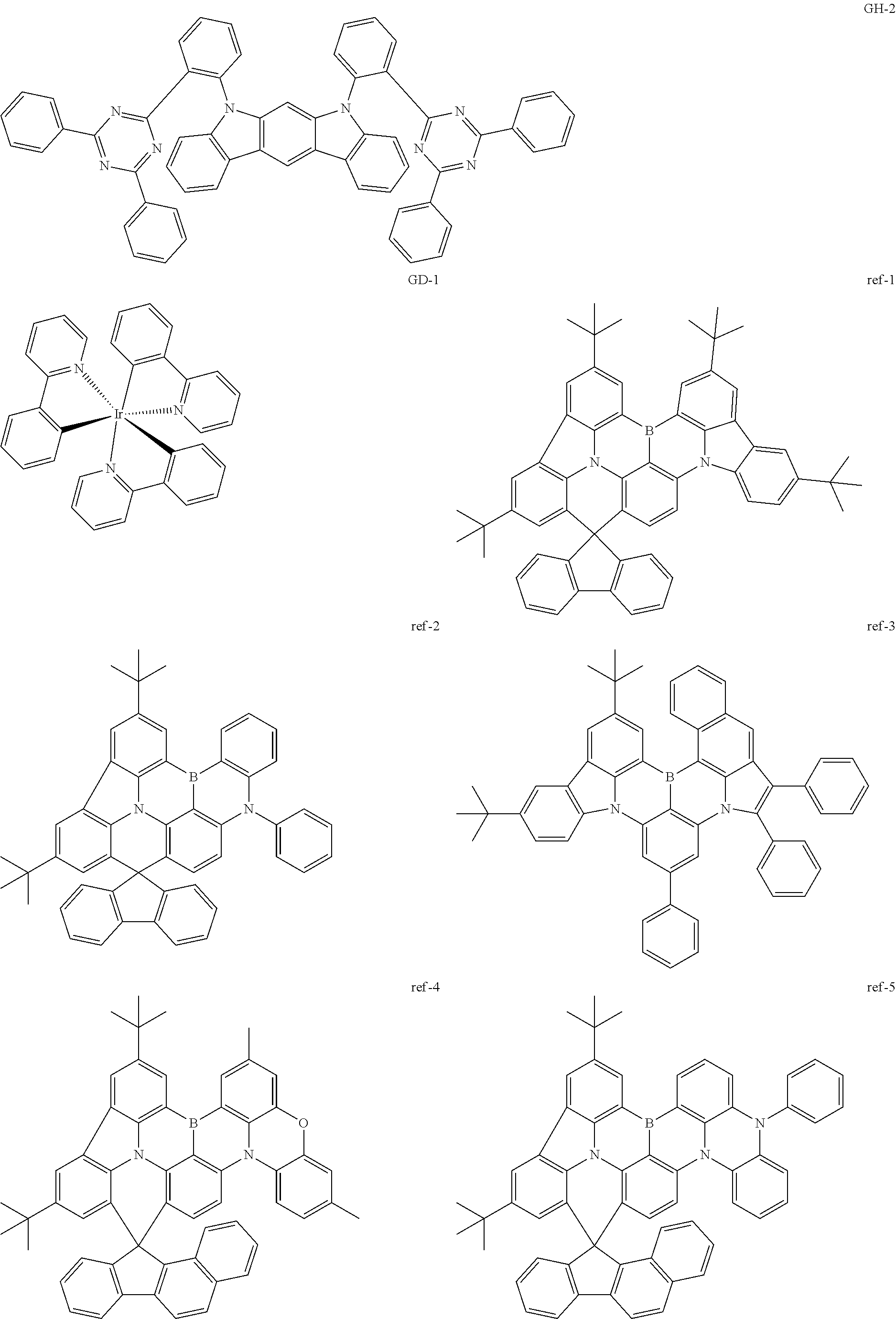

After the OLED light-emitting device was completed as described above, the anode and cathode were connected by a known driving circuit, and the current efficiency and service life of the device were measured. The Device Examples and Comparative Examples prepared by the same method were as shown in Table 2-1 and Table 2-2; the test results of the current efficiency and service life of the obtained devices were as shown in Table 3.

TABLE 2-1

| Device | | | | | | | | |
|---|---|---|---|---|---|---|---|---|
| Example/ | | | | | | | | |
| Device | Hole | Hole | Electron | Light | Hole | Electron | Electron | |
| Comparative | injection | transport | blocking | emitting | blocking | transport | injection | Cathode |
| Example | layer/ | layer/ | layer/ | layer/ | layer/ | layer/ | layer/ | layer/ |
| Numbers | Thickness | Thickness | Thickness | Thickness | Thickness | Thickness | thickness | thickness |
| Device | HT-1:HI-1 = | HT-1 | EB-1 | GH-1:GH- | HB-1 | ET-1:Liq = | LiF | Mg:Ag = |
| Example 1 | 97:3 | (60 nm) | (30 nm) | 2:compound | (5 nm) | 1:1 | (1 nm) | 1:9 |
| | (10 nm) | | | 18 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 2 | 97:3 | (60 nm) | (30 nm) | 2:compound | (5 nm) | 1:1 | (1 nm) | 1:9 |
| | (10 nm) | | | 64 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 3 | 97:3 | (60 nm) | (30 nm) | 2:compound | (5 nm) | 1:1 | (1 nm) | 1:9 |
| | (10 nm) | | | 71 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 4 | 97:3 | (60 nm) | (30 nm) | 2:compound | (5 nm) | 1:1 | (1 nm) | 1:9 |
| | (10 nm) | | | 100 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 5 | 97:3 | (60 nm) | (30 nm) | 2:compound | (5 nm) | 1:1 | (1 nm) | 1:9 |
| | (10 nm) | | | 102 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 6 | 97:3 | (60 nm) | (30 nm) | 2:compound | (5 nm) | 1:1 | (1 nm) | 1:9 |
| | (10 nm) | | | 166 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 7 | 97:3 | (60 nm) | (30 nm) | 2:compound | (5 nm) | 1:1 | (1 nm) | 1:9 |
| | (10 nm) | | | 230 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 8 | 97:3 | (60 nm) | (30 nm) | 2:compound | (5 nm) | 1:1 | (1 nm) | 1:9 |
| | (10 nm) | | | 299 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 9 | 97:3 | (60 nm) | (30 nm) | 2:compound | (5 nm) | 1:1 | (1 nm) | 1:9 |
| | (10 nm) | | | 87 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 10 | 97:3 | (60 nm) | (30 nm) | 2:compound | (5 nm) | 1:1 | (1 nm) | 1:9 |
| | (10 nm) | | | 101 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 11 | 97:3 | (60 nm) | (30 nm) | 2:compound | (5 nm) | 1:1 | (1 nm) | 1:9 |
| | (10 nm) | | | 334 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 12 | 97:3 | (60 nm) | (30 nm) | 2:compound | (5 nm) | 1:1 | (1 nm) | 1:9 |
| | (10 nm) | | | 348 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 13 | 97:3 | (60 nm) | (30 nm) | 2:compound | (5 nm) | 1:1 | (1 nm) | 1:9 |
| | (10 nm) | | | 370 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 14 | 97:3 | (60 nm) | (30 nm) | 2:compound | (5 nm) | 1:1 | (1 nm) | 1:9 |
| | (10 nm) | | | 8 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 15 | 97:3 | (60 nm) | (30 nm) | 2:compound | (5 nm) | 1:1 | (1 nm) | 1:9 |
| | (10 nm) | | | 104 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 16 | 97:3 | (60 nm) | (30 nm) | 2:compound | (5 nm) | 1:1 | (1 nm) | 1:9 |
| | (10 nm) | | | 276 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 17 | 97:3 | (60 nm) | (30 nm) | 2:compound | (5 nm) | 1:1 | (1 nm) | 1:9 |
| | (10 nm) | | | 320 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 18 | 97:3 | (60 nm) | (30 nm) | 2:compound | (5 nm) | 1:1 | (1 nm) | 1:9 |
| | (10 nm) | | | 390 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 19 | 97:3 | (60 nm) | (30 nm) | 2:compound | (5 nm) | 1:1 | (1 nm) | 1:9 |
| | (10 nm) | | | 394 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 20 | 97:3 | (60 nm) | (30 nm) | 2:compound | (5 nm) | 1:1 | (1 nm) | 1:9 |
| | (10 nm) | | | 401 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 21 | 97:3 | (60 nm) | (30 nm) | 2:compound | (5 nm) | 1:1 | (1 nm) | 1:9 |
| | (10 nm) | | | 402 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 22 | 97:3 | (60 nm) | (30 nm) | 2:compound | (5 nm) | 1:1 | (1 nm) | 1:9 |
| | (10 nm) | | | 405 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 23 | 97:3 | (60 nm) | (30 nm) | 2:compound | (5 nm) | 1:1 | (1 nm) | 1:9 |
| | (10 nm) | | | 408 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 24 | 97:3 | (60 nm) | (30 nm) | 2:compound | (5 nm) | 1:1 | (1 nm) | 1:9 |
| | (10 nm) | | | 424 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 25 | 97:3 | (60 nm) | (30 nm) | 2:compound | (5 nm) | 1:1 | (1 nm) | 1:9 |
| | (10 nm) | | | 428 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 26 | 97:3 | (60 nm) | (30 nm) | 2:compound | (5 nm) | 1:1 | (1 nm) | 1:9 |
| | (10 nm) | | | 435 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 27 | 97:3 | (60 nm) | (30 nm) | 2:compound | (5 nm) | 1:1 | (1 nm) | 1:9 |
| | (10 nm) | | | 437 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 28 | 97:3 | (60 nm) | (30 nm) | 2:compound | (5 nm) | 1:1 | (1 nm) | 1:9 |
| | (10 nm) | | | 443 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 29 | 97:3 | (60 nm) | (30 nm) | 2:compound | (5 nm) | 1:1 | (1 nm) | 1:9 |
| | (10 nm) | | | 447 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 30 | 97:3 | (60 nm) | (30 nm) | 2:compound | (5 nm) | 1:1 | (1 nm) | 1:9 |
| | (10 nm) | | | 452 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 31 | 97:3 | (60 nm) | (30 nm) | 2:compound | (5 nm) | 1:1 | (1 nm) | 1:9 |
| | (10 nm) | | | 469 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 32 | 97:3 | (60 nm) | (30 nm) | 2:compound | (5 nm) | 1:1 | (1 nm) | 1:9 |
| | (10 nm) | | | 476 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 33 | 97:3 | (60 nm) | (30 nm) | 2:compound | (5 nm) | 1:1 | (1 nm) | 1:9 |
| | (10 nm) | | | 477 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 34 | 97:3 | (60 nm) | (30 nm) | 2:compound | (5 nm) | 1:1 | (1 nm) | 1:9 |
| | (10 nm) | | | 483 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Example 35 | 97:3 | (60 nm) | (30 nm) | 2:compound | (5 nm) | 1:1 | (1 nm) | 1:9 |
| | (10 nm) | | | 487 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Comparative | 97:3 | (60 nm) | (30 nm) | 2:ref- | (5 nm) | 1:1 | (1 nm) | 1:9 |
| Example 1 | (10 nm) | | | 1 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Comparative | 97:3 | (60 nm) | (30 nm) | 2:ref- | (5 nm) | 1:1 | (1 nm) | 1:9 |
| Example 2 | (10 nm) | | | 2 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Comparative | 97:3 | (60 nm) | (30 nm) | 2:ref- | (5 nm) | 1:1 | (1 nm) | 1:9 |
| Example 3 | (10 nm) | | | 3 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Comparative | 97:3 | (60 nm) | (30 nm) | 2:ref- | (5 nm) | 1:1 | (1 nm) | 1:9 |
| Example 4 | (10 nm) | | | 4 = 69:30:1 | | (30 nm) | | (80 nm) |
| | | | | (30 nm) | | | | |
| Device | HT-1:HI-1 = | HT-1 | EB-1 | GH-1:GH- | HB-1 | ET-1:Liq = | LiF | Mg:Ag = |
| Comparative | 97:3 | (60 nm) | (30 nm) | 2:ref- | (5 nm) | 1:1 | (1 nm) | 1:9 |
| Example 5 | (10 nm) | | | 5 = 69:30:1 | | (30 nm) | | (80 nm) |
| | | | | (30 nm) | | | | |

TABLE 2-2

| Device | | | | | | | | |
|---|---|---|---|---|---|---|---|---|
| Example/ | | | | | | | | |
| Device | Hole | Hole | Electron | Light | Hole | Electron | Electron | |
| Comparative | injection | transport | blocking | emitting | blocking | transport | injection | Cathode |
| Example | layer/ | layer/ | layer/ | layer/ | layer/ | layer/ | layer/ | layer/ |
| Numbers | Thickness | Thickness | Thickness | Thickness | Thickness | Thickness | Thickness | Thickness |
| Device | HT-1:HI-1 = | HT-1 | EB-1 | GH-1:GH-2:GD- | HB-1 | ET-1:Liq = | LiF | Mg:Ag = |
| Example 36 | 97:3 | (60 nm) | (30 nm) | 1:compound 18 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 37 | 97:3 | (60 nm) | (30 nm) | 1:compound 64 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 38 | 97:3 | (60 nm) | (30 nm) | 1:compound 71 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 39 | 97:3 | (60 nm) | (30 nm) | 1:compound 100 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 40 | 97:3 | (60 nm) | (30 nm) | 1:compound 102 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 41 | 97:3 | (60 nm) | (30 nm) | 1:compound 166 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 42 | 97:3 | (60 nm) | (30 nm) | 1:compound 230 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 43 | 97:3 | (60 nm) | (30 nm) | 1:compound 299 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 44 | 97:3 | (60 nm) | (30 nm) | 1:compound 87 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 45 | 97:3 | (60 nm) | (30 nm) | 1:compound 101 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 46 | 97:3 | (60 nm) | (30 nm) | 1:compound 334 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 47 | 97:3 | (60 nm) | (30 nm) | 1:compound 348 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Example 48 | 97:3 | (60 nm) | (30 nm) | 1:compound 370 = | (5 nm) | 1:1 | (1 nm) | 1:9 |
| | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Comparative | 97:3 | (60 nm) | (30 nm) | 1:ref-1 = | (5 nm) | 1:1 | (1 nm) | 1:9 |
| Example 6 | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Comparative | 97:3 | (60 nm) | (30 nm) | 1:ref-2 = | (5 nm) | 1:1 | (1 nm) | 1:9 |
| Example 7 | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Comparative | 97:3 | (60 nm) | (30 nm) | 1:ref-3 = | (5 nm) | 1:1 | (1 nm) | 1:9 |
| Example 8 | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Comparative | 97:3 | (60 nm) | (30 nm) | 1:ref-4 = | (5 nm) | 1:1 | (1 nm) | 1:9 |
| Example 9 | (10 nm) | | | 66.5:30:3:0.5 | | (30 nm) | | (80 nm) |
| | | | | (30 nm) | | | | |
| Device | HT-1:HI-1 = | HT-1 | EB-1 | GH-1:GH-2:GD- | HB-1 | ET-1:Liq = | LiF | Mg:Ag = |
| Comparative | 97:3 | (60 nm) | (30 nm) | 1:ref-5 = | (5 nm) | 1:1 | (1 nm) | 1:9 |
| Example 10 | (10 nm) | | | 66.5:30:3:0.5 | | (30 nm) | | (80 nm) |
| | | | | (30 nm) | | | | |

TABLE 3

| Device Examples/ | Current | Luminescence | LT95 |
|---|---|---|---|
| Comparative | efficiency | peak | service life |
| Examples | (cd/A) | (nm) | (H) |
| Device Example 1 | 51.03 | 518 | 259.5 |
| Device Example 2 | 54.41 | 538 | 269.6 |
| Device Example 3 | 53.22 | 537 | 279.2 |
| Device Example 4 | 52.19 | 538 | 233.4 |
| Device Example 5 | 54.35 | 540 | 242.2 |
| Device Example 6 | 56.01 | 539 | 278.6 |
| Device Example 7 | 56.19 | 537 | 314.6 |
| Device Example 8 | 57.12 | 541 | 295.6 |
| Device Example 9 | 58.45 | 535 | 288.3 |
| Device Example 10 | 58.22 | 534 | 314.8 |
| Device Example 11 | 56.15 | 525 | 289.4 |
| Device Example 12 | 57.53 | 532 | 305.3 |
| Device Example 13 | 57.03 | 524 | 319.7 |
| Device Example 14 | 53.27 | 519 | 293.7 |
| Device Example 15 | 56.26 | 517 | 283.5 |
| Device Example 16 | 51.49 | 532 | 303.9 |
| Device Example 17 | 56.92 | 534 | 284.8 |
| Device Example 18 | 57.25 | 520 | 277.9 |
| Device Example 19 | 51.26 | 521 | 306.4 |
| Device Example 20 | 54.59 | 522 | 276.6 |
| Device Example 21 | 56.27 | 522 | 303.7 |
| Device Example 22 | 54.96 | 524 | 303.2 |
| Device Example 23 | 56.09 | 526 | 304.7 |
| Device Example 24 | 53.63 | 525 | 305.4 |
| Device Example 25 | 54.76 | 531 | 276.9 |
| Device Example 26 | 56.86 | 533 | 272 |
| Device Example 27 | 54.93 | 533 | 304.2 |
| Device Example 28 | 53.33 | 534 | 272.6 |
| Device Example 29 | 53.49 | 535 | 300.2 |
| Device Example 30 | 54.8 | 537 | 274.8 |
| Device Example 31 | 55.89 | 535 | 290.5 |
| Device Example 32 | 54.78 | 535 | 283.1 |
| Device Example 33 | 57.92 | 538 | 305.2 |
| Device Example 34 | 53.97 | 534 | 281.4 |
| Device Example 35 | 51.43 | 535 | 287.9 |
| Comparative Example 1 | 52.72 | — | 193 |
| Comparative Example 2 | 44.43 | — | 131 |
| Comparative Example 3 | 48.56 | — | 159 |
| Comparative Example 4 | 40.38 | — | 77 |
| Comparative Example 5 | 39.47 | — | 15 |
| Device Example 36 | 70.93 | 519 | 358.4 |
| Device Example 37 | 74.46 | 539 | 384.6 |
| Device Example 38 | 72.05 | 539 | 381.2 |
| Device Example 39 | 71.59 | 540 | 343.1 |
| Device Example 40 | 73.47 | 542 | 345.9 |
| Device Example 41 | 76.34 | 540 | 388.6 |
| Device Example 42 | 77.18 | 538 | 435.8 |
| Device Example 43 | 79.34 | 542 | 420.5 |
| Device Example 44 | 79.28 | 536 | 392.1 |
| Device Example 45 | 79.01 | 535 | 443.7 |
| Device Example 46 | 77.49 | 527 | 411.2 |
| Device Example 47 | 78.57 | 533 | 432.7 |
| Device Example 48 | 77.98 | 525 | 424.5 |
| Comparative Example 6 | 61.43 | — | 278 |
| Comparative Example 7 | 50.16 | — | 217 |
| Comparative Example 8 | 54.28 | — | 255 |
| Comparative Example 9 | 46.54 | — | 123 |
| Comparative Example 10 | 43.59 | — | 37 |

Note:
The current efficiency and luminescence peak were measured by using the IVL (current-voltage-luminance) test system (Suzhou Fstar Scientific Instrument Co., Ltd.); the service life test system was the EAS-62C Model OLED Device Service Life Tester from Japan System Technology Co., Ltd.; LT95 refers to the time it takes for the brightness of the device to decay to 95%; all data were tested at 10 mA/cm².

It can be seen from the data results of the devices in Table 3 that the luminescence peak of the compound of the present disclosure is between 510 and 550 nm, which can well achieve the effect of green luminescence; compared with the Device Comparative Examples 1-10, the organic light-emitting device of the present disclosure, whether in a single doping system or a double doping system, has a greatly improved service life of device relative to the OLED device made of known materials; when an exciton sensitizing material was used as the first doping material, the device efficiency and service life are significantly improved compared to the single doping.

In summary, the above contents are only preferred embodiments of the present disclosure and are not intended to limit the present disclosure. Any modifications, equivalent substitutions, improvements, etc., made within the spirit and principles of the present disclosure should be included within the scope of protection of the present disclosure.

What is claimed is:

1. A boron-containing resonance-type organic compound, wherein the structure of the boron-containing resonance-type organic compound is as shown in general formula (1): 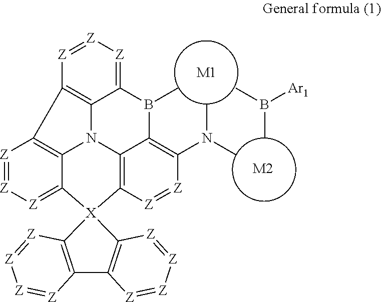
in the general formula (1), Z is the same or different at each occurrence and is represented by C—(H) or C—(R₀); R₀ is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
the M1 and M2 rings are represented as one of one or more R substituted or unsubstituted C₆-C₃₀ aromatic rings, one or more R substituted or unsubstituted C₂-C₃₀ heteroaromatic rings, one or more R substituted or unsubstituted C₆-C₃₀ aliphatic rings, and one or more R substituted or unsubstituted C₁₀-C₃₀ fused rings formed by fusing two or more of aromatic rings, heteroaromatic rings and aliphatic rings;
R is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted C₆-C₁₀ aryloxy group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
the substitution pattern of R is a single bond or a fused-ring connection;
Ar₁ is represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
any adjacent R₀ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the Ar₁ and M1 ring are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the Ar₁ and M2 ring are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented as one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
X is the same or different at each occurrence and is represented by one of a carbon atom or a silicon atom;
the substituents of the above-mentioned substitutable groups are optionally selected from one or more of deuterium atoms, halogen atoms, cyano groups, C₁-C₁₀ alkyl groups, deuterium or tritium substituted C₁-C₁₀ alkyl groups, C₃-C₁₀ cycloalkyl groups, C₆-C₃₀ aryl groups, deuterium or tritium substituted C₆-C₃₀ aryl groups, C₅-C₃₀ heteroaryl groups, and deuterium or tritium substituted C₂-C₃₀ heteroaryl groups; and
the heteroatoms in the heteroaryl groups are optionally selected from one or more of O, S, N, Si, and B.

2. The boron-containing resonance-type organic compound of claim 1, wherein the structure of the boron-containing resonance-type organic compound is as shown in general formula (2): 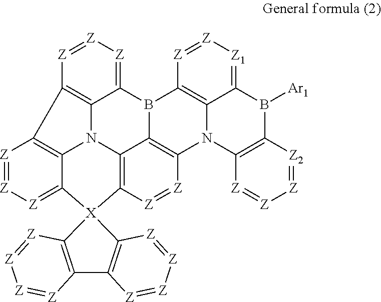
in the general formula (2), Z is the same or different at each occurrence and is represented by C—(H) or C—(R₀); R₀ is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Z₁ is represented by C—(H) or C—(Rₐ); Rₐ is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Z₂ is represented by C—(H) or C—(R_{b}); R_{b} is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Ar₁ is represented by one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
any adjacent R₀ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Ar₁ and Rₐ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Ar₁ and R_{b} are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented as one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
X is the same or different at each occurrence and is represented by one of a carbon atom or a silicon atom;
the substituents of the above-mentioned substitutable groups are optionally selected from one or more of deuterium atoms, halogen atoms, cyano groups, C₁-C₁₀ alkyl groups, deuterium or tritium substituted C₁-C₁₀ alkyl groups, C₃-C₁₀ cycloalkyl groups, C₆-C₃₀ aryl groups, deuterium or tritium substituted C₆-C₃₀ aryl groups, C₅-C₃₀ heteroaryl groups, and deuterium or tritium substituted C₂-C₃₀ heteroaryl groups; and
the heteroatoms in the heteroaryl groups are optionally selected from one or more of O, S, N, Si, and B.

3. The boron-containing resonance-type organic compound of claim 1, wherein the structure of the boron-containing resonance-type organic compound is as shown in general formula (A-1) or general formula (A-2): 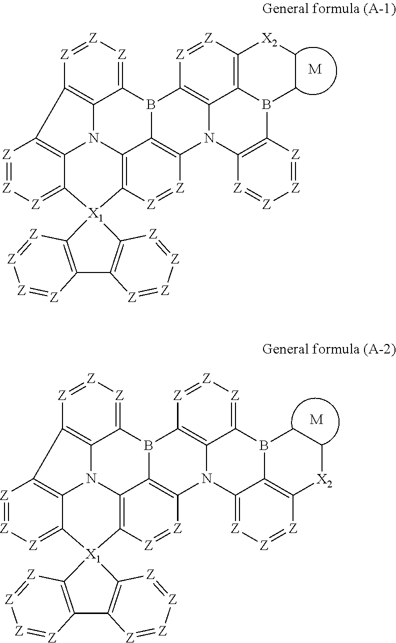
in the general formula (A-1) or general formula (A-2), Z is the same or different at each occurrence and is represented by C—(H) or C—(R₀); R₀ at each occurrence is independently represented as one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
X₁ is the same or different at each occurrence and is independently represented as one of a carbon atom or a silicon atom;
X₂ is the same or different at each occurrence and is independently represented as one of O, S and N(Rᵢ);
the Rᵢ is represented by one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
M is represented by one of one or more R substituted or unsubstituted C₆-C₃₀ aromatic ring, or one or more R substituted or an unsubstituted C₂-C₃₀ heteroaromatic ring.
R is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group; the substitution pattern of R is a single bond or a fused-ring connection;
any adjacent R₀ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Rᵢ and adjacent Z are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
Rᵢ and M are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented as one of a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
the substituents for substituting the above-mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups; and
the heteroatoms in the heteroaryl groups are optionally selected from one or more of O, S, N, Si, and B.

4. The boron-containing resonance-type organic compound of claim 1, wherein the structure of the boron-containing resonance-type organic compound is as shown in any one of general formula (A-3) to general formula (A-6): 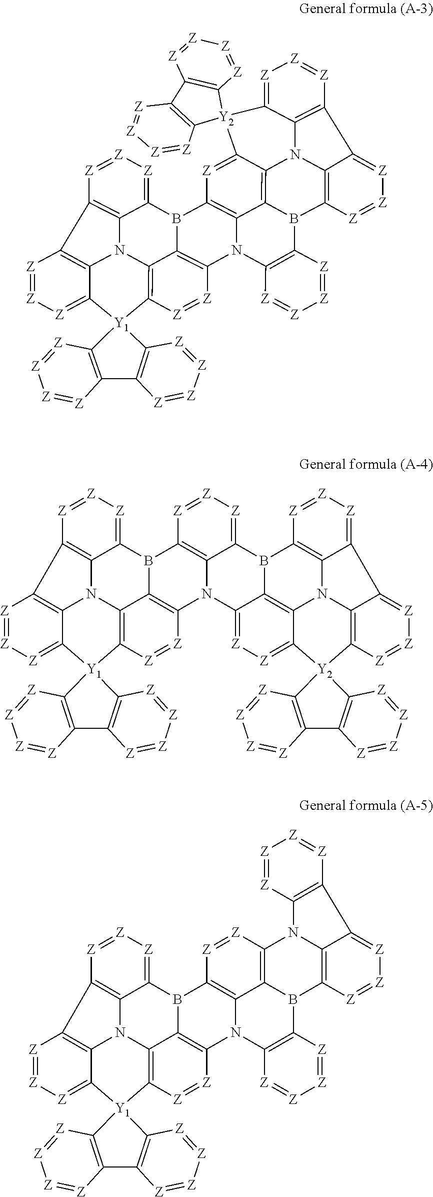 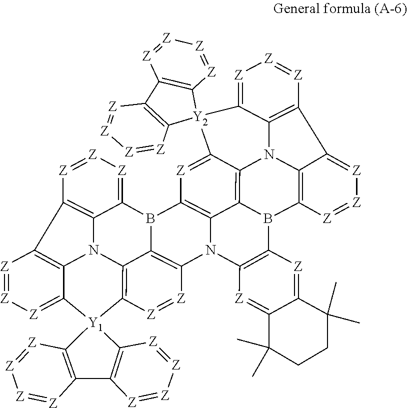
in the general formula (A-3) to general formula (A-6), Z is the same or different at each occurrence and is represented by C—(H) or C—(R₀); R₀ at each occurrence is independently represented as one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

5. The boron-containing resonance-type organic compound of claim 1, wherein the structure of the boron-containing resonance-type organic compound is as shown in any one of general formula (A-7) to general formula (A-9): 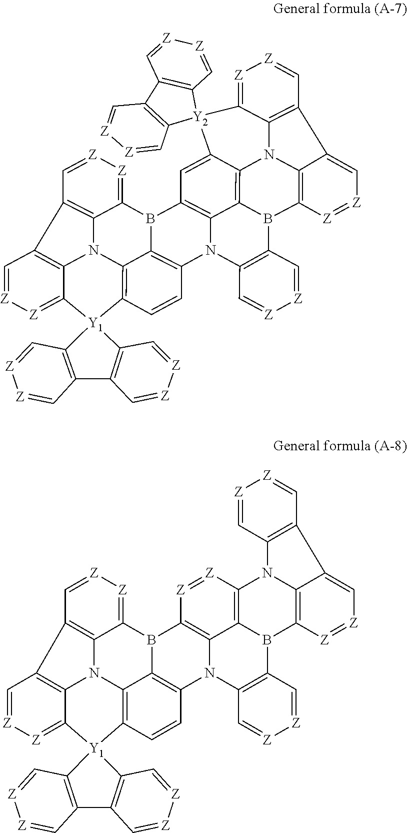 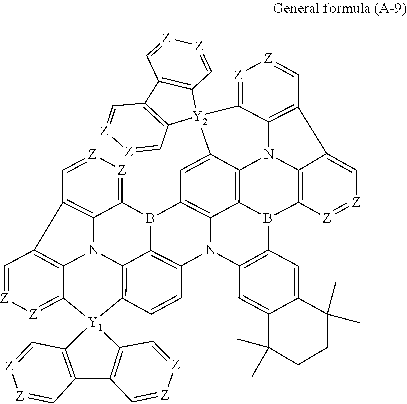
in the general formula (A-7) to general formula (A-9), Z is the same or different at each occurrence and is represented by C—(H) or C—(R₀); R₀ at each occurrence is independently represented as one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

6. The boron-containing resonance-type organic compound of claim 1, wherein the structure of the boron-containing resonance-type organic compound is as shown in any one of general formula (A-10) to general formula (A-12): 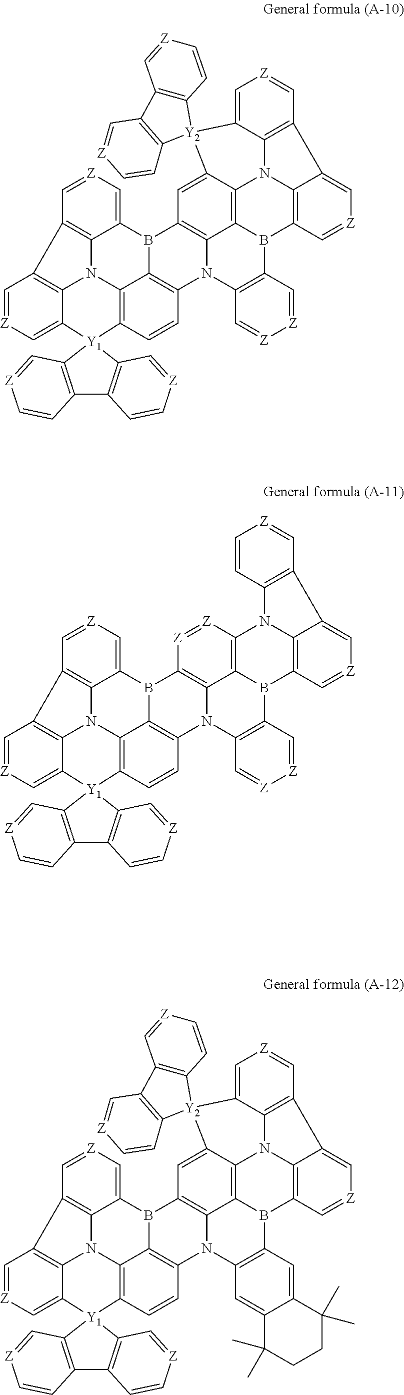
in the general formula (A-10) to general formula (A-12), Z is the same or different at each occurrence and is represented by C—(H) or C—(R₀); R₀ at each occurrence is independently represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

7. The boron-containing resonance-type organic compound of claim 1, wherein the structure of the boron-containing resonance-type organic compound is as shown in any one of general formula (A-13) to general formula (A-15): 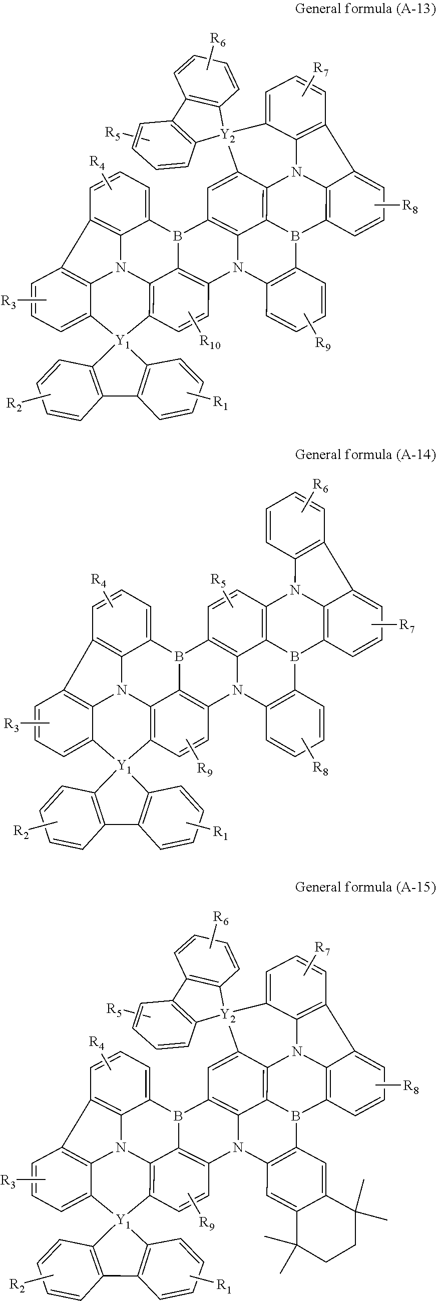
in the general formula (A-13) to general formula (A-15), R₁, R₂, R₃, R₄, R₅, R₆, R₇, R₈, R₉ and R₁₀ are the same or different at each occurrence and are represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Y₁ and Y₂ are independently represented by one of a carbon atom or a silicon atom;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups; and
the heteroatoms in the heteroaryl groups are optionally selected from one or more of O, S, N, Si, and B.

8. The boron-containing resonance-type organic compound of claim 1, wherein the structure of the boron-containing resonance-type organic compound is as shown in any one of general formula (B-1) to general formula (B-2): 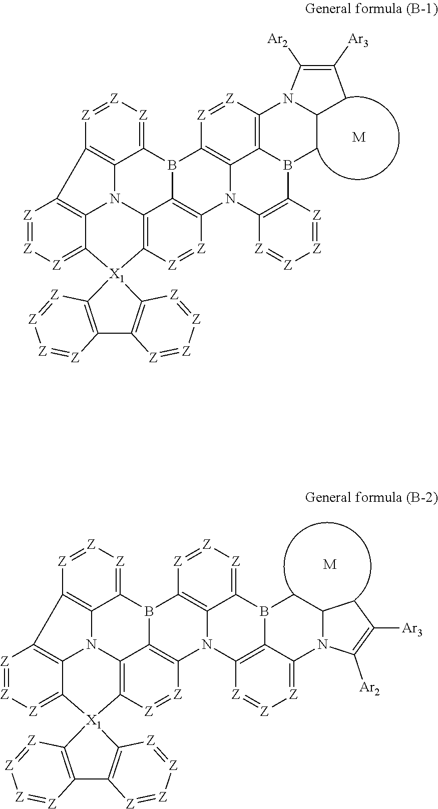
in the general formula (B-1) and general formula (B-2), Z at each occurrence is independently represented by C—(H) or C—(R₀); R₀ at each occurrence is independently represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group; any adjacent R₀ can be connected to form a ring;
X₁ at each occurrence is independently represented by one of a carbon atom or a silicon atom;
M is represented by one of one or more R substituted or unsubstituted C₆-C₃₀ aromatic ring, or one or more R substituted or unsubstituted C₂-C₃₀ heteroaromatic ring;
R is represented by one of a deuterium atom, a tritium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group; and the substitution pattern of R is a single bond or a fused-ring connection;
Ar₂ and Ar₃ at each occurrence are independently represented by hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

9. The boron-containing resonance-type organic compound of claim 8, wherein the structure of the boron-containing resonance-type organic compound is as shown in any one of general formula (B-3) to general formula (B-8): 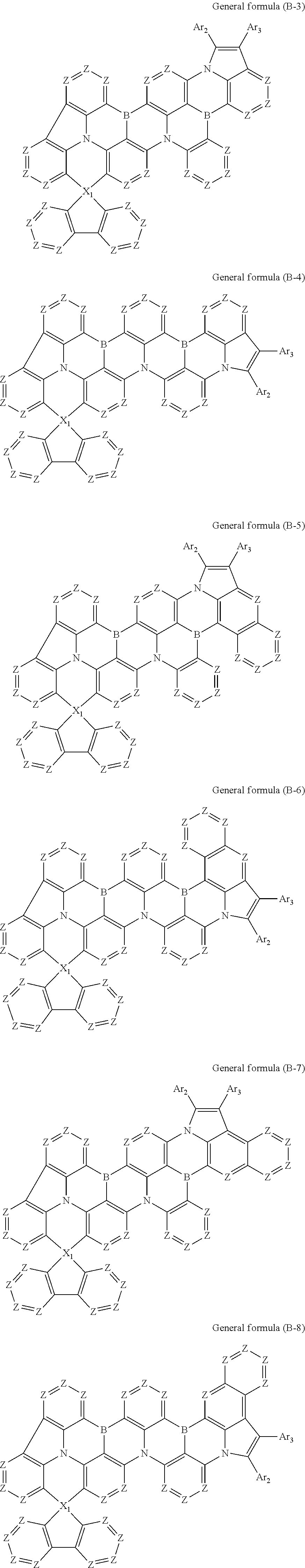
in the general formula (B-3) to general formula (B-8), the definitions of Z, Ar₂, Ar₃, and X₁ are the same as those in the general formula (B-1) and general formula (B-2).

10. The boron-containing resonance-type organic compound of claim 8, wherein the structure of the boron-containing resonance-type organic compound is as shown in any one of general formula (B-9) to general formula (B-12): 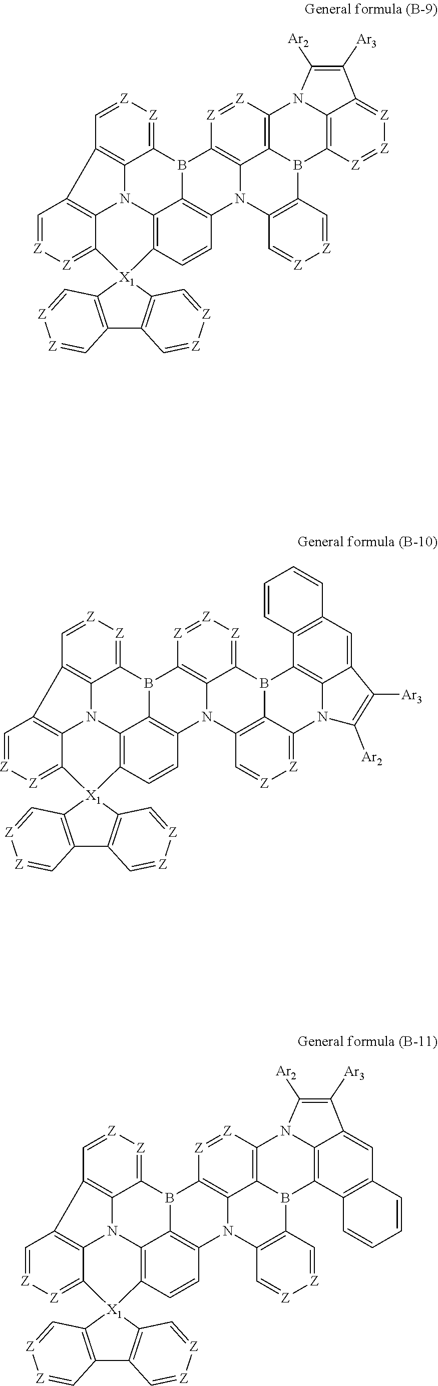 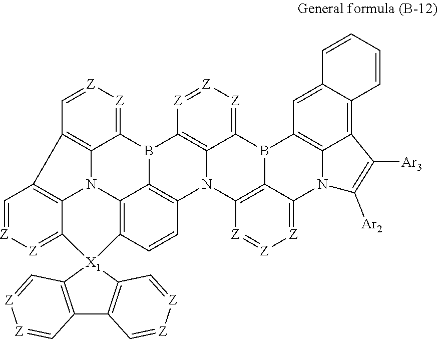
in the general formula (B-9) to general formula (B-12), the definitions of Z, Ar₂, Ar₃, and X₁ are the same as those in the general formula (B-1) and general formula (B-2).

11. The boron-containing resonance-type organic compound of claim 8, wherein the structure of the boron-containing resonance-type organic compound is as shown in any one of general formula (B-13) to general formula (B-16): 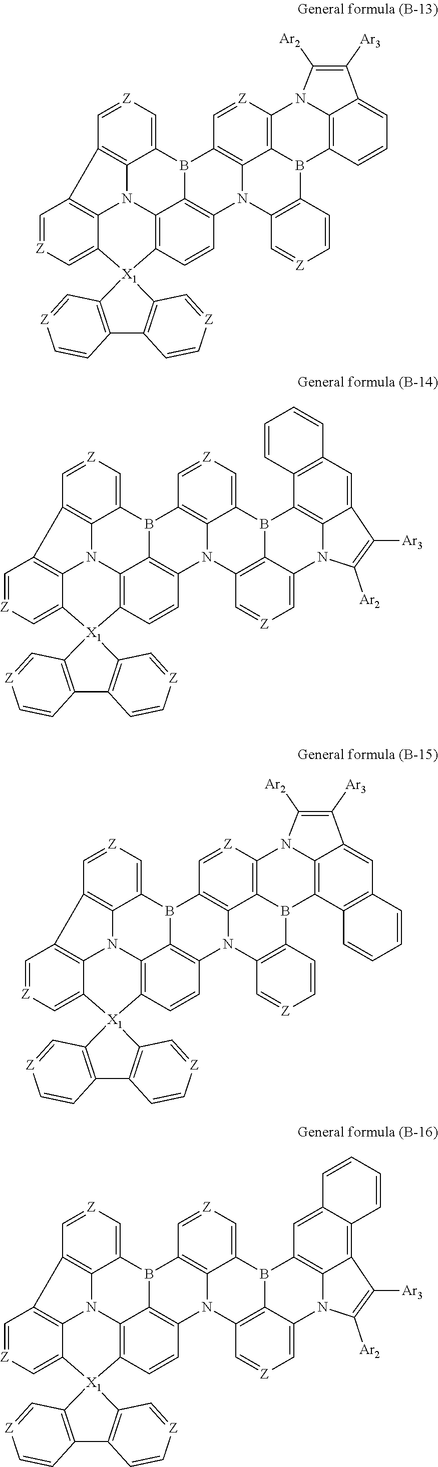
in the general formula (B-13) to general formula (B-16), the definitions of Z, Ar₂, Ar₃, and X₁ are the same as those in the general formula (B-1) and general formula (B-2).

12. The boron-containing resonance-type organic compound of claim 8, wherein the structure of the boron-containing resonance-type organic compound is as shown in any one of general formula (B-17) to general formula (B-20): 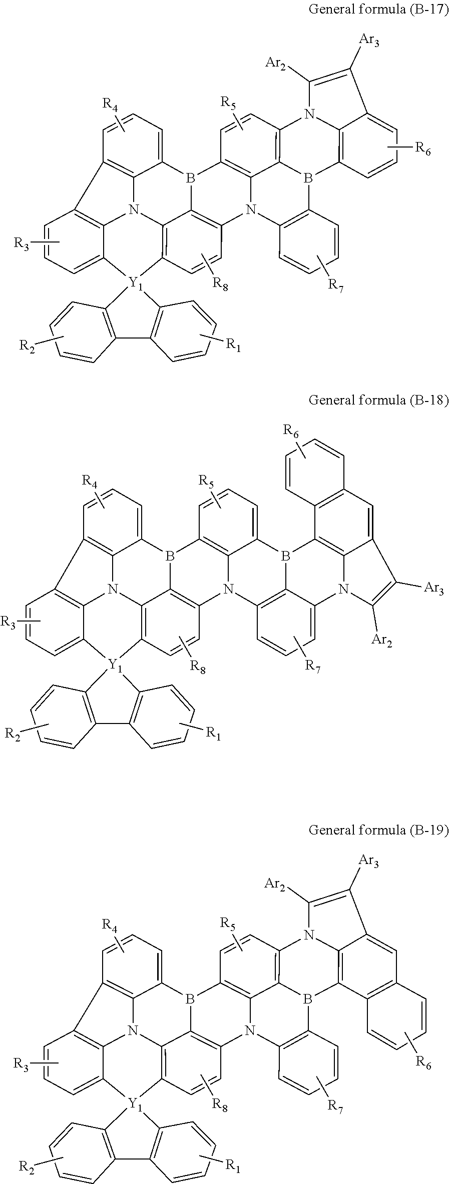 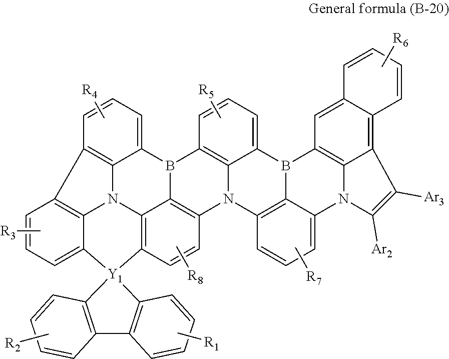
in the general formula (B-17) to general formula (B-20), R₁, R₂, R₃, R₄, R₅, R₆, R₇, and R₈ are the same or different at each occurrence and are represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, a substituted or unsubstituted C₂-C₃₀ boranyl group, and a substituted or unsubstituted silyl group;
Y₁ is independently represented by one of a carbon atom or a silicon atom;
Ar₂ and Ar₃ at each occurrence are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, and a substituted or unsubstituted C₂-C₃₀ heteroaryl group;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups; and
the heteroatoms in the heteroaryl groups are optionally selected from one or more of O, S, N, Si, and B.

13. The boron-containing resonance-type organic compound of claim 1, wherein the structure of the boron-containing resonance-type organic compound is as shown in general formula (C-1): 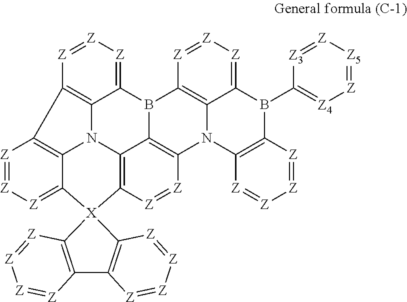
in the general formula (C-1), the definitions of X and Z are the same as those in the general formula (1);
Z₃, Z₄, and Z₅ at each occurrence are independently represented by C—(H) or C—(R₀); R₀ is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted arylamino group, a substituted or unsubstituted C₆-C₃₀ aryl group, a substituted or unsubstituted C₂-C₃₀ heteroaryl group, and a substituted or unsubstituted C₂-C₃₀ boranyl group;
the substituents for substituting the above mentioned substitutable groups are optionally selected from one or more of deuterium atoms, tritium atoms, halogen atoms, cyano groups, C₁-C₁₀ alkyl groups, deuterium substituted C₁-C₁₀ alkyl groups, C₃-C₁₀ cycloalkyl groups, C₆-C₃₀ aryl groups, deuterium substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

14. The boron-containing resonance-type organic compound of claim 1, wherein the M1, M2, and M rings are represented by the following R substituted or unsubstituted groups: any one of phenyl, naphthyl, anthryl, phenanthryl, pyridyl, quinolyl, furyl, thienyl, benzofuranyl, benzothienyl, dibenzofuranyl, dibenzothienyl, N-phenylcarbazolyl, 9,9-dimethylfluorenyl, indolo[3,2,1-jk]carbazolyl, 1,1,4,4-tetramethyl-1,2,3,4-tetrahydronaphthyl, and spirofluorenyl;
the R, R₀, Rₐ, and R_{b} are represented by a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, and a substituted or unsubstituted triazinyl;
the R₁, R₂, R₃, R₄, R₅, R₆, R₇, R₈, R₉, and R₁₀ are represented by a hydrogen atom, a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, and a substituted or unsubstituted triazinyl;
the Rᵢ, R_{c}, R_{d}, Rₑ, R_{f}, R_{g}, Rₚ, R_{q}, Ar₁, Ar₂, and Ar₃ are independently represented by a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, and a substituted or unsubstituted triazinyl;
the substituents for substituting the groups are optionally selected from one or more of a deuterium atom, a chlorine atom, a fluorine atom, a trifluoromethyl, an adamantyl, a cyano, a methyl, an ethyl, a propyl, an isopropyl, a tert-amyl, a tert-butyl, a butyl, a methoxy, a phenyl, a biphenyl, a naphthyl, an anthryl, a phenanthryl, a pyridyl, a pyrimidyl, a pyrazinyl, a pyridazinyl, a benzoxazolyl, a benzothiazolyl, a quinoxalinyl, a quinolyl, an isoquinolyl, a furyl, a thienyl, an indolyl, a pyrrolyl, a dibenzofuranyl, a dibenzothienyl, a 9,9-dimethylfluorenyl, a spirofluorenyl, a carbazolyl, an N-phenylcarbazolyl, a carbazolinyl, and an azaphenanthryl.

15. The boron-containing resonance-type organic compound of claim 1, wherein the M1 and M rings are independently represented by any one of the following ring structures: 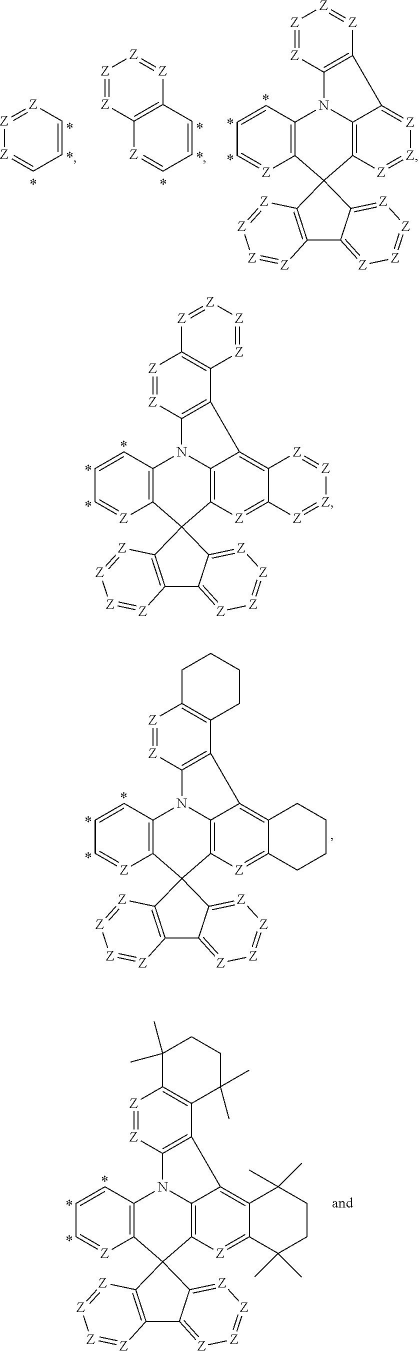 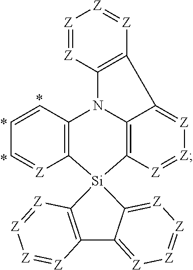
the M2 and M rings are represented by any one of the following groups: 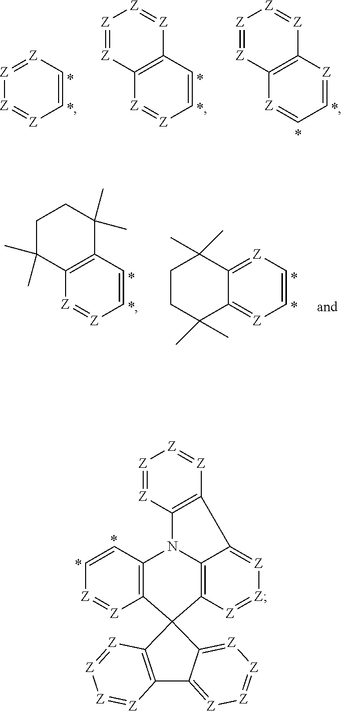
Z is the same or different at each occurrence and is represented by C—(H) or C—(R₀);
the R, R₀, Rₐ, R_{b}, R₁, R₂, R₃, R₄, R₅, R₆, R₇, R₈, R₉, and R₁₀ are independently represented by any one of the following structures shown below: a hydrogen atom, a deuterium atom, a methyl group, an ethyl group, an isopropyl group, a tert-butyl group, a cyano group, a trifluoromethyl group, 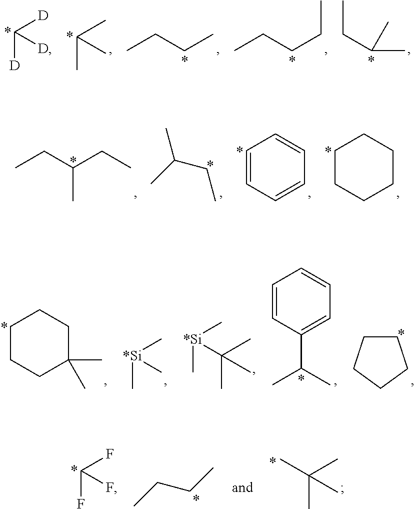
the Rᵢ, R_{c}, R_{d}, Rₑ, R_{f}, R_{g}, Rₚ, R_{q}, Ar₁, Ar₂, and Ar₃ are represented by any one of the following structures shown below: a methyl group, an ethyl group, an isopropyl group, a tert-butyl group,

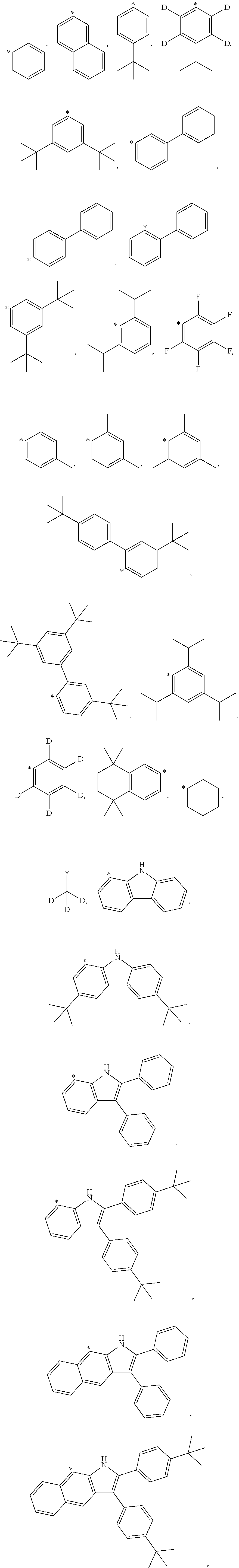

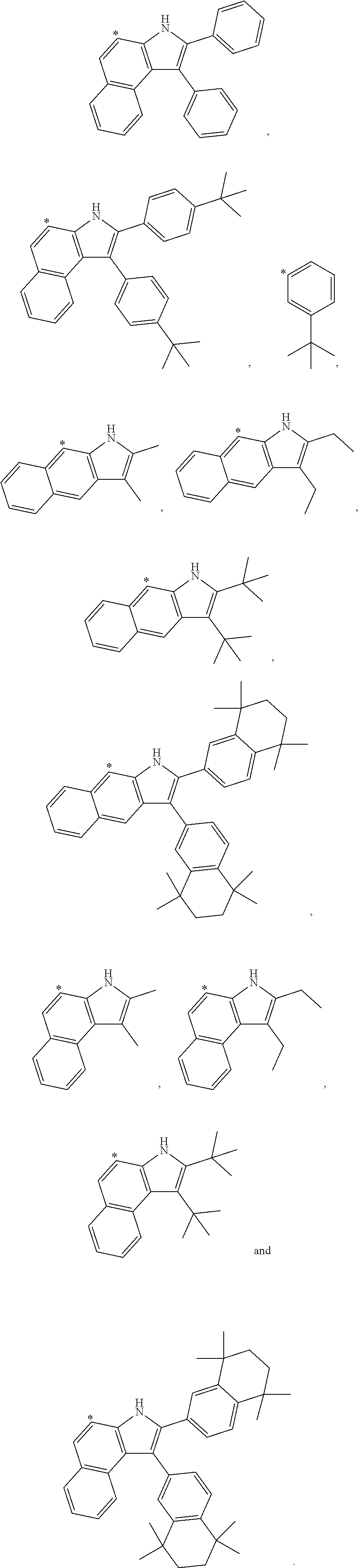

16. The boron-containing resonance-type organic compound of claim 1, wherein the structure of the diboron-containing resonance-type organic compound is as shown in general formula (D-1): 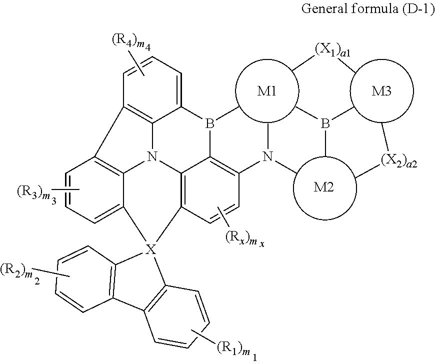
in the general formula (D-1), the M1, M2 and M3 are represented by one of one or more R substituted or unsubstituted C₆-C₃₀ aromatic rings, one or more R substituted or unsubstituted C₂-C₃₀ heteroaromatic rings, one or more R substituted or unsubstituted C₆-C₃₀ aliphatic rings, and one or more R substituted or unsubstituted C₁₀-C₃₀ fused rings formed by fusing two or more of aromatic rings, heteroaromatic rings and aliphatic rings;
R is the same or different at each occurrence and is represented by one of a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
the substitution pattern of R is a single bond or a fused-ring connection;
X is represented by one of carbon atom or silicon atom;
the R₁, R₂, R₃, R₄, and Rₓ are independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₁ and m₂ are represented as 0, 1, 2, 3 or 4;
m₃ and m₄ are represented as 0, 1, 2 or 3;
mₓ is represented as 0, 1 or 2;
a₁ and a₂ are represented as 0 or 1;
X₁ and X₂ are represented as a single bond, a double bond, —O—, —S—, —N(R_{c})—, —C(R_{d})(Rₑ)—, —Si(R_{f})(R_{g})—, or —C(Rₚ)═C(R_{q})—;
R_{c} and M₁ ring are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
R_{c} and M₃ are not connected or connected by a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group;
R_{d} and Rₑ are not connected or connected by a single bond, a double bond, —O—, —S—, —N(ph)-, a dimethyl-substituted methylene group, and a diphenyl-substituted methylene group;
R_{f} and R_{g} are not connected or connected by a single bond, a double bond, —O—, —S—, —N(ph)-, a dimethyl-substituted methylene group, and a diphenyl-substituted methylene group;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

17. The boron-containing resonance-type organic compound of claim 16, wherein the structure of the boron-containing resonance-type organic compound is as shown in general formula (D-2): 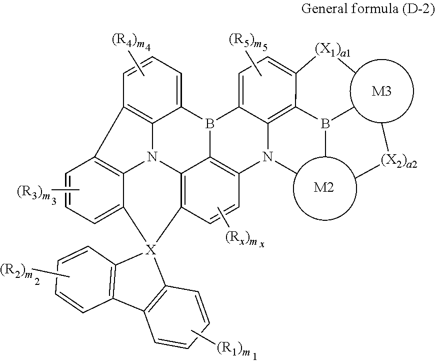
in the general formula (D-2), the definitions of X, X₁, X₂, R₁, R₂, R₃, R₄, Rₓ, a₁, a₂, m₁, m₂, m₃, m₄, mₓ, M2, and M3 are the same as those in the general formula (D-1);
the R₅ is represented as one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₅ is represented as 0, 1 or 2;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

18. The boron-containing resonance-type organic compound of claim 16, wherein the structure of the boron-containing resonance-type organic compound is as shown in any one of general formula (D-3) or general formula (D-4): 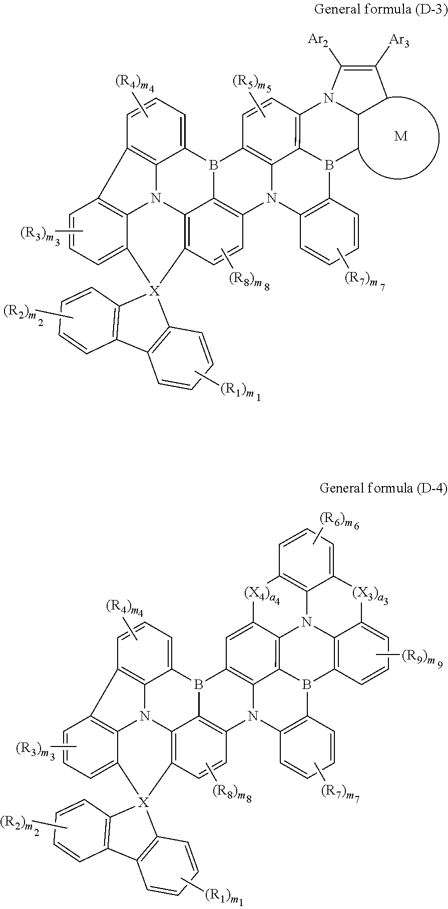
in the general formula (D-3) and general formula (D-4), the definitions of X, R₁, R₂, R₃, R₄, m₁, m₂, m₃, and m₄ are the same as those in the general formula (D-1);
M is represented by one of one or more R substituted or unsubstituted C₆-C₃₀ aromatic rings, and one or more R substituted or unsubstituted C₂-C₃₀ heteroaromatic rings;
R is represented by one of a deuterium atom, a tritium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group; the substitution pattern of R is a single bond or a fused-ring connection;
Ar₂ and Ar₃ are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, and a substituted or unsubstituted C₂-C₃₀ heteroaryl group;
R₅, R₆, R₇, R₈, and R₉ are independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₅ and mg are represented by 0, 1 or 2;
m₇ is represented by 0, 1, 2, 3 or 4;
m₆ and m₉ are represented by 0, 1, 2 or 3;
a₃ and a₄ are represented by 0 or 1;
X₃ and X₄ are independently represented by one of a single bond, a double bond, —O—, —S—, —N(R_{c})—, —C(R_{d})(Rₑ)—, —Si(R_{f})(R_{g})—, or —C(Rₚ)═C(R_{q})—;
the R_{c}, R_{d}, Rₑ, R_{f}, R_{g}, Rₚ, and R_{q} are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, and a substituted or unsubstituted boranyl group;
the R_{d} and Rₑ are not connected or connected by a single bond, a double bond, —O—, —S—, —N(ph)-, a dimethyl-substituted methylene group, and a diphenyl-substituted methylene group;
the R_{f} and R_{g} are not connected or connected by a single bond, a double bond, —O—, —S—, —N(ph)-, a dimethyl-substituted methylene group, and a diphenyl-substituted methylene group;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

19. The boron-containing resonance-type organic compound of claim 16, wherein the structure of the boron-containing resonance-type organic compound is as shown in any one of general formula (D-5) to general formula (D-9) and general formula (D-16): 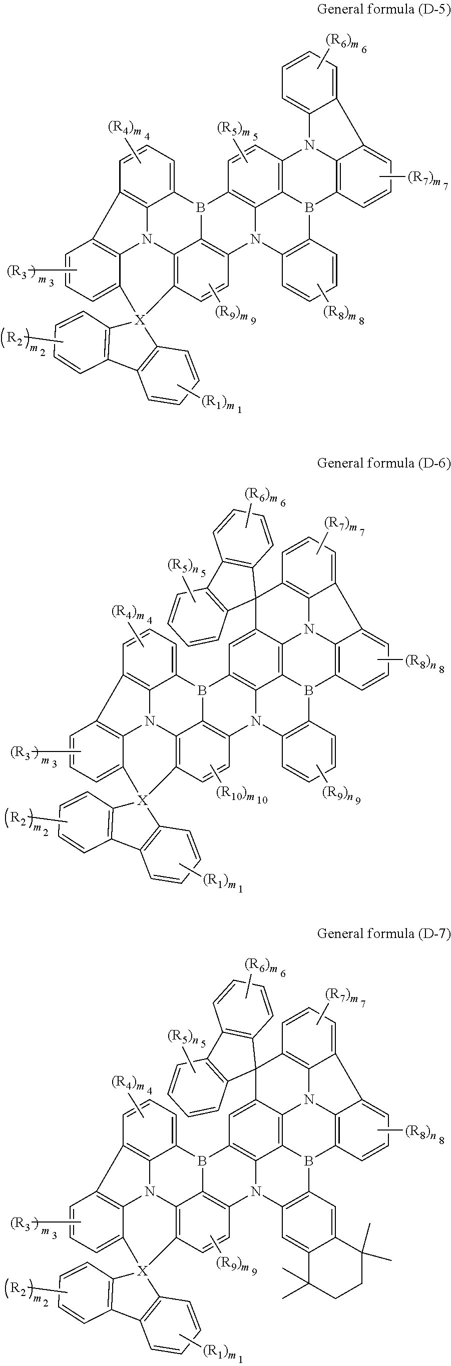 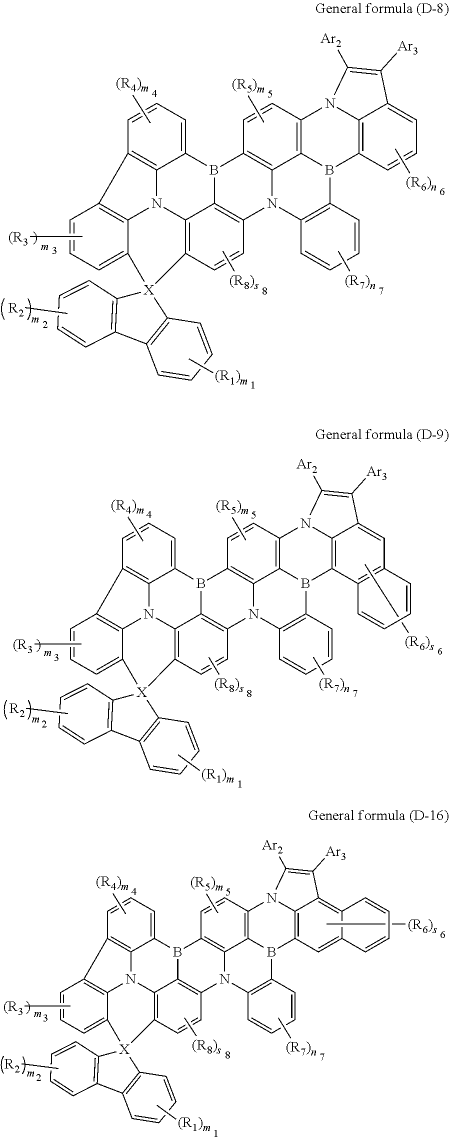
in any one of the general formula (D-5) to general formula (D-9) and general formula (D-16), the definitions of X, R₁, R₂, R₃, R₄, m₁, m₂, m₃, and m₄ are the same as those in the general formula (D-1);
Ar₂ and Ar₃ are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, and a substituted or unsubstituted C₂-C₃₀ heteroaryl group;
R₅, R₆, R₇, R₈, R₉, and R₁₀ are independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
m₅, m₉, m₁₀, and s₈ are represented by 0, 1 or 2;
n₅, m₆, n₇, n₉, and m₈ are represented by 0, 1, 2, 3 or 4;
m₇, s₅, n₆, and n₈ are represented by 0, 1, 2 or 3; and
s₆ is represented by 0, 1, 2, 3, 4 or 5;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₁-C₁₀ alkyl substituted C₆-C₃₀ aryl groups, C₂-C₃₀ heteroaryl groups, and deuterium substituted C₂-C₃₀ heteroaryl groups;
the heteroatoms in the heteroaryl groups are optionally selected from one or more of O, S, N, Si, and B.

20. The boron-containing resonance-type organic compound of claim 16, wherein the structure of the boron-containing resonance-type organic compound is as shown in any one of general formula (D-10) or general formula (D-15): 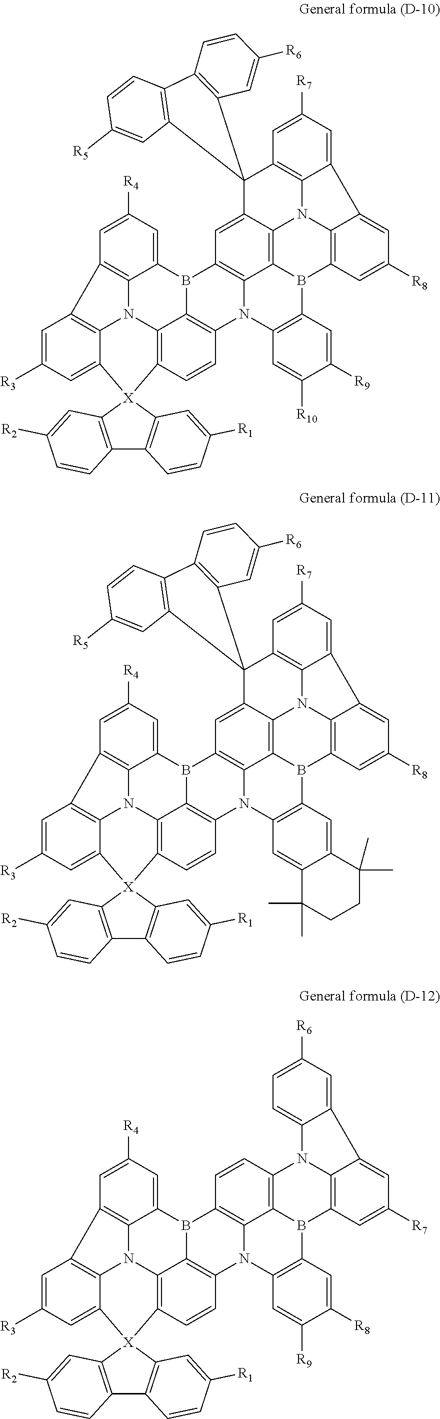 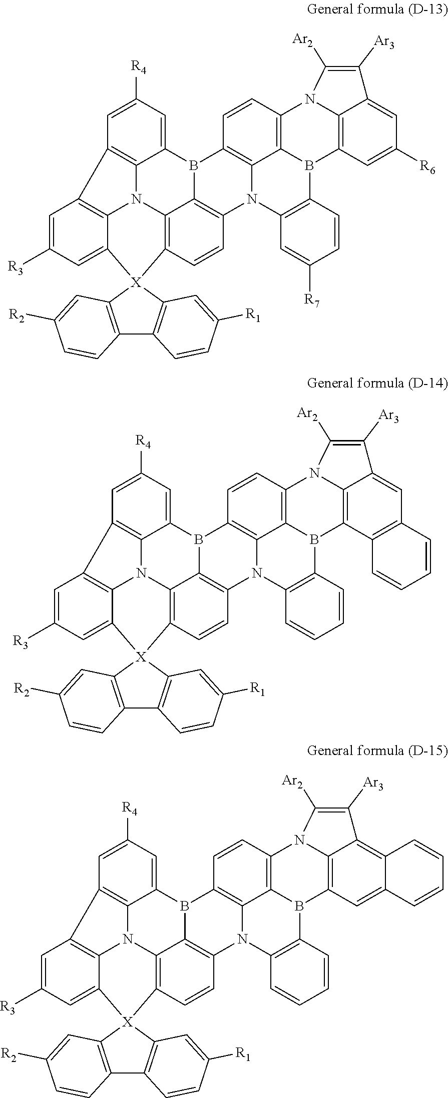
in the general formula (D-10) to general formula (D-15), the definitions of X, R₁, R₂, R₃, and R₄ are the same as those in the general formula (D-1);
Ar₂ and Ar₃ are independently represented by one of a hydrogen atom, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, and a substituted or unsubstituted C₂-C₃₀ heteroaryl group;
R₅, R₆, R₇, R₈, R₉, and R₁₀ are independently represented by one of a hydrogen atom, a deuterium atom, a halogen atom, a cyano group, a substituted or unsubstituted C₁-C₁₀ alkyl group, a substituted or unsubstituted C₃-C₁₀ cycloalkyl group, a substituted or unsubstituted C₂-C₁₀ alkenyl group, a substituted or unsubstituted C₂-C₁₀ alkynyl group, a substituted or unsubstituted arylamino group, a substituted or unsubstituted C₆-C₃₀ aryl group, a substituted or unsubstituted C₂-C₃₀ heteroaryl group, a substituted or unsubstituted boranyl group, and a substituted or unsubstituted silyl group;
the substituents of the above-mentioned substitutable groups are optionally selected from any one or more of deuterium atoms, halogen atoms, cyano groups, C₁-C₁₀ alkyl groups, deuterium substituted C₁-C₁₀ alkyl groups, C₃-C₁₀ cycloalkyl groups, deuterium substituted C₃-C₁₀ cycloalkyl groups, C₆-C₃₀ aryl groups, deuterium substituted C₆-C₃₀ aryl groups, C₆-C₃₀ aryl groups substituted with C₁-C₁₀ alkyl, C₂-C₃₀ heteroaryl groups, and deuterium substituted C₂-C₃₀ heteroaryl groups;
the heteroatoms in the heteroaryl groups are optionally selected from one or more of O, S, N, Si, and B.

21. The boron-containing resonance-type organic compound of claim 1, wherein the M1, M2, M3 and M rings are represented by the following one or more R substituted or unsubstituted groups: any one of phenyl, naphthyl, anthryl, phenanthryl, pyridyl, quinolyl, furyl, thienyl, benzofuranyl, benzothienyl, dibenzofuranyl, dibenzothienyl, N-phenylcarbazolyl, 9,9-dimethylfluorenyl, indolo[3,2,1-jk]carbazolyl, 1,1,4,4-tetramethyl-1,2,3,4-tetrahydronaphthyl, and spirofluorenyl;
the R, R₀, Rₐ, R_{b}, R_{c}, R_{d}, Rₑ R_{f}, R_{g}, Rₚ, and R_{q} are represented by a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, a substituted or unsubstituted a triazinyl, substituted or unsubstituted 1,1,4,4-tetramethyl-1,2,3,4-tetrahydronaphthyl, a substituted or unsubstituted diphenylamino, a substituted or unsubstituted indolyl, and a substituted or unsubstituted benzindolyl;
the R₁, R₂, R₃, R₄, R₅, R₆, R₇, R₈, R₉, R₁₀, and Rₓ are represented by a hydrogen atom, a deuterium atom, a halogen atom, a cyano, a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, a substituted or unsubstituted triazinyl, a substituted or unsubstituted 1,1,4,4-tetramethyl-1,2,3,4-tetrahydronaphthyl, a substituted or unsubstituted diphenylamino, a substituted or unsubstituted indolyl, and a substituted or unsubstituted benzindolyl;
the Rᵢ, R_{c}, R_{d}, Rₑ, R_{f}, R_{g}, Rₚ, R_{q}, Ar₁, Ar₂, and Ar₃ are independently represented by a substituted or unsubstituted methyl, a substituted or unsubstituted ethyl, a substituted or unsubstituted isopropyl, a substituted or unsubstituted tert-butyl, a substituted or unsubstituted cyclohexyl, a substituted or unsubstituted adamantyl, a substituted or unsubstituted phenyl, a substituted or unsubstituted biphenyl, a substituted or unsubstituted terphenyl, a substituted or unsubstituted naphthyl, a substituted or unsubstituted anthryl, a substituted or unsubstituted phenanthryl, a substituted or unsubstituted pyridyl, a substituted or unsubstituted quinolyl, a substituted or unsubstituted furyl, a substituted or unsubstituted thienyl, a substituted or unsubstituted benzofuranyl, a substituted or unsubstituted benzothienyl, a substituted or unsubstituted dibenzofuranyl, a substituted or unsubstituted dibenzothienyl, a substituted or unsubstituted carbazolyl, a substituted or unsubstituted N-phenylcarbazolyl, a substituted or unsubstituted 9,9-dimethylfluorenyl, a substituted or unsubstituted 9,9-diphenylfluorenyl, a substituted or unsubstituted spirofluorenyl, a substituted or unsubstituted amino, a substituted or unsubstituted triazinyl, a substituted or unsubstituted 1,1,4,4-tetramethyl-1,2,3,4-tetrahydronaphthyl, a substituted or unsubstituted diphenylamino, a substituted or unsubstituted indolyl, and a substituted or unsubstituted benzindolyl;
the substituents for substituting the groups are optionally selected from one or more of a deuterium atom, a chlorine atom, a fluorine atom, a trifluoromethyl, an adamantyl, a cyano, a methyl, an ethyl, a propyl, an isopropyl, a tert-amyl, a tert-butyl, a butyl, a methoxy, a phenyl, a biphenyl, a naphthyl, an anthryl, a phenanthryl, a pyridyl, a pyrimidyl, a pyrazinyl, a pyridazinyl, a benzoxazolyl, a benzothiazolyl, a quinoxalinyl, a quinolyl, an isoquinolyl, a furyl, a thienyl, an indolyl, a pyrrolyl, a dibenzofuranyl, a dibenzothienyl, a 9,9-dimethylfluorenyl, a spirofluorenyl, a carbazolyl, an N-phenylcarbazolyl, a carbazolinyl, an azaphenanthryl, diphenylamino, 1,1,4,4-tetramethyl-1,2,3,4-tetrahydronaphthyl, methyl-substituted phenyl, ethyl-substituted phenyl, isopropyl-substituted phenyl, tert-butyl-substituted phenyl, adamantyl-substituted phenyl, methyl-substituted biphenyl, ethyl-substituted biphenyl, isopropyl-substituted biphenyl, tert-butyl-substituted biphenyl, deuterated methyl-substituted phenyl, deuterated ethyl-substituted phenyl, deuterated isopropyl-substituted phenyl, deuterated tert-butyl-substituted phenyl, deuterated methyl-substituted biphenyl, deuterated ethyl-substituted biphenyl, deuterated isopropyl-substituted biphenyl, and deuterated tert-butyl-substituted biphenyl.

22. The boron-containing resonance-type organic compound of claim 1, wherein the specific structural formula of the boron-containing resonance-type organic compound is any one of the following structures:

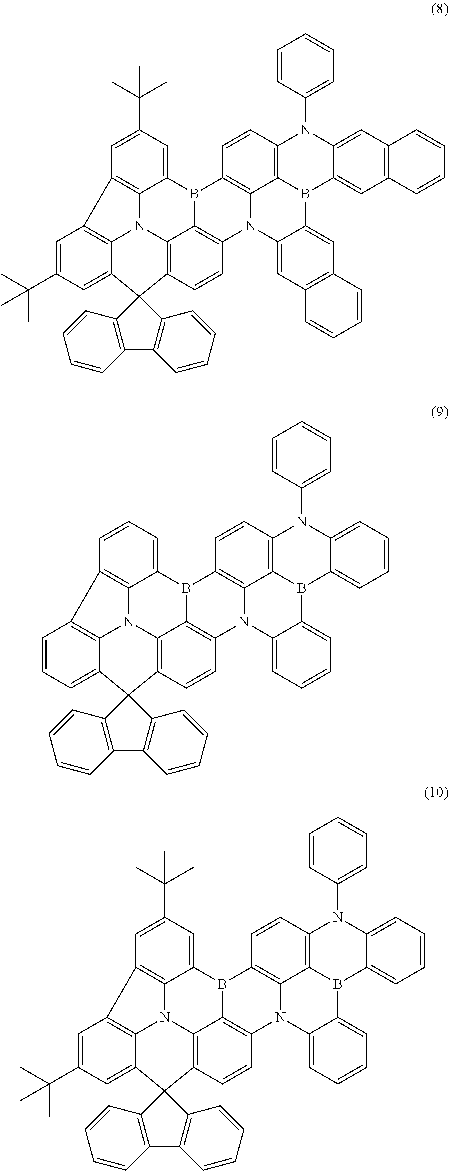 [SMILES: CC(C)(C)c1cc2c3c(c1)c1cc(C(C)(C)C)cc4c1n3-c1c(ccc3c1B2c1ccc2c5c1N3c1cc3ccccc3cc1B5c1cc3ccccc3cc1N2c1ccccc1)C41c2ccccc2-c2ccccc21 ; c1ccc(N2c3ccccc3B3c4ccccc4N4c5ccc6c7c5B(c5ccc2c3c54)c2cccc3c4cccc(c4n-7c23)C62c3ccccc3-c3ccccc32)cc1 ; CC(C)(C)c1cc2c3c(c1)c1cc(C(C)(C)C)cc4c1n3-c1c(ccc3c1B2c1ccc2c5c1N3c1ccccc1B5c1ccccc1N2c1ccccc1)C41c2ccccc2-c2ccccc21]

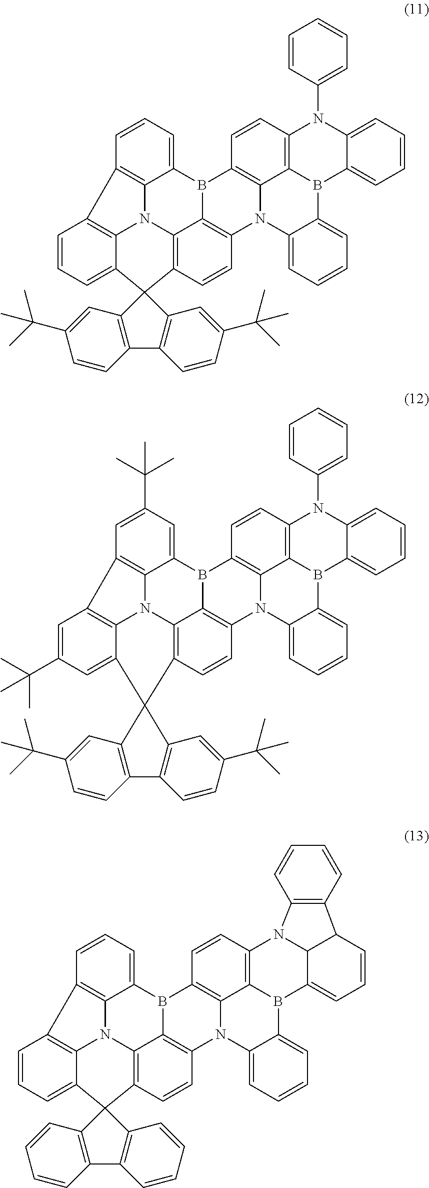 [SMILES: CC(C)(C)c1ccc2c(c1)C1(c3cc(C(C)(C)C)ccc3-2)c2ccc3c4c2-n2c5c(cccc5c5cccc1c52)B4c1ccc2c4c1N3c1ccccc1B4c1ccccc1N2c1ccccc1 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccccc1B4c1ccccc1N2c1ccccc1 ; C1=CC2c3ccccc3N3c4ccc5c6c4B(C(=C1)C23)c1ccccc1N6c1ccc2c3c1B5c1cccc4c5cccc(c5n-3c14)C21c2ccccc2-c2ccccc21]

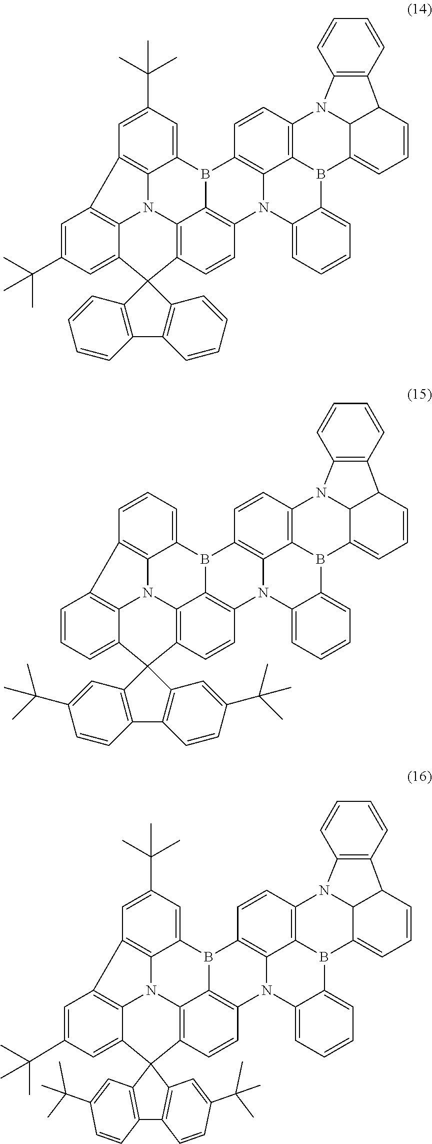 [SMILES: CC(C)(C)c1cc2c3c(c1)c1cc(C(C)(C)C)cc4c1n3-c1c(ccc3c1B2c1ccc2c5c1N3c1ccccc1B5C1=CC=CC3c5ccccc5N2C13)C41c2ccccc2-c2ccccc21 ; CC(C)(C)c1ccc2c(c1)C1(c3cc(C(C)(C)C)ccc3-2)c2ccc3c4c2-n2c5c(cccc5c5cccc1c52)B4c1ccc2c4c1N3c1ccccc1B4C1=CC=CC3c4ccccc4N2C13 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccccc1B4C1=CC=CC3c4ccccc4N2C13]

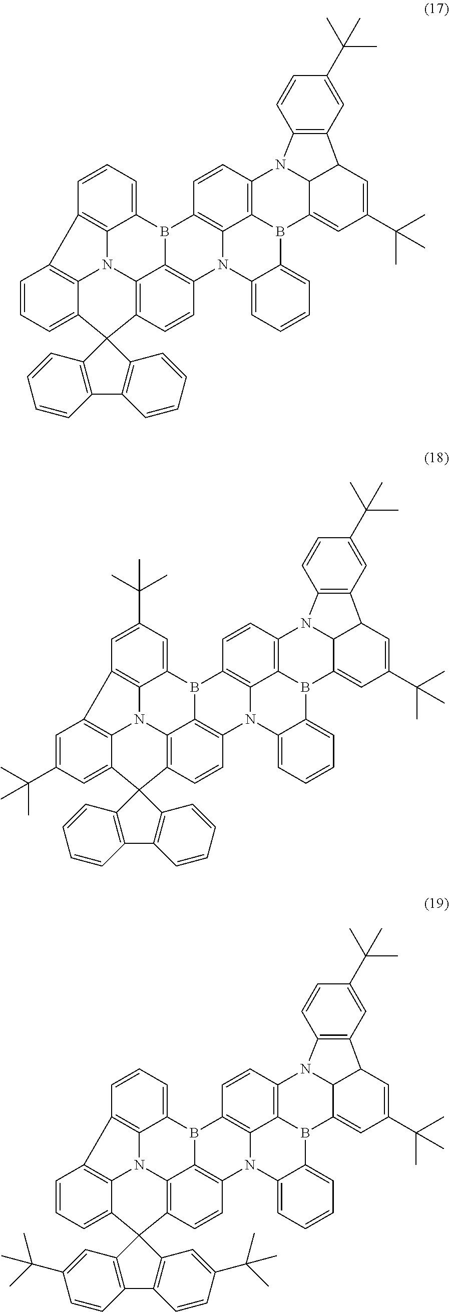

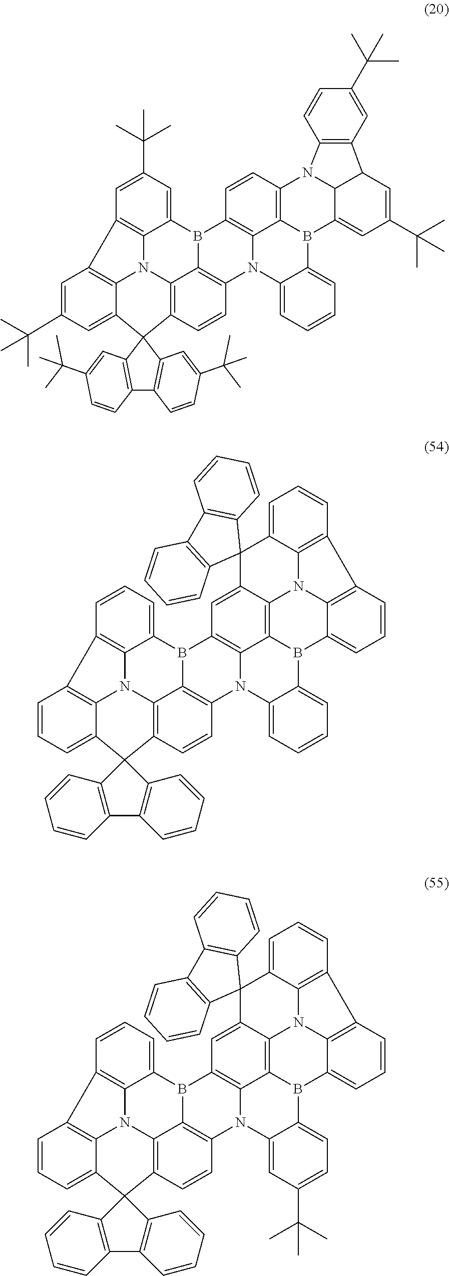 [SMILES: CC(C)(C)C1=CC2c3cc(C(C)(C)C)ccc3N3c4ccc5c6c4B(C(=C1)C23)c1ccccc1N6c1ccc2c3c1B5c1cc(C(C)(C)C)cc4c5cc(C(C)(C)C)cc(c5n-3c14)C21c2cc(C(C)(C)C)ccc2-c2ccc(C(C)(C)C)cc21 ; c1ccc2c(c1)B1c3c4c(cc5c3-n3c6c1cccc6c1cccc(c13)C51c3ccccc3-c3ccccc31)B1c3c(ccc5c3-n3c6c1cccc6c1cccc(c13)C51c3ccccc3-c3ccccc31)N24 ; CC(C)(C)c1ccc2c(c1)N1c3ccc4c5c3B(c3cc6c7c(c31)B2c1cccc2c3cccc(c3n-7c12)C61c2ccccc2-c2ccccc21)c1cccc2c3cccc(c3n-5c12)C41c2ccccc2-c2ccccc21]

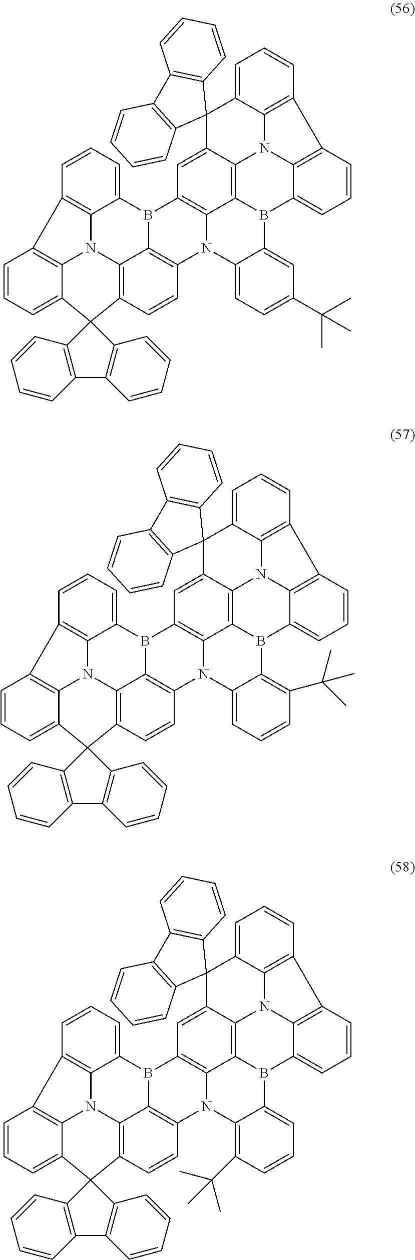 [SMILES: CC(C)(C)c1ccc2c(c1)B1c3c4c(cc5c3-n3c6c1cccc6c1cccc(c13)C51c3ccccc3-c3ccccc31)B1c3c(ccc5c3-n3c6c1cccc6c1cccc(c13)C51c3ccccc3-c3ccccc31)N24 ; CC(C)(C)c1cccc2c1B1c3c4c(cc5c3-n3c6c1cccc6c1cccc(c13)C51c3ccccc3-c3ccccc31)B1c3c(ccc5c3-n3c6c1cccc6c1cccc(c13)C51c3ccccc3-c3ccccc31)N24 ; CC(C)(C)c1cccc2c1N1c3ccc4c5c3B(c3cc6c7c(c31)B2c1cccc2c3cccc(c3n-7c12)C61c2ccccc2-c2ccccc21)c1cccc2c3cccc(c3n-5c12)C41c2ccccc2-c2ccccc21]

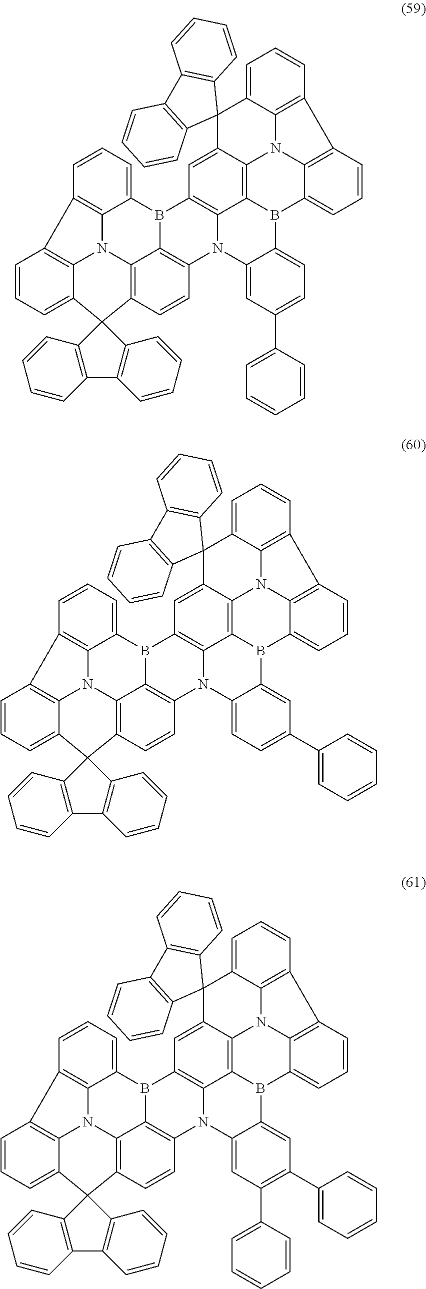 [SMILES: c1ccc(-c2ccc3c(c2)N2c4ccc5c6c4B(c4cc7c8c(c42)B3c2cccc3c4cccc(c4n-8c23)C72c3ccccc3-c3ccccc32)c2cccc3c4cccc(c4n-6c23)C52c3ccccc3-c3ccccc32)cc1 ; c1ccc(-c2ccc3c(c2)B2c4c5c(cc6c4-n4c7c2cccc7c2cccc(c24)C62c4ccccc4-c4ccccc42)B2c4c(ccc6c4-n4c7c2cccc7c2cccc(c24)C62c4ccccc4-c4ccccc42)N35)cc1 ; c1ccc(-c2cc3c(cc2-c2ccccc2)N2c4ccc5c6c4B(c4cc7c8c(c42)B3c2cccc3c4cccc(c4n-8c23)C72c3ccccc3-c3ccccc32)c2cccc3c4cccc(c4n-6c23)C52c3ccccc3-c3ccccc32)cc1]

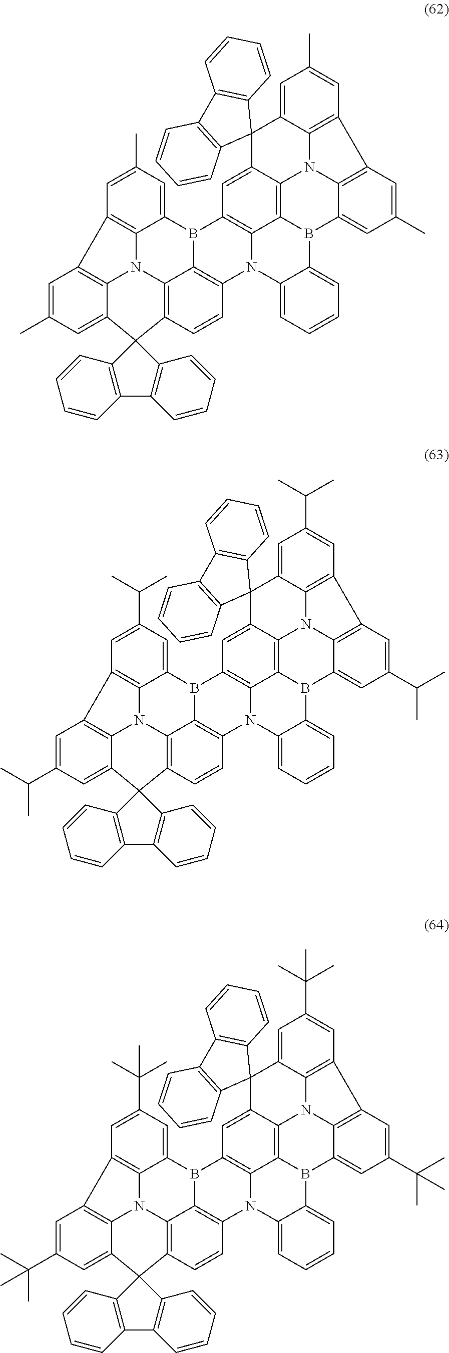

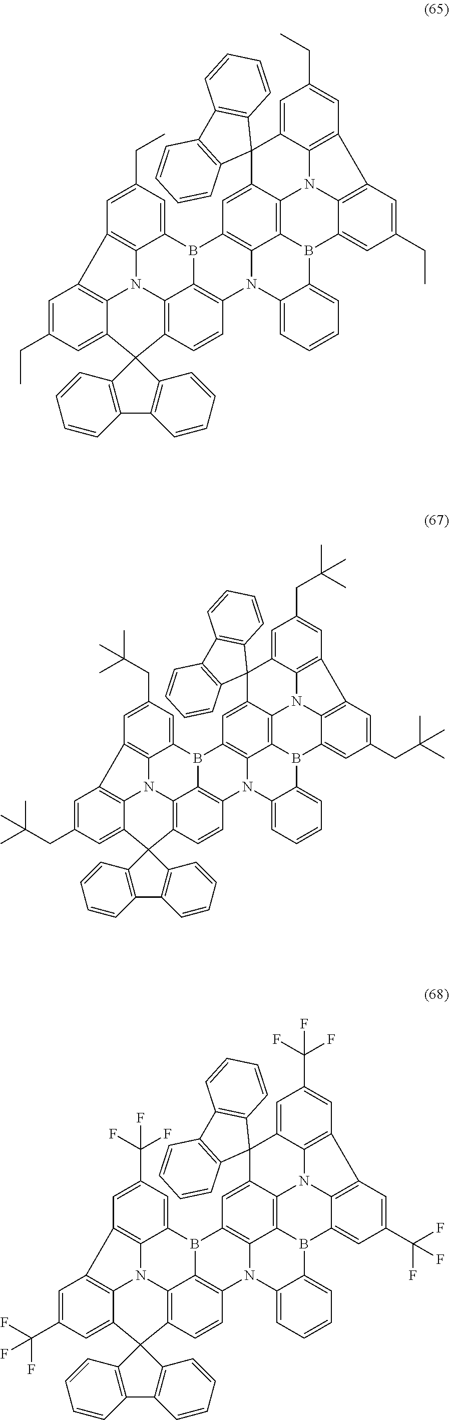

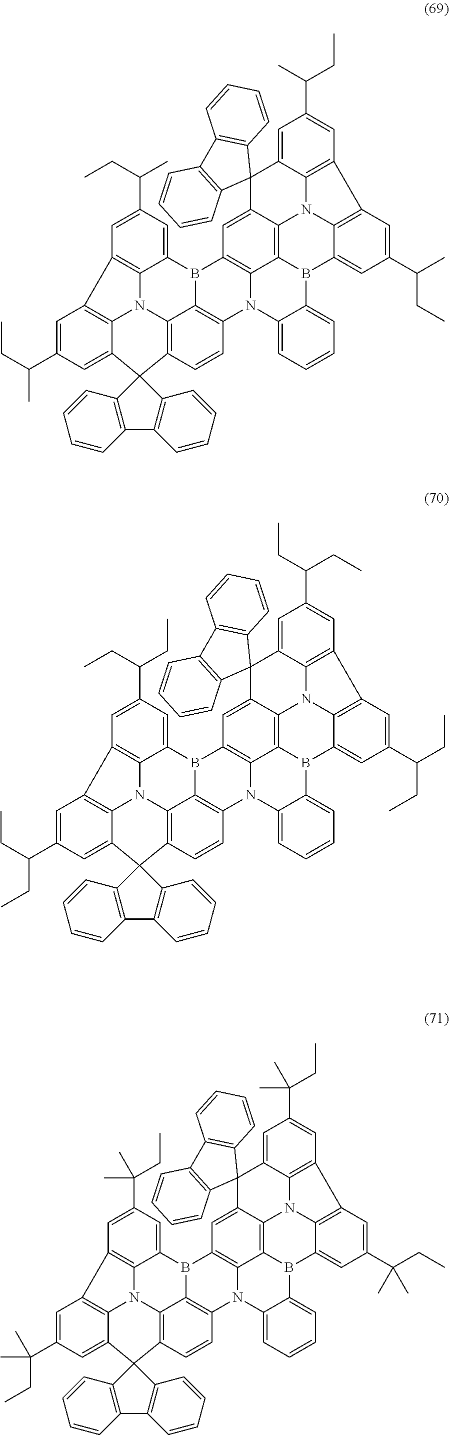

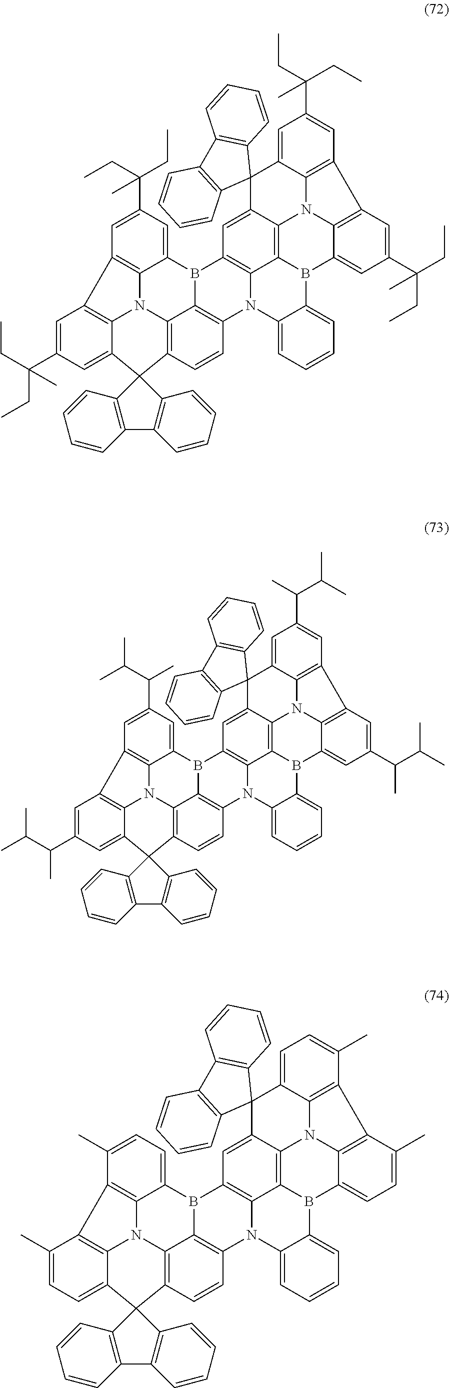

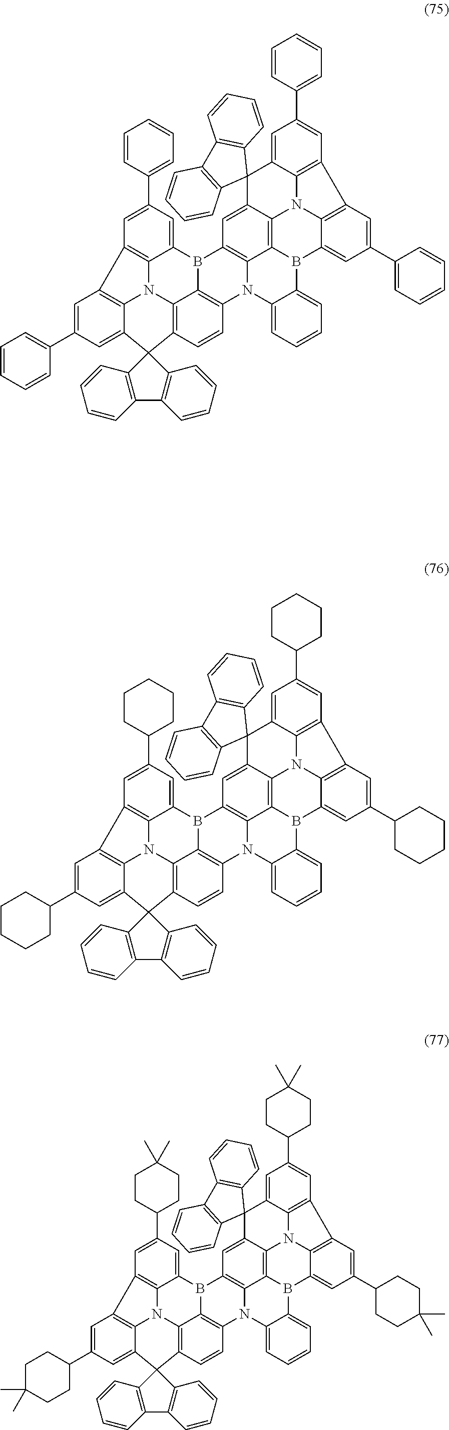

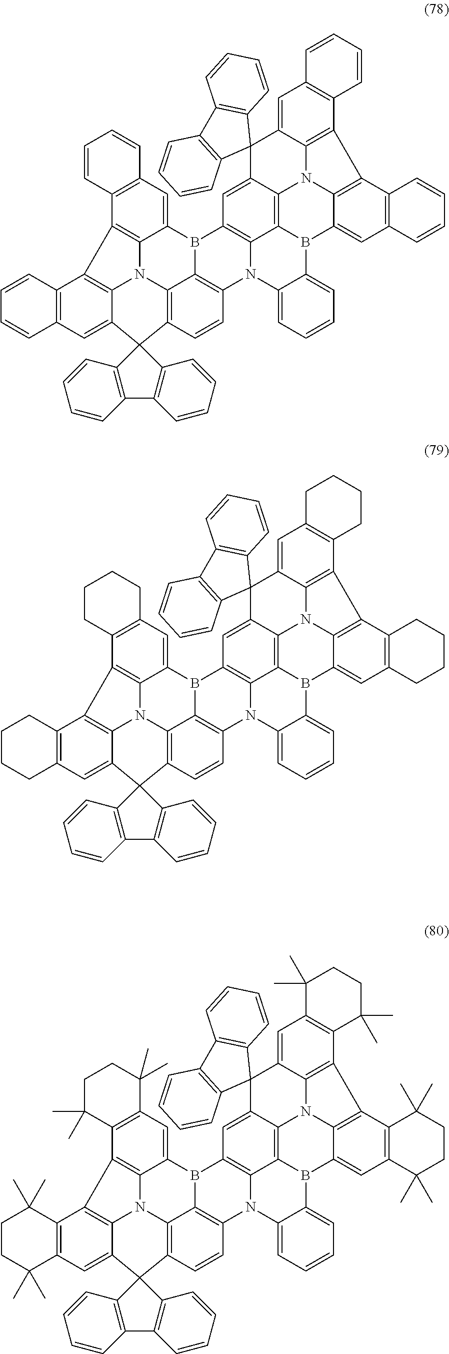

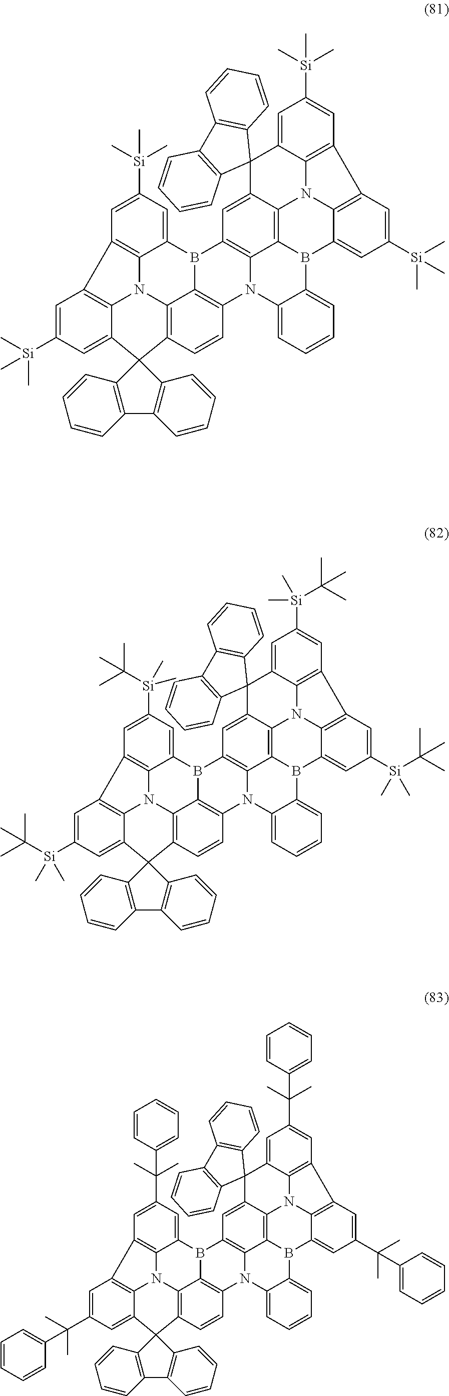

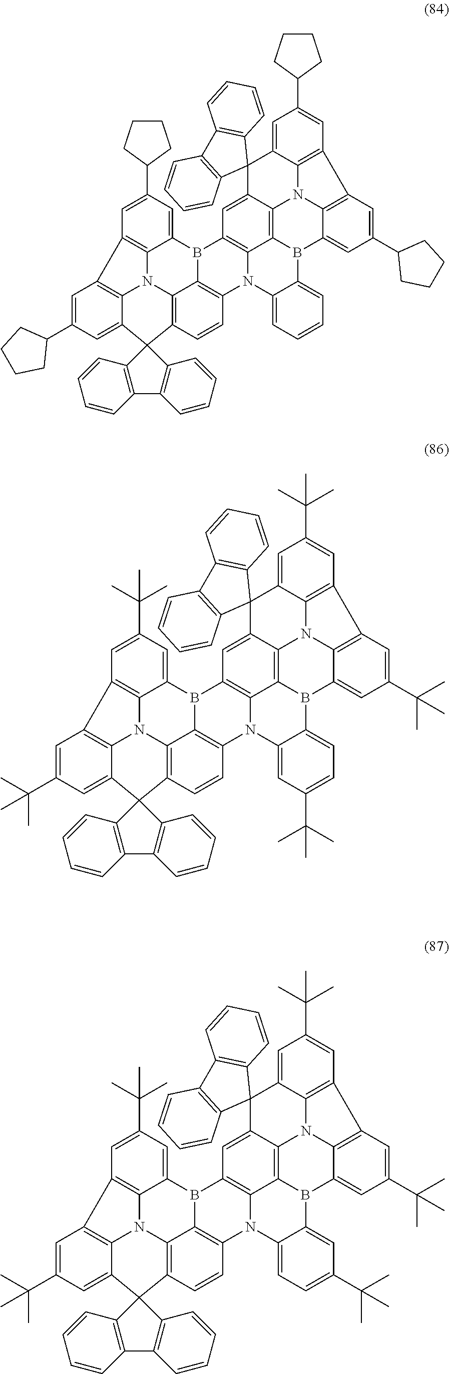

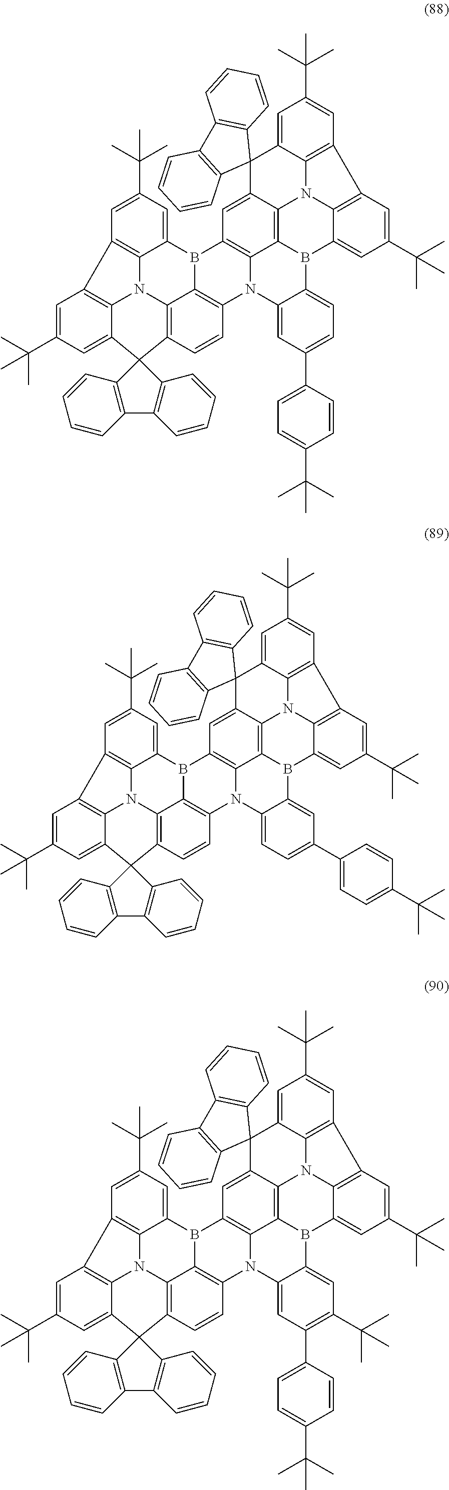

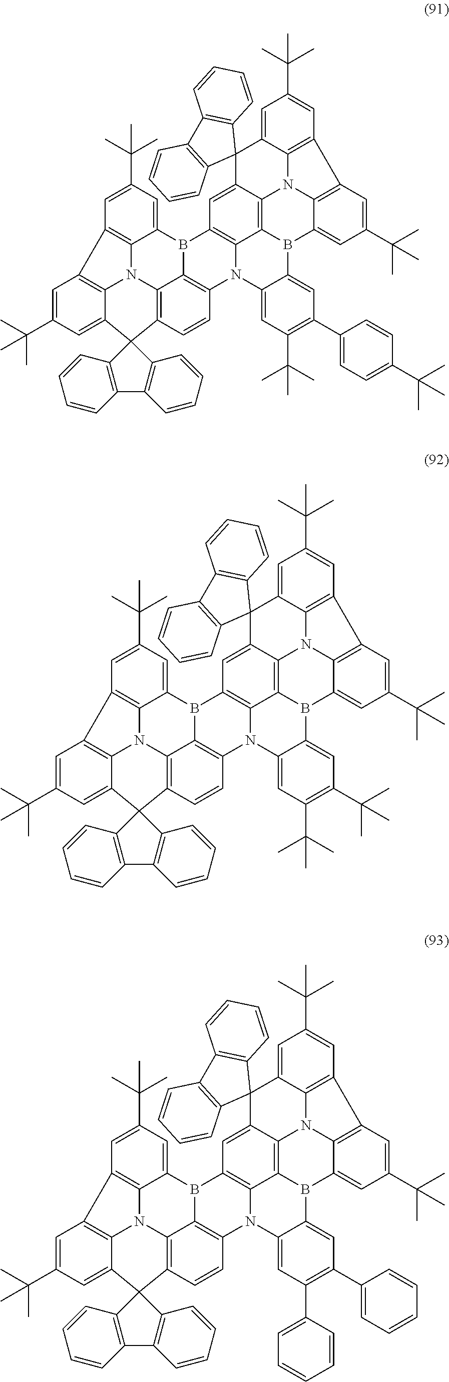

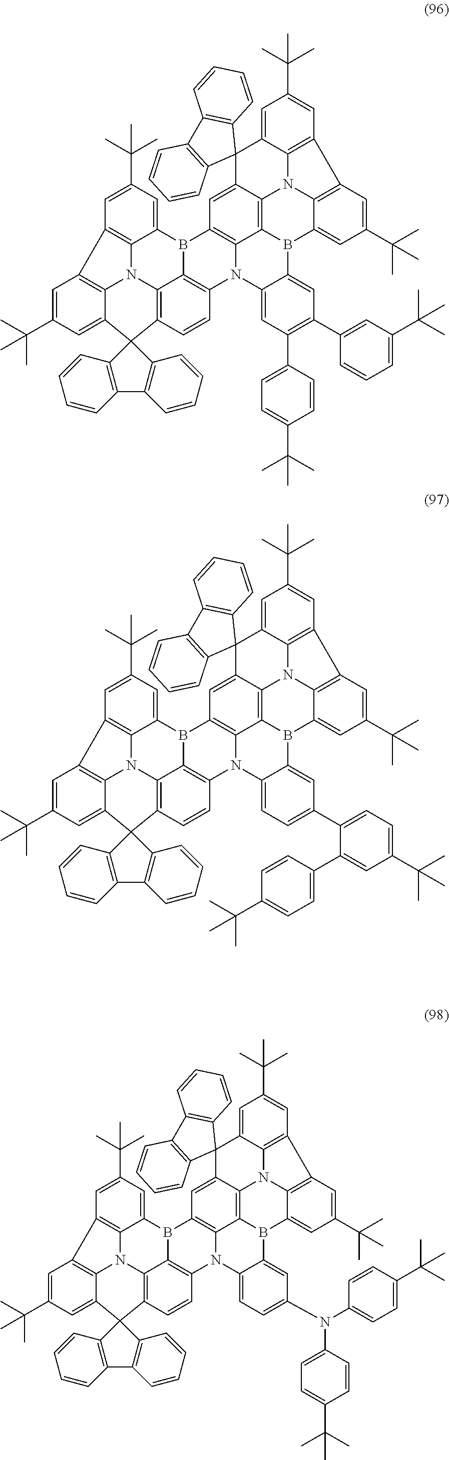

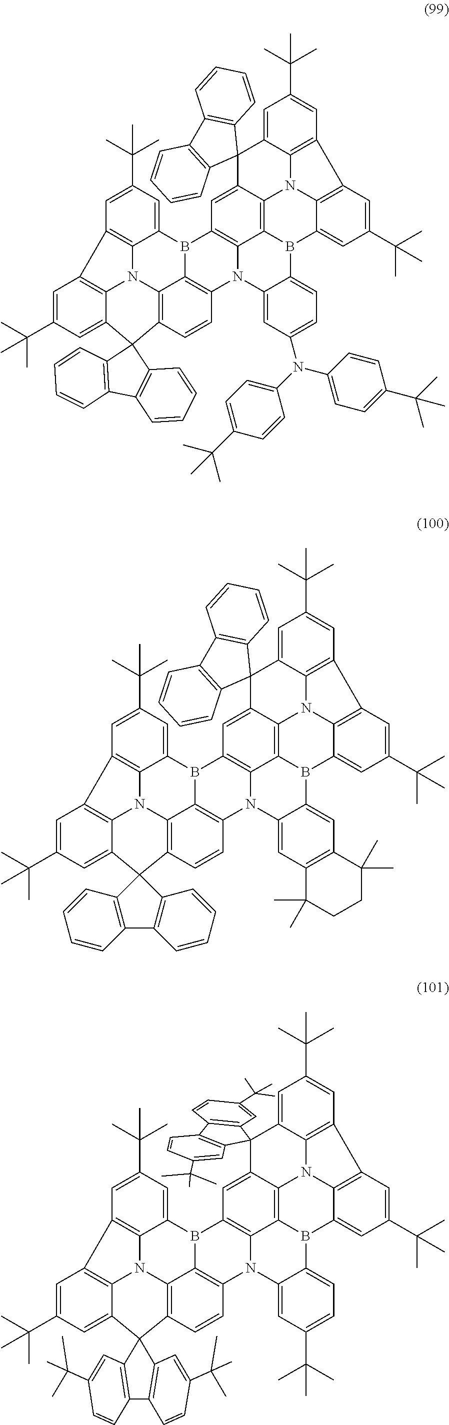

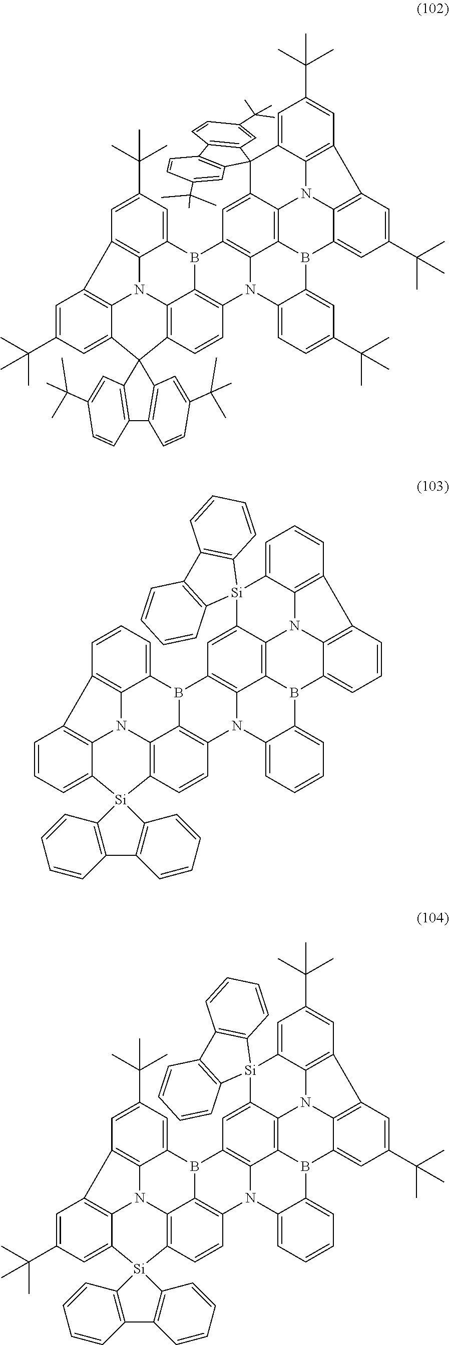

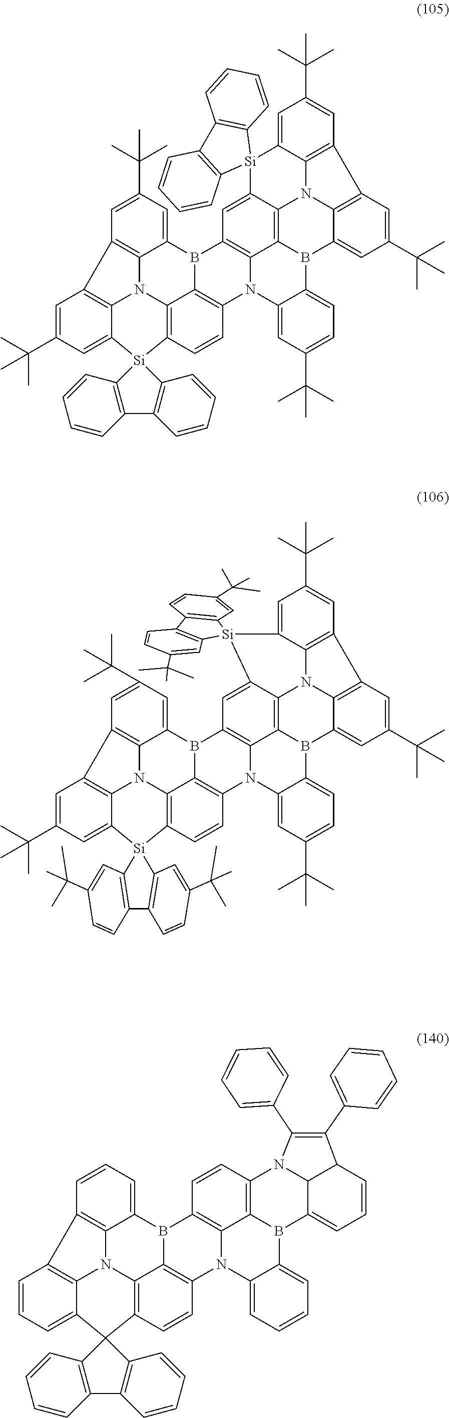

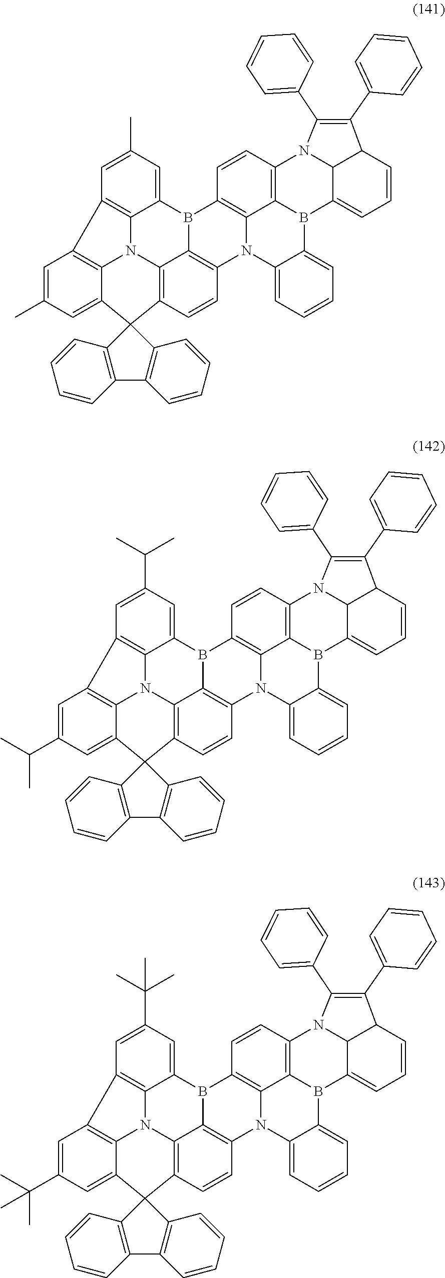 [SMILES: Cc1cc2c3c(c1)c1cc(C)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CC(C)c1cc2c3c(c1)c1cc(C(C)C)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CC(C)(C)c1cc2c3c(c1)c1cc(C(C)(C)C)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21]

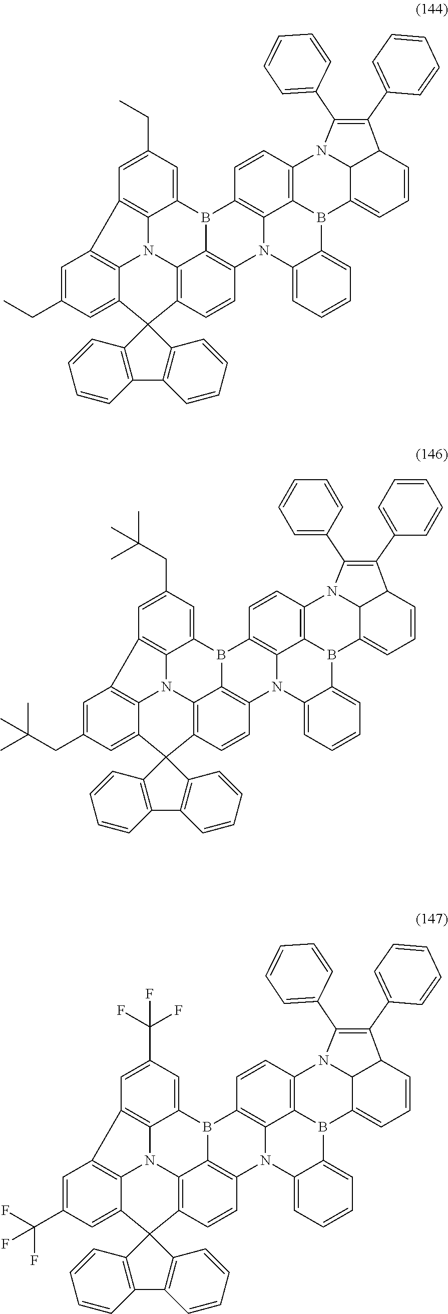 [SMILES: CCc1cc2c3c(c1)c1cc(CC)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CC(C)(C)Cc1cc2c3c(c1)c1cc(CC(C)(C)C)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; FC(F)(F)c1cc2c3c(c1)c1cc(C(F)(F)F)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21]

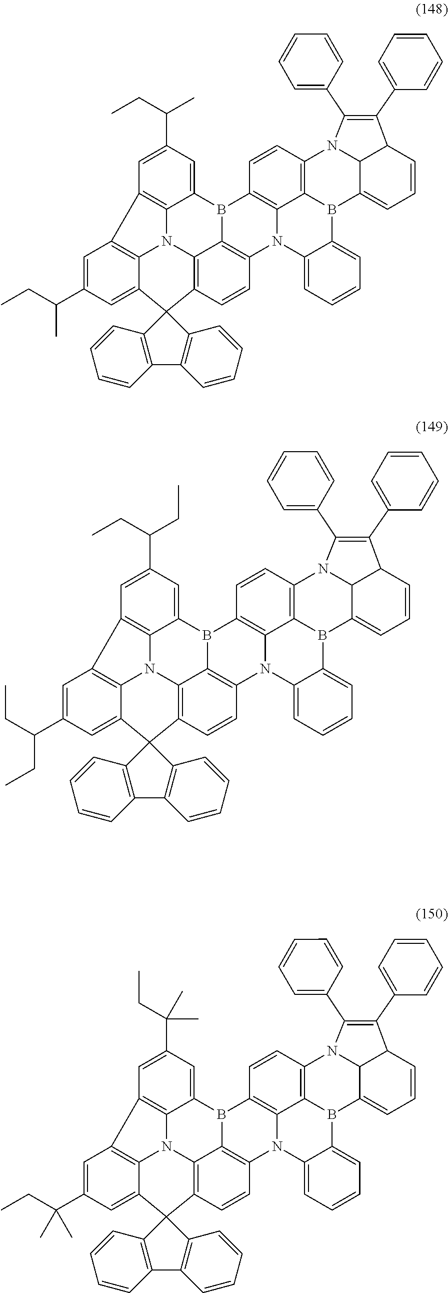 [SMILES: CCC(C)c1cc2c3c(c1)c1cc(C(C)CC)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CCC(CC)c1cc2c3c(c1)c1cc(C(CC)CC)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CCC(C)(C)c1cc2c3c(c1)c1cc(C(C)(C)CC)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21]

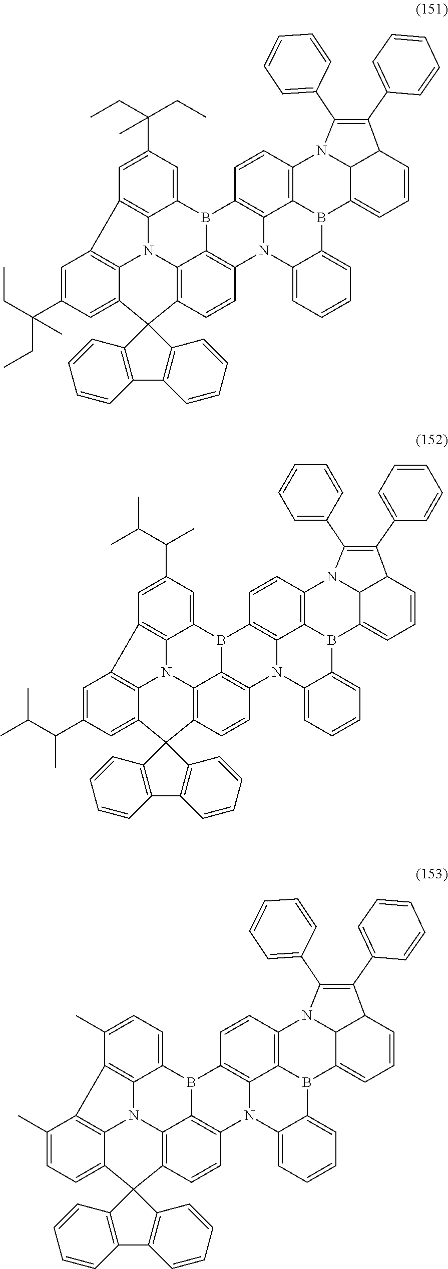 [SMILES: CCC(C)(CC)c1cc2c3c(c1)c1cc(C(C)(CC)CC)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CC(C)C(C)c1cc2c3c(c1)c1cc(C(C)C(C)C)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; Cc1ccc2c3c1c1c(C)ccc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21]

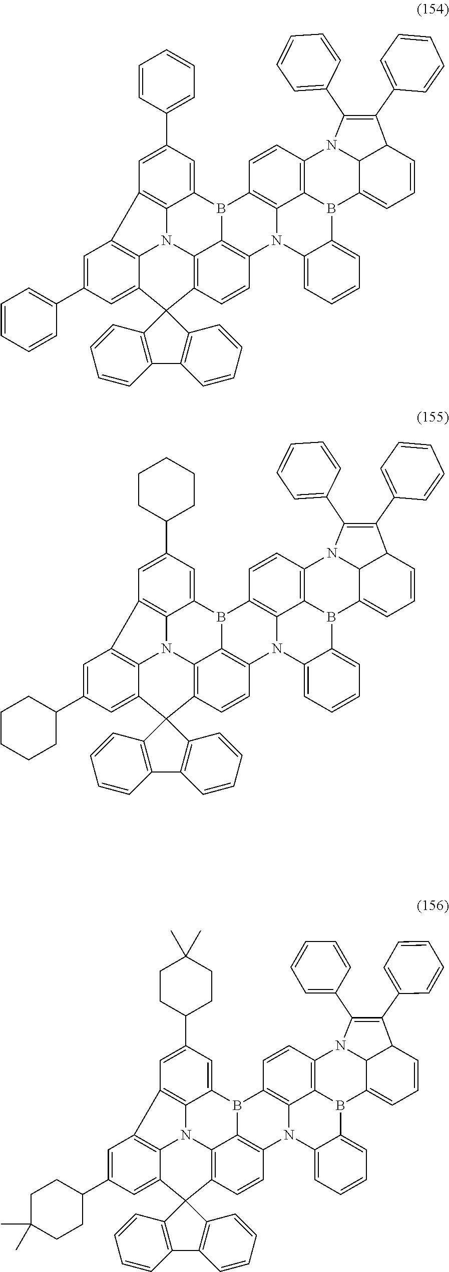 [SMILES: C1=CC2C(c3ccccc3)=C(c3ccccc3)N3c4ccc5c6c4B(C(=C1)C23)c1ccccc1N6c1ccc2c3c1B5c1cc(-c4ccccc4)cc4c5cc(-c6ccccc6)cc(c5n-3c14)C21c2ccccc2-c2ccccc21 ; C1=CC2C(c3ccccc3)=C(c3ccccc3)N3c4ccc5c6c4B(C(=C1)C23)c1ccccc1N6c1ccc2c3c1B5c1cc(C4CCCCC4)cc4c5cc(C6CCCCC6)cc(c5n-3c14)C21c2ccccc2-c2ccccc21 ; CC1(C)CCC(c2cc3c4c(c2)c2cc(C5CCC(C)(C)CC5)cc5c2n4-c2c(ccc4c2B3c2ccc3c6c2N4c2ccccc2B6C2=CC=CC4C(c6ccccc6)=C(c6ccccc6)N3C24)C52c3ccccc3-c3ccccc32)CC1]

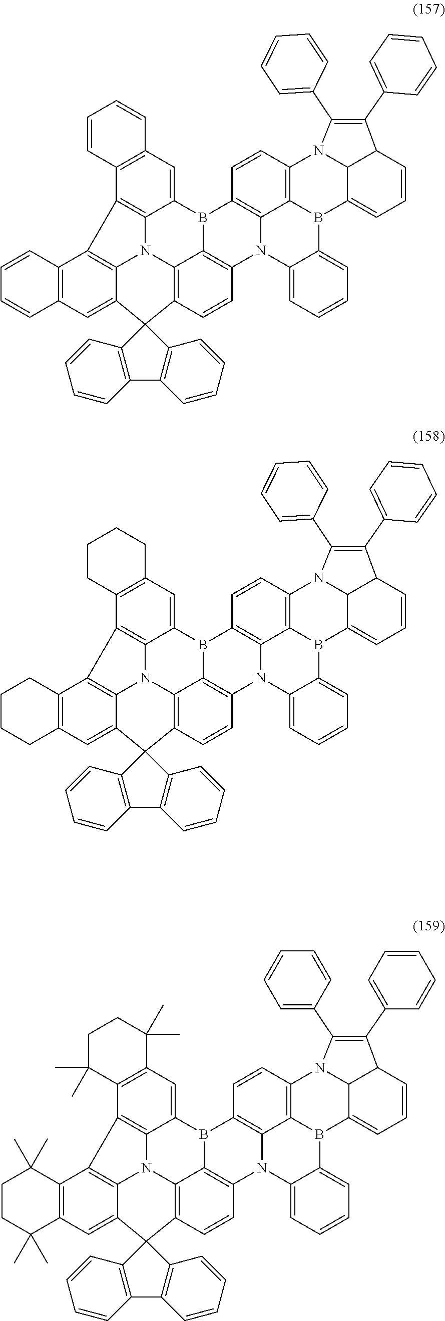 [SMILES: C1=CC2C(c3ccccc3)=C(c3ccccc3)N3c4ccc5c6c4B(C(=C1)C23)c1ccccc1N6c1ccc2c3c1B5c1cc4ccccc4c4c5c6ccccc6cc(c5n-3c14)C21c2ccccc2-c2ccccc21 ; C1=CC2C(c3ccccc3)=C(c3ccccc3)N3c4ccc5c6c4B(C(=C1)C23)c1ccccc1N6c1ccc2c3c1B5c1cc4c(c5c6c7c(cc(c6n-3c15)C21c2ccccc2-c2ccccc21)CCCC7)CCCC4 ; CC1(C)CCC(C)(C)c2c1cc1c3c2c2c4c(cc5c2n3-c2c(ccc3c2B1c1ccc2c6c1N3c1ccccc1B6C1=CC=CC3C(c6ccccc6)=C(c6ccccc6)N2C13)C51c2ccccc2-c2ccccc21)C(C)(C)CCC4(C)C]

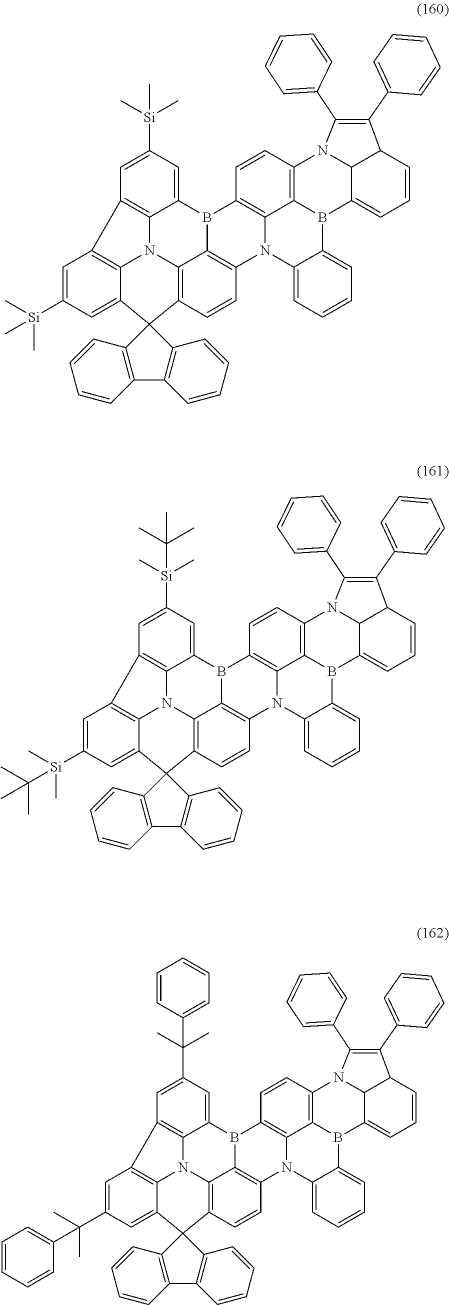 [SMILES: C[Si](C)(C)c1cc2c3c(c1)c1cc([Si](C)(C)C)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CC(C)(C)[Si](C)(C)c1cc2c3c(c1)c1cc([Si](C)(C)C(C)(C)C)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21 ; CC(C)(c1ccccc1)c1cc2c3c(c1)c1cc(C(C)(C)c4ccccc4)cc4c1n3-c1c(ccc3c1B2c1ccc2c5c1N3c1ccccc1B5C1=CC=CC3C(c5ccccc5)=C(c5ccccc5)N2C13)C41c2ccccc2-c2ccccc21]

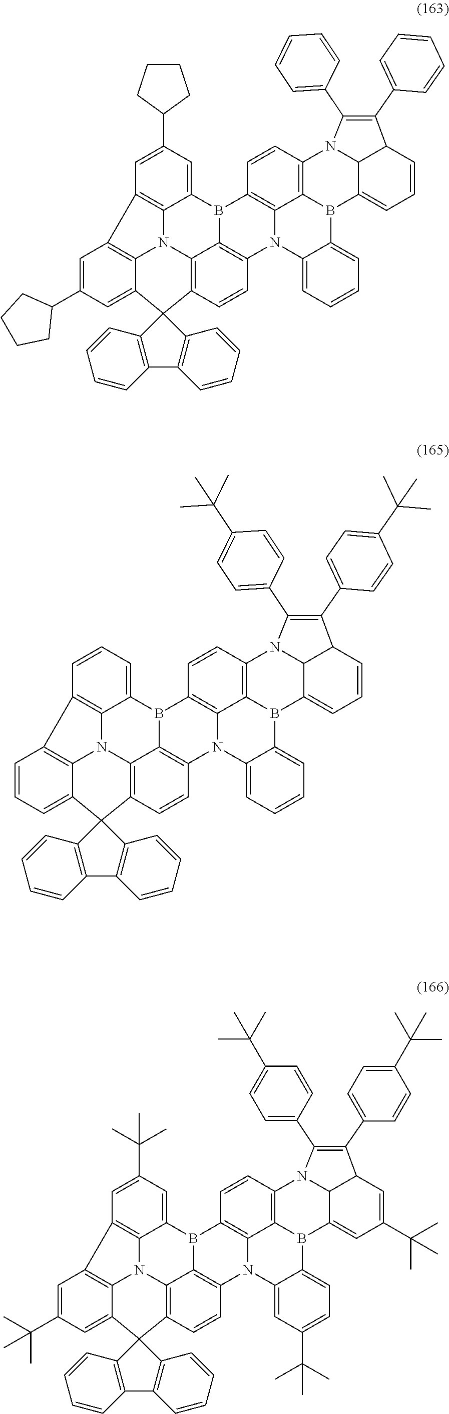

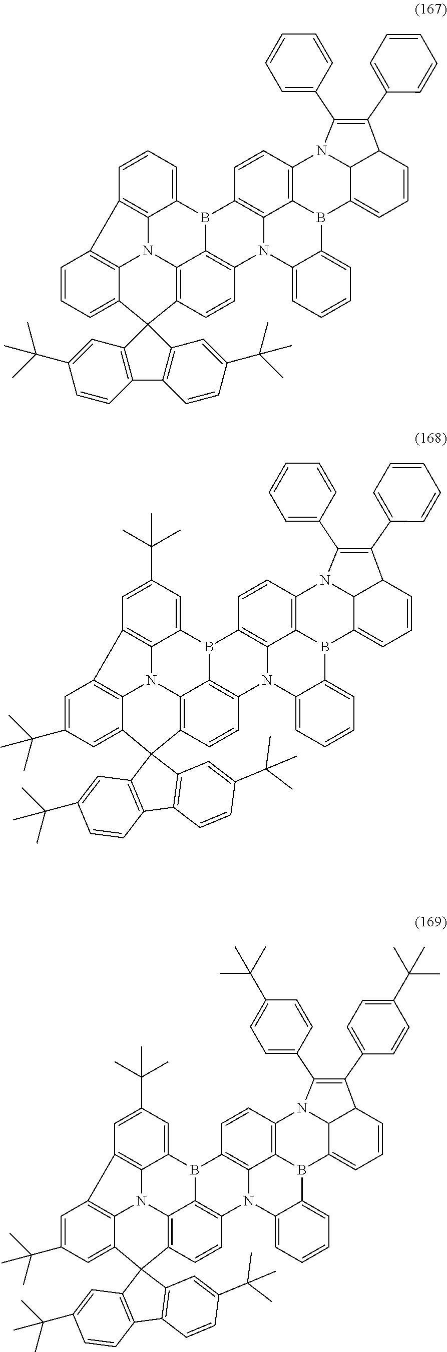 [SMILES: CC(C)(C)c1ccc2c(c1)C1(c3cc(C(C)(C)C)ccc3-2)c2ccc3c4c2-n2c5c(cccc5c5cccc1c52)B4c1ccc2c4c1N3c1ccccc1B4C1=CC=CC3C(c4ccccc4)=C(c4ccccc4)N2C13 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1ccc2c4c1N3c1ccccc1B4C1=CC=CC3C(c4ccccc4)=C(c4ccccc4)N2C13 ; CC(C)(C)c1ccc(C2=C(c3ccc(C(C)(C)C)cc3)N3c4ccc5c6c4B(C4=CC=CC2C43)c2ccccc2N6c2ccc3c4c2B5c2cc(C(C)(C)C)cc5c6cc(C(C)(C)C)cc(c6n-4c25)C32c3cc(C(C)(C)C)ccc3-c3ccc(C(C)(C)C)cc32)cc1]

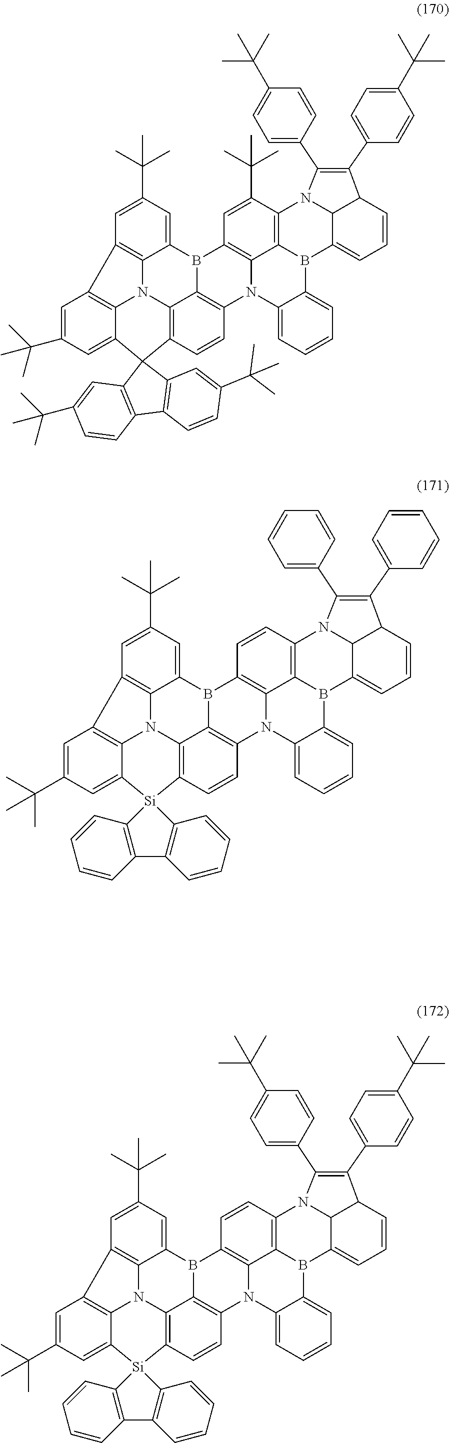

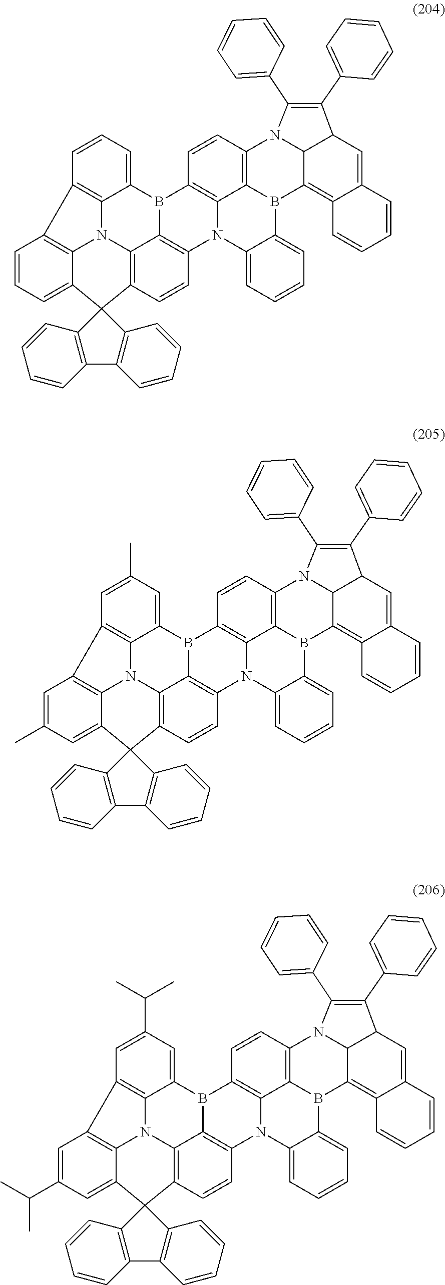 [SMILES: C1=c2ccccc2=C2B3c4ccccc4N4c5ccc6c7c5B(c5ccc(c3c54)N3C(c4ccccc4)=C(c4ccccc4)C1C23)c1cccc2c3cccc(c3n-7c12)C61c2ccccc2-c2ccccc21 ; Cc1cc2c3c(c1)c1cc(C)cc4c1n3-c1c(ccc3c1B2c1ccc2c5c1N3c1ccccc1B5C1=c3ccccc3=CC3C(c5ccccc5)=C(c5ccccc5)N2C13)C41c2ccccc2-c2ccccc21 ; CC(C)c1cc2c3c(c1)c1cc(C(C)C)cc4c1n3-c1c(ccc3c1B2c1ccc2c5c1N3c1ccccc1B5C1=c3ccccc3=CC3C(c5ccccc5)=C(c5ccccc5)N2C13)C41c2ccccc2-c2ccccc21]

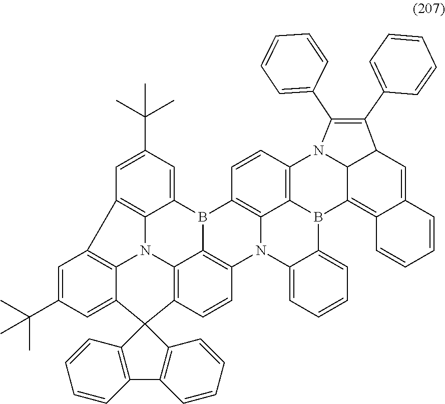 [SMILES: CC(C)(C)c1cc2c3c(c1)c1cc(C(C)(C)C)cc4c1n3-c1c(ccc3c1B2c1ccc2c5c1N3c1ccccc1B5C1=c3ccccc3=CC3C(c5ccccc5)=C(c5ccccc5)N2C13)C41c2ccccc2-c2ccccc21]

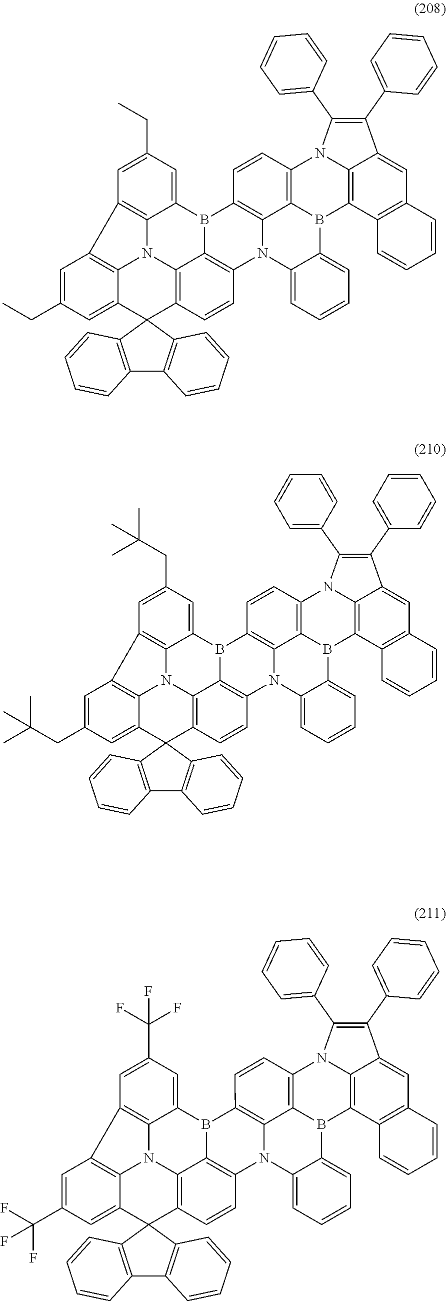 [SMILES: CCc1cc2c3c(c1)c1cc(CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CC(C)(C)Cc1cc2c3c(c1)c1cc(CC(C)(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; FC(F)(F)c1cc2c3c(c1)c1cc(C(F)(F)F)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

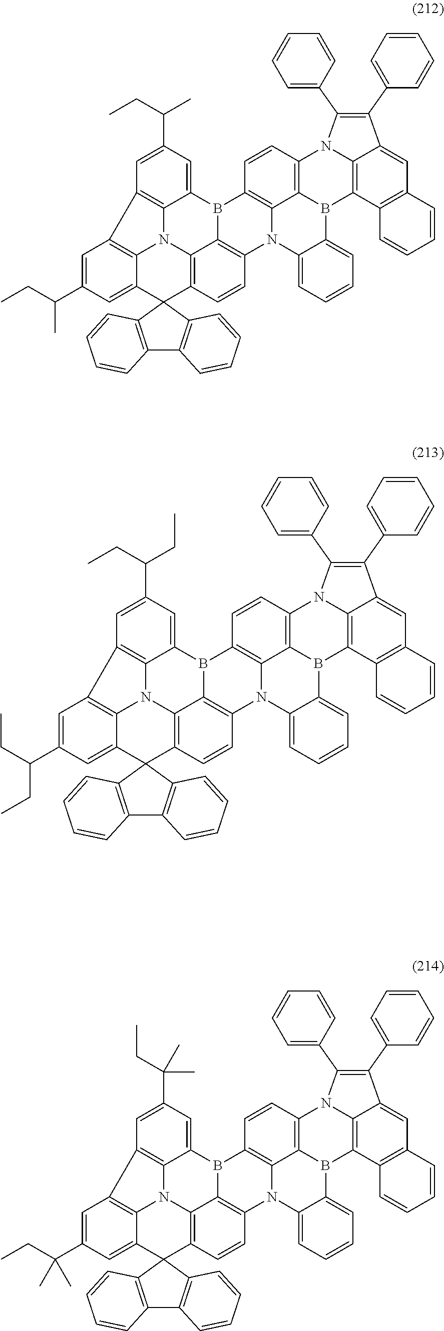 [SMILES: CCC(C)c1cc2c3c(c1)c1cc(C(C)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CCC(CC)c1cc2c3c(c1)c1cc(C(CC)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CCC(C)(C)c1cc2c3c(c1)c1cc(C(C)(C)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

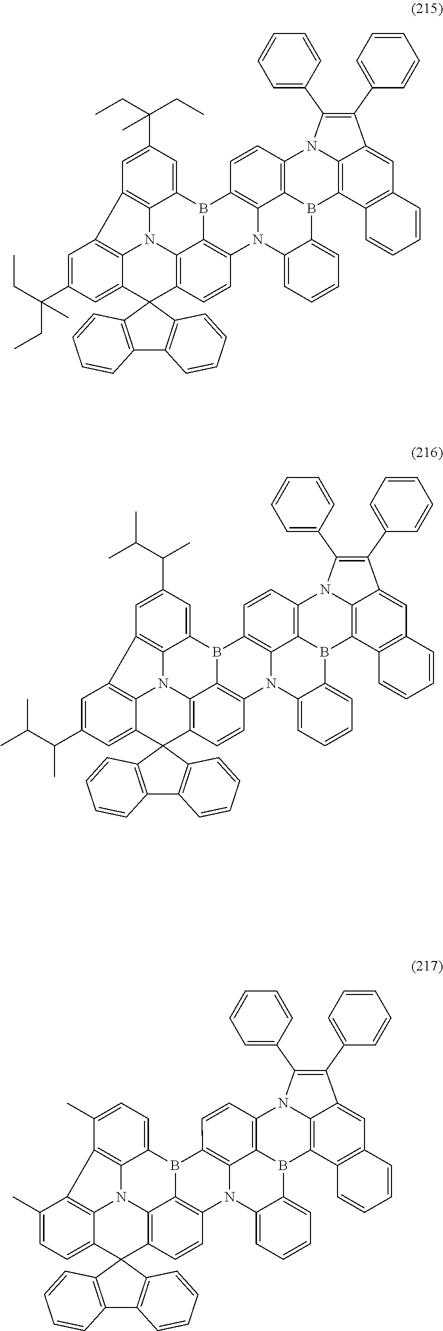 [SMILES: CCC(C)(CC)c1cc2c3c(c1)c1cc(C(C)(CC)CC)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CC(C)C(C)c1cc2c3c(c1)c1cc(C(C)C(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; Cc1ccc2c3c1c1c(C)ccc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

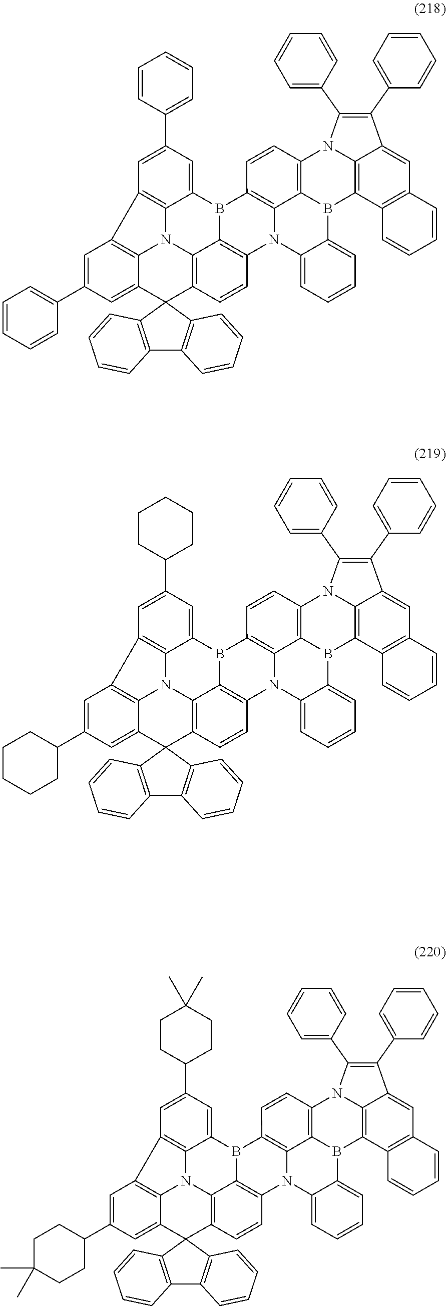 [SMILES: c1ccc(-c2cc3c4c(c2)c2cc(-c5ccccc5)cc5c2n4-c2c(ccc4c2B3c2ccc3c6c2N4c2ccccc2B6c2c4ccccc4cc4c(-c6ccccc6)c(-c6ccccc6)n-3c24)C52c3ccccc3-c3ccccc32)cc1 ; c1ccc(-c2c(-c3ccccc3)n3c4c(c5ccccc5cc24)B2c4ccccc4N4c5ccc6c7c5B(c5ccc-3c2c54)c2cc(C3CCCCC3)cc3c4cc(C5CCCCC5)cc(c4n-7c23)C62c3ccccc3-c3ccccc32)cc1 ; CC1(C)CCC(c2cc3c4c(c2)c2cc(C5CCC(C)(C)CC5)cc5c2n4-c2c(ccc4c2B3c2ccc3c6c2N4c2ccccc2B6c2c4ccccc4cc4c(-c6ccccc6)c(-c6ccccc6)n-3c24)C52c3ccccc3-c3ccccc32)CC1]

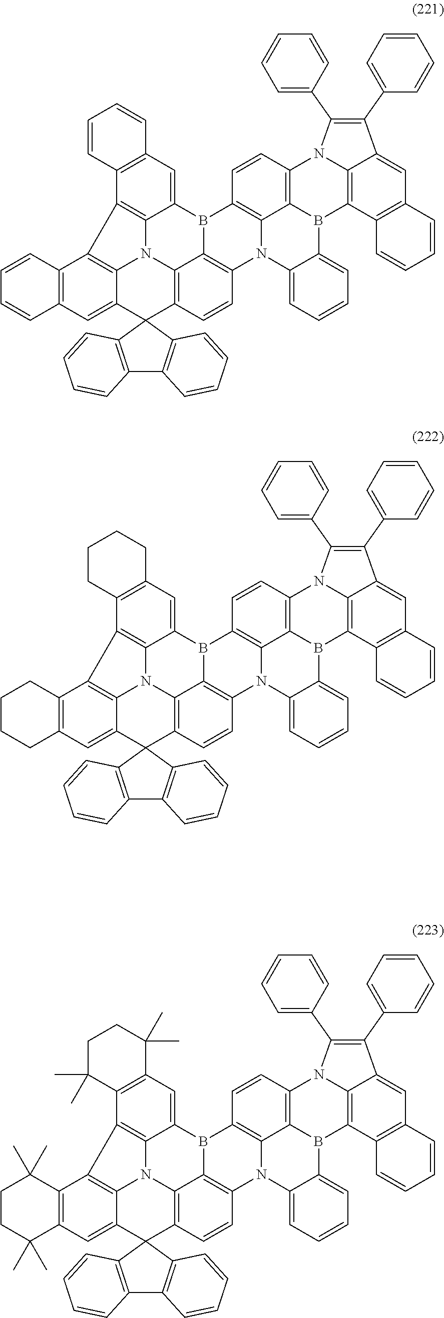 [SMILES: c1ccc(-c2c(-c3ccccc3)n3c4c(c5ccccc5cc24)B2c4ccccc4N4c5ccc6c7c5B(c5ccc-3c2c54)c2cc3ccccc3c3c4c5ccccc5cc(c4n-7c23)C62c3ccccc3-c3ccccc32)cc1 ; c1ccc(-c2c(-c3ccccc3)n3c4c(c5ccccc5cc24)B2c4ccccc4N4c5ccc6c7c5B(c5ccc-3c2c54)c2cc3c(c4c5c8c(cc(c5n-7c24)C62c4ccccc4-c4ccccc42)CCCC8)CCCC3)cc1 ; CC1(C)CCC(C)(C)c2c1cc1c3c2c2c4c(cc5c2n3-c2c(ccc3c2B1c1ccc2c6c1N3c1ccccc1B6c1c3ccccc3cc3c(-c6ccccc6)c(-c6ccccc6)n-2c13)C51c2ccccc2-c2ccccc21)C(C)(C)CCC4(C)C]

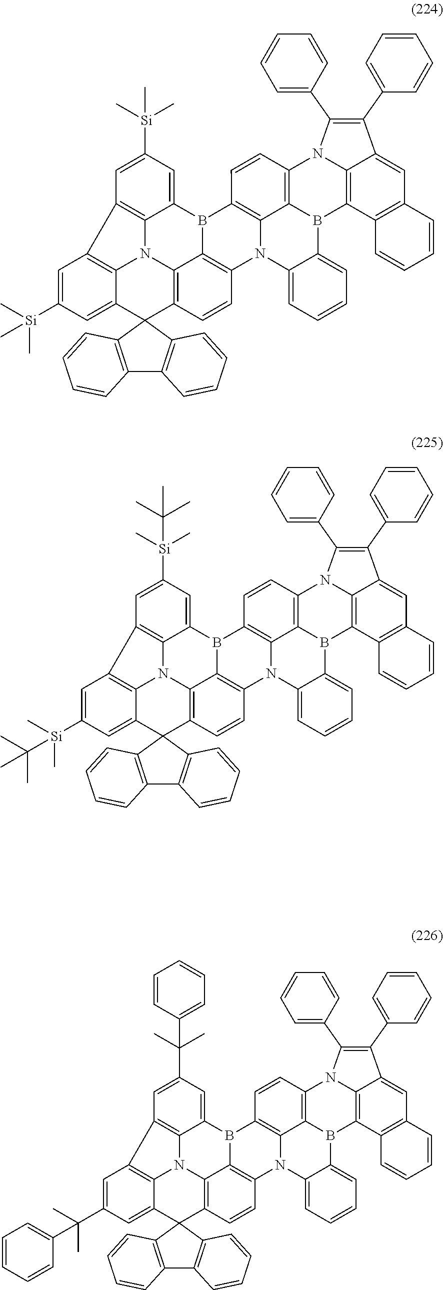 [SMILES: C[Si](C)(C)c1cc2c3c(c1)c1cc([Si](C)(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CC(C)(C)[Si](C)(C)c1cc2c3c(c1)c1cc([Si](C)(C)C(C)(C)C)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21 ; CC(C)(c1ccccc1)c1cc2c3c(c1)c1cc(C(C)(C)c4ccccc4)cc4c1n3-c1c(ccc3c1B2c1ccc2c5c1N3c1ccccc1B5c1c3ccccc3cc3c(-c5ccccc5)c(-c5ccccc5)n-2c13)C41c2ccccc2-c2ccccc21]

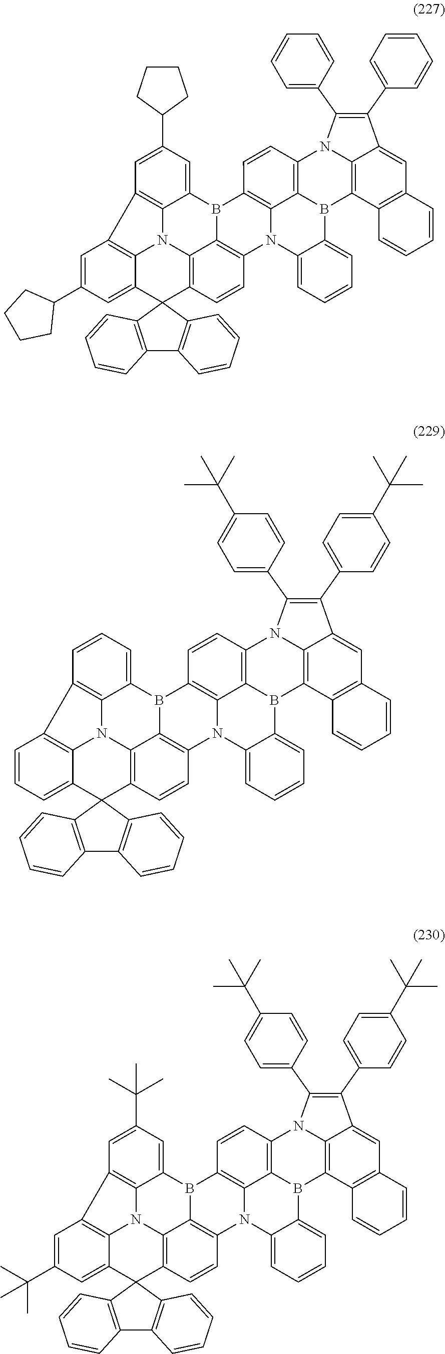

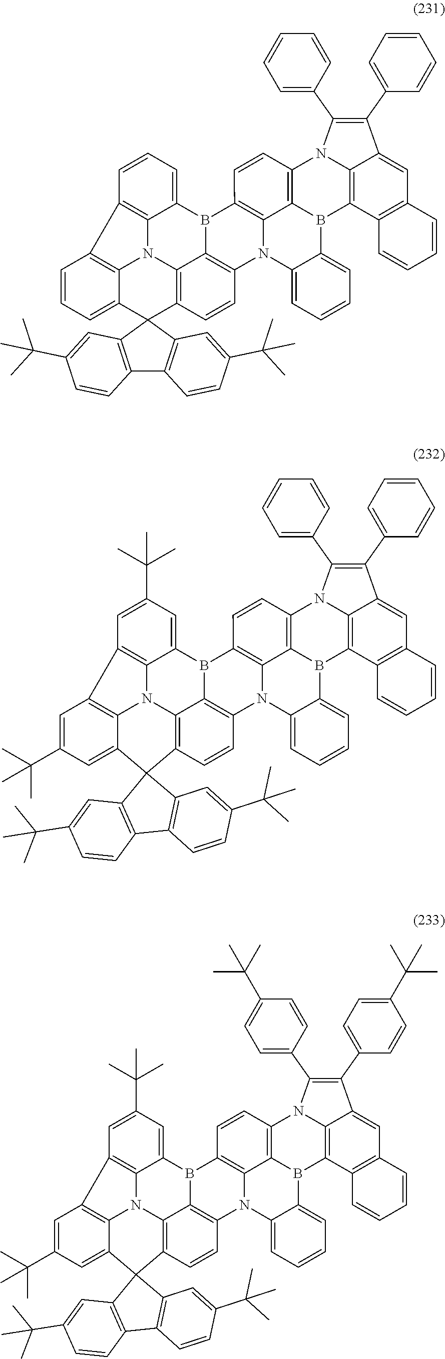

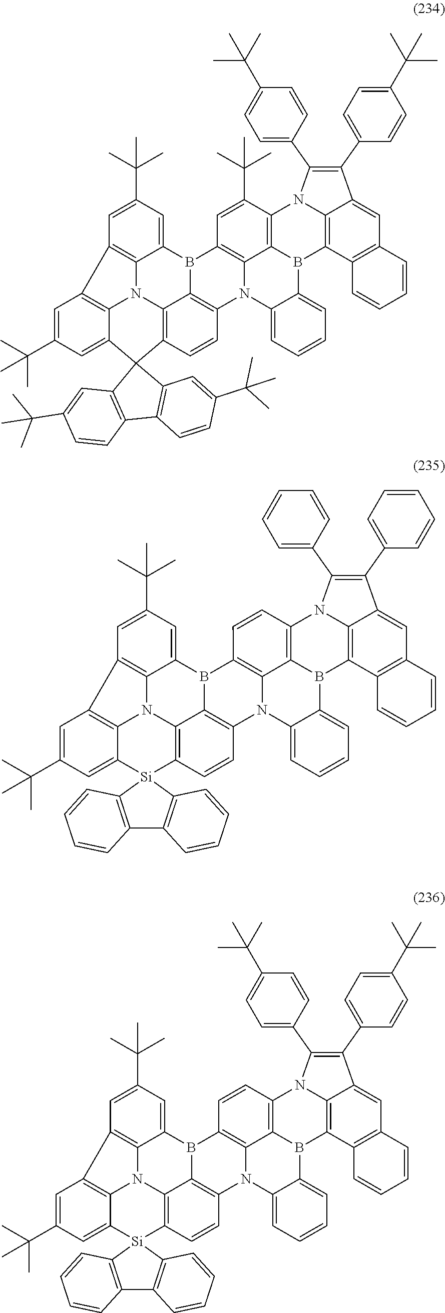

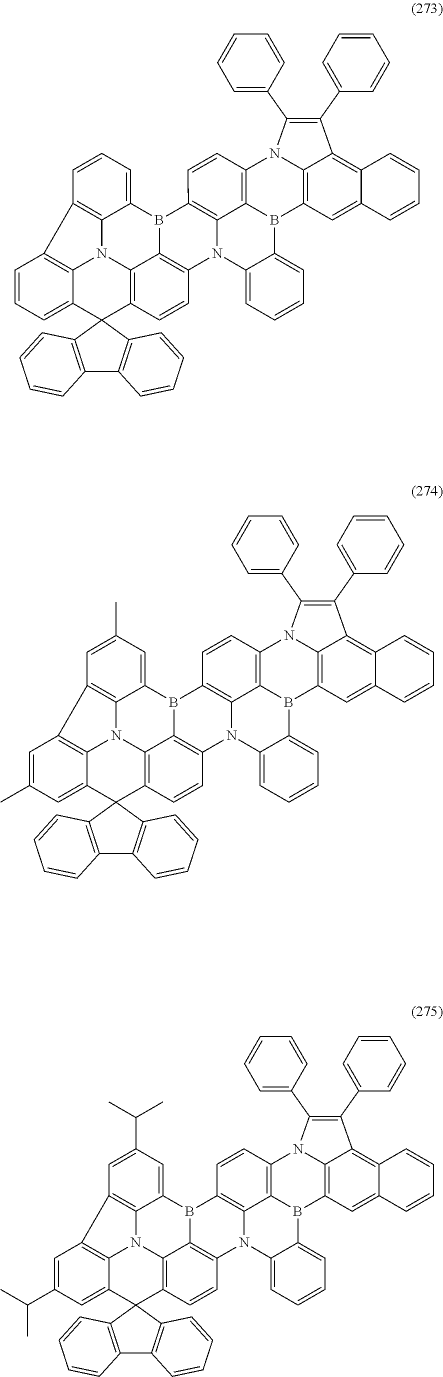 [SMILES: c1ccc(-c2c(-c3ccccc3)n3c4c(cc5ccccc5c24)B2c4ccccc4N4c5ccc6c7c5B(c5ccc-3c2c54)c2cccc3c4cccc(c4n-7c23)C62c3ccccc3-c3ccccc32)cc1 ; Cc1cc2c3c(c1)c1cc(C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CC(C)c1cc2c3c(c1)c1cc(C(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21]

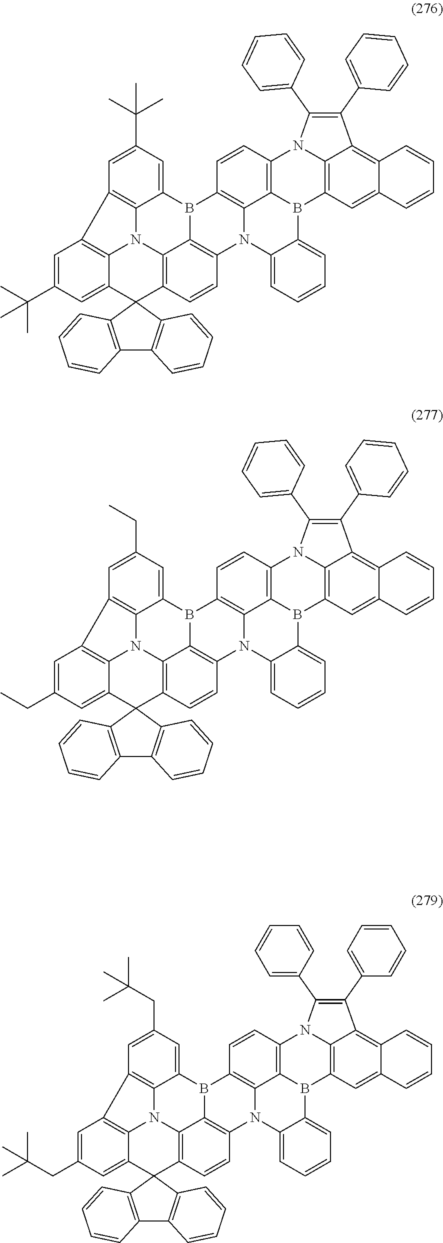 [SMILES: CC(C)(C)c1cc2c3c(c1)c1cc(C(C)(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CCc1cc2c3c(c1)c1cc(CC)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CC(C)(C)Cc1cc2c3c(c1)c1cc(CC(C)(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21]

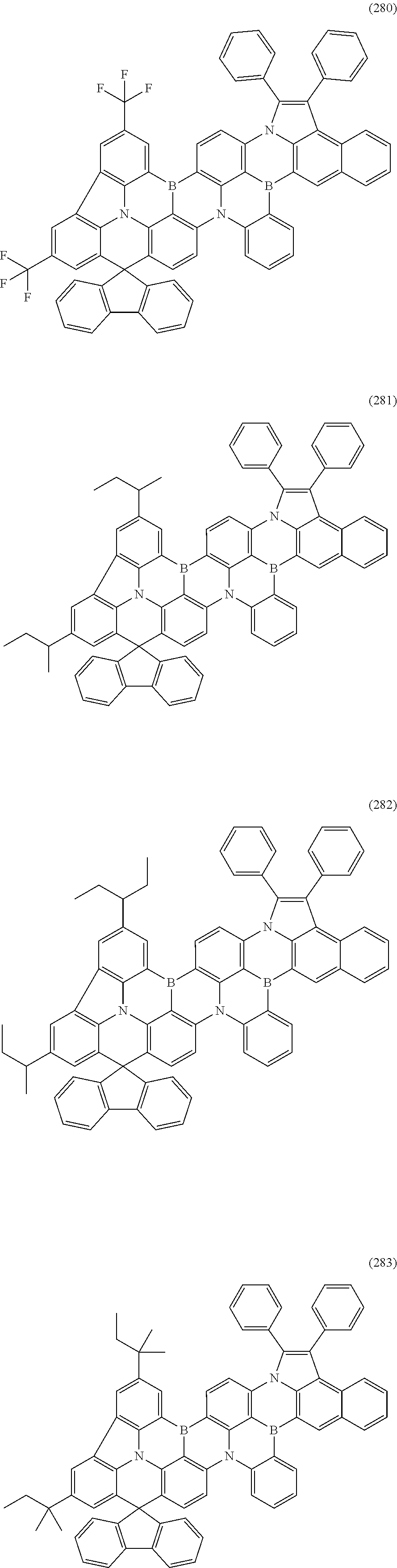

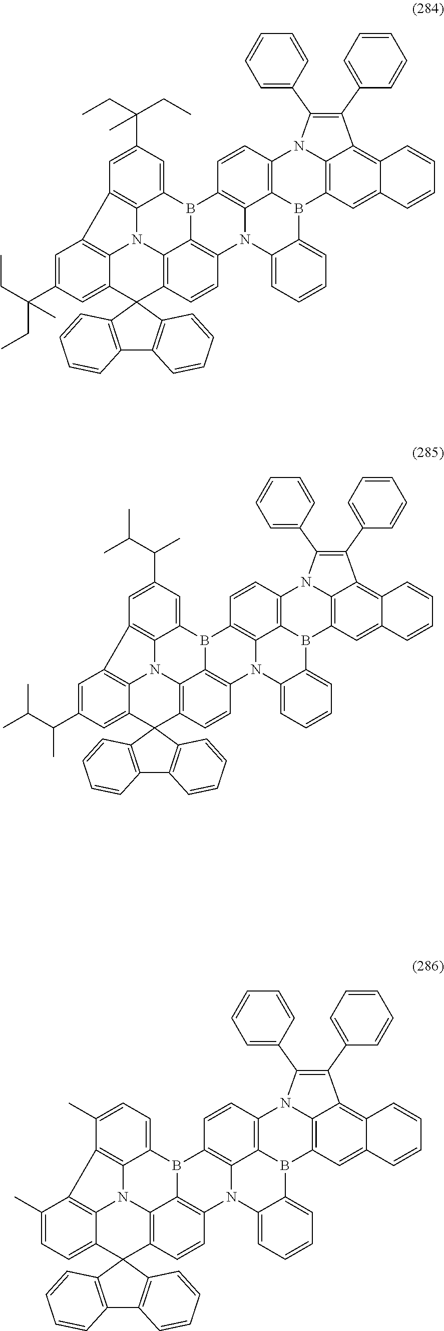 [SMILES: CCC(C)(CC)c1cc2c3c(c1)c1cc(C(C)(CC)CC)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CC(C)C(C)c1cc2c3c(c1)c1cc(C(C)C(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; Cc1ccc2c3c1c1c(C)ccc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21]

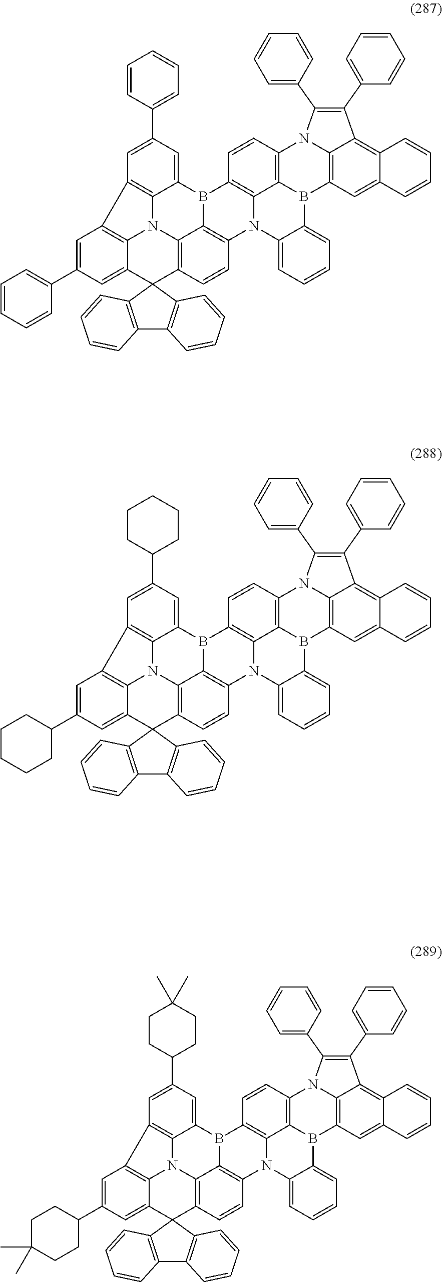 [SMILES: c1ccc(-c2cc3c4c(c2)c2cc(-c5ccccc5)cc5c2n4-c2c(ccc4c2B3c2ccc3c6c2N4c2ccccc2B6c2cc4ccccc4c4c(-c6ccccc6)c(-c6ccccc6)n-3c24)C52c3ccccc3-c3ccccc32)cc1 ; c1ccc(-c2c(-c3ccccc3)n3c4c(cc5ccccc5c24)B2c4ccccc4N4c5ccc6c7c5B(c5ccc-3c2c54)c2cc(C3CCCCC3)cc3c4cc(C5CCCCC5)cc(c4n-7c23)C62c3ccccc3-c3ccccc32)cc1 ; CC1(C)CCC(c2cc3c4c(c2)c2cc(C5CCC(C)(C)CC5)cc5c2n4-c2c(ccc4c2B3c2ccc3c6c2N4c2ccccc2B6c2cc4ccccc4c4c(-c6ccccc6)c(-c6ccccc6)n-3c24)C52c3ccccc3-c3ccccc32)CC1]

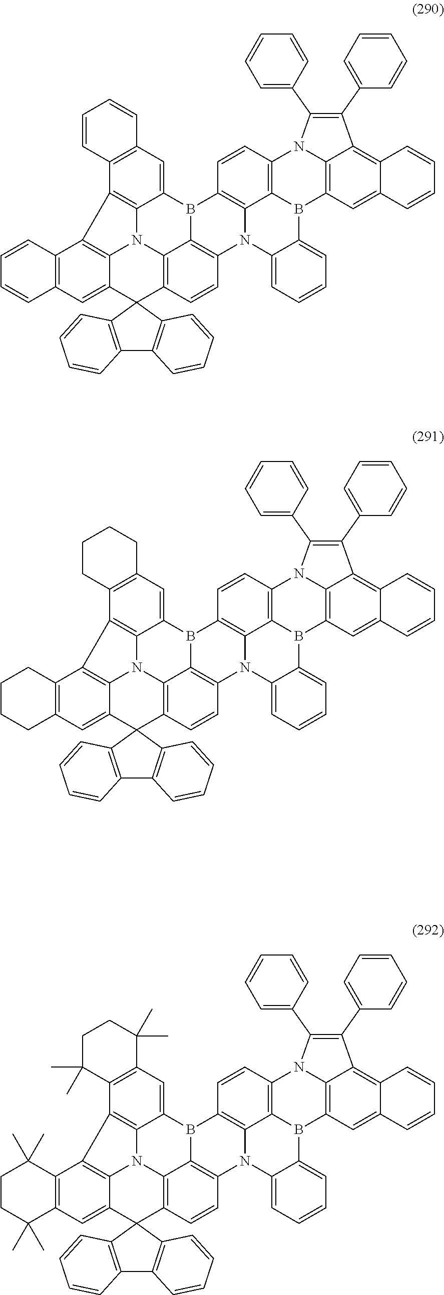 [SMILES: c1ccc(-c2c(-c3ccccc3)n3c4c(cc5ccccc5c24)B2c4ccccc4N4c5ccc6c7c5B(c5ccc-3c2c54)c2cc3ccccc3c3c4c5ccccc5cc(c4n-7c23)C62c3ccccc3-c3ccccc32)cc1 ; c1ccc(-c2c(-c3ccccc3)n3c4c(cc5ccccc5c24)B2c4ccccc4N4c5ccc6c7c5B(c5ccc-3c2c54)c2cc3c(c4c5c8c(cc(c5n-7c24)C62c4ccccc4-c4ccccc42)CCCC8)CCCC3)cc1 ; CC1(C)CCC(C)(C)c2c1cc1c3c2c2c4c(cc5c2n3-c2c(ccc3c2B1c1ccc2c6c1N3c1ccccc1B6c1cc3ccccc3c3c(-c6ccccc6)c(-c6ccccc6)n-2c13)C51c2ccccc2-c2ccccc21)C(C)(C)CCC4(C)C]

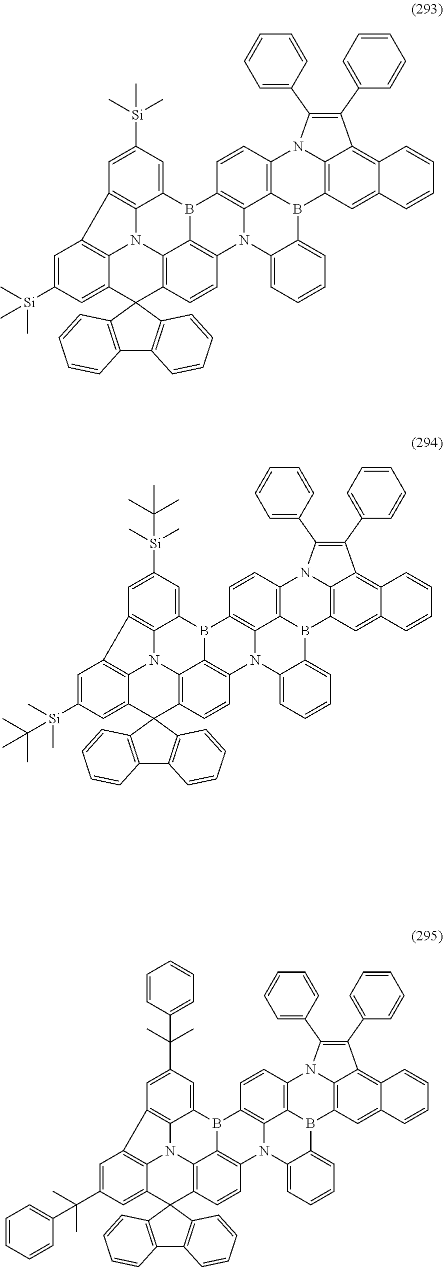 [SMILES: C[Si](C)(C)c1cc2c3c(c1)c1cc([Si](C)(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CC(C)(C)[Si](C)(C)c1cc2c3c(c1)c1cc([Si](C)(C)C(C)(C)C)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21 ; CC(C)(c1ccccc1)c1cc2c3c(c1)c1cc(C(C)(C)c4ccccc4)cc4c1n3-c1c(ccc3c1B2c1ccc2c5c1N3c1ccccc1B5c1cc3ccccc3c3c(-c5ccccc5)c(-c5ccccc5)n-2c13)C41c2ccccc2-c2ccccc21]

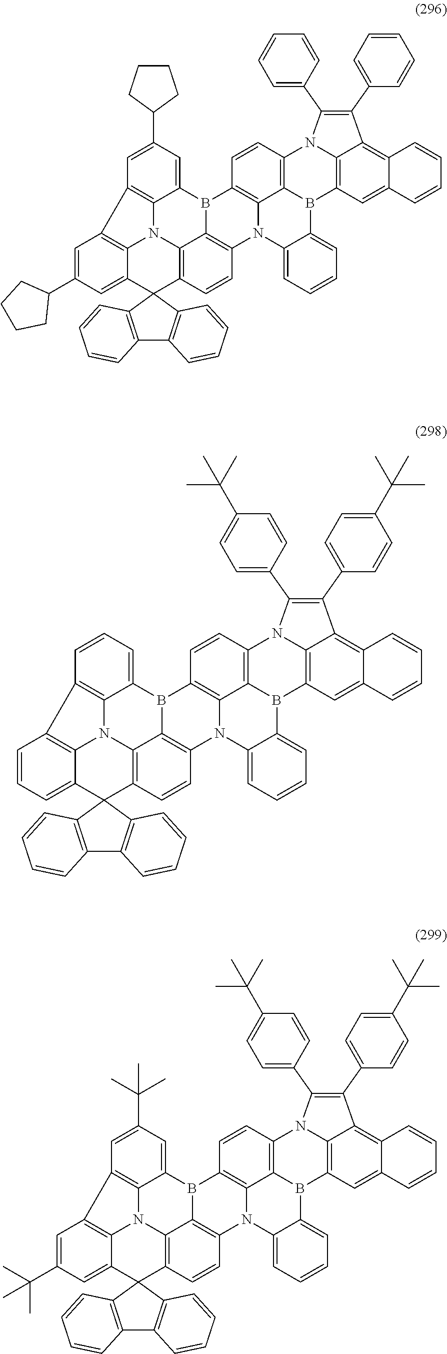

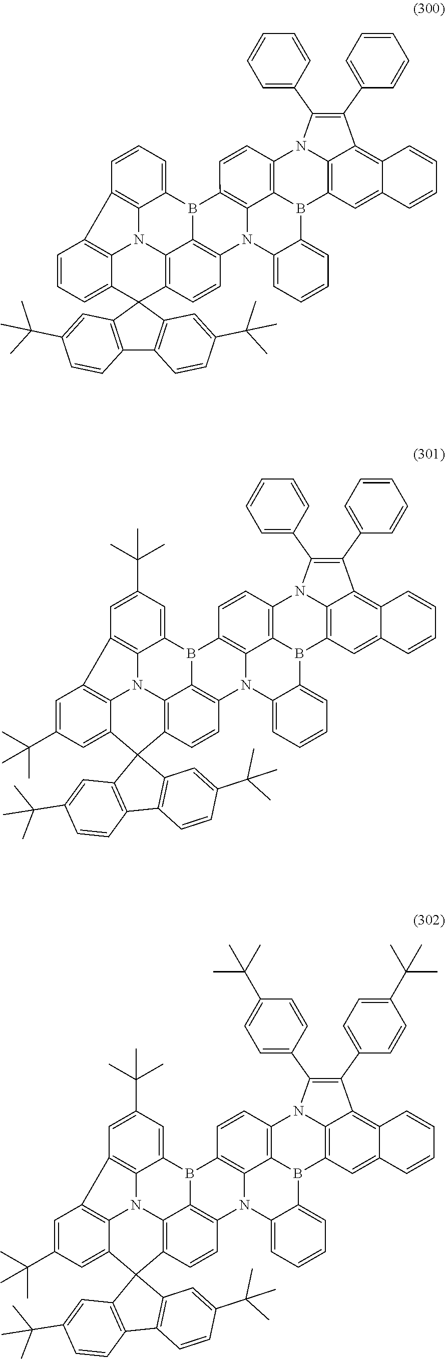

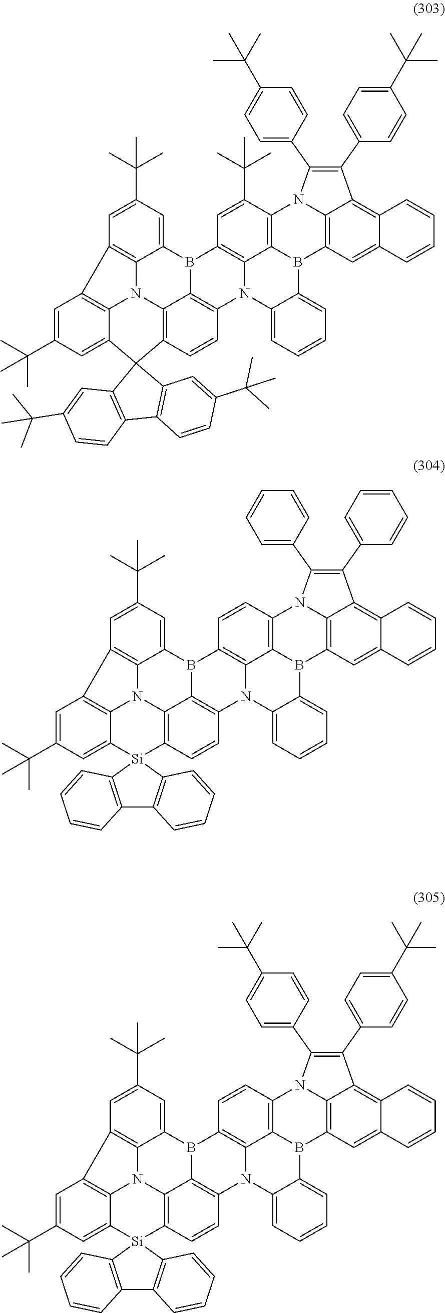

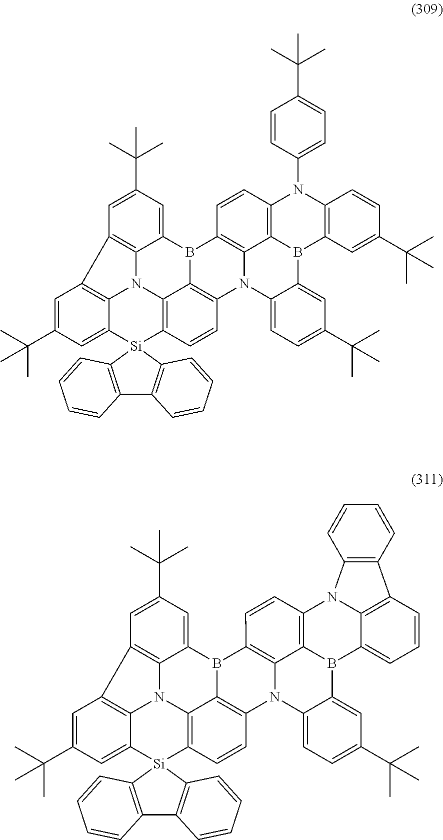

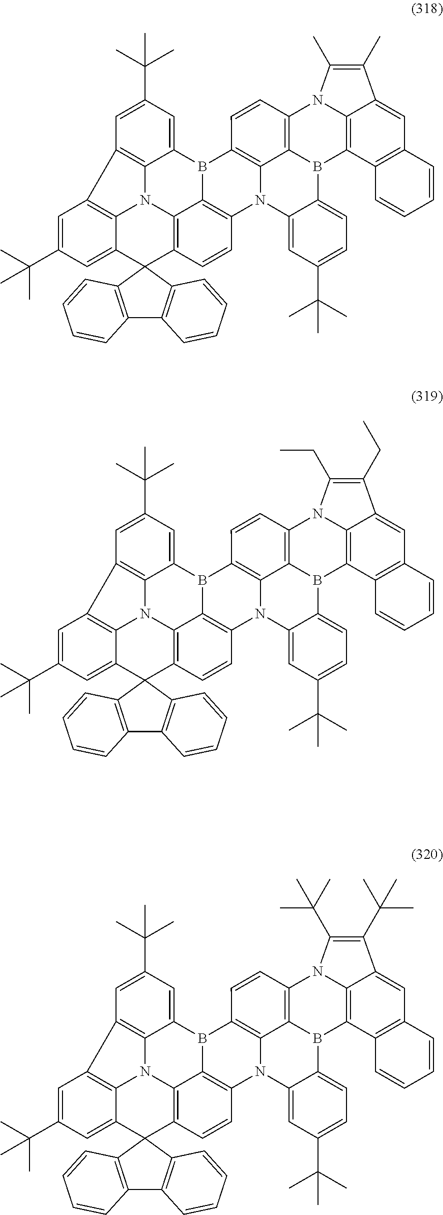 [SMILES: Cc1c(C)n2c3c(c4ccccc4cc13)B1c3ccc(C(C)(C)C)cc3N3c4ccc5c6c4B(c4ccc-2c1c43)c1cc(C(C)(C)C)cc2c3cc(C(C)(C)C)cc(c3n-6c12)C51c2ccccc2-c2ccccc21 ; CCc1c(CC)n2c3c(c4ccccc4cc13)B1c3ccc(C(C)(C)C)cc3N3c4ccc5c6c4B(c4ccc-2c1c43)c1cc(C(C)(C)C)cc2c3cc(C(C)(C)C)cc(c3n-6c12)C51c2ccccc2-c2ccccc21 ; CC(C)(C)c1ccc2c(c1)N1c3ccc4c5c3B(c3ccc6c(c31)B2c1c2ccccc2cc2c(C(C)(C)C)c(C(C)(C)C)n-6c12)c1cc(C(C)(C)C)cc2c3cc(C(C)(C)C)cc(c3n-5c12)C41c2ccccc2-c2ccccc21]

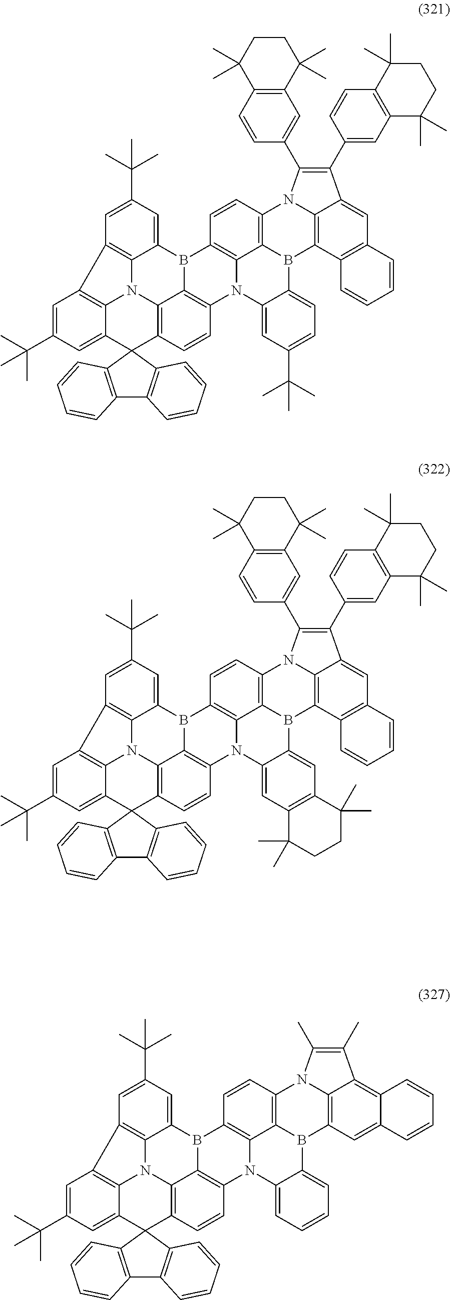

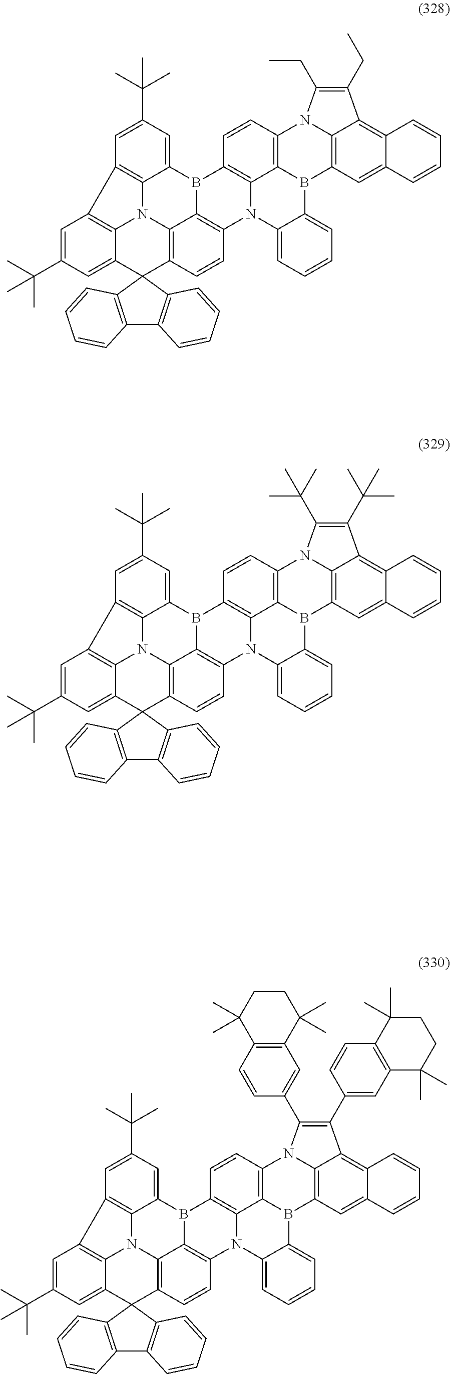 [SMILES: CCc1c(CC)n2c3c(cc4ccccc4c13)B1c3ccccc3N3c4ccc5c6c4B(c4ccc-2c1c43)c1cc(C(C)(C)C)cc2c3cc(C(C)(C)C)cc(c3n-6c12)C51c2ccccc2-c2ccccc21 ; CC(C)(C)c1cc2c3c(c1)c1cc(C(C)(C)C)cc4c1n3-c1c(ccc3c1B2c1ccc2c5c1N3c1ccccc1B5c1cc3ccccc3c3c(C(C)(C)C)c(C(C)(C)C)n-2c13)C41c2ccccc2-c2ccccc21 ; CC(C)(C)c1cc2c3c(c1)c1cc(C(C)(C)C)cc4c1n3-c1c(ccc3c1B2c1ccc2c5c1N3c1ccccc1B5c1cc3ccccc3c3c(-c5ccc6c(c5)C(C)(C)CCC6(C)C)c(-c5ccc6c(c5)C(C)(C)CCC6(C)C)n-2c13)C41c2ccccc2-c2ccccc21]

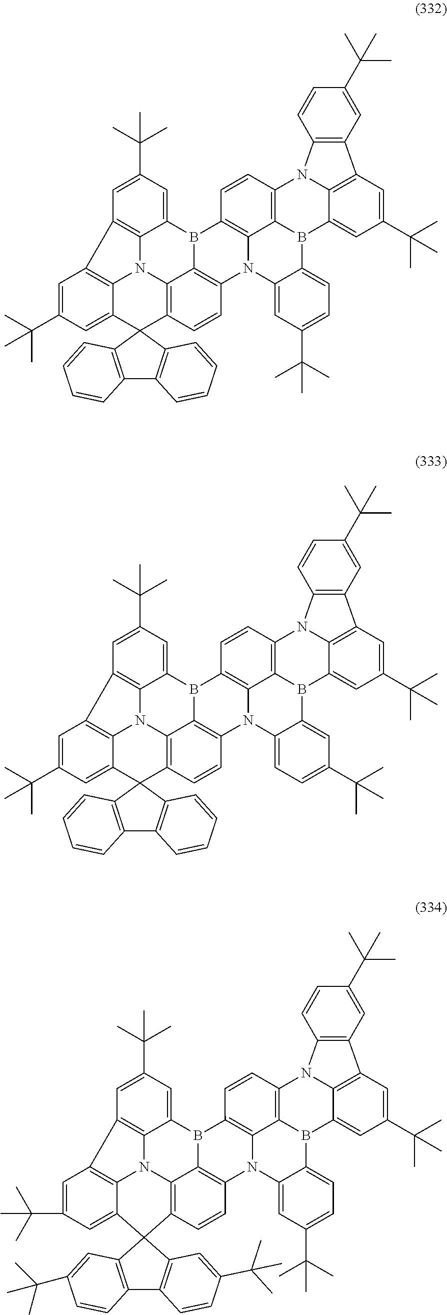

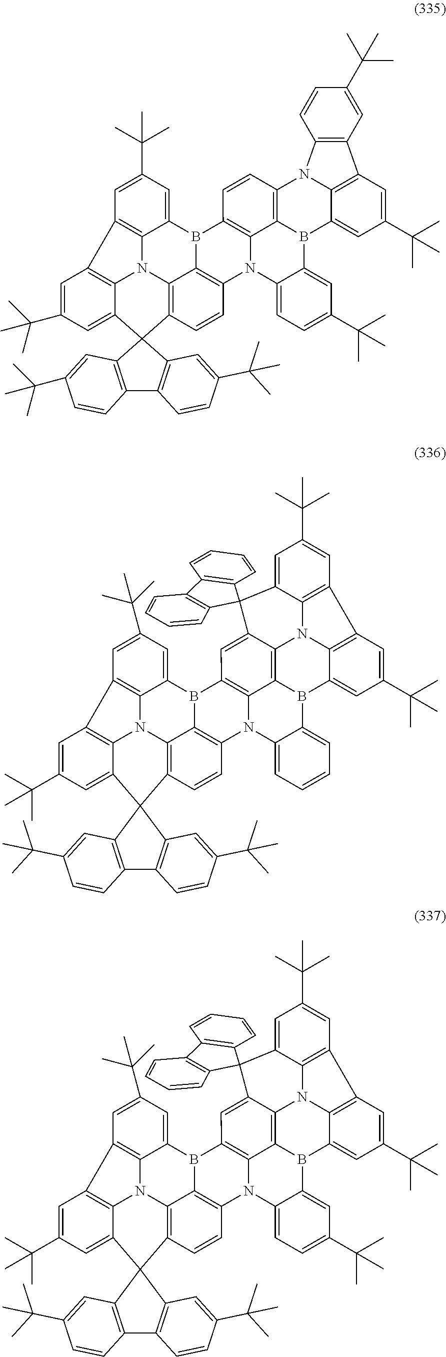

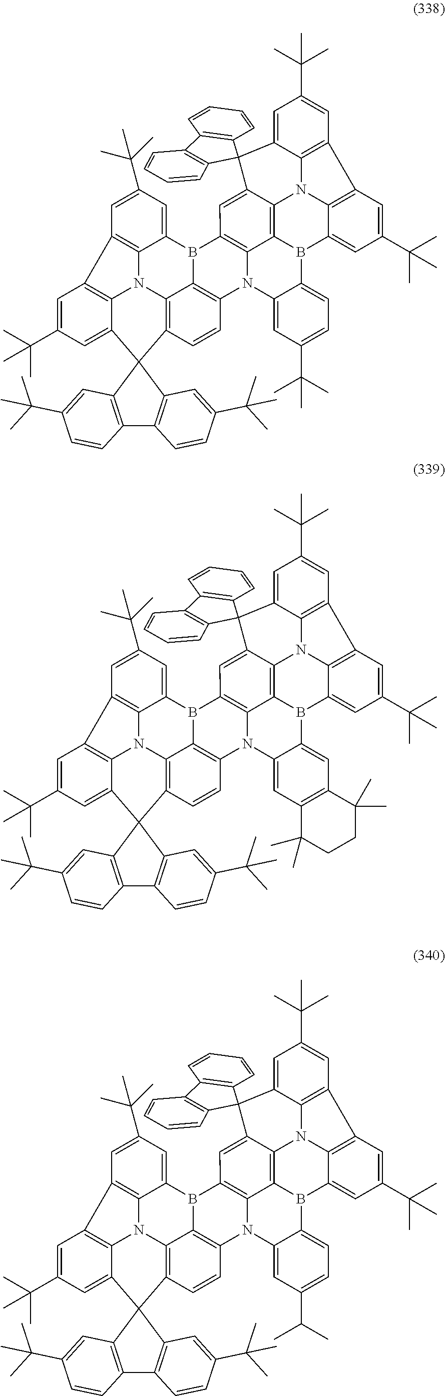

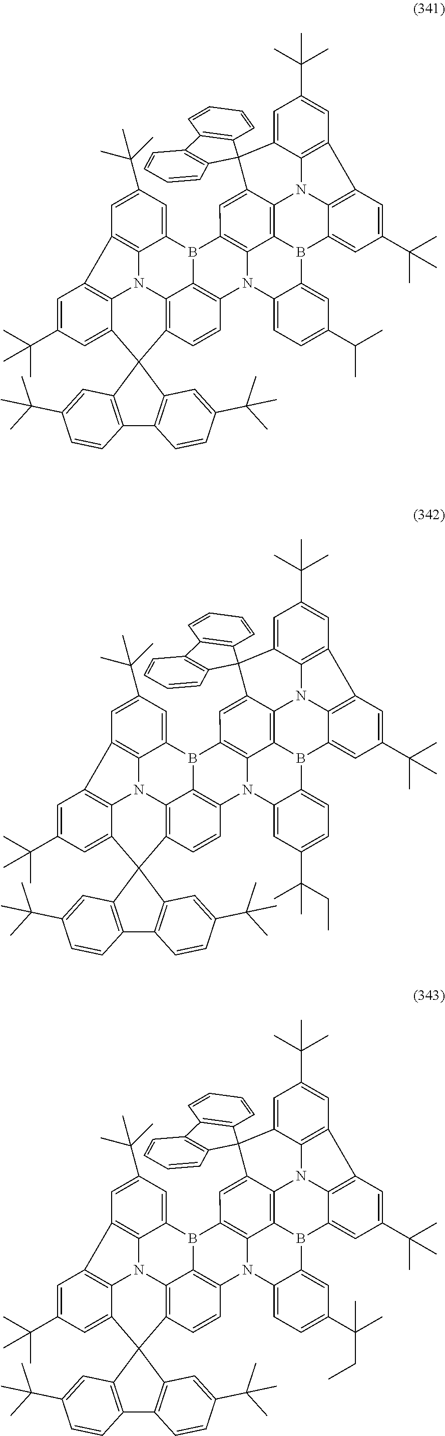

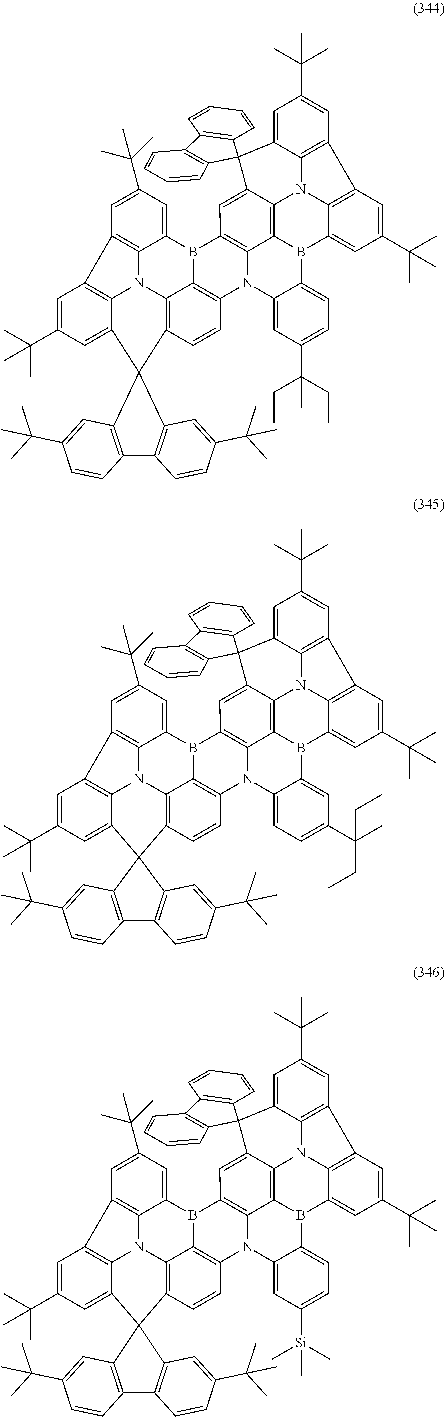

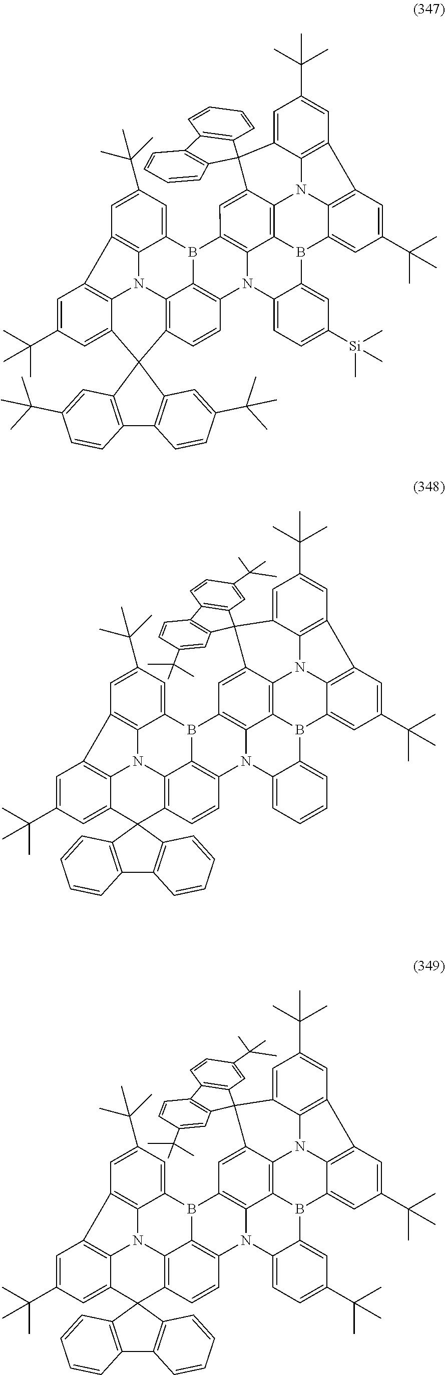

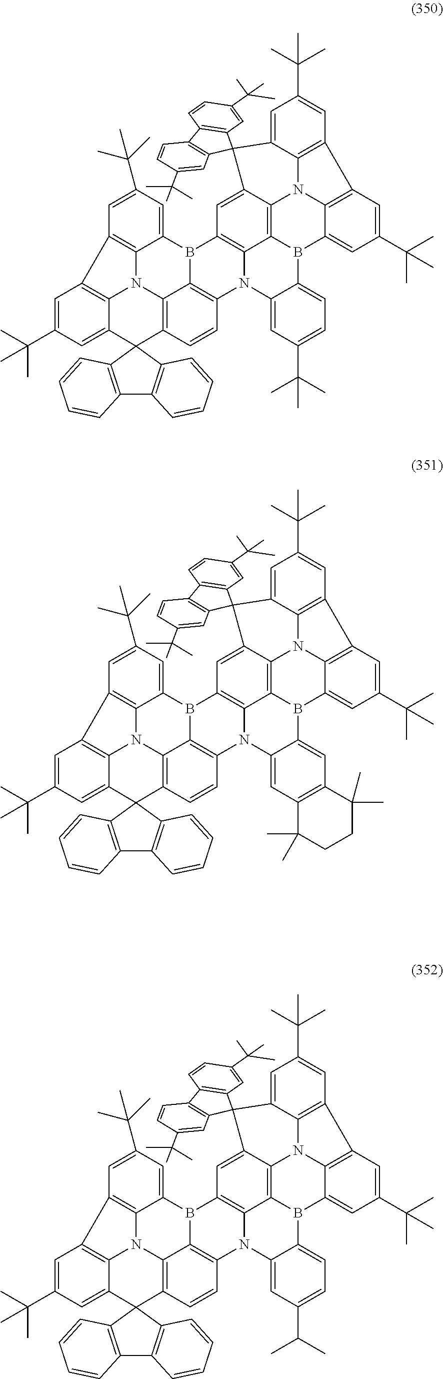

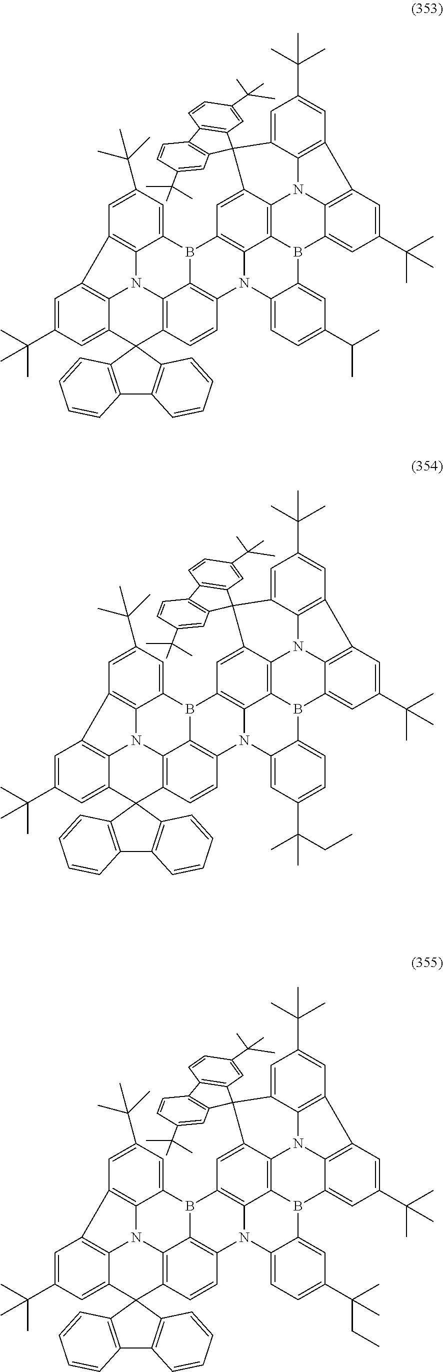

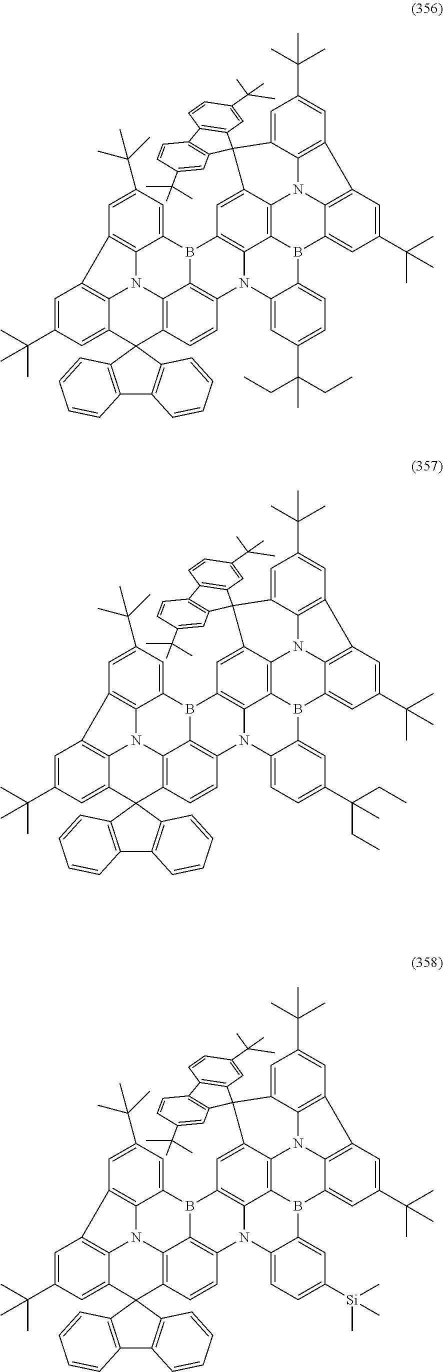

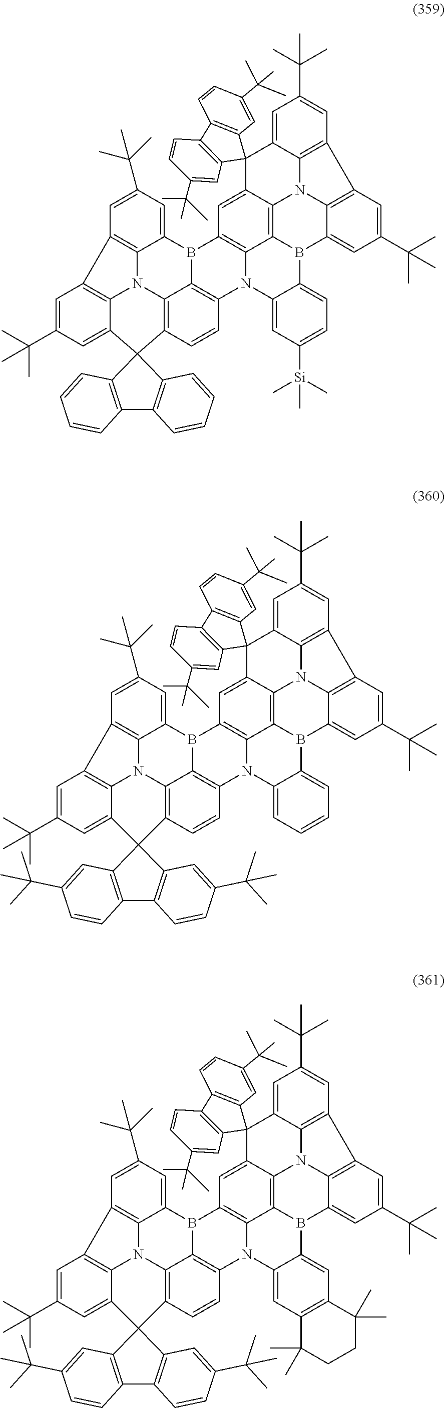

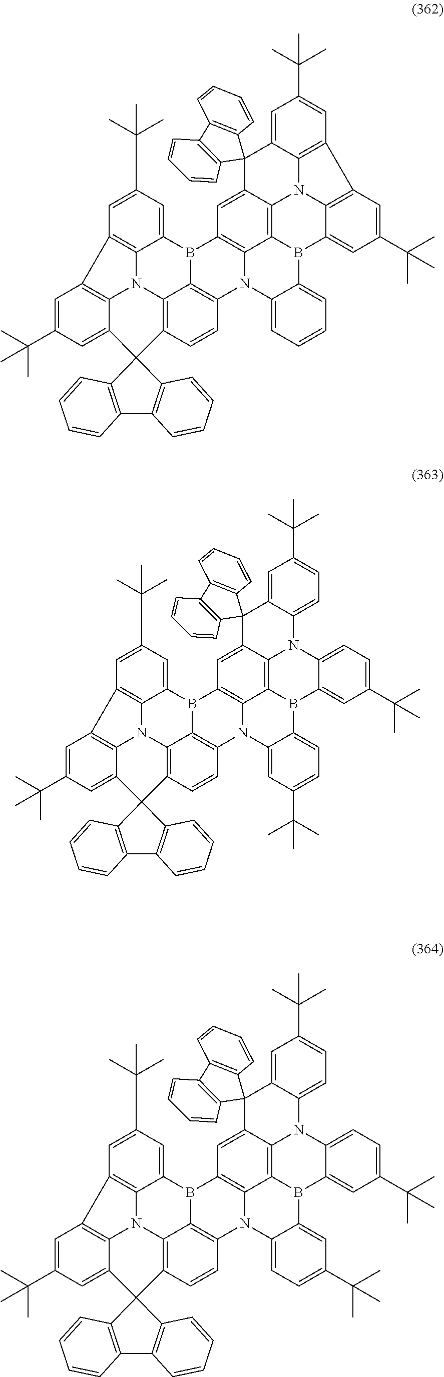

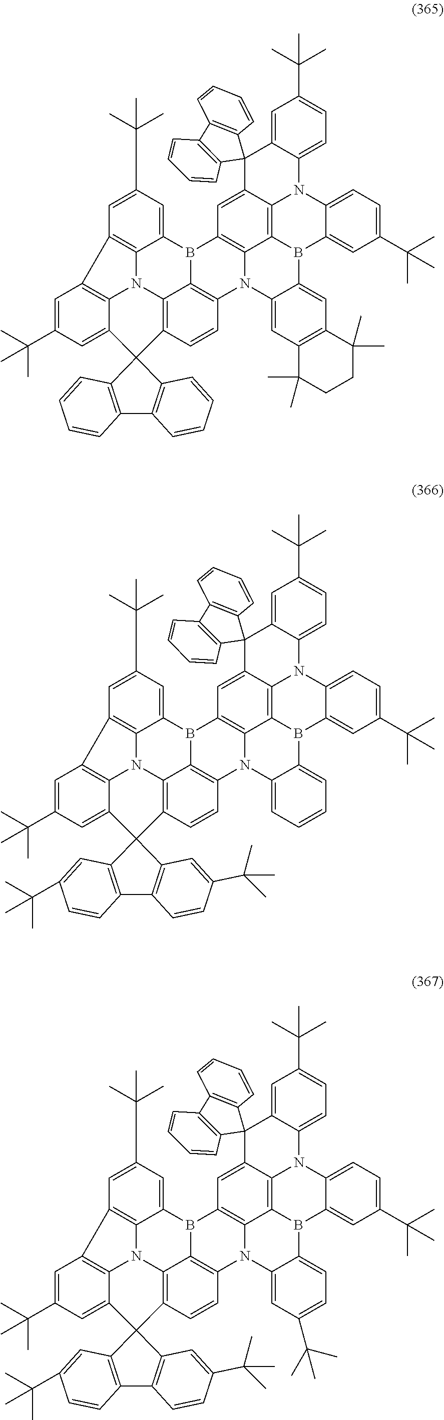

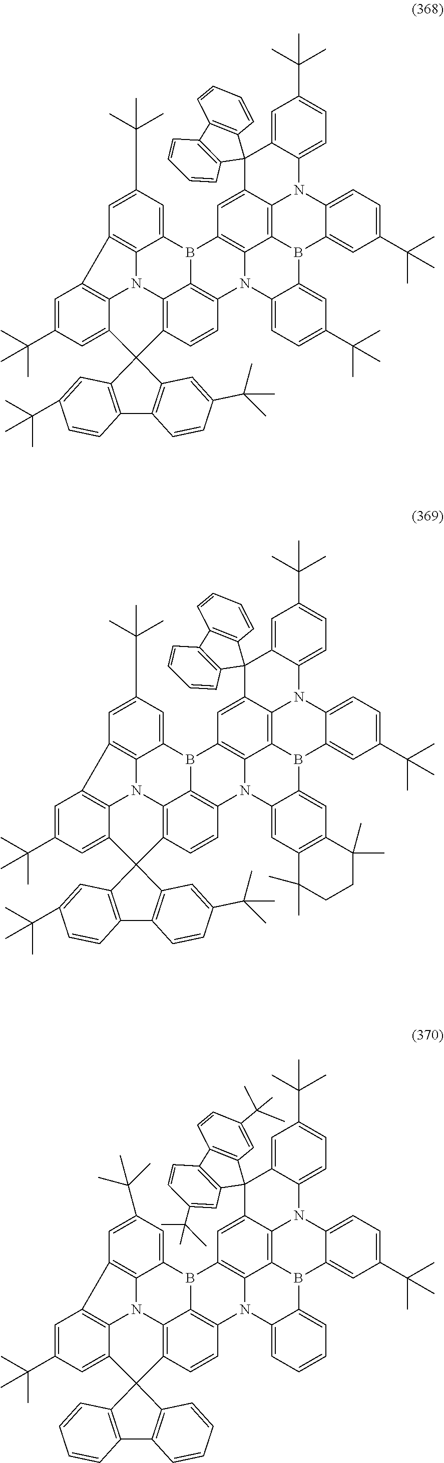

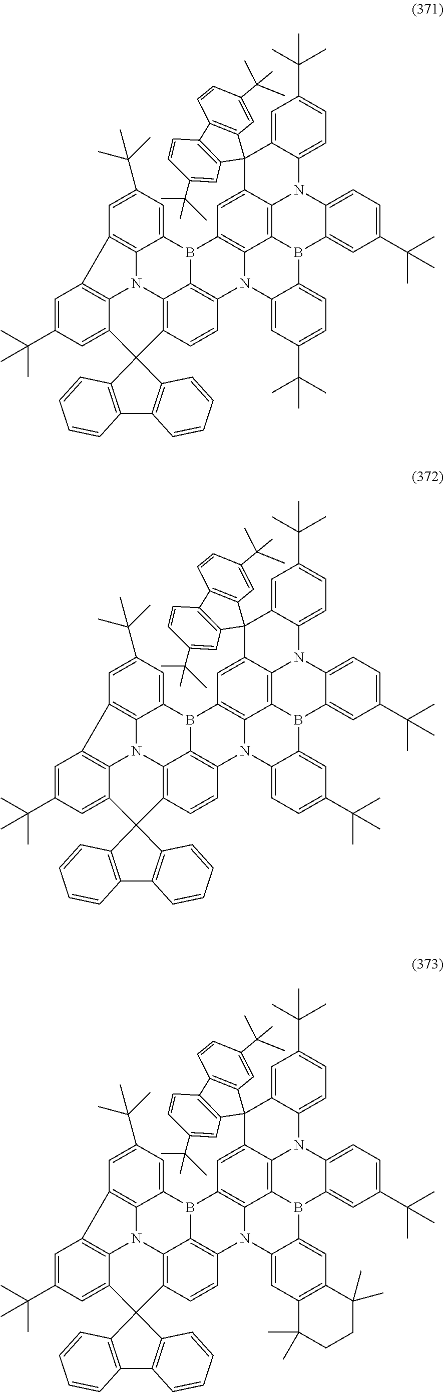

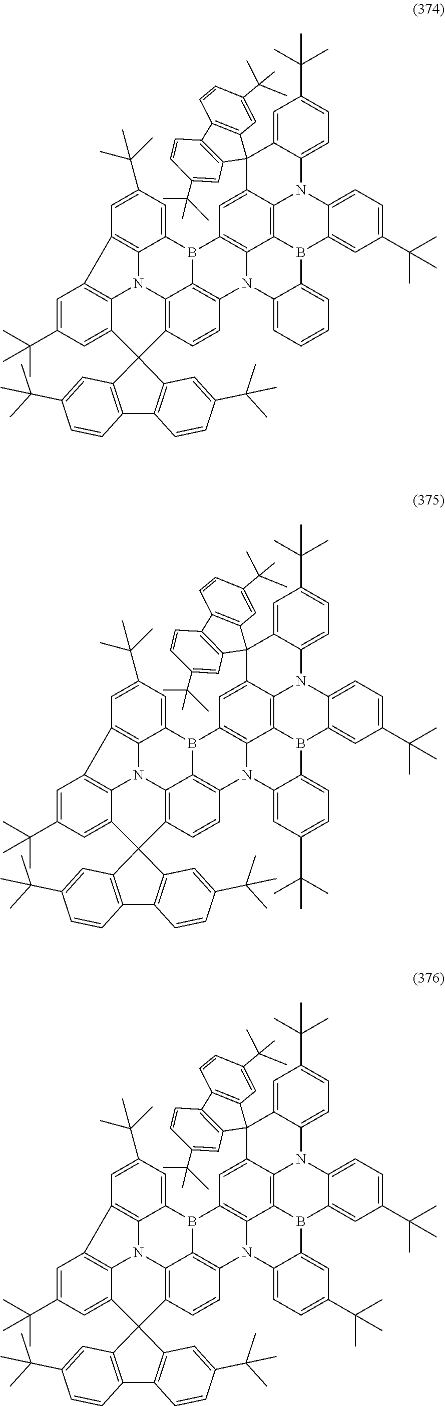

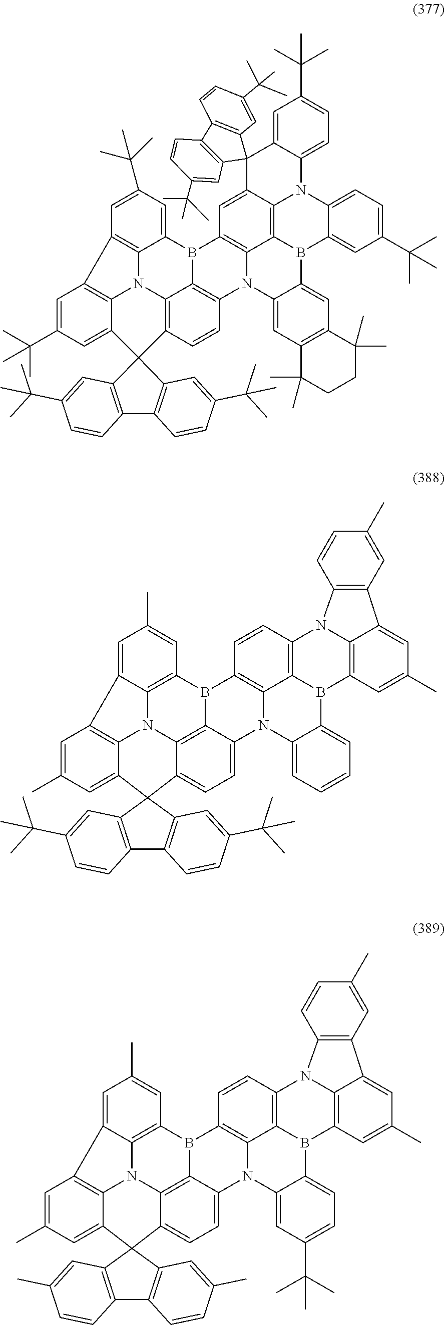

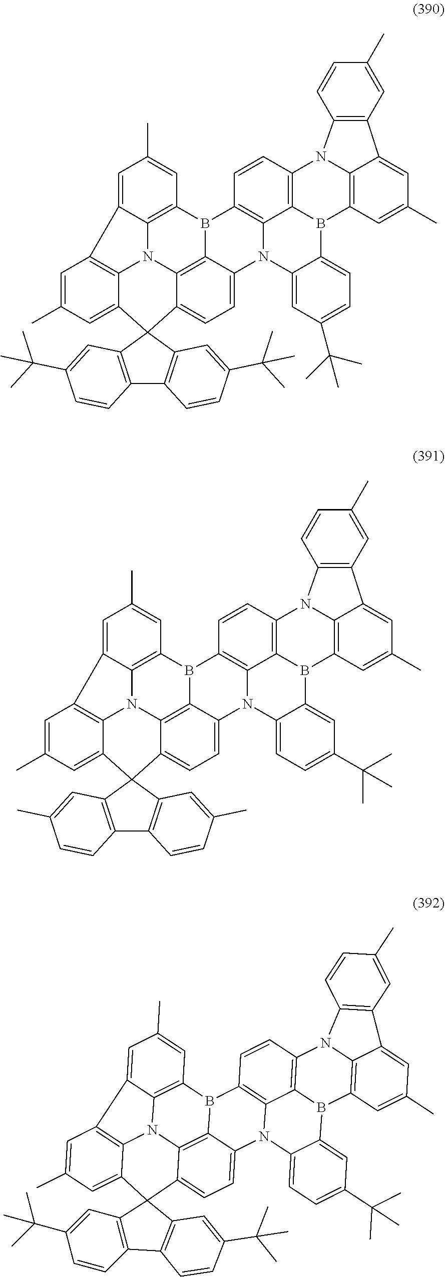

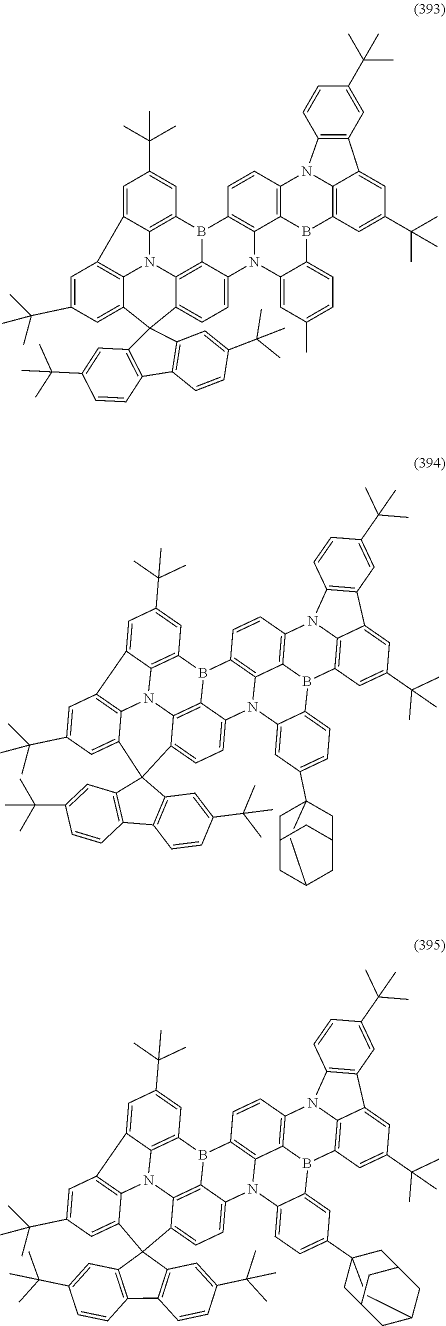

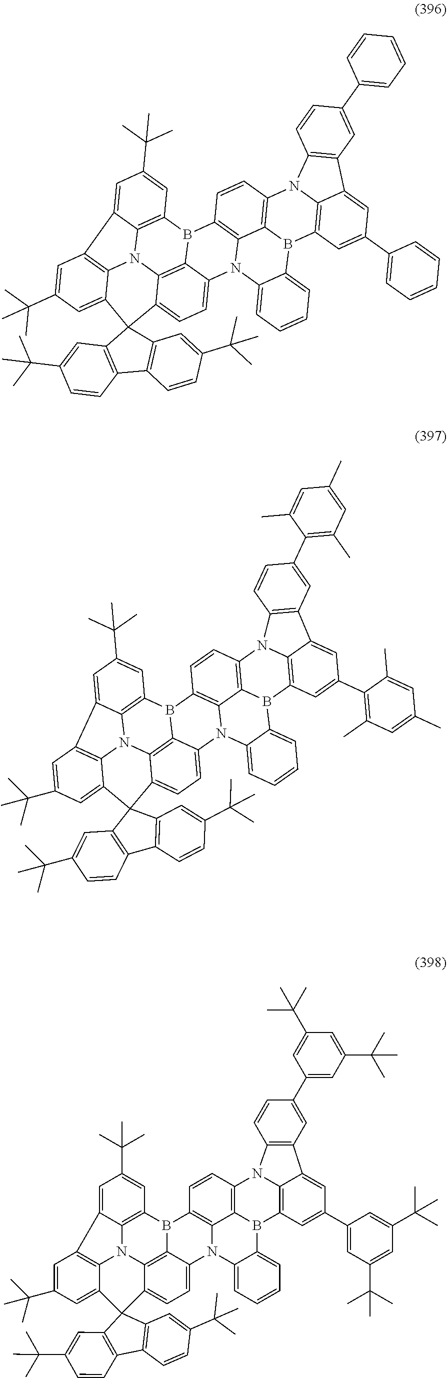

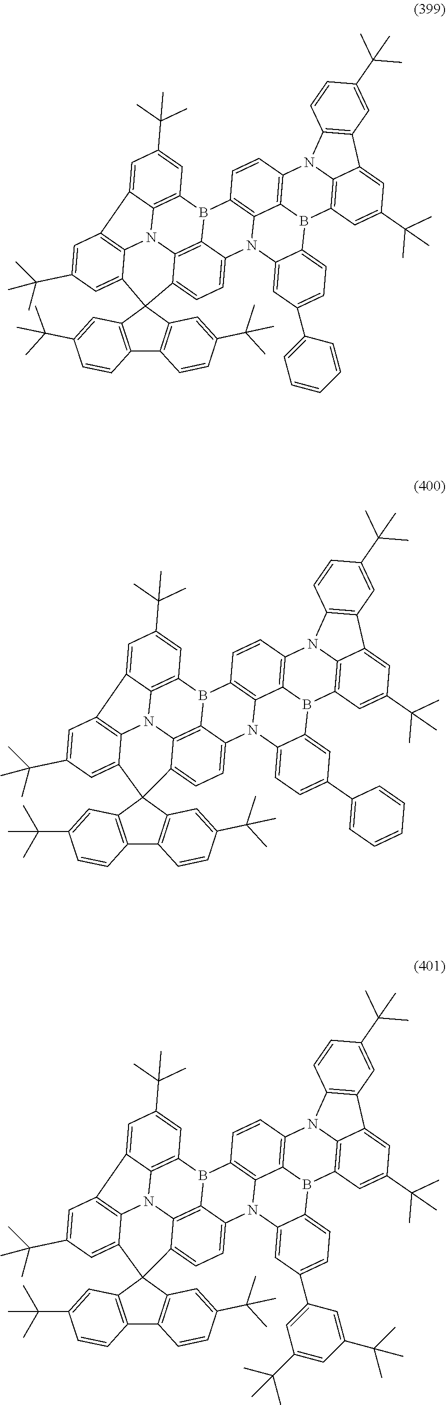

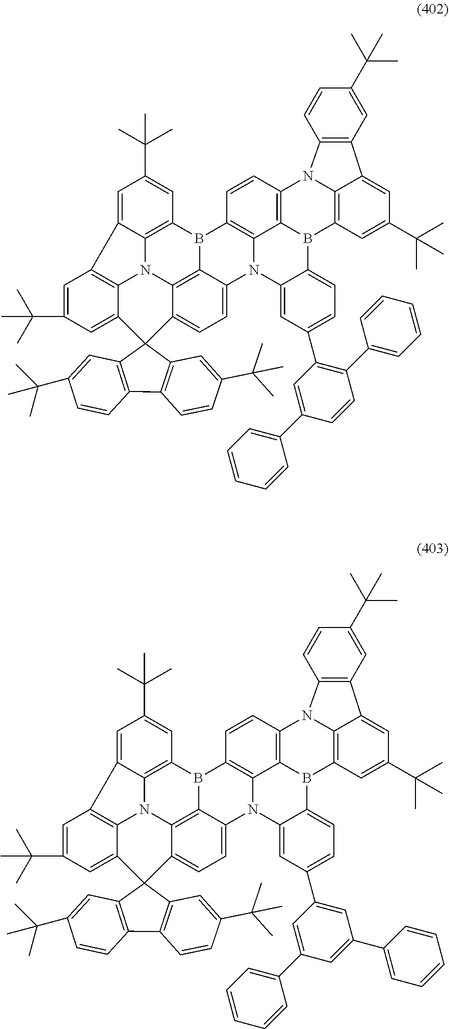

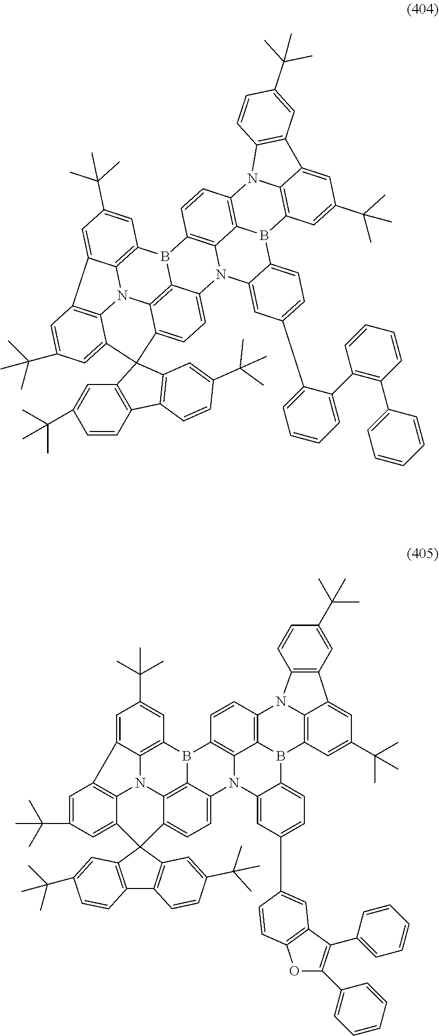

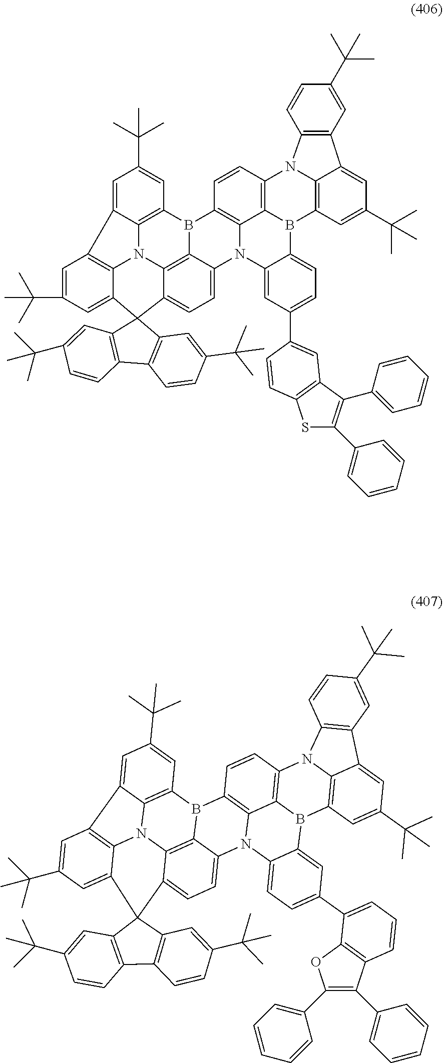

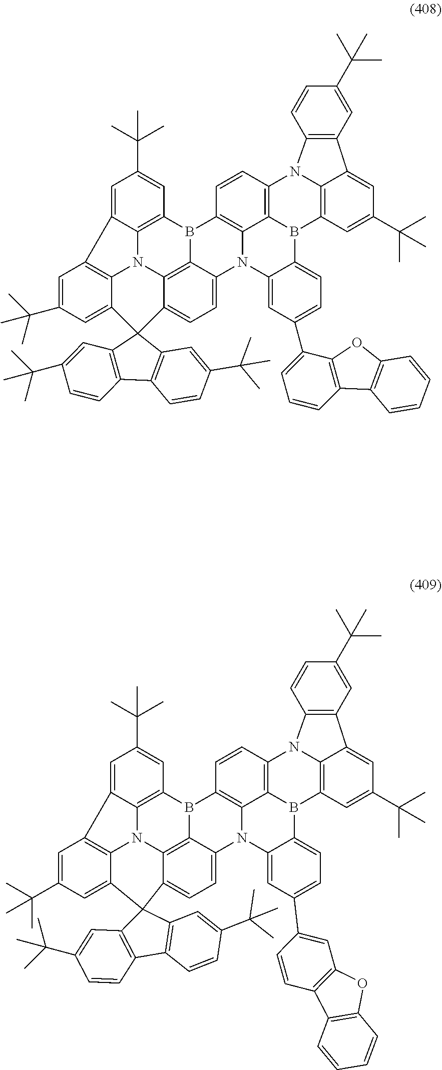

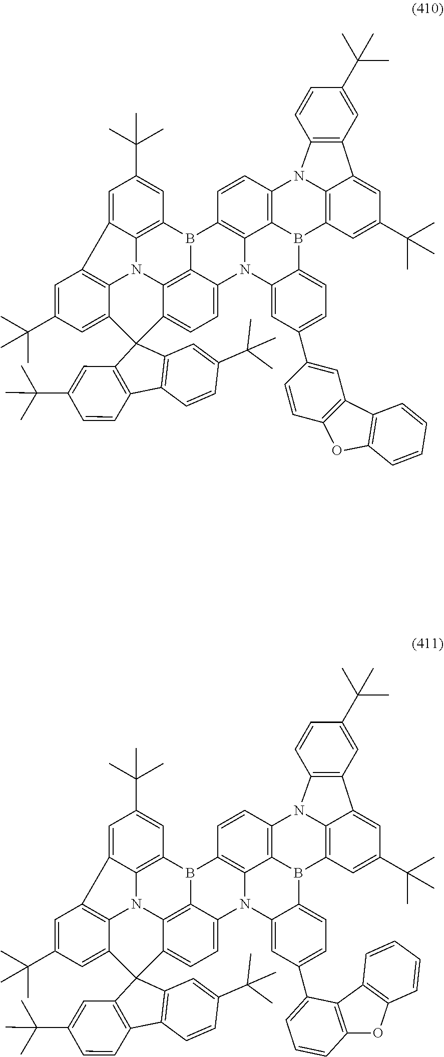

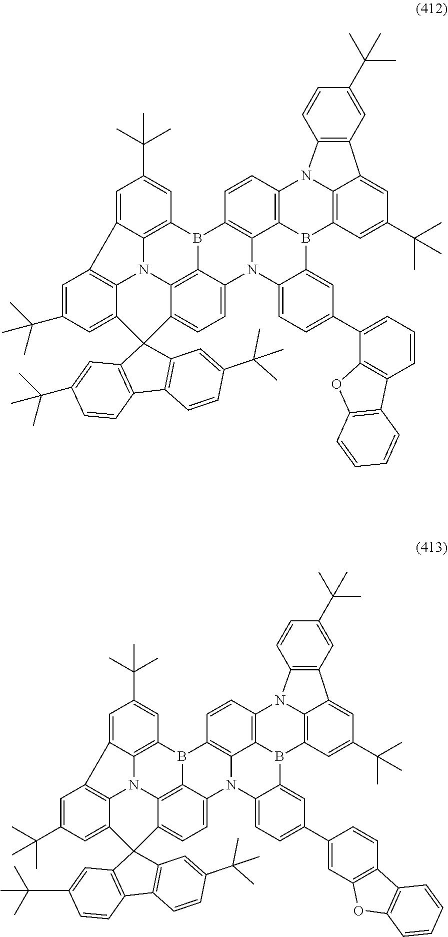

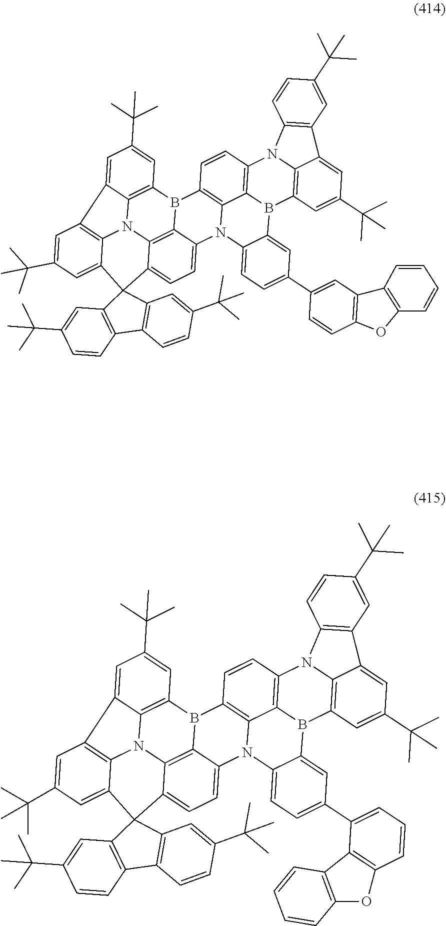

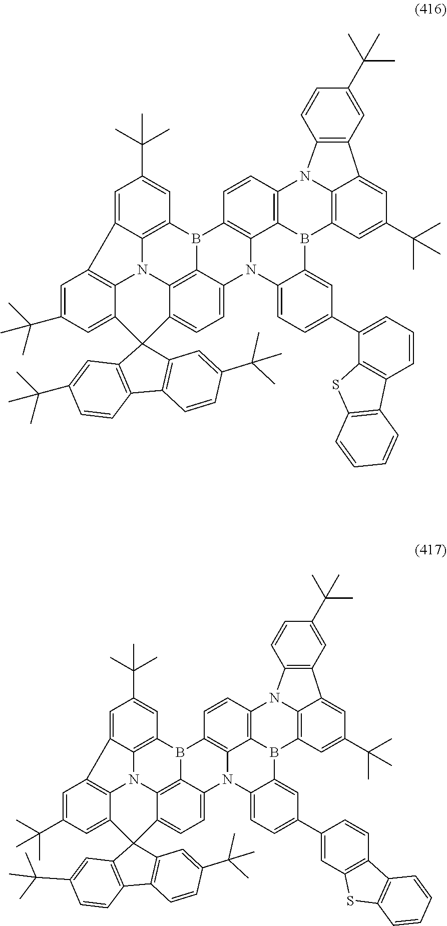

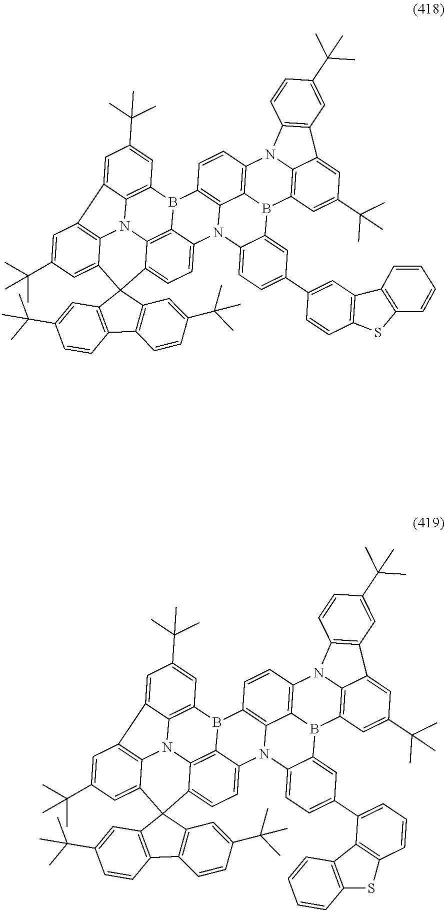

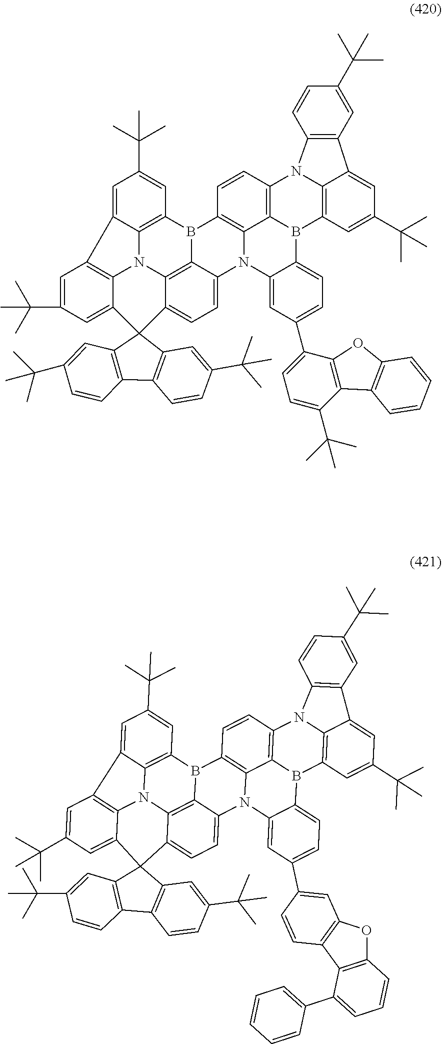

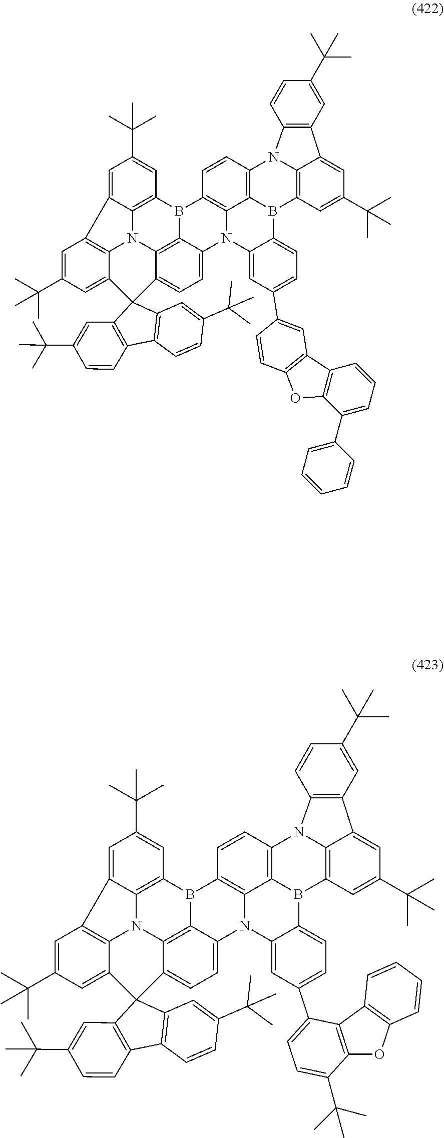

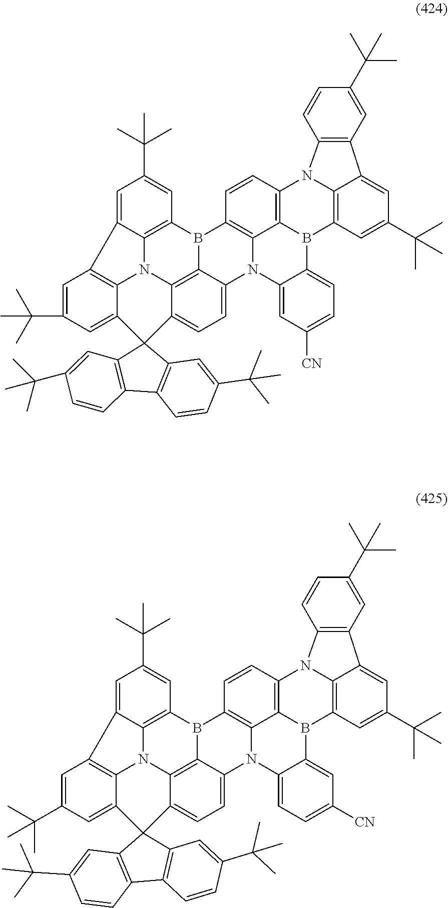

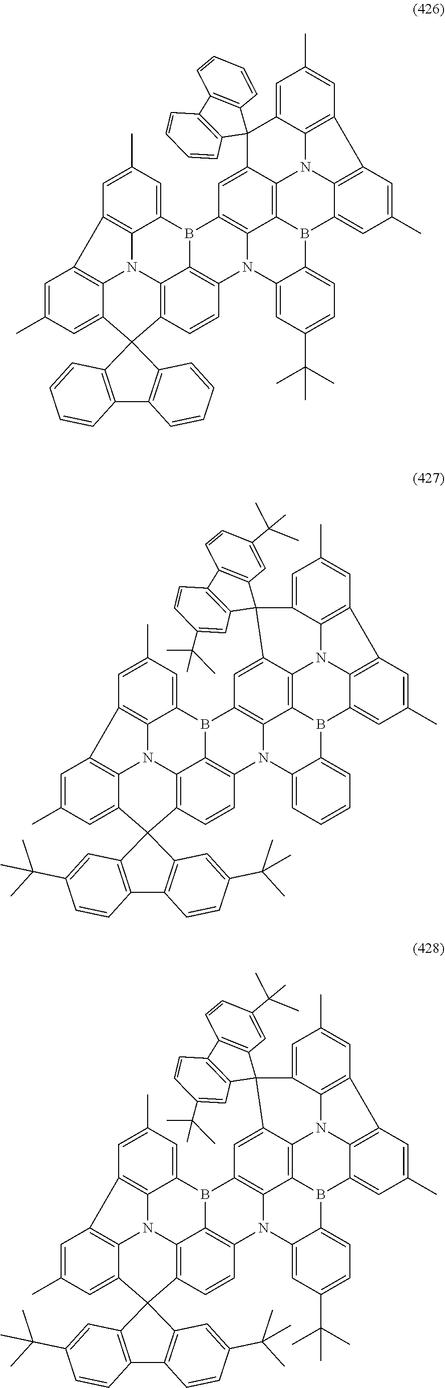

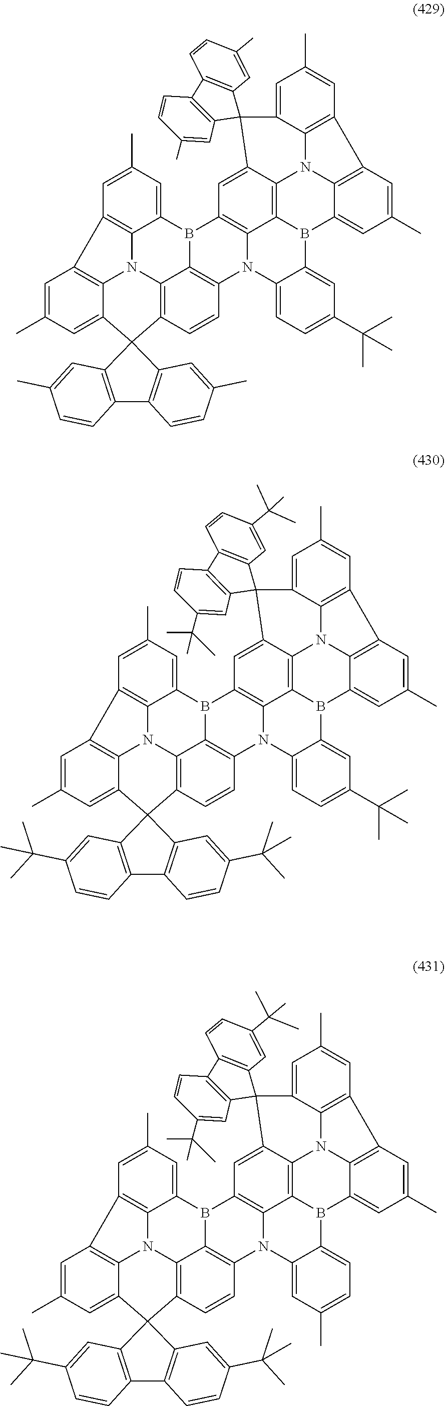

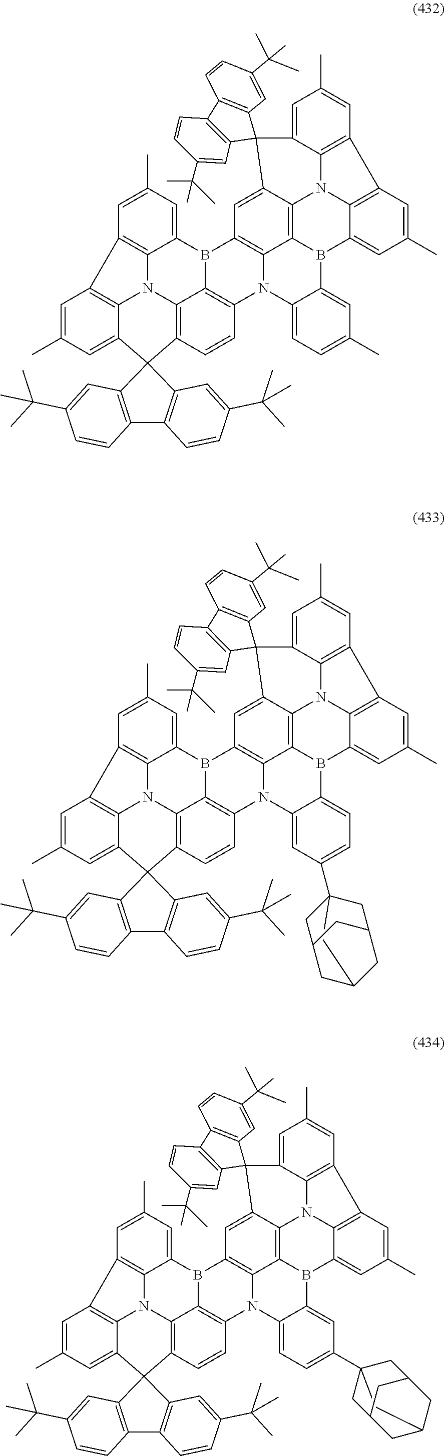

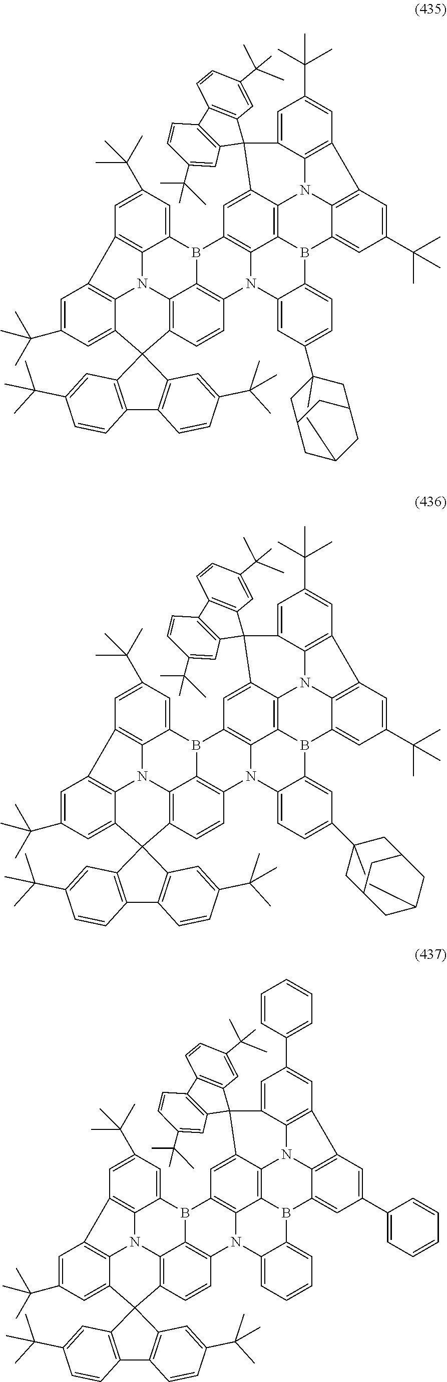

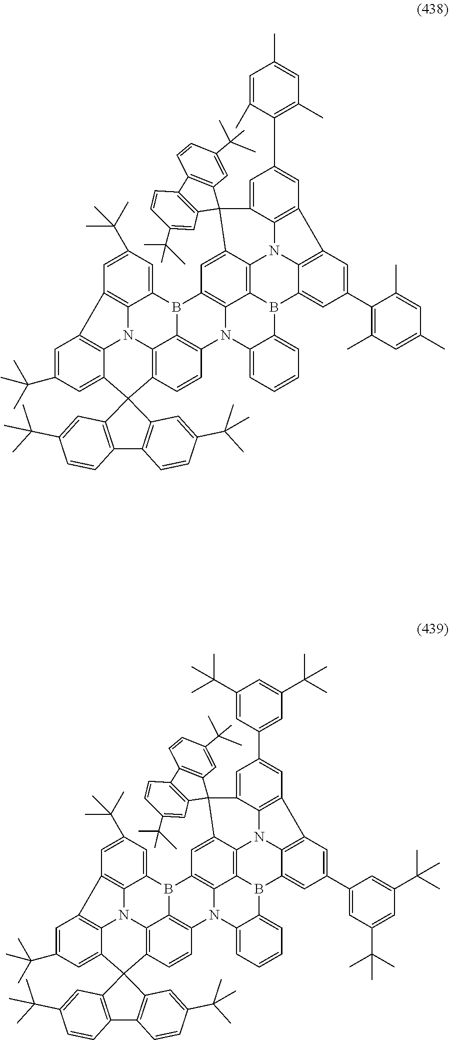

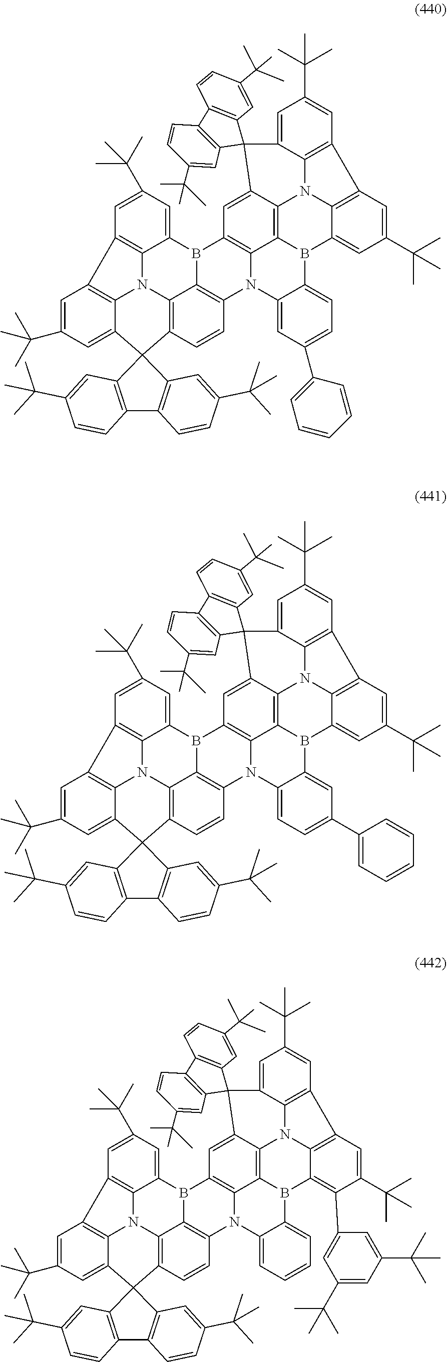

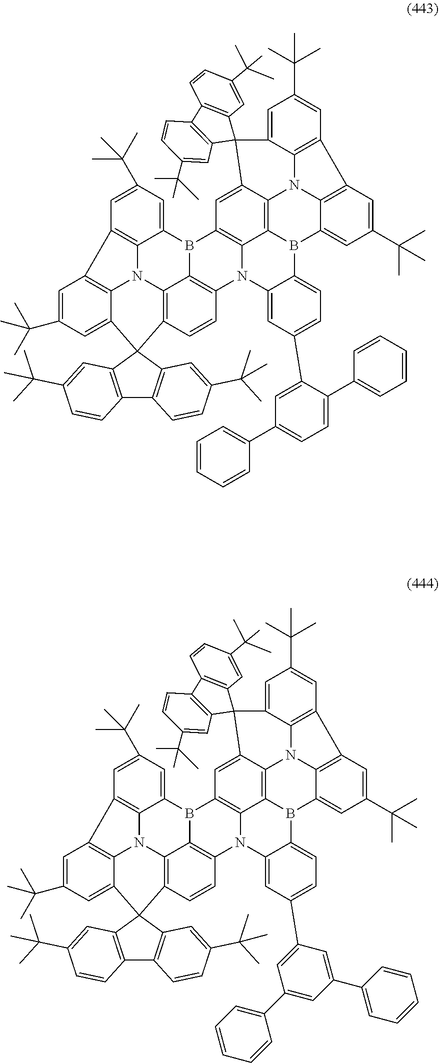

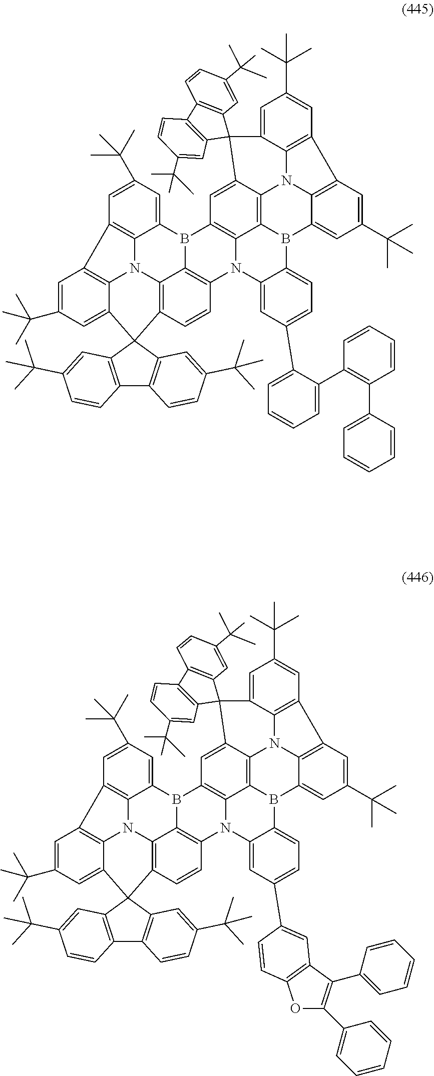

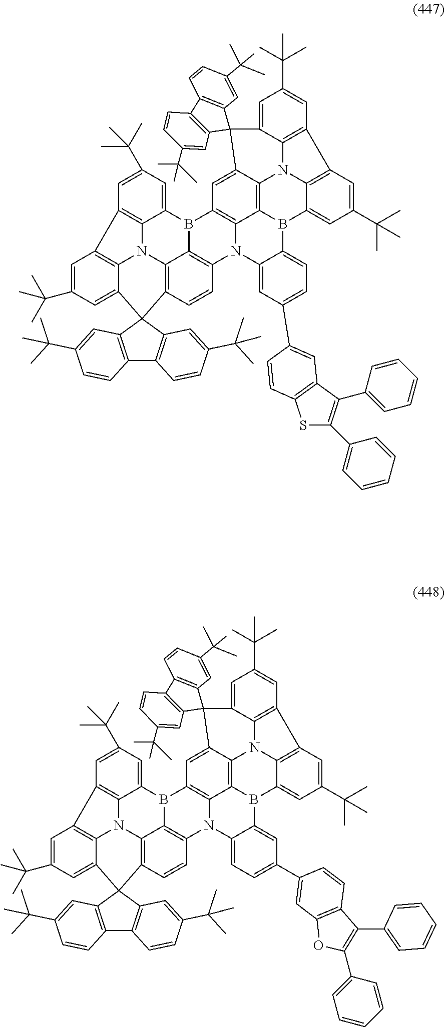 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1cc2c4c5c1N3c1cc(-c3ccc6sc(-c7ccccc7)c(-c7ccccc7)c6c3)ccc1B5c1cc(C(C)(C)C)cc3c5cc(C(C)(C)C)cc(c5n-4c13)C21c2cc(C(C)(C)C)ccc2-c2ccc(C(C)(C)C)cc21 ; CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1cc2c4c5c1N3c1ccc(-c3ccc6c(-c7ccccc7)c(-c7ccccc7)oc6c3)cc1B5c1cc(C(C)(C)C)cc3c5cc(C(C)(C)C)cc(c5n-4c13)C21c2cc(C(C)(C)C)ccc2-c2ccc(C(C)(C)C)cc21]

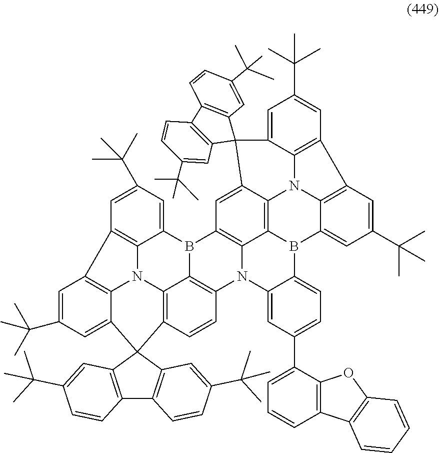 [SMILES: CC(C)(C)c1ccc2c(c1)C1(c3cc(C(C)(C)C)ccc3-2)c2ccc3c4c2-n2c5c(cc(C(C)(C)C)cc5c5cc(C(C)(C)C)cc1c52)B4c1cc2c4c5c1N3c1cc(-c3cccc6c3oc3ccccc36)ccc1B5c1cc(C(C)(C)C)cc3c5cc(C(C)(C)C)cc(c5n-4c13)C21c2cc(C(C)(C)C)ccc2-c2ccc(C(C)(C)C)cc21]

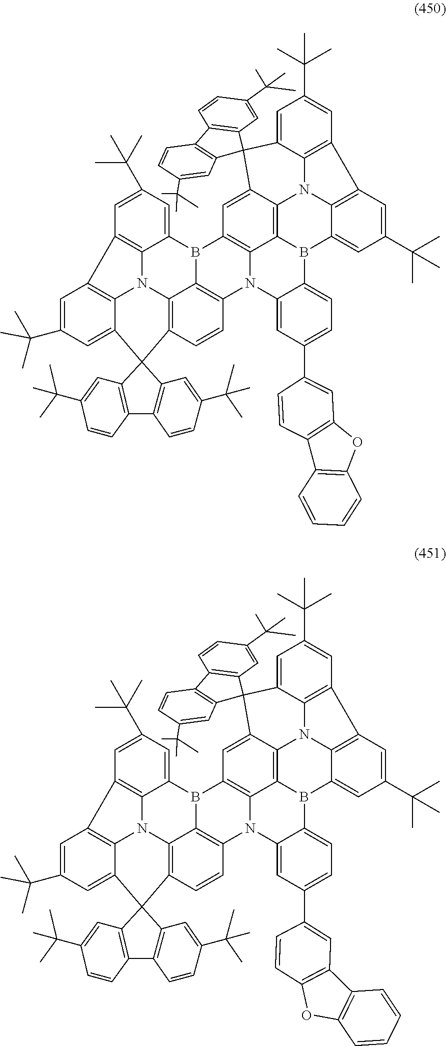

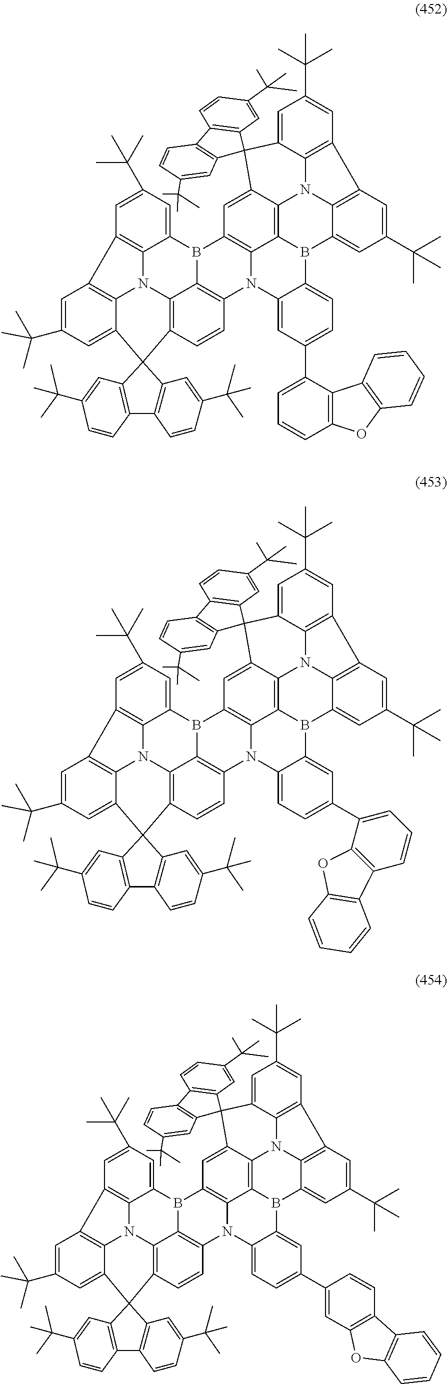

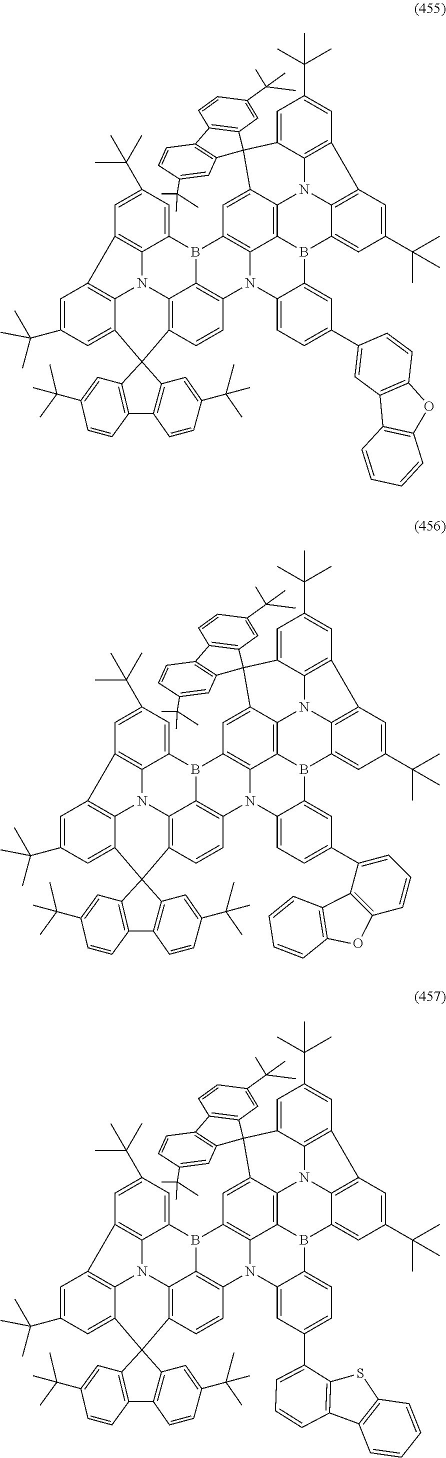

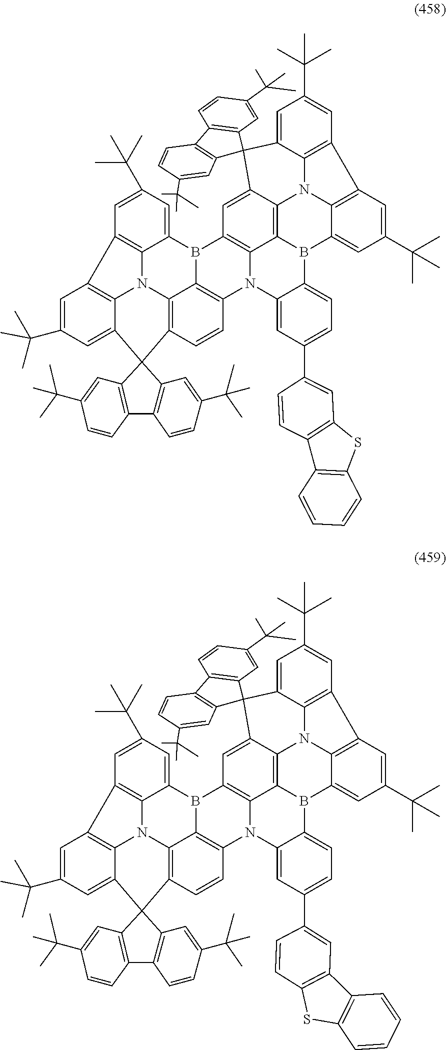

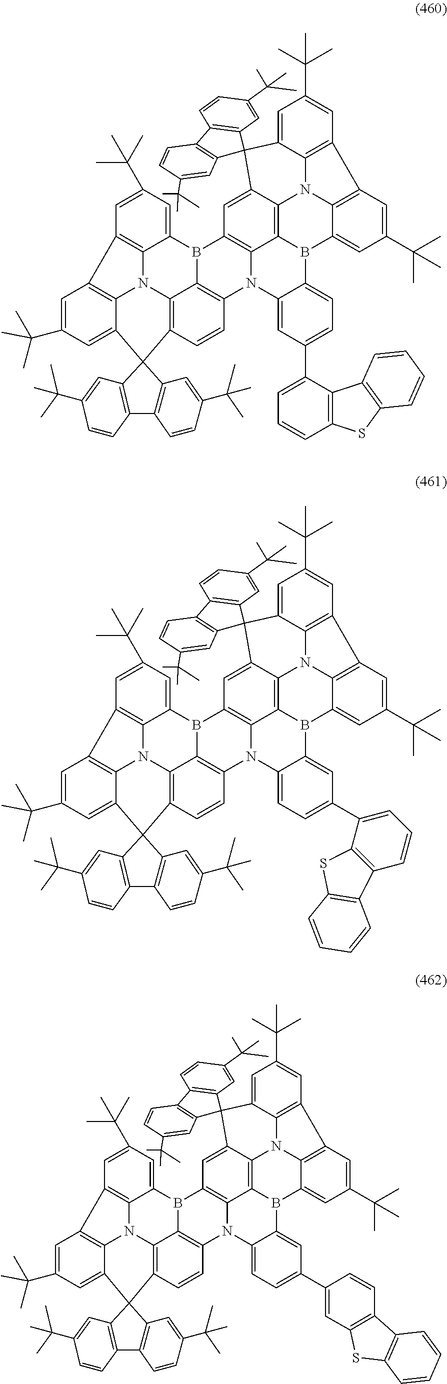

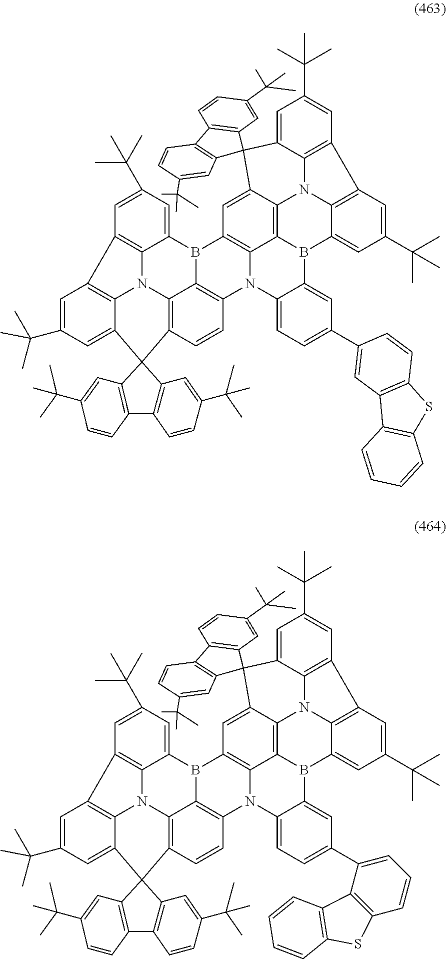

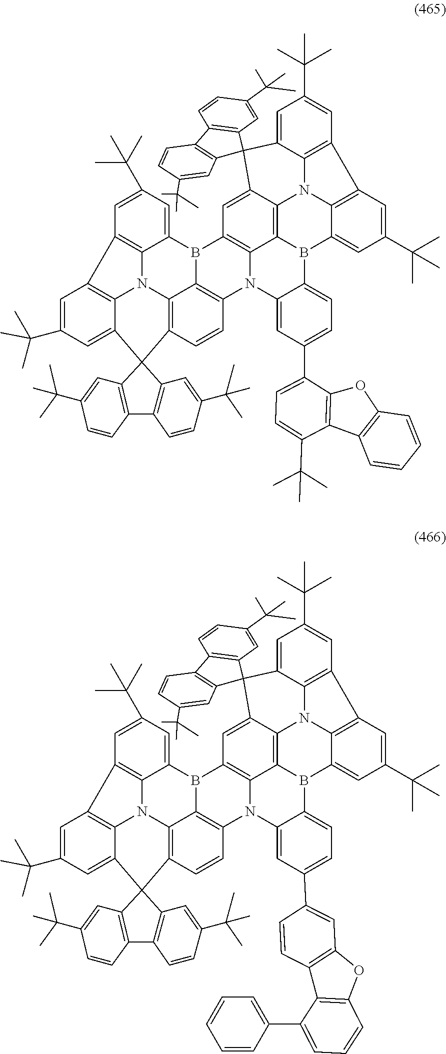

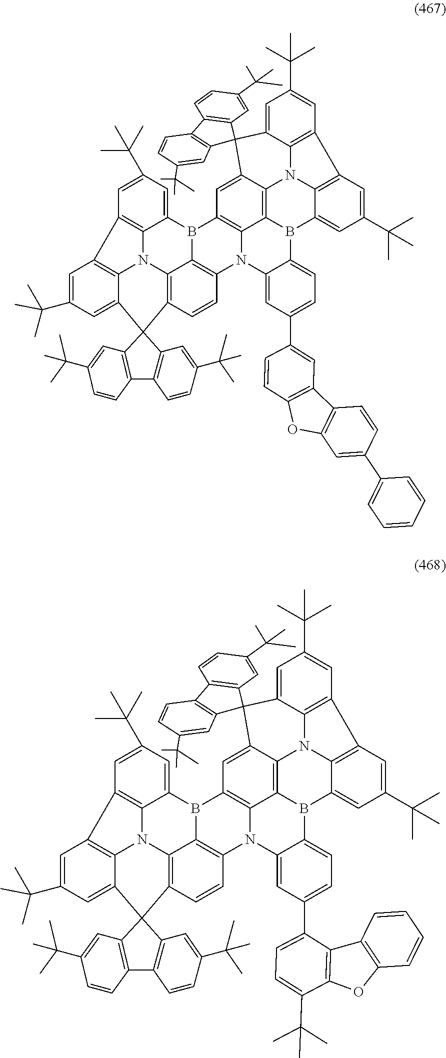 [SMILES: CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4cc(-c5ccc6oc7cc(-c8ccccc8)ccc7c6c5)ccc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32 ; CC(C)(C)c1cc2c3c(c1)c1cc(C(C)(C)C)cc4c1n3-c1c3c(ccc1[C@]41c4cc(C(C)(C)C)ccc4-c4ccc(C(C)(C)C)cc41)N1c4cc(-c5ccc(C(C)(C)C)c6oc7ccccc7c56)ccc4B4c5c1c(cc1c5-n5c6c4cc(C(C)(C)C)cc6c4cc(C(C)(C)C)cc(c45)[C@@]14c1cc(C(C)(C)C)ccc1-c1ccc(C(C)(C)C)cc14)B32]

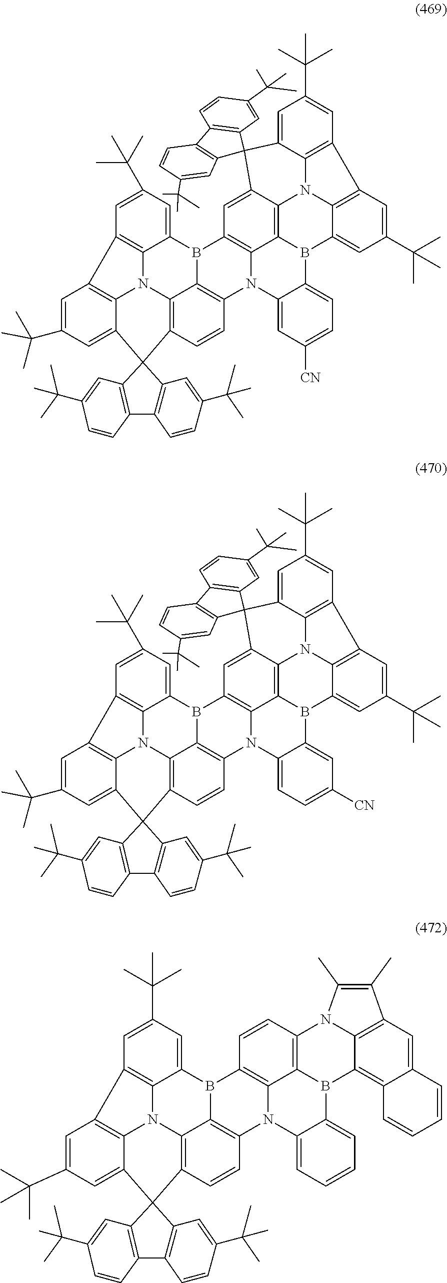

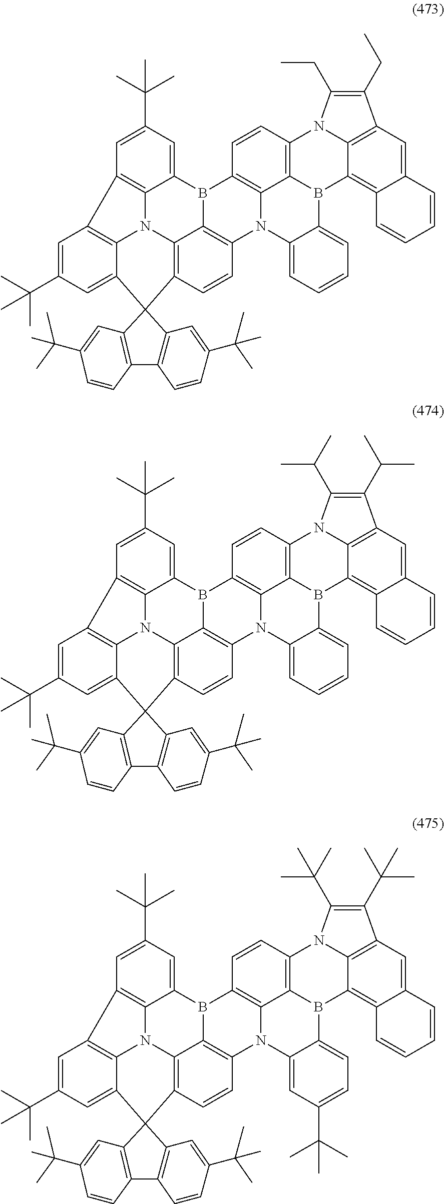 [SMILES: CCc1c(CC)n2c3c(c4ccccc4cc13)B1c3ccccc3N3c4ccc5c6c4B(c4ccc-2c1c43)c1cc(C(C)(C)C)cc2c3cc(C(C)(C)C)cc(c3n-6c12)C51c2cc(C(C)(C)C)ccc2-c2ccc(C(C)(C)C)cc21 ; CC(C)c1c(C(C)C)n2c3c(c4ccccc4cc13)B1c3ccccc3N3c4ccc5c6c4B(c4ccc-2c1c43)c1cc(C(C)(C)C)cc2c3cc(C(C)(C)C)cc(c3n-6c12)C51c2cc(C(C)(C)C)ccc2-c2ccc(C(C)(C)C)cc21 ; CC(C)(C)c1ccc2c(c1)N1c3ccc4c5c3B(c3ccc6c(c31)B2c1c2ccccc2cc2c(C(C)(C)C)c(C(C)(C)C)n-6c12)c1cc(C(C)(C)C)cc2c3cc(C(C)(C)C)cc(c3n-5c12)C41c2cc(C(C)(C)C)ccc2-c2ccc(C(C)(C)C)cc21]

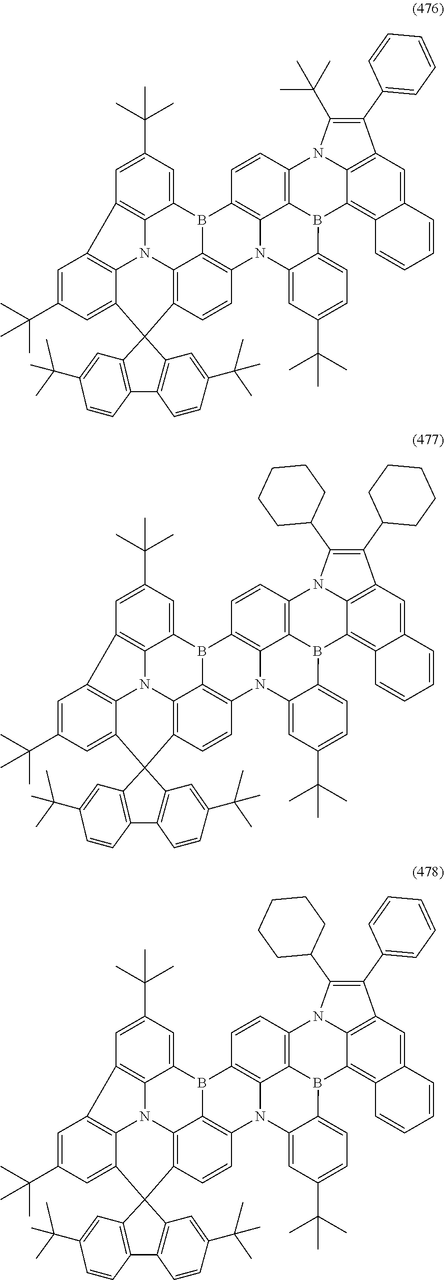

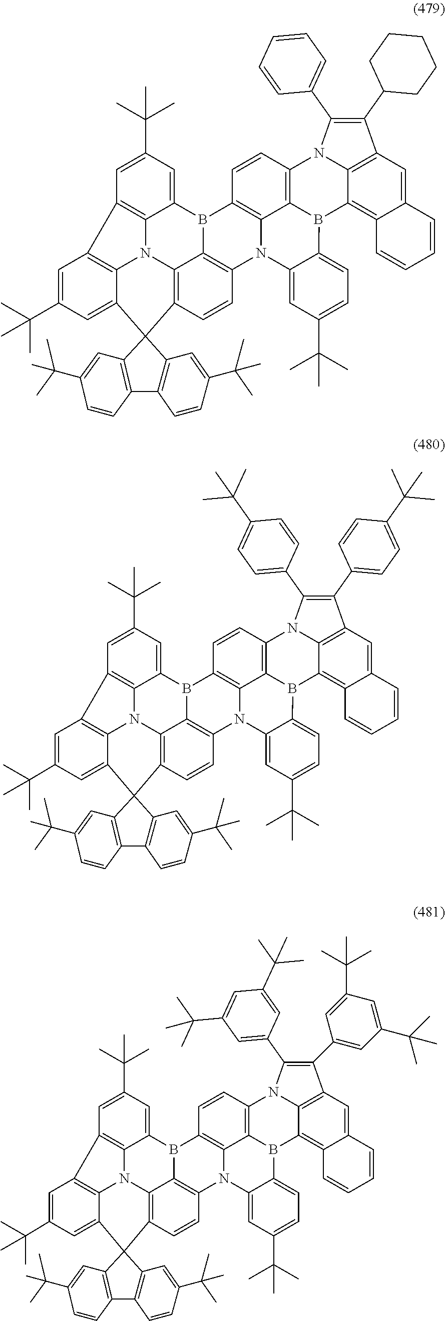

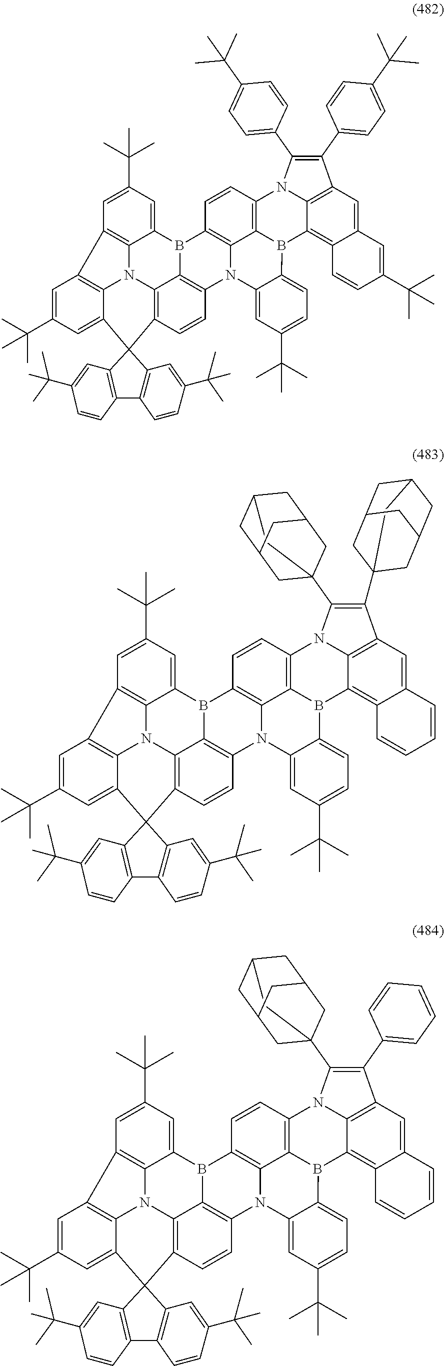

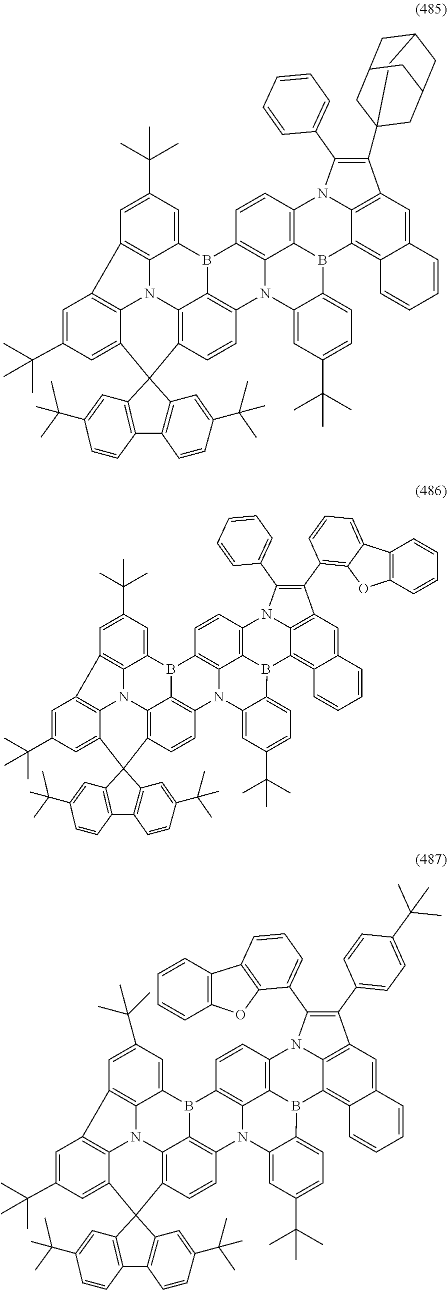

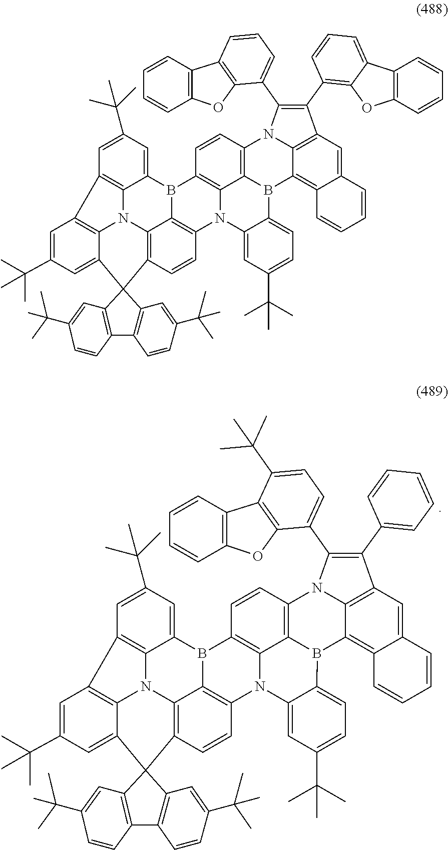 [SMILES: CC(C)(C)c1ccc2c(c1)N1c3ccc4c5c3B(c3ccc6c(c31)B2c1c2ccccc2cc2c(-c3cccc7c3oc3ccccc37)c(-c3cccc7c3oc3ccccc37)n-6c12)c1cc(C(C)(C)C)cc2c3cc(C(C)(C)C)cc(c3n-5c12)C41c2cc(C(C)(C)C)ccc2-c2ccc(C(C)(C)C)cc21 ; CC(C)(C)c1ccc2c(c1)N1c3ccc4c5c3B(c3ccc6c(c31)B2c1c2ccccc2cc2c(-c3ccccc3)c(-c3ccc(C(C)(C)C)c7c3oc3ccccc37)n-6c12)c1cc(C(C)(C)C)cc2c3cc(C(C)(C)C)cc(c3n-5c12)C41c2cc(C(C)(C)C)ccc2-c2ccc(C(C)(C)C)cc21]

23. An organic light-emitting device comprising a substrate, a first electrode, a second electrode and a functional layer in sequence, with the functional layer being located between the first electrode and the second electrode;
the functional layer comprises a light-emitting layer comprising a host material and a doping material, wherein the doping material is the boron-containing resonance-type organic compound of claim 1.

24. An organic light-emitting device comprising a substrate, a first electrode, a second electrode and a functional layer in sequence, with the functional layer being located between the first electrode and the second electrode;
the functional layer comprises a light-emitting layer comprising a first host material, a second host material and a doping material, wherein at least one of the first host material and the second host material is TADF material, and the doping material is the boron-containing resonance-type organic compound of claim 1.

25. An organic light-emitting device comprising a substrate, a first electrode, a second electrode and a functional layer in sequence, with the functional layer being located between the first electrode and the second electrode;
the functional layer comprises a light-emitting layer comprising a host material, an exciton sensitizing material and a doping material, wherein the exciton sensitizing material is a complex containing metal elements, and the doping material is the boron-containing resonance-type organic compound of claim 1.
